(19) United States
(12) Patent Application Publication
(10) Pub. No.: US 2023/0146532 A1
(43) Pub. Date: May 11, 2023

(54) LIGHT EMITTING DEVICE

(71) Applicant: Samsung Display Co., Ltd., Yongin-si (KR)

(72) Inventors: MUN-KI SIM, Seoul (KR); TAEIL KIM, Hwaseong-si (KR); SUN YOUNG PAK, Suwon-si (KR); JUNHA PARK, Gwacheon-si (KR); JANG YEOL BAEK, Yongin-si (KR); Kyoung SUNWOO, Hwaseong-si (KR); CHANSEOK OH, Seoul (KR); MINJUNG JUNG, Hongcheon-gun (KR)

(21) Appl. No.: 17/874,110

(22) Filed: Jul. 26, 2022

(30) Foreign Application Priority Data
Oct. 7, 2021 (KR) 10-2021-0133150

(51) Int. Cl. C07F 5/02; H01L 51/50; H01L 51/00

(52) U.S. Cl. CPC C07F 5/027; H01L 51/5056; H01L 51/008; H01L 51/0073; H01L 51/0059; H01L 51/0087; H01L 51/5072; C07B 2200/05

(57) ABSTRACT

A light emitting device that includes a first electrode, a second electrode opposite to the first electrode, and an emission layer between the first electrode and the second electrode is provided. The emission layer includes a first compound, and at least one of a second compound, a third compound, or a fourth compound. Improved emission efficiency properties are obtained.

### CROSS-REFERENCE TO RELATED APPLICATION

This application claims priority to and the benefit of Korean Patent Application No. 10-2021-0133150, filed on Oct. 7, 2021, the entire content of which is hereby incorporated by reference.

### BACKGROUND

### 1. Field

One or more embodiments of the present disclosure herein relate to a light emitting device, and for example, to a light emitting device including multiple materials including a fused polycyclic compound utilized as a light emitting material in an emission layer.

### 2. Description of the Related Art

Recently, the development of an organic electroluminescence display as an image display is being actively conducted. The organic electroluminescence display is different from a liquid crystal display and may be referred to as a self-luminescent display in which holes and electrons injected from a first electrode and a second electrode recombine in an emission layer so that a light emitting material including an organic compound in the emission layer emits light to achieve a display.

In the application of an organic electroluminescence device to a display, the decrease of a driving voltage, and the increase of emission efficiency and the life of the organic electroluminescence device are desired, and development on materials for an organic electroluminescence device stably achieving the desired requirements is being continuously sought.

For example, recently, in order to achieve an organic electroluminescence device with high efficiency, techniques on phosphorescence emission which use energy in a triplet state or delayed fluorescence emission which use the generating phenomenon of singlet excitons by the collision of triplet excitons (triplet-triplet annihilation, TTA) are being developed, and development on a material for thermally activated delayed fluorescence (TADF) utilizing delayed fluorescence phenomenon is being conducted.

### SUMMARY

Aspects of one or more embodiments of the present disclosure are directed to a light emitting device having improved (increased) emission efficiency and device life.

Aspects of one or more embodiments of the present disclosure are direct to a fused polycyclic compound which may improve the emission efficiency and device life of a light emitting device.

An embodiment of the present disclosure provides a light emitting device including a first electrode, a second electrode oppositely disposed to the first electrode, and an emission layer between the first electrode and the second electrode, wherein the emission layer may include a first compound represented by Formula 1, and include at least one of a second compound represented by Formula H-1, a third compound represented by Formula H-2, or a fourth compound represented by Formula D-2.

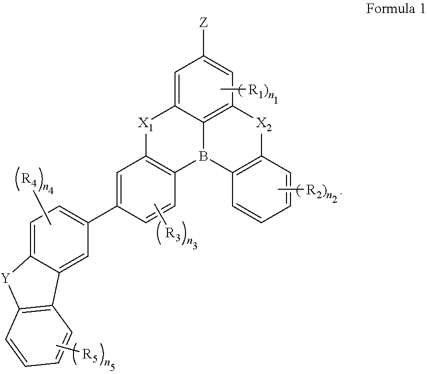

In Formula 1, X₁ and X₂ may each independently be NR₆, O, or S, where at least one of X₁ or X₂ is NR₆, Y is NR₇, O, or S, Z is a substituted or unsubstituted t-butyl group, a substituted or unsubstituted aryl group of 6 to 30 ring-forming carbon atoms, or a substituted or unsubstituted heteroaryl group of 2 to 30 ring-forming carbon atoms, R₁ to R₇ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, n₁ is an integer of 0 to 2, n₂ and n₅ may each independently be an integer of 0 to 4, and n₃ and n₄ may each independently be an integer of 0 to 3.

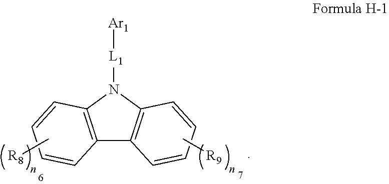

In Formula H-1, L₁ is a direct linkage, a substituted or unsubstituted arylene group of 6 to 30 ring-forming carbon atoms, or a substituted or unsubstituted heteroarylene group of 2 to 30 ring-forming carbon atoms, Ar₁ is a substituted or unsubstituted aryl group of 6 to 30 ring-forming carbon atoms, or a substituted or unsubstituted heteroaryl group of 2 to 30 ring-forming carbon atoms, R₈ and R₉ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and n₆ and n₇ may each independently be an integer of 0 to 4.

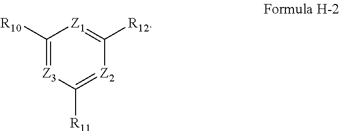

In Formula H-2, at least one of Z₁ to Z₃ is N, and the remainder are CR₁₃, and R₁₀ to R₁₃ may each independently be a hydrogen atom, a deuterium atom, a cyano group, a substituted or unsubstituted silyl group, a substituted or unsubstituted aryl group of 6 to 30 ring-forming carbon atoms, or a substituted or unsubstituted heteroaryl group of 2 to 30 ring-forming carbon atoms.

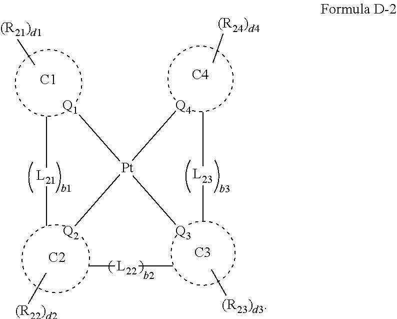

In Formula D-2, Q₁ to Q₄ may each independently be C or N, C1 to C4 may each independently be a substituted or unsubstituted hydrocarbon ring of 5 to 30 ring-forming carbon atoms, or a substituted or unsubstituted heterocycle of 2 to 30 ring-forming carbon atoms, L₂₁ to L₂₃ may each independently be a direct linkage, *—O—*, *—S—*,

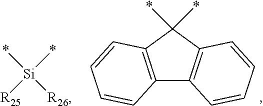

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, b1 to b3 may each independently be 0 or 1, R₂₁ to R₂₆ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 1 to 30 ring-forming carbon atoms, and/or combined with an adjacent group to form a ring, and d1 to d4 may each independently be an integer of 0 to 4.

In an embodiment, the emission layer may emit delayed fluorescence.

In an embodiment, the emission layer may include the first compound, the second compound, and/or the third compound.

In an embodiment, the emission layer may include the first compound, the second compound, the third compound, and/or the fourth compound.

In an embodiment, the emission layer may emit light having a light emitting central wavelength of about 430 nm to about 490 nm.

In an embodiment, the first compound represented by Formula 1 may be represented by any one of Formula 2-1 to Formula 2-4.

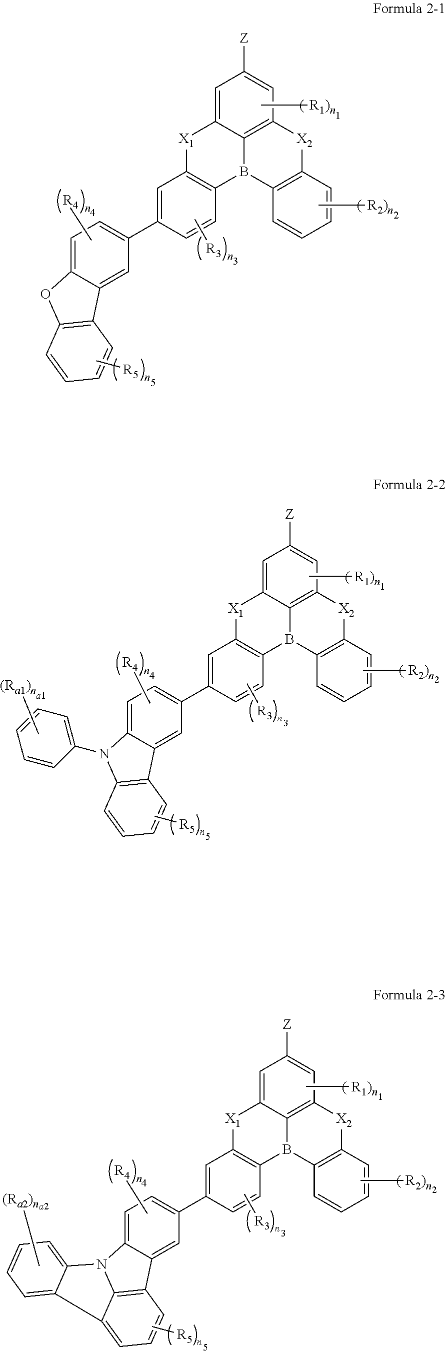

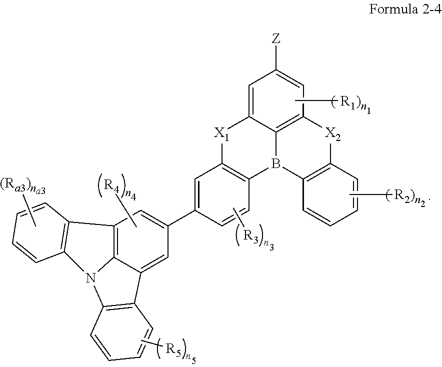

In Formula 2-1 to Formula 2-4, Rₐ₁ to Rₐ₃ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, nₐ₁ is an integer of 0 to 5, nₐ₂ and nₐ₃ may each independently be an integer of 0 to 4, n_{a4′} is an integer of 0 to 2, and n_{a5′} is an integer of 0 to 3.

In Formula 2-1 to Formula 2-4, for X₁, X₂, Z, R₁ to R₇, and n₁ to n₅ the substituents and values in Formula 1 may be used.

In an embodiment, the first compound represented by Formula 1 may be represented by any one of Formula 3-1 to Formula 3-3.

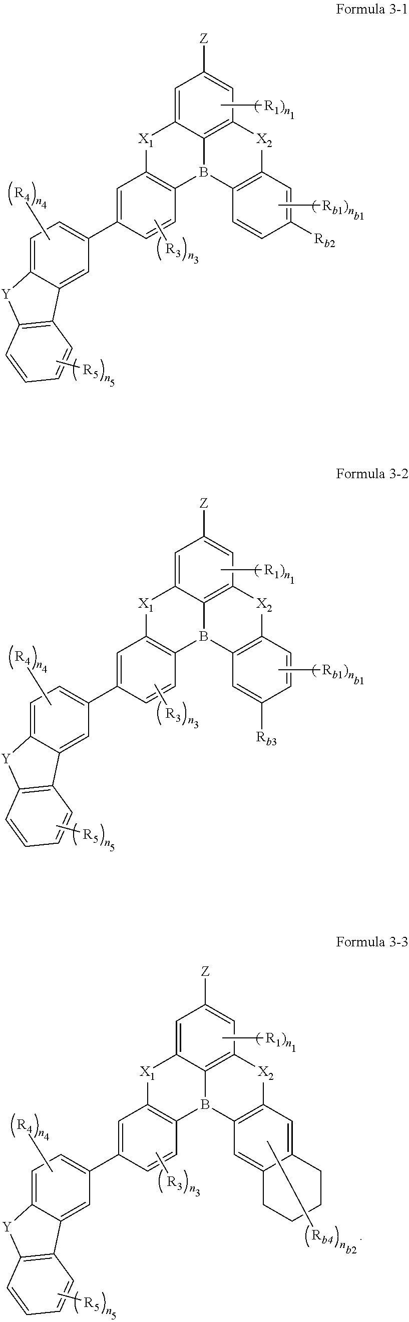

In Formula 3-1 to Formula 3-3, R_{b1} to R_{b4} may each independently be a hydrogen atom, a deuterium atom, a halogen atom, a cyano group, a substituted or an unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, n_{b1} is an integer of 0 to 3, and n_{b2} is an integer of 0 to 10.

In Formula 3-1 to Formula 3-3, for X₁, X₂, Y, Z, R₁, R₃ to R₇, n₁, and n₃ to n₅ the substituents and values in Formula 1 may be used.

In an embodiment, the first compound represented by Formula 1 may be represented by any one of Formula 3-1-1 to Formula 3-3-1.

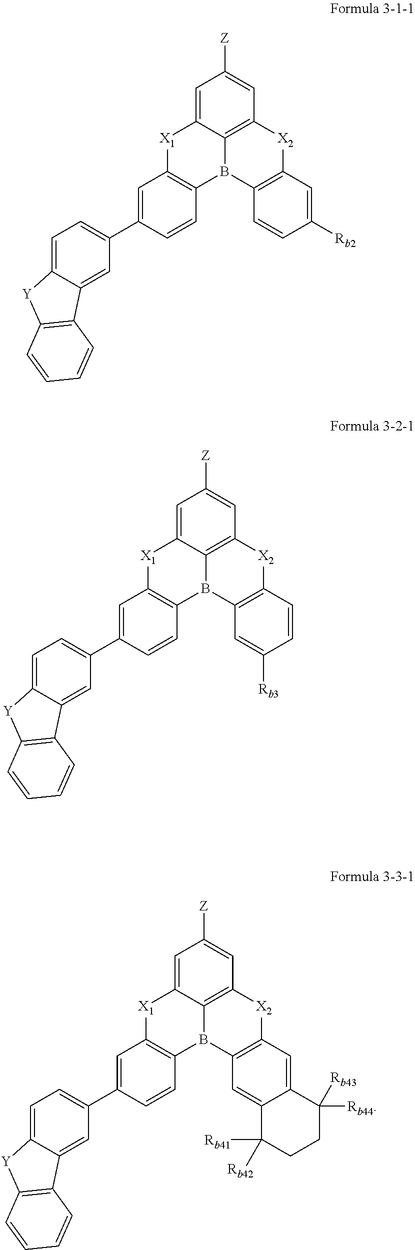

In Formula 3-1-1 to Formula 3-3-1, R_{b41} to R_{b44} may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula 3-1-1 to Formula 3-3-1, for X₁, X₂, Y, Z, R₆, R₇, R_{b2} and R_{b3} the substituents in Formula 1 and Formula 3-1 to Formula 3-3 may be used.

In an embodiment, in Formula 3-1, R_{b2} may be a substituted or unsubstituted amine group, a substituted or unsubstituted phenyl group, a substituted or unsubstituted dibenzofuran group, a substituted or unsubstituted carbazole group, or a substituted or unsubstituted indolocarbazole group, in Formula 3-2, R_{b3} may be a substituted or unsubstituted t-butyl group, or a substituted or unsubstituted phenyl group, and in Formula 3-3, R_{b4} may be a hydrogen atom, a deuterium atom, or a substituted or unsubstituted methyl group.

In an embodiment, the first compound represented by Formula 1 may be represented by Formula 4.

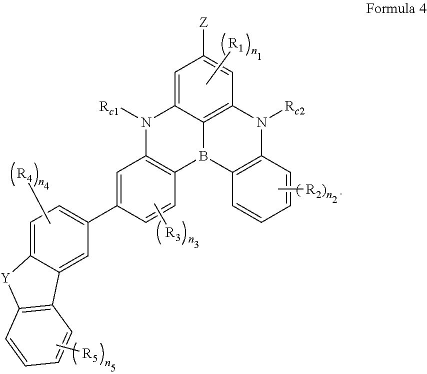

In Formula 4, R_{c1} and R_{c2} may each independently be a substituted or unsubstituted aryl group of 6 to 30 ring-forming carbon atoms, or a substituted or unsubstituted heteroaryl group of 2 to 30 ring-forming carbon atoms.

In Formula 4, for Y, Z, R₁ to R₇, and n₁ to n₅ the substituents in Formula 1 may be used.

In an embodiment, in Formula 4, each of R_{c1} and R_{c2} may be represented by any one of Formula 5-1 to Formula 5-6.

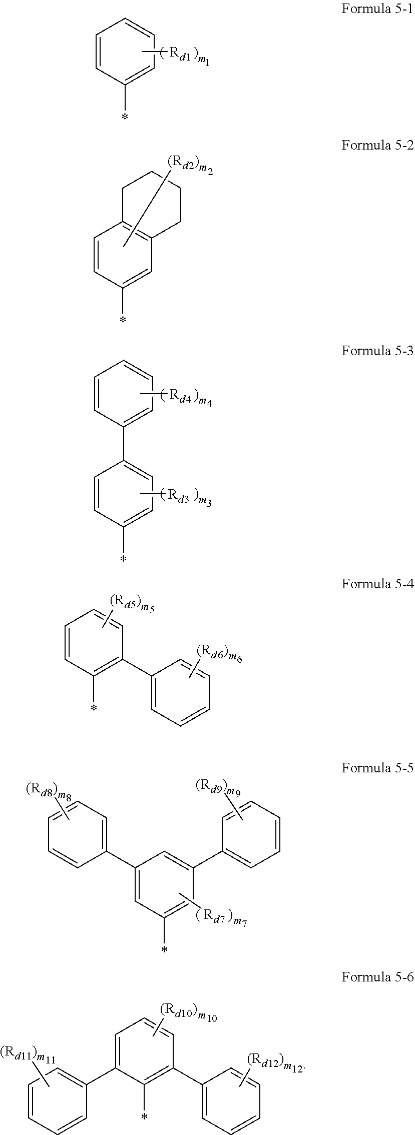

In Formula 5-1 to Formula 5-6, R_{d1} to R_{d12} may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, m₁, m₄, m₆, m₈, m₉, m₁₁ and m₁₂ may each independently be an integer of 0 to 5, m₂ is an integer of 0 to 11, m₃ and m₅ may each independently be an integer of 0 to 4, and m₇ and m₁₀ may each independently be an integer of 0 to 3.

In an embodiment, the first compound represented by Formula 1 may be represented by any one of Formula 6-1 to Formula 6-5.

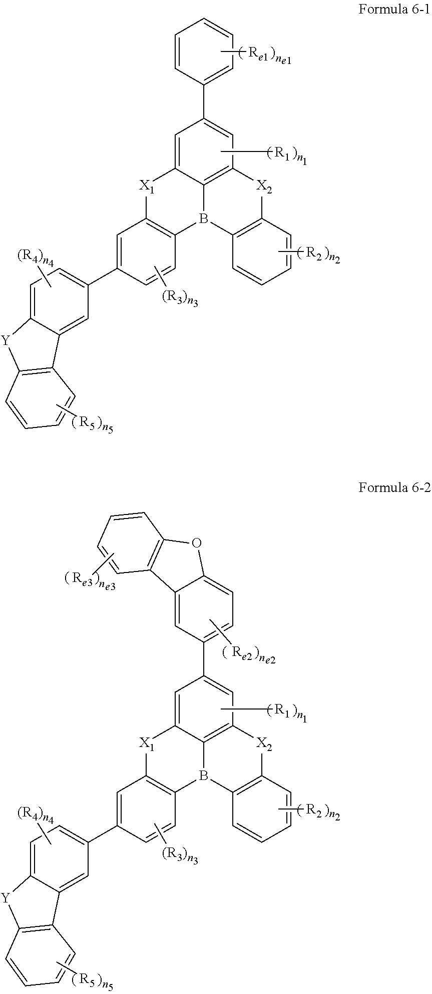

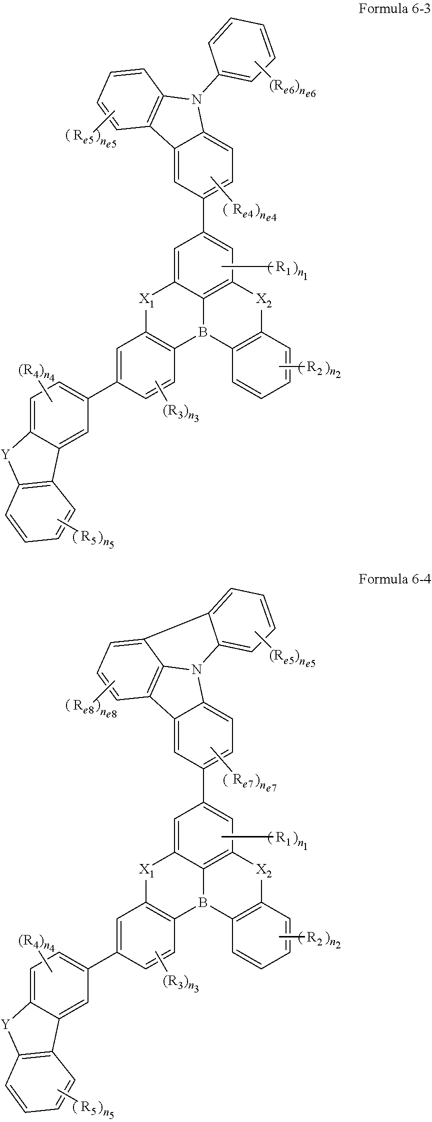

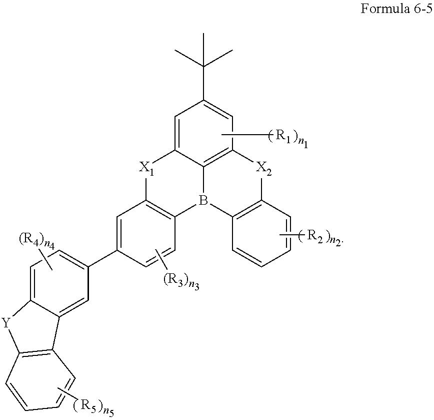

In Formula 6-1 to Formula 6-5, Rₑ₁ to Rₑ₉ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, nₑ₁ and nₑ₆ may each independently be an integer of 0 to 5, nₑ₂, nₑ₄, nₑ₇ and nₑ₈ may each independently be an integer of 0 to 3, and nₑ₃, nₑ₅ and nₑ₉ may each independently be an integer of 0 to 4.

In Formula 6-1 to Formula 6-5, X₁, X₂, Y, R₁ to R₇, and n₁ to n₅ may each independently be the same as defined in Formula 1.

In an embodiment, the light emitting device may further include a capping layer on the second electrode, and the capping layer may have a refractive index of about 1.6 or more.

According to an embodiment of the present disclosure, a light emitting device may include a first electrode, a hole transport region on the first electrode, an emission layer on the hole transport region, an electron transport region on the emission layer, and a second electrode on the electron transport region, wherein the emission layer may include a first compound represented by Formula 1, and the hole transport region may include a hole transport compound represented by Formula H-a.

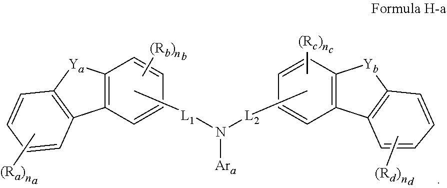

In Formula H-a, Yₐ and Y_{b} may each independently be CRₑR_{f}, NR_{g}, O, or S, Ara is a substituted or unsubstituted aryl group of 6 to 30 ring-forming carbon atoms, or a substituted or unsubstituted heteroaryl group of 2 to 30 ring-forming carbon atoms, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms, Rₐ to R_{g} may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, nₐ and n_{d} may each independently be an integer of 0 to 4, and n_{b} and n_{c} may each independently be an integer of 0 to 3.

The fused polycyclic compound according to an embodiment of the present disclosure may be represented by Formula 1.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a plan view of a display apparatus according to an embodiment of the present disclosure;

FIG. 2 is a cross-sectional view of a display apparatus according to an embodiment of the present disclosure;

FIG. 3 is a cross-sectional view schematically showing a light emitting device according to an embodiment of the present disclosure;

FIG. 4 is a cross-sectional view schematically showing a light emitting device according to an embodiment of the present disclosure;

FIG. 5 is a cross-sectional view schematically showing a light emitting device according to an embodiment of the present disclosure;

FIG. 6 is a cross-sectional view schematically showing a light emitting device according to an embodiment of the present disclosure;

FIG. 7 is a cross-sectional view of a display apparatus according to an embodiment of the present disclosure;

FIG. 8 is a cross-sectional view of a display apparatus according to an embodiment of the present disclosure;

FIG. 9 is a cross-sectional view showing a display apparatus according to an embodiment of the present disclosure; and

FIG. 10 is a cross-sectional view showing a display apparatus according to an embodiment of the present disclosure.

### DETAILED DESCRIPTION

The present disclosure may have one or more suitable modifications and may be embodied in different forms, and example embodiments will be explained in more detail with reference to the accompanying drawings. The present disclosure may, however, be embodied in different forms and should not be construed as limited to the embodiments set forth herein. Rather, all modifications, equivalents, and substituents which are included in the spirit and technical scope of the present disclosure should be included in the present disclosure.

Like reference numerals refer to like elements throughout, and duplicative descriptions thereof may not be provided. In the drawings, the dimensions of structures may be exaggerated for clarity of illustration. It will be understood that, although the terms first, second, etc. may be utilized herein to describe one or more suitable elements, these elements should not be limited by these terms. These terms are only utilized to distinguish one element from another element. Thus, a first element could be termed a second element without departing from the teachings of the present disclosure. Similarly, a second element could be termed a first element. As utilized herein, the singular forms are intended to include the plural forms as well, unless the context clearly indicates otherwise.

In the description, it will be further understood that the terms “comprises,” “includes,” and/or “comprising,” “including,” when utilized in this specification, specify the presence of stated features, numerals, steps, operations, elements, parts, or the combination thereof, but do not preclude the presence or addition of one or more other features, numerals, steps, operations, elements, parts, or the combination thereof.

In the description, when a layer, a film, a region, a plate, etc. is referred to as being “on” or “above” another part, it can be “directly on” the other part, or intervening layers may also be present. In contrast, when a layer, a film, a region, a plate, etc. is referred to as being “under” or “below” another part, it can be “directly under” the other part, or intervening layers may also be present. Also, when an element is referred to as being disposed “on” another element, it can be disposed under the other element.

In the description, the term “substituted or unsubstituted” corresponds to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In some embodiments, each of the exemplified substituents may be substituted or unsubstituted. For example, a biphenyl group may be interpreted as an aryl group or a phenyl group substituted with a phenyl group.

In the description, the term “forming a ring via the combination with an adjacent group” may refer to forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In some embodiments, the ring formed via the combination with an adjacent group may be combined with another ring to form a spiro structure.

In the description, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In some embodiments, in 1,2-divinylbenzene, two vinyl groups may be interpreted as “adjacent groups” to each other.

In the disclosure, the halogen atom may be a fluorine atom, a chlorine atom, a bromine atom or an iodine atom.

In the, the alkyl group may be a linear, branched or cyclic type or kind. The carbon number of the alkyl group (e.g., the number of carbon atoms in the alkyl group) may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the disclosure, a cycloalkyl group may refer to a cyclic alkyl group. The carbon number of the cycloalkyl group (e.g., the number of carbon atoms in the cycloalkyl group) may be 3 to 50, 3 to 30, 3 to 20, or 3 to 10. Examples of the cycloalkyl group include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., without limitation.

In the disclosure, an alkenyl group refers to a hydrocarbon group including one or more carbon double bonds in the middle or at the terminal of an alkyl group having a carbon number of 2 or more. The alkenyl group may be a linear chain or a branched chain. The carbon number is not specifically limited, but may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, etc., without limitation.

In the disclosure, a hydrocarbon ring group refers to an arbitrary functional group or substituent derived from an aliphatic hydrocarbon ring. The hydrocarbon ring group may be a saturated hydrocarbon ring group of 5 to 20 ring-forming carbon atoms.

In the disclosure, an aryl group refers to an arbitrary functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the disclosure, a heterocyclic group refers to an arbitrary functional group or substituent derived from a ring including one or more of B, O, N, P, Si, and/or S as heteroatoms. The heterocyclic group includes an aliphatic heterocyclic group and/or an aromatic heterocyclic group. The aromatic heterocyclic group may be a heteroaryl group. The aliphatic heterocyclic group and the aromatic heterocyclic group may be a monocycle or a polycycle.

In the disclosure, a heterocyclic group may include one or more of B, O, N, P, Si, and/or S as heteroatoms. When the heterocyclic group includes two or more heteroatoms, two or more heteroatoms may be the same or different. The heterocyclic group may be a monocyclic heterocyclic group or a polycyclic heterocyclic group, and has the concept including a heteroaryl group. The carbon number for forming rings of the heteroaryl group may be 2 to 30, 2 to 20, or 2 to 10.

In the disclosure, a heteroaryl group may include one or more of B, O, N, P, Si, and/or S as heteroatoms. When the heteroaryl group includes two or more heteroatoms, two or more heteroatoms may be the same or different. The heteroaryl group may be a monocyclic heterocyclic group or polycyclic heterocyclic group. The carbon number for forming rings of the heteroaryl group may be 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the disclosure, a silyl group includes an alkyl silyl group and/or an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the disclosure, a thio group may include an alkyl thio group and/or an aryl thio group. The thio group may refer to the above-defined alkyl group or aryl group combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the disclosure, an oxy group may refer to the above-defined alkyl group or aryl group which is combined with an oxygen atom. The oxy group may include an alkoxy group and/or an aryl oxy group. The alkoxy group may be a linear, branched or cyclic chain. The carbon number of the alkoxy group (e.g., the number of carbon atoms in the alkoxy group) is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, an embodiment of the present disclosure is not limited thereto.

In the disclosure, a boron group may refer to the above-defined alkyl group or aryl group which is combined with a boron atom. The boron group includes an alkyl boron group and/or an aryl boron group. Examples of the boron group include a trimethylboron group, a triethylboron group, a t-butyldimethylboron group, a triphenylboron group, a diphenylboron group, a phenylboron group, etc., without limitation.

In the disclosure, the carbon number of the amine group (e.g., the number of carbon atoms in the group containing the amine) is not specifically limited, but may be 1 to 30. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, a triphenylamine group, etc., without limitation.

In the disclosure, the aryl group in the aryloxy group, arylthio group, arylsulfoxy group, aryl amino group, aryl boron group, and/or aryl silyl group may be the same as the examples of the above-described aryl group.

In the disclosure, a direct linkage may refer to a single bond.

In some embodiments, in the description, “-*” refers to a position to be connected.

Hereinafter, embodiments of the present disclosure will be explained referring to the drawings.

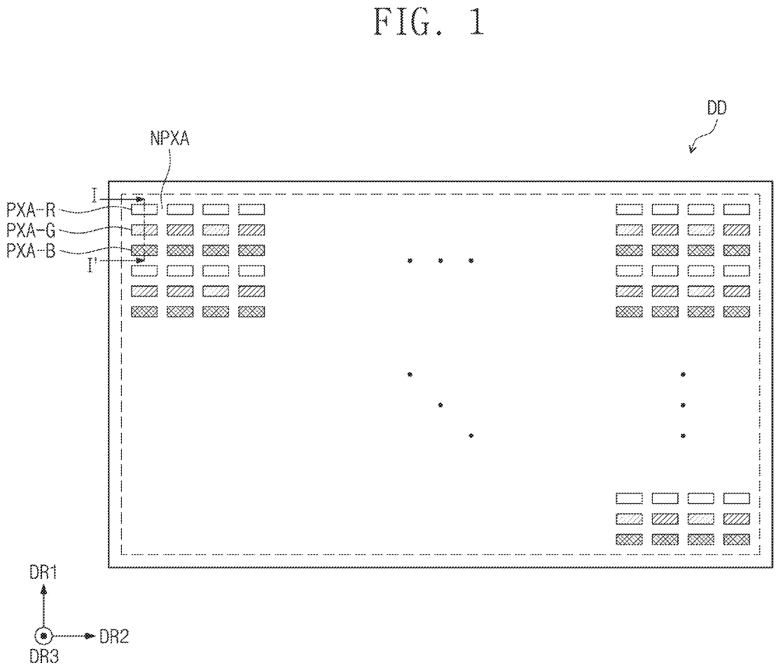

FIG. 1 is a plan view showing an embodiment of a display apparatus DD.

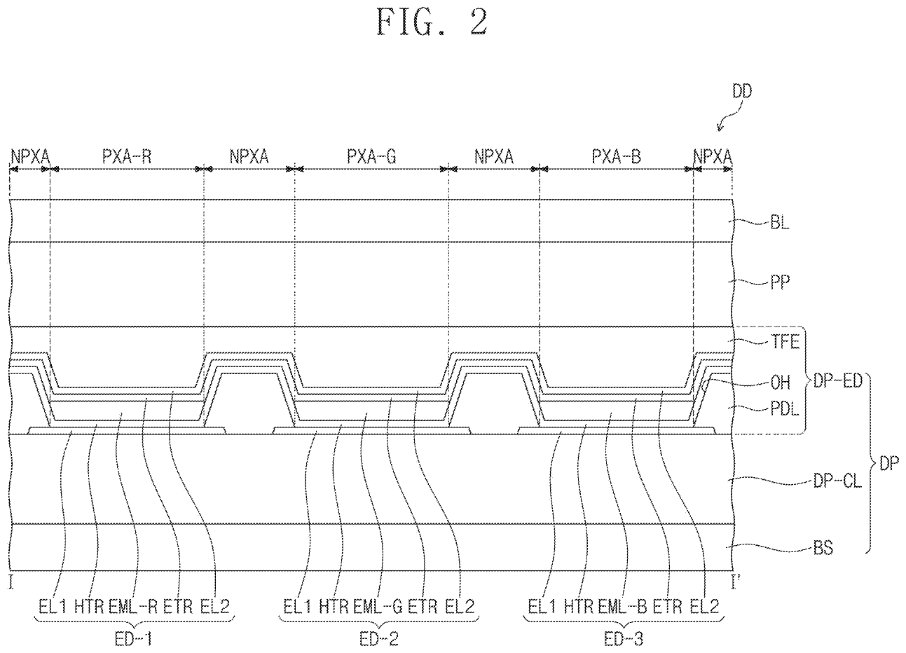

FIG. 2 is a cross-sectional view of a display apparatus DD of an embodiment. FIG. 2 is a cross-sectional view showing a part corresponding to line I-I′.

The display apparatus DD may include a display panel DP and an optical layer PP disposed on the display panel DP. The display panel DP may include light emitting devices ED-1, ED-2 and ED-3. The display apparatus DD may include multiple light emitting devices ED-1, ED-2 and ED-3. The optical layer PP may be disposed on the display panel DP and control reflected light by external light at the display panel DP. The optical layer PP may include, for example, a polarization layer or a color filter layer. In some embodiments, different from the drawings, the optical layer PP may not be provided in the display apparatus DD of an embodiment.

On the optical layer PP, a base substrate BL may be disposed. The base substrate BL may be a member providing a base surface where the optical layer PP is disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, different from the drawings, the base substrate BL may not be provided in an embodiment.

The display apparatus DD according to an embodiment may further include a plugging layer. The plugging layer may be disposed between a display device layer DP-ED and a base substrate BL. The plugging layer may be an organic layer. The plugging layer may include at least one of an acrylic resin, a silicon-based resin and/or an epoxy-based resin.

The display panel DP may include a base layer BS, a circuit layer DP-CL provided on the base layer BS and a display device layer DP-ED. The display device layer DP-ED may include a pixel definition layer PDL, light emitting devices ED-1, ED-2 and ED-3 disposed in the pixel definition layer PDL, and an encapsulating layer TFE disposed on the light emitting devices ED-1, ED-2 and ED-3.

The base layer BS may be a member providing a base surface where the display device layer DP-ED is disposed. The base layer BS may be a glass substrate, a metal substrate, a plastic substrate, etc. However, an embodiment of the present disclosure is not limited thereto, and the base layer BS may be an inorganic layer, an organic layer or a composite material layer.

In an embodiment, the circuit layer DP-CL is disposed on the base layer BS, and the circuit layer DP-CL may include multiple transistors. Each of the transistors may include a control electrode, an input electrode, and an output electrode. For example, the circuit layer DP-CL may include switching transistors and driving transistors for driving the light emitting devices ED-1, ED-2 and ED-3 of the display device layer DP-ED.

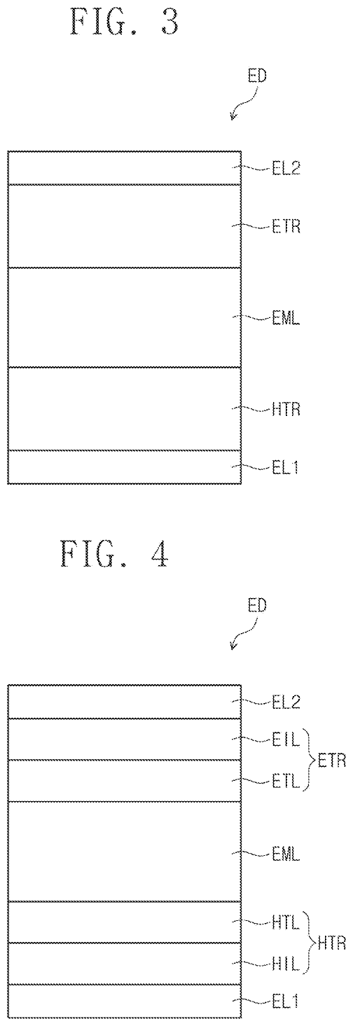

Each of the light emitting devices ED-1, ED-2 and ED-3 may have the structures of light emitting devices ED of embodiments according to FIG. 3 to FIG. 6. Each of the light emitting devices ED-1, ED-2 and ED-3 may include a first electrode EL1, a hole transport region HTR, emission layers EML-R, EML-G and EML-B, an electron transport region ETR, and a second electrode EL2.

In FIG. 2, shown is an embodiment where the emission layers EML-R, EML-G and EML-B of light emitting devices ED-1, ED-2 and ED-3, which are in opening portions OH defined in a pixel definition layer PDL, are disposed, and a hole transport region HTR, an electron transport region ETR and a second electrode EL2 are provided as common layers in all light emitting devices ED-1, ED-2 and ED-3. However, an embodiment of the present disclosure is not limited thereto. Different from FIG. 2, in an embodiment, the hole transport region HTR and the electron transport region ETR may be patterned and provided in the opening portions OH defined in the pixel definition layer PDL. For example, in an embodiment, the hole transport region HTR, the emission layers EML-R, EML-G and EML-B, and the electron transport region ETR of the light emitting devices ED-1, ED-2 and ED-3 may be patterned by an ink jet printing method and provided.

An encapsulating layer TFE may cover the light emitting devices ED-1, ED-2 and ED-3. The encapsulating layer TFE may encapsulate the display device layer DP-ED. The encapsulating layer TFE may be a thin film encapsulating layer. The encapsulating layer TFE may be one layer or a stacked layer of multiple layers. The encapsulating layer TFE includes at least one insulating layer. The encapsulating layer TFE according to an embodiment may include at least one inorganic layer (hereinafter, encapsulating inorganic layer). In some embodiments, the encapsulating layer TFE according to an embodiment may include at least one organic layer (hereinafter, encapsulating organic layer) and at least one encapsulating inorganic layer.

The encapsulating inorganic layer protects the display device layer DP-ED from moisture/oxygen, and the encapsulating organic layer protects the display device layer DP-ED from foreign materials such as dust particles. The encapsulating inorganic layer may include silicon nitride, silicon oxy nitride, silicon oxide, titanium oxide, or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be disposed on the second electrode EL2 and may be disposed while filling the opening portion OH.

Referring to FIG. 1 and FIG. 2, the display apparatus DD may include a non-luminous area NPXA and luminous areas PXA-R, PXA-G and PXA-B. The luminous areas PXA-R, PXA-G and PXA-B may be areas emitting light produced from the light emitting devices ED-1, ED-2 and ED-3, respectively. The luminous areas PXA-R, PXA-G and PXA-B may be separated from each other on a plane.

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In some embodiments, in the disclosure, each of the luminous areas PXA-R, PXA-G and PXA-B may correspond to each pixel. The pixel definition layer PDL may divide the light emitting devices ED-1, ED-2 and ED-3. The emission layers EML-R, EML-G and EML-B of the light emitting devices ED-1, ED-2 and ED-3 may be disposed and divided in the opening portions OH defined in the pixel definition layer PDL.

The luminous areas PXA-R, PXA-G and PXA-B may be divided into multiple groups according to the color of light produced from the light emitting devices ED-1, ED-2 and ED-3. In the display apparatus DD of an embodiment, shown in FIG. 1 and FIG. 2, three luminous areas PXA-R, PXA-G and PXA-B emitting red light, green light and blue light are illustrated as an embodiment. For example, the display apparatus DD of an embodiment may include a red luminous area PXA-R, a green luminous area PXA-G and a blue luminous area PXA-B, which are separated from each other.

In the display apparatus DD according to an embodiment, multiple light emitting devices ED-1, ED-2 and ED-3 may be to emit light having different wavelength regions. For example, in an embodiment, the display apparatus DD may include a first light emitting device ED-1 emitting red light, a second light emitting device ED-2 emitting green light, and a third light emitting device ED-3 emitting blue light. For example, each of the red luminous area PXA-R, the green luminous area PXA-G, and the blue luminous area PXA-B of the display apparatus DD may correspond to a corresponding one of the first light emitting device ED-1, the second light emitting device ED-2, and/or the third light emitting device ED-3.

However, an embodiment of the present disclosure is not limited thereto, and the first to third light emitting devices ED-1, ED-2 and ED-3 may emit light in substantially the same wavelength region, or at least one thereof may emit light in a different wavelength region. For example, all the first to third light emitting devices ED-1, ED-2 and ED-3 may emit blue light.

The luminous areas PXA-R, PXA-G and PXA-B in the display apparatus DD according to an embodiment may be arranged in a stripe shape. Referring to FIG. 1, multiple red luminous areas PXA-R, multiple green luminous areas PXA-G and multiple blue luminous areas PXA-B may be arranged along a second direction DR2. In some embodiments, the red luminous area PXA-R, the green luminous area PXA-G and the blue luminous area PXA-B may be arranged by turns along a first direction DR1.

In FIG. 1 and FIG. 2, the areas of the luminous areas PXA-R, PXA-G and PXA-B are shown to be similar (in size), but an embodiment of the present disclosure is not limited thereto. The areas of the luminous areas PXA-R, PXA-G and PXA-B may be different from each other according to the wavelength region of light emitted. In some embodiments, the areas of the luminous areas PXA-R, PXA-G and PXA-B may refer to areas on a plane defined by the first direction DR1 and the second direction DR2 (and DR3 is a third direction which is perpendicular or normal to the plane defined by the first direction DR1 and the second direction DR2).

In some embodiments, the arrangement type or kind of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in one or more suitable combinations according to the properties of display quality required (or desired) for the display apparatus DD. For example, the arrangement type or kind of the luminous areas PXA-R, PXA-G and PXA-B may be a pentile (PENTILE®) arrangement type or kind, or a diamond arrangement type or kind. PENTILE® arrangement (for example, an RGBG matrix, an RGBG structure, or RGBG matrix structure), but the present disclosure is not limited thereto. PENTILE® is a duly registered trademark of Samsung Display Co., Ltd.

In some embodiments, the areas of the luminous areas PXA-R, PXA-G and PXA-B may be different from each other. For example, in an embodiment, the area of the green luminous area PXA-G may be smaller than the area of the blue luminous area PXA-B, but an embodiment of the present disclosure is not limited thereto.

Hereinafter, FIG. 3 to FIG. 6 are cross-sectional views schematically showing light emitting devices according to embodiments. The light emitting device ED according to an embodiment may include a first electrode EL1, a hole transport region HTR, an emission layer EML, an electron transport region ETR, and a second electrode EL2 stacked in order.

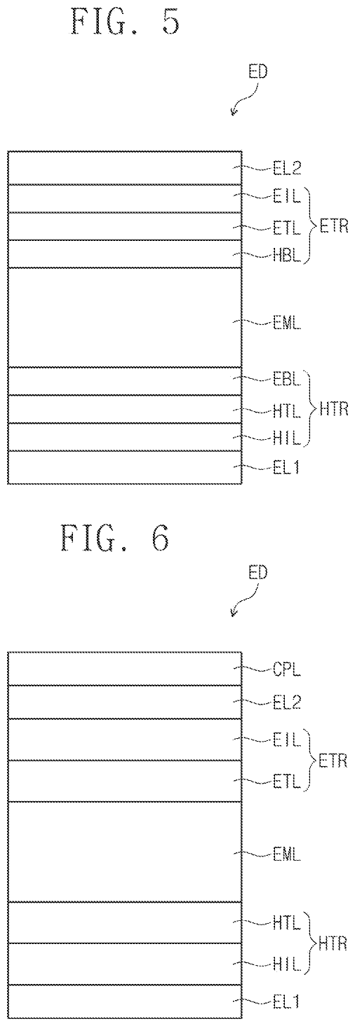

When compared with FIG. 3, FIG. 4 shows the cross-sectional view of a light emitting device ED of an embodiment, wherein a hole transport region HTR includes a hole injection layer HIL and a hole transport layer HTL, and an electron transport region ETR includes an electron injection layer EIL and an electron transport layer ETL. In some embodiments, when compared with FIG. 3, FIG. 5 shows the cross-sectional view of a light emitting device ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared with FIG. 4, FIG. 6 shows the cross-sectional view of a light emitting device ED of an embodiment, including a capping layer CPL disposed on the second electrode EL2.

The first electrode EL1 has conductivity (e.g., is a conductor). The first electrode EL1 may be formed utilizing a metal material, a metal alloy or a conductive compound. The first electrode EL1 may be an anode or a cathode. However, an embodiment of the present disclosure is not limited thereto. In some embodiments, the first electrode EL1 may be a pixel electrode. The first electrode EL1 may be a transmissive electrode, a transflective electrode, or a reflective electrode. When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, one or more compounds thereof, or one or more mixtures thereof (for example, a mixture of Ag and Mg). In addition, the first electrode EL1 may have a structure including multiple layers including a reflective layer or a transflective layer formed utilizing the above materials, and a transmissive conductive layer formed utilizing ITO, IZO, ZnO, or ITZO. For example, the first electrode EU may include a three-layer structure of ITO/Ag/ITO. However, an embodiment of the present disclosure is not limited thereto. The first electrode EL1 may include the above-described metal materials, combinations of two or more metal materials selected from the above-described metal materials, or oxides of the above-described metal materials. The thickness of the first electrode EU may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer, an emission auxiliary layer or an electron blocking layer EBL. The thickness of the hole transport region HTR may be from about 50 Å to about 15,000 Å.

The hole transport region HTR may have a single layer formed utilizing a single material, a single layer formed utilizing multiple different materials, or a multilayer structure including multiple layers formed utilizing multiple different materials.

For example, the hole transport region HTR may have the structure of a single layer of a hole injection layer HIL or a hole transport layer HTL, and may have a structure of a single layer formed utilizing a hole injection material and a hole transport material. In some embodiments, the hole transport region HTR may have a structure of a single layer formed utilizing multiple different materials, or a structure stacked from the first electrode EU of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, without limitation.

The hole transport region HTR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1.

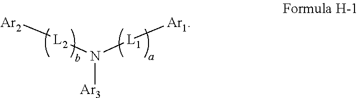

In Formula H-1 above, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. “a” and “b” may each independently be an integer of 0 to 10. In some embodiments, when “a” or “b” is an integer of 2 or more, multiple L₁ and L₂ may each independently be a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. In some embodiments, in Formula H-1, Ar₃ may be a substituted or unsubstituted aryl group of 6 to 30 ring-forming carbon atoms.

The compound represented by Formula H-1 may be a monoamine compound. In some embodiments, the compound represented by Formula H-1 may be a diamine compound in which at least one of Ar₁ to Ar₃ includes an amine group as a substituent. In some embodiments, the compound represented by Formula H-1 may be a carbazole-based compound in which at least one of Ar₁ or Ar₂ includes a substituted or unsubstituted carbazole group, or a fluorene-based compound in which at least one of Ar₁ or Ar₂ includes a substituted or unsubstituted fluorene group.

The compound represented by Formula H-1 may be represented by any one of the compounds in Compound Group H. However, the compounds shown in Compound Group H are only illustrations (examples), and the compound represented by Formula H-1 is not limited to the compounds represented in Compound Group H.

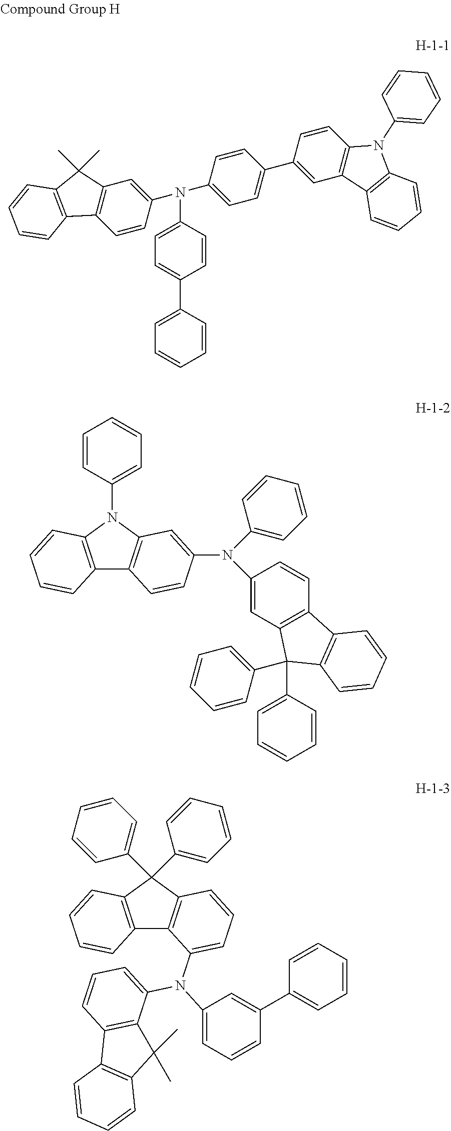 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

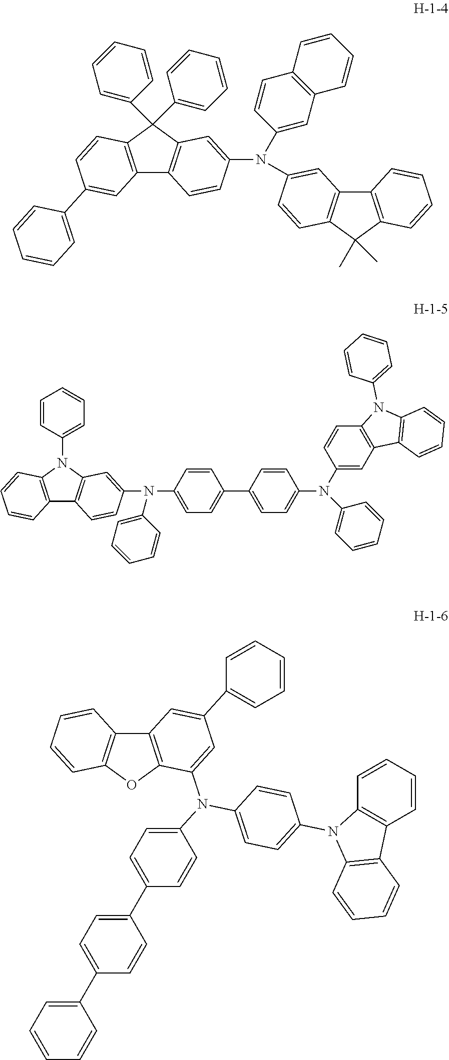 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

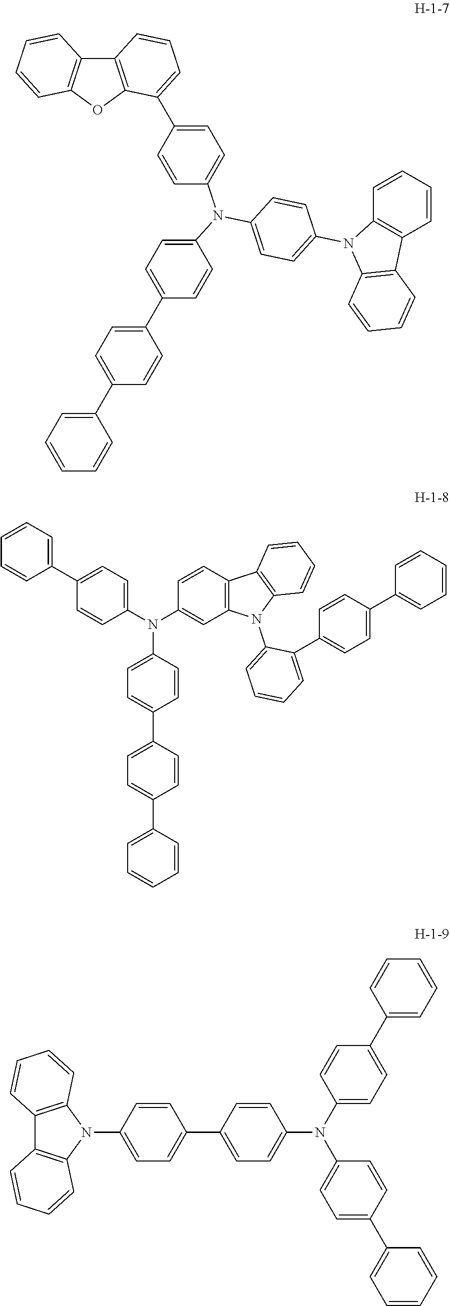 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

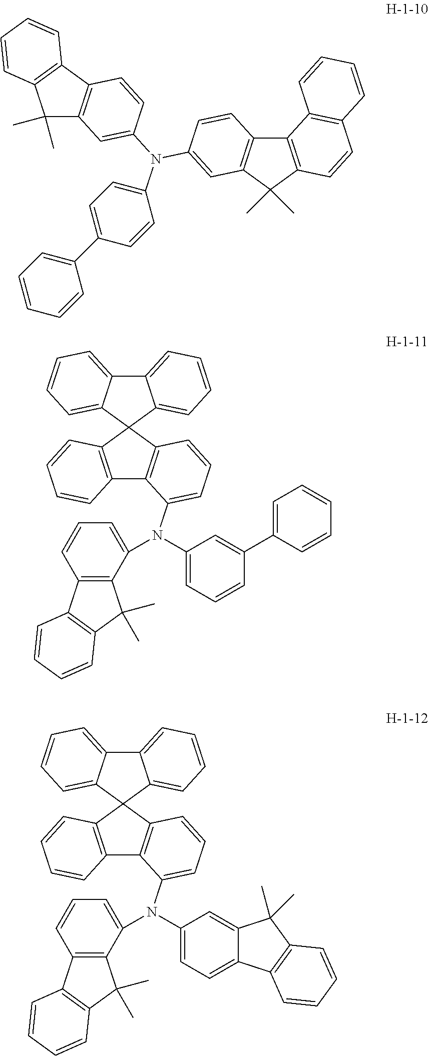

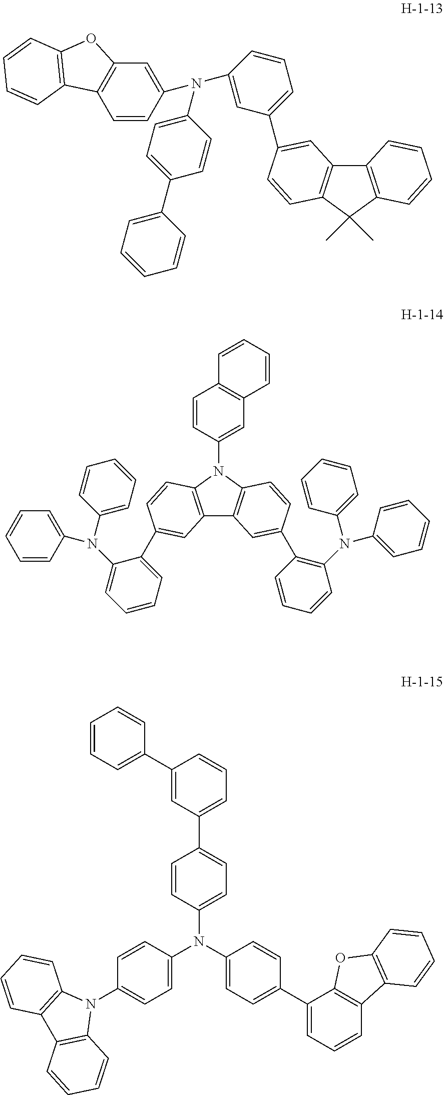 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

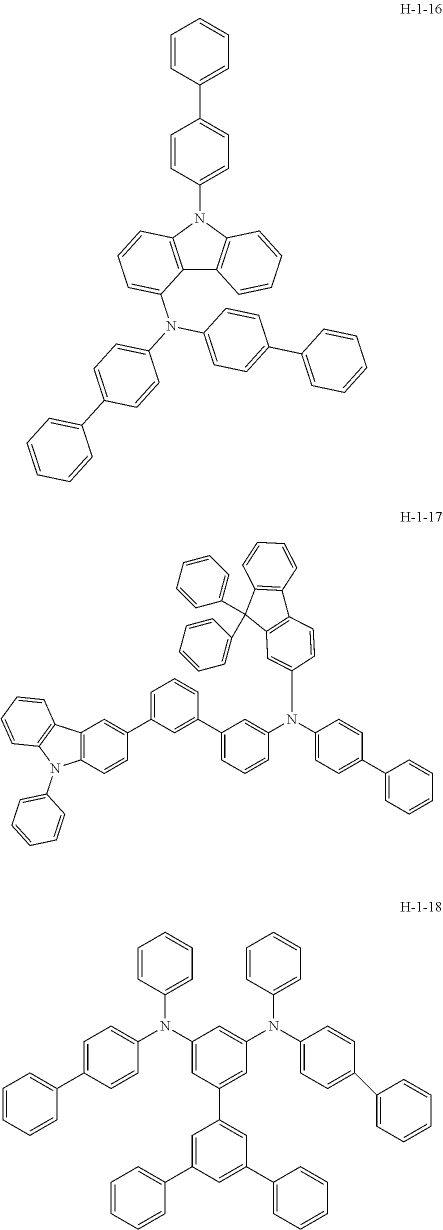 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

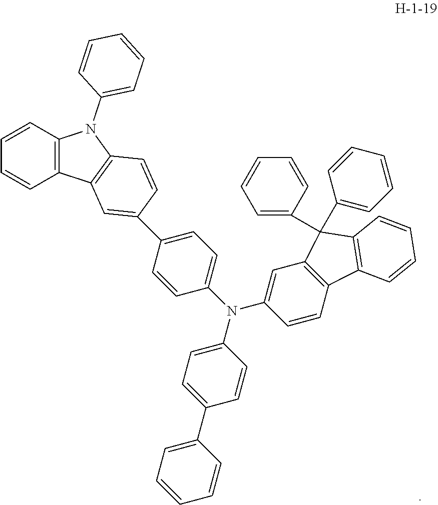 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region may include a compound represented by Formula H-a. The compound represented by Formula H-a may be a monoamine compound.

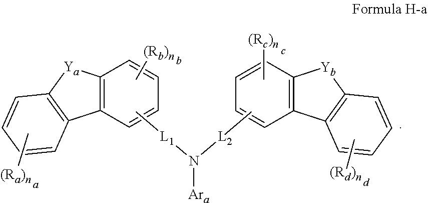

In Formula H-a, Yₐ and Y_{b} may each independently be CRₑR_{f}, NR_{g}, O, or S. Yₐ and Y_{b} may be the same or different. In an embodiment, both (e.g., simultaneously) Yₐ and Y_{b} may be CRₑR_{f}. In some embodiments, any one of Yₐ or Y_{b} may be CRₑR_{f}, and the other one may be NR_{g}.

In Formula H-a, Arₐ is a substituted or unsubstituted aryl group of 6 to 30 ring-forming carbon atoms, or a substituted or unsubstituted heteroaryl group of 2 to 30 ring-forming carbon atoms. For example, Arₐ may be a substituted or unsubstituted phenyl group, a substituted or unsubstituted biphenyl group, a substituted or unsubstituted naphthyl group, a substituted or unsubstituted fluorenyl group, or a substituted or unsubstituted terphenyl group.

In Formula H-a, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. For example, L₁ and L₂ may be direct linkages, substituted or unsubstituted phenylene groups, or substituted or unsubstituted divalent biphenyl groups.

In Formula H-a, Rₐ to R_{g} may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. For example, Rₐ to R_{g} may each independently be a hydrogen atom, a substituted or unsubstituted methyl group, or a substituted or unsubstituted phenyl group.

In Formula H-a, nₐ and n_{d} may each independently be an integer of 0 to 4, and n_{b} and n_{c} may each independently be an integer of 0 to 3.

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate], and/or dipyrazino[2,3-f:2′,3′-h] quinoxaline-2,3,6,7,10,11-hexacarbonitrile (HAT-CN).

The hole transport region HTR may include carbazole derivatives such as N-phenyl carbazole and/or polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one of the hole injection layer HIL, hole transport layer HTL, and/or the electron blocking layer EBL.

The thickness of the hole transport region HTR may be from about 100 Å to about 10,000 Å, for example, from about 100 Å to about 5,000 Å. When the hole transport region HTR includes a hole injection layer HIL, the thickness of the hole injection region HIL may be, for example, from about 30 Å to about 1,000 Å. When the hole transport region HTR includes a hole transport layer HTL, the thickness of the hole transport layer HTL may be from about 30 Å to about 1,000 Å. For example, when the hole transport region HTR includes an electron blocking layer, the thickness of the electron blocking layer EBL may be from about 10 Å to about 1,000 Å. When the thicknesses of the hole transport region HTR, the hole injection layer HIL, the hole transport layer HTL and the electron blocking layer EBL satisfy the above-described ranges, satisfactory (suitable) hole transport properties may be achieved without substantial increase of a driving voltage.

The hole transport region HTR may further include a charge generating material to increase conductivity in addition to the above-described materials. The charge generating material may be dispersed substantially uniformly or non-uniformly in the hole transport region HTR. The charge generating material may be, for example, a p-dopant. The p-dopant may include at least one of metal halide compounds, quinone derivatives, metal oxides, and/orcyano group-containing compounds, without limitation. For example, the p-dopant may include metal halide compounds such as CuI and/or RbI, quinone derivatives such as tetracyanoquinodimethane (TCNQ) and/or 2,3,5,6-tetrafluoro-7,7′,8,8-tetracyanoquinodimethane (F4-TCNQ), metal oxides such as tungsten oxide and/or molybdenum oxide, cyano group-containing compounds such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NPD9), etc., without limitation.

As described above, the hole transport region HTR may further include at least one of a buffer layer or an electron blocking layer EBL in addition to the hole injection layer HIL and the hole transport layer HTL. The buffer layer may compensate resonance distance according to the wavelength of light emitted from an emission layer EML and may increase light emitting efficiency. Materials which may be included in the hole transport region HTR may be utilized as materials included in the buffer layer. The electron blocking layer EBL is a layer playing the role of blocking the injection of electrons from an electron transport region ETR to a hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed utilizing a single material, a single layer formed utilizing multiple different materials, or a multilayer structure having multiple layers formed utilizing multiple different materials.

In the light emitting device ED of an embodiment, the emission layer EML may include multiple light emitting materials. The light emitting device ED of an embodiment may include a first compound and at least one of a second compound, a third compound, and/or a fourth compound in the emission layer EML. In the light emitting device ED of an embodiment, the emission layer EML may include at least one host and at least one dopant. For example, the emission layer EML of an embodiment may include a dopant, and a first host and a second host, which are different from each other, as hosts. The emission layer EML of an embodiment may include the above-described first host and the second host, and a first dopant and a second dopant, which are different from each other.

In the emission layer EML of the light emitting device ED of an embodiment, the first compound may include a fused polycyclic compound having a fused structure of multiple aromatic rings through one boron atom and two heteroatoms. The first compound of an embodiment may include a fused structure of multiple aromatic rings through one boron atom and two heteroatoms selected from the group including (e.g., consisting of) nitrogen, oxygen and/or sulfur. In some embodiments, the first compound of an embodiment may include a structure in which a substituent of an electron donating group having a fused ring type or kind is bonded through a carbon-carbon bond to at least one of the para positions to the boron atom in the core of the fused ring. In some embodiments, the first compound of an embodiment may include a structure in which an additional substituent of an electron donating group is bonded through a carbon-carbon bond to another one of the para positions to the boron atom in the core of the fused ring.

The first compound of an embodiment is represented by Formula 1.

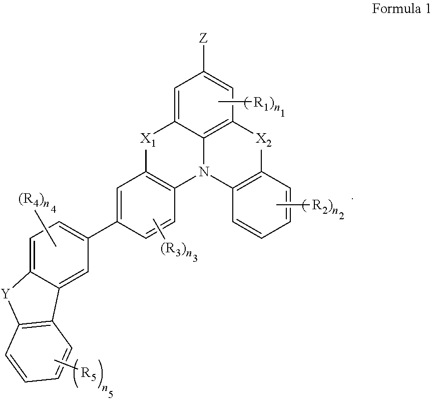

In Formula 1, X₁ and X₂ may each independently be NR₆, O, or S, and at least one of X₁ or X₂ is NR₆. For example, both (e.g., simultaneously) X₁ and X₂ may be NR₆. In some embodiments, any one of X₁ or X₂ may be O, and the remainder may be NR₆.

In Formula 1, Y is NR₇, O, or S. Y may be, for example, NR₇ or O.

In Formula 1, Z is a substituted or unsubstituted t-butyl group, a substituted or unsubstituted aryl group of 6 to 30 ring-forming carbon atoms, or a substituted or unsubstituted heteroaryl group of 2 to 30 ring-forming carbon atoms. Z may be, for example, an unsubstituted t-butyl group, a substituted or unsubstituted phenyl group, a substituted or unsubstituted dibenzofuran group, a substituted or unsubstituted carbazole group, or a substituted or unsubstituted indolocarbazole group.

In Formula 1, R₁ to R₇ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, R₁ to R₇ may each independently be combined with an adjacent group to form a ring. For example, R₁ to R₇ may each independently be a hydrogen atom, a deuterium atom, a substituted or unsubstituted diarylamine group, a substituted or unsubstituted t-butyl group, a substituted or unsubstituted phenyl group, a substituted or unsubstituted diphenyl group, a substituted or unsubstituted terphenyl group, a substituted or unsubstituted tetrahydronaphthyl group, a substituted or unsubstituted dibenzofuran group, a substituted or unsubstituted carbazole group, or a substituted or unsubstituted indolocarbazole group.

In Formula 1, n₁ is an integer of 0 to 2, n₂ is an integer of 0 to 4, n₃ and n₄ may each independently be an integer of 0 to 3, and n₅ is an integer of 0 to 4. When n₁ to n₅ are 0, the first compound according to an embodiment may not be substituted with R₁ to R₅, respectively. When each of n₁ to n₅ is an integer of 2 or more, each of multiple R₁ to R₅ may be the same, or at least one of multiple R₁ to R₅ may be different. In Formula 1, an embodiment in which n₁ is 2, and multiple R₁ are all hydrogen atoms, may be the same as Formula 1 in which n₁ is 0. In Formula 1, an embodiment in which n₂ is 4, and multiple R₂ are all hydrogen atoms, may be the same as Formula 1 in which n₂ is 0. In Formula 1, an embodiment in which n₃ is 3, and multiple R₃ are all hydrogen atoms, may be the same as Formula 1 in which n₃ is 0. In Formula 1, an embodiment in which n₄ is 3, and multiple R₄ are all hydrogen atoms, may be the same as Formula 1 in which n₄ is 0. In Formula 1, an embodiment in which n₅ is 4, and multiple R₅ are all hydrogen atoms, may be the same as Formula 1 in which n₅ is 0.

The first compound of an embodiment has a plate-type or kind skeleton structure with one boron atom as a center and has a structure in which a substituent of an electron donating group having a fused ring type or kind is bonded to the plate-type or kind skeleton structure through a carbon-carbon bond. The substituent of an electron donating group is bonded to a para position to the boron atom. In some embodiments, the first compound of an embodiment has a structure in which an additional substituent of an electron donating group is bonded to a para position to the boron atom through a carbon-carbon bond. The first compound of an embodiment may show increased electron donating properties through the substituent of an electron donating group bonded at the para position to the boron atom, and because the substituent of an electron donating group is connected with a central core through the carbon-carbon bond, chemical stability may be expected on the whole molecule.

In the first compound of an embodiment, the substituent of an electron donating group has a strong structure of a fused ring type or kind and may have strong binding energy compared to an unfused substituent like aryl amine. In some embodiments, through introducing a substituent having a high extinction coefficient, the light absorptivity of the compound itself may be increased, and accordingly, efficient energy transfer from a host may be performed, and the emission efficiency of a light emitting device may be improved (increased). The first compound of an embodiment may show reinforced electron donating properties by the substituent of an electron donating group, and a multi-resonance structure may be reinforced to reinforce thermally activated delayed fluorescence (TADF) properties.

In some embodiments, the first compound of an embodiment has a structure introducing a substituent of an electron donating group not through a carbon-nitrogen bond which has weak binding energy but through a carbon-carbon bond, and the chemical stability of the material itself is improved, and accordingly, when applied to a light emitting device ED, the efficiency and life of the light emitting device ED may be improved.

The first compound of an embodiment may be represented by any one of Formula 2-1 to Formula 2-4.

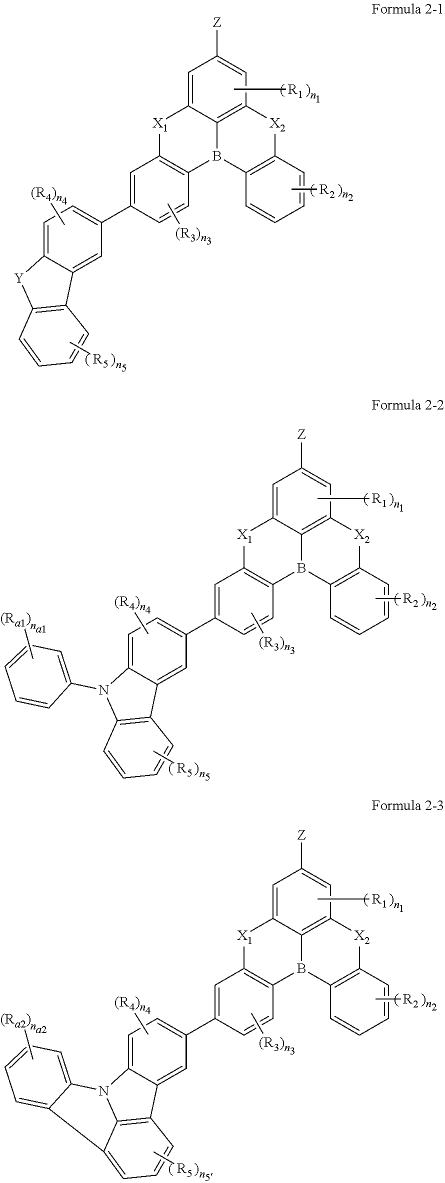

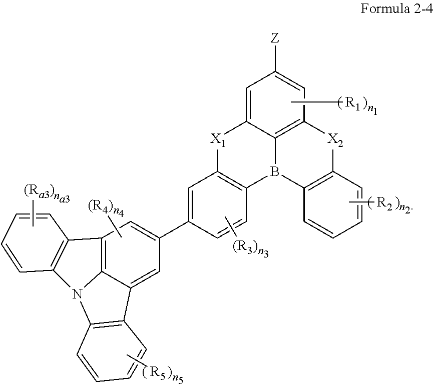

Formula 2-1 to Formula 2-4 represent Formula 1 in which Y is specified. Formula 2-1 is an embodiment of Formula 1 in which Y is O, Formula 2-2 to Formula 2-4 are embodiments of Formula 1 in which Y is NR₇, and Formula 2-3 and Formula 2-4 are embodiments of Formula 1 in which Y is NR₇, and any one of R₇ is combined with an adjacent group to form a ring.

In Formula 2-1 to Formula 2-4, Rₐ₁ to Rₐ₃ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Rₐ₁ to Rₐ₃ may each independently be a hydrogen atom or a deuterium atom.

In Formula 2-2 to Formula 2-4, nₐ₁ is an integer of 0 to 5, nₐ₂ and nₐ₃ may each independently be an integer of 0 to 4, n_{a4′} is an integer of 0 to 2, and n_{a5′} is an integer of 0 to 3. When nₐ₁ to nₐ₃, n_{4′} and n_{5′} are 0, the first compound of according to embodiment may not be substituted with Rₐ₁ to Rₐ₃, R₄ and R₅, respectively. When each of nₐ₁ to nₐ₃, n_{4′} and n_{5′} is an integer of 2 or more, each of multiple Rₐ₁ to Rₐ₃, R₄ and R₅ may be the same, or at least one of multiple Rₐ₁ to Rₐ₃, R₄ and R₅ may be different. In Formula 2-2, an embodiment in which nₐ₁ is 5, and multiple Rₐ₁ are all hydrogen atoms, may be the same as an embodiment of Formula 2-2 in which nₐ₁ is 0. In Formula 2-3, an embodiment in which nₐ₂ is 4, and multiple Rae are all hydrogen atoms, may be the same as an embodiment of Formula 2-3 in which nₐ₂ is 0. In Formula 2-4, an embodiment in which nₐ₃ is 4, and multiple Rₐ₁ are all hydrogen atoms, may be the same an embodiment of Formula 2-4 in which nₐ₃ is 0. In Formula 2-3, an embodiment in which n_{4′} is 2, and multiple R₄ are all hydrogen atoms, may be the same as an embodiment of Formula 2-3 in which n_{4′} is 0. In Formula 2-4, an embodiment in which n_{5′} is 3, and multiple R_{5′} are all hydrogen atoms, may be the same as an embodiment of Formula 2-4 in which n_{5′} is 0.

In some embodiments, in Formula 2-2 to Formula 2-4, for X₁, X₂, Z, R₁ to R₇, and n₁ to n₅ the substituents and values in Formula 1 may be used.

In an embodiment, the first compound represented by Formula 1 may be represented by any one of Formula 3-1 to Formula 3-3.

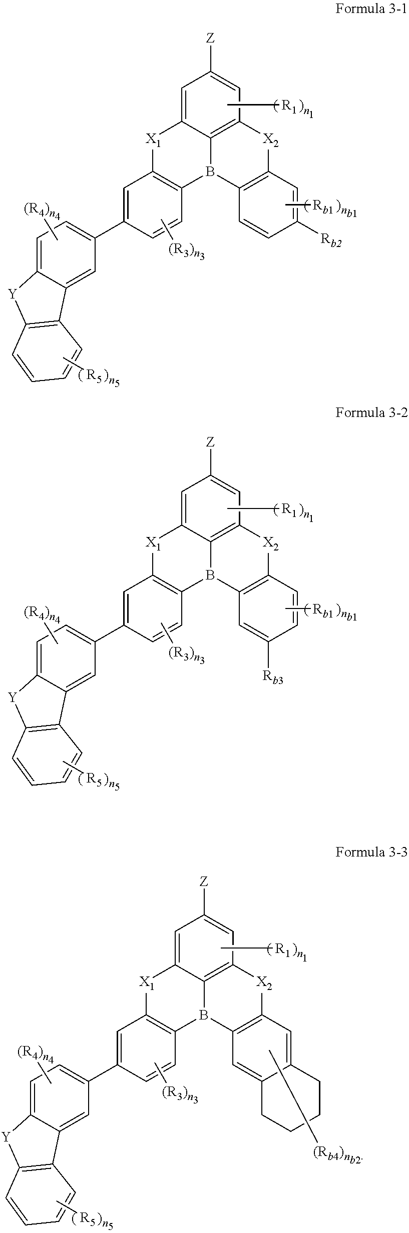

Formula 3-1 to Formula 3-3 represent Formula 1 in which the substitution position of R₂ and whether an additional ring is formed or not are specified. Formula 3-1 is a case where R₂ is substituted at the para position to the boron atom, Formula 3-2 is an embodiment in which R₂ is substituted at the meta position to the boron atom, and Formula 3-3 is an embodiment in which R₂ substituted at the para position to the boron atom and R₂ substituted at the meta position to the boron atom form an additional ring.

In Formula 3-1 to Formula 3-3, R_{b1} to R_{b4} may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R_{b1} may be a hydrogen atom or a deuterium atom. R_{b2} may be a substituted or unsubstituted amine group, a substituted or unsubstituted phenyl group, a substituted or unsubstituted dibenzofuran group, a substituted or unsubstituted carbazole group, or a substituted or unsubstituted indolocarbazole group. R_{b3} may be a substituted or unsubstituted t-butyl group or a substituted or unsubstituted phenyl group. R_{b4} may be a hydrogen atom, a deuterium atom or a substituted or unsubstituted methyl group.

In Formula 3-1 to Formula 3-3, n_{b1} is an integer of 0 to 3, n_{b2} is an integer of 0 to 10. When n_{b1} and n_{b2} are 0, the first compound according to an embodiment may not be substituted with R_{b1} and R_{b2}, respectively. When each of n_{b1} and n_{b2} is an integer of 2 or more, multiple R_{b1} and R_{b2} may be all the same, or at least one of multiple R_{b1} and/or R_{b2} may be different. Embodiments of Formulae 3-1 and 3-2 in which n_{b1} is 3, and multiple R_{b1} are all hydrogen atoms, may be the same as embodiments of Formulae 3-1 and 3-2 in which n_{b1} is 0. An embodiment of Formula 3-3 in which n_{b2} is 10, and multiple R_{b4} are all hydrogen atoms, may be the same as an embodiment of Formulae 3-3 in which n_{b2} is 0.

In some embodiments, in Formula 3-1 to Formula 3-3, for X₁, X₂, Y, Z, R₁, R₃ to R₇, n₁, and n₃ to n₅ the substituents and values in Formula 1 may be used.

In an embodiment, the first compound represented by Formula 1 may be represented by any one of Formula 3-1-1 to Formula 3-3-1.

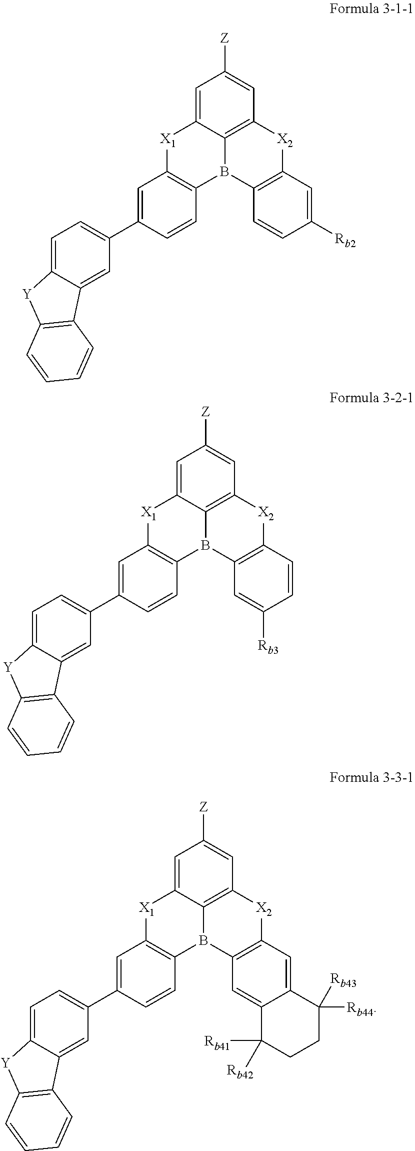

Formula 3-1-1 to Formula 3-3-1 represent Formula 3-1 to Formula 3-3, respectively, in which some substituents are specified.

In Formula 3-1-1 to Formula 3-3-1, R_{b41} to R_{b44} may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R_{b41} to R_{b44} may each independently be a hydrogen atom, a deuterium atom, or a substituted or unsubstituted methyl group.

In some embodiments, in Formula 3-1-1 to Formula 3-3-1, the same explanation on X₁, X₂, Y, Z, R₆, R₇, R_{b2} and R_{b3} referring to Formula 1 and Formula 3-1 to Formula 3-3 may be applied.

In an embodiment, the first compound represented by Formula 1 may be represented by Formula 4.

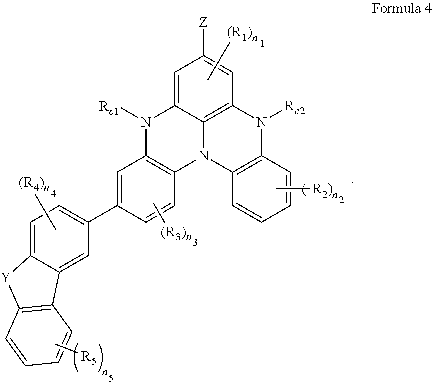

Formula 4 represents an embodiment of Formula 1 in which X₁ and X₂ are specified to be NR₆.

In Formula 4, R_{c1} and R_{c2} may each independently be a substituted or unsubstituted aryl group of 6 to 30 ring-forming carbon atoms, or a substituted or unsubstituted heteroaryl group of 2 to 30 ring-forming carbon atoms. For example, R_{c1} and R_{c2} may each independently be a substituted or unsubstituted phenyl group, a substituted or unsubstituted tetrahydronaphthyl group, a substituted or unsubstituted biphenyl group or a substituted or unsubstituted terphenyl group.

In some embodiments, in Formula 4, for Y, Z, R₁ to R₇, and n₁ to n₅ can be referred to Formula 1.

In Formula 4, each of R_{c1} and R_{c2} may be represented by any one of Formula 5-1 to Formula 5-6.

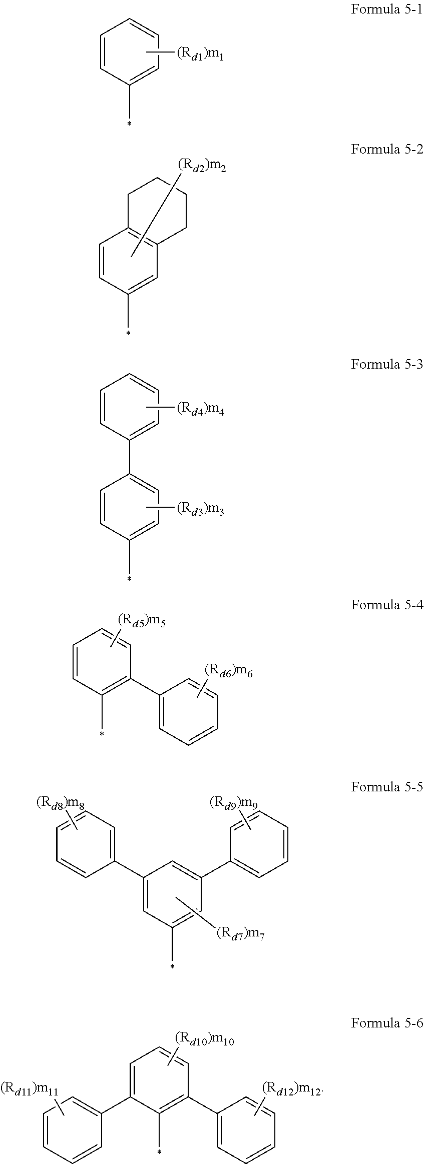

In Formula 5-1 to Formula 5-6, R_{d1} to R_{d12} may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R_{d1} to R_{d12} may each independently be a hydrogen atom, a deuterium atom, a substituted or unsubstituted methyl group, a substituted or unsubstituted t-butyl group, a substituted or unsubstituted phenyl group, or a substituted or unsubstituted tetrahydronaphthyl group.

In an embodiment, the first compound represented by Formula 1 may be represented by any one of Formula 6-1 to Formula 6-5.

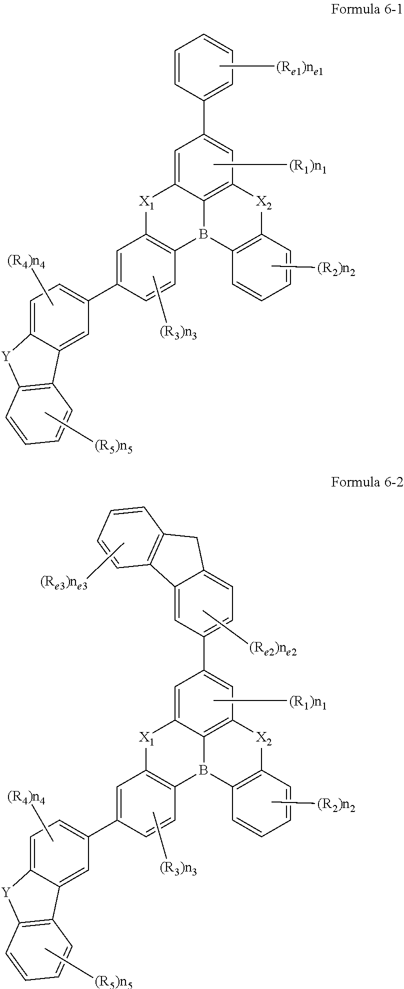

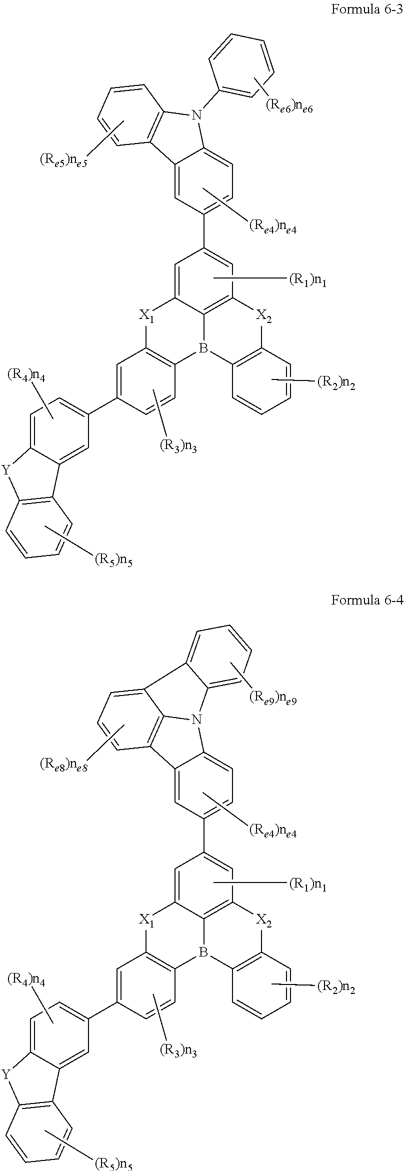

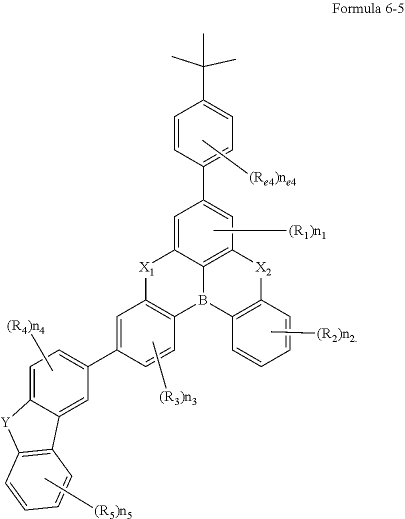

Formula 6-1 to Formula 6-5 represent Formula 1 in which Z is specified.

In Formula 6-1 to Formula 6-5, Rₑ₁ to Rₑ₉ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Rₑ₁ to Rₑ₉ may each independently be a hydrogen atom, a deuterium atom, a substituted or unsubstituted methyl group, a substituted or unsubstituted t-butyl group, or a substituted or unsubstituted phenyl group.

In some embodiments, in Formula 6-1 to Formula 6-5, for X₁, X₂, Y, R₁ to R₇, and n₁ to n₅ the substituents and values in Formula 1 may be used.

The first compound of an embodiment may be any one of the compounds represented in Compound Group 1. The light emitting device ED of an embodiment may include at least one fused polycyclic compound of the compounds represented in Compound Group 1 in an emission layer EML as the first compound.

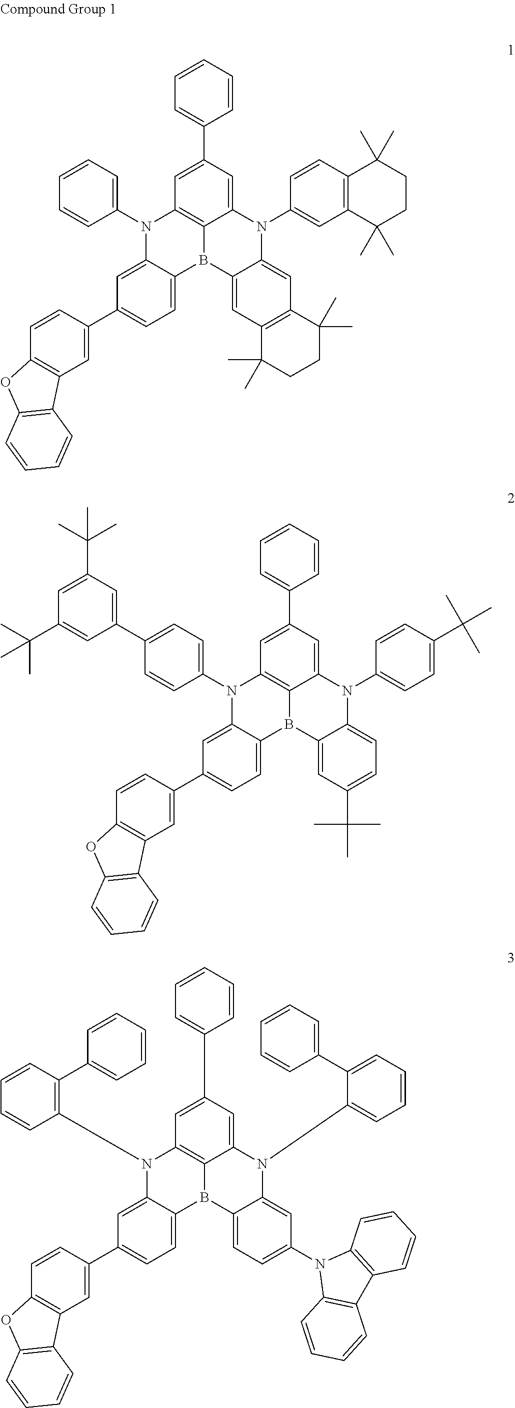 [SMILES: CC1(C)CCC(C)(C)c2cc(N3c4cc5c(cc4B4c6ccc(-c7ccc8oc9ccccc9c8c7)cc6N(c6ccccc6)c6cc(-c7ccccc7)cc3c64)C(C)(C)CCC5(C)C)ccc21 ; CC(C)(C)c1ccc(N2c3ccc(C(C)(C)C)cc3B3c4ccc(-c5ccc6oc7ccccc7c6c5)cc4N(c4ccc(-c5cc(C(C)(C)C)cc(C(C)(C)C)c5)cc4)c4cc(-c5ccccc5)cc2c43)cc1 ; c1ccc(-c2cc3c4c(c2)N(c2ccccc2-c2ccccc2)c2cc(-n5c6ccccc6c6ccccc65)ccc2B4c2ccc(-c4ccc5oc6ccccc6c5c4)cc2N3c2ccccc2-c2ccccc2)cc1]

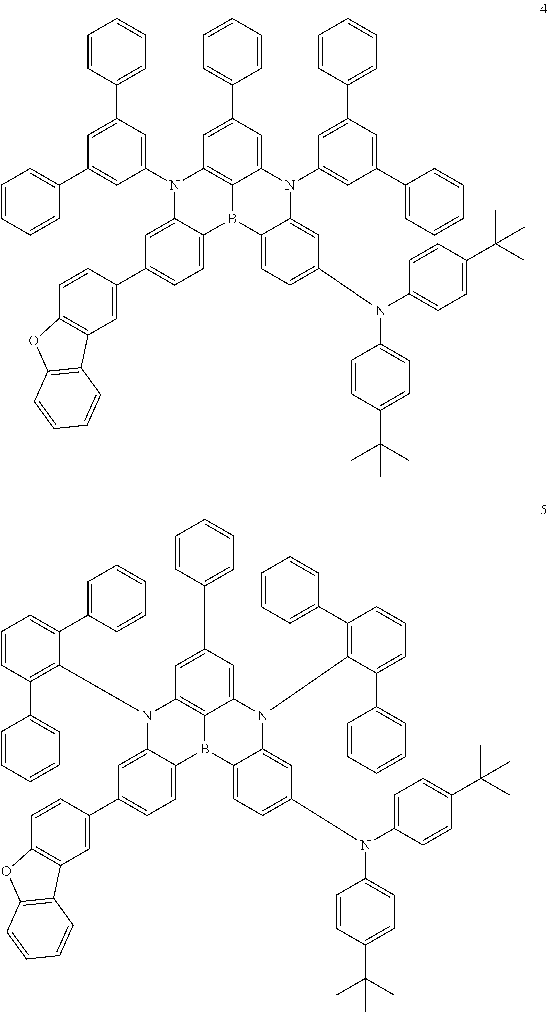 [SMILES: CC(C)(C)c1ccc(N(c2ccc(C(C)(C)C)cc2)c2ccc3c(c2)N(c2cc(-c4ccccc4)cc(-c4ccccc4)c2)c2cc(-c4ccccc4)cc4c2B3c2ccc(-c3ccc5oc6ccccc6c5c3)cc2N4c2cc(-c3ccccc3)cc(-c3ccccc3)c2)cc1 ; CC(C)(C)c1ccc(N(c2ccc(C(C)(C)C)cc2)c2ccc3c(c2)N(c2c(-c4ccccc4)cccc2-c2ccccc2)c2cc(-c4ccccc4)cc4c2B3c2ccc(-c3ccc5oc6ccccc6c5c3)cc2N4c2c(-c3ccccc3)cccc2-c2ccccc2)cc1]

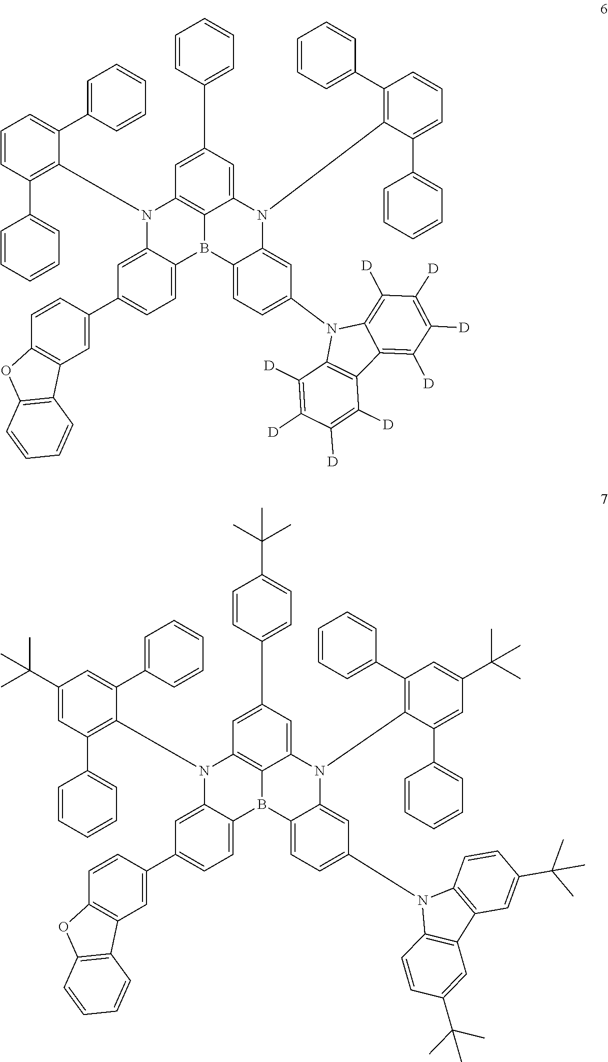 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccccc3)cc3c1B2c1ccc(-c2ccc4oc5ccccc5c4c2)cc1N3c1c(-c2ccccc2)cccc1-c1ccccc1 ; CC(C)(C)c1ccc(-c2cc3c4c(c2)N(c2c(-c5ccccc5)cc(C(C)(C)C)cc2-c2ccccc2)c2cc(-n5c6ccc(C(C)(C)C)cc6c6cc(C(C)(C)C)ccc65)ccc2B4c2ccc(-c4ccc5oc6ccccc6c5c4)cc2N3c2c(-c3ccccc3)cc(C(C)(C)C)cc2-c2ccccc2)cc1]

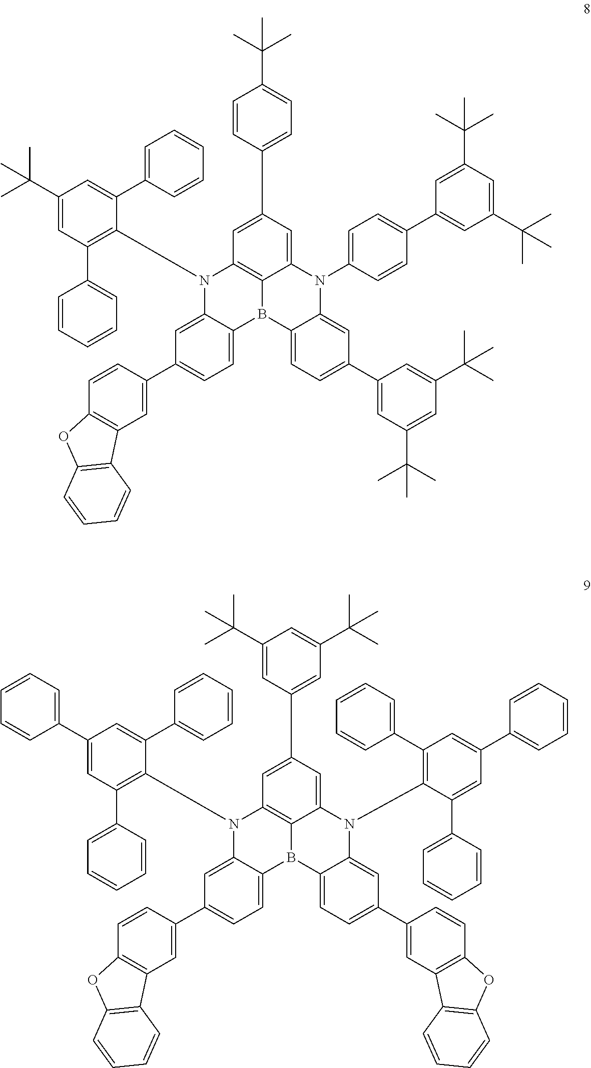 [SMILES: CC(C)(C)c1ccc(-c2cc3c4c(c2)N(c2c(-c5ccccc5)cc(C(C)(C)C)cc2-c2ccccc2)c2cc(-c5ccc6oc7ccccc7c6c5)ccc2B4c2ccc(-c4cc(C(C)(C)C)cc(C(C)(C)C)c4)cc2N3c2ccc(-c3cc(C(C)(C)C)cc(C(C)(C)C)c3)cc2)cc1 ; CC(C)(C)c1cc(-c2cc3c4c(c2)N(c2c(-c5ccccc5)cc(-c5ccccc5)cc2-c2ccccc2)c2cc(-c5ccc6oc7ccccc7c6c5)ccc2B4c2ccc(-c4ccc5oc6ccccc6c5c4)cc2N3c2c(-c3ccccc3)cc(-c3ccccc3)cc2-c2ccccc2)cc(C(C)(C)C)c1]

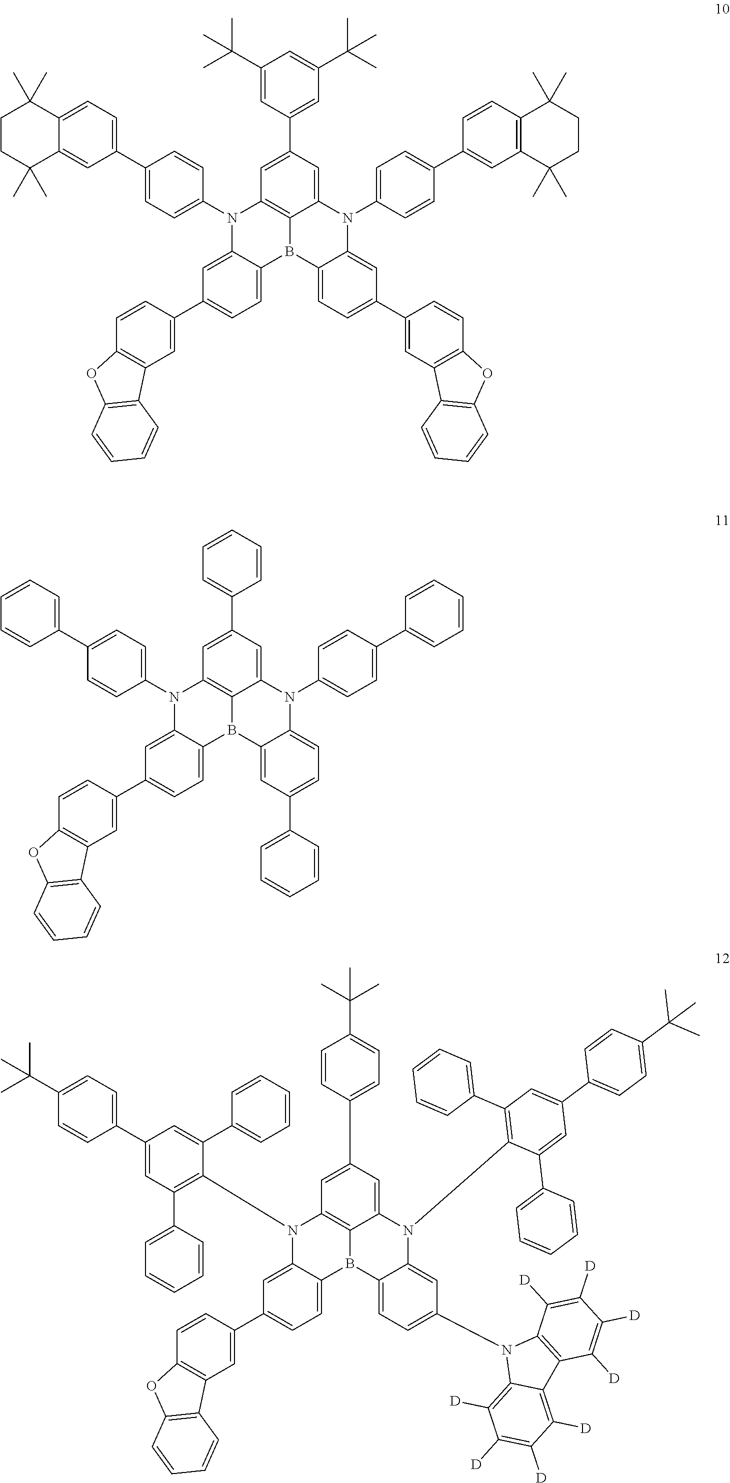

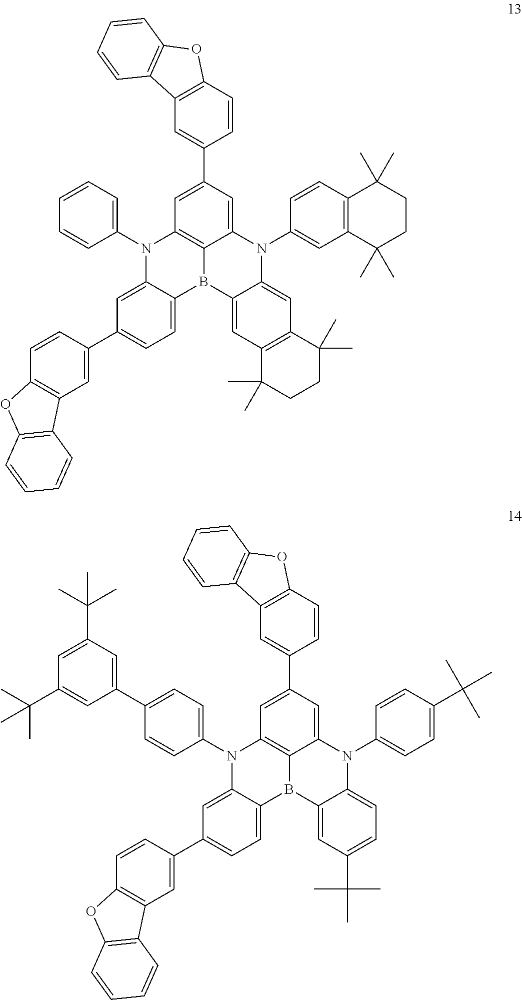 [SMILES: CC1(C)CCC(C)(C)c2cc(N3c4cc5c(cc4B4c6ccc(-c7ccc8oc9ccccc9c8c7)cc6N(c6ccccc6)c6cc(-c7ccc8oc9ccccc9c8c7)cc3c64)C(C)(C)CCC5(C)C)ccc21 ; CC(C)(C)c1ccc(N2c3ccc(C(C)(C)C)cc3B3c4ccc(-c5ccc6oc7ccccc7c6c5)cc4N(c4ccc(-c5cc(C(C)(C)C)cc(C(C)(C)C)c5)cc4)c4cc(-c5ccc6oc7ccccc7c6c5)cc2c43)cc1]

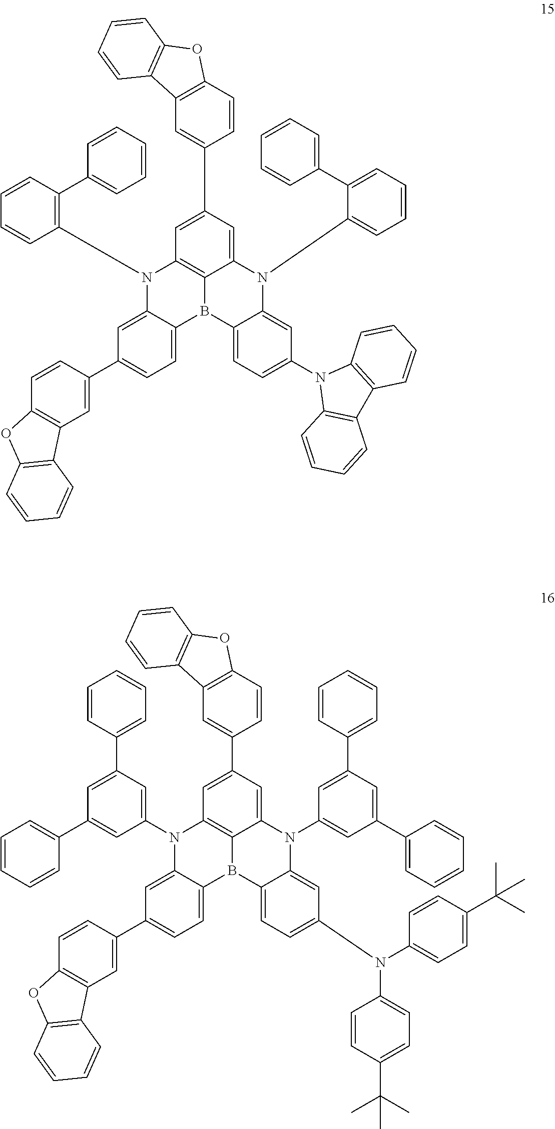 [SMILES: c1ccc(-c2ccccc2N2c3cc(-c4ccc5oc6ccccc6c5c4)ccc3B3c4ccc(-n5c6ccccc6c6ccccc65)cc4N(c4ccccc4-c4ccccc4)c4cc(-c5ccc6oc7ccccc7c6c5)cc2c43)cc1 ; CC(C)(C)c1ccc(N(c2ccc(C(C)(C)C)cc2)c2ccc3c(c2)N(c2cc(-c4ccccc4)cc(-c4ccccc4)c2)c2cc(-c4ccc5oc6ccccc6c5c4)cc4c2B3c2ccc(-c3ccc5oc6ccccc6c5c3)cc2N4c2cc(-c3ccccc3)cc(-c3ccccc3)c2)cc1]

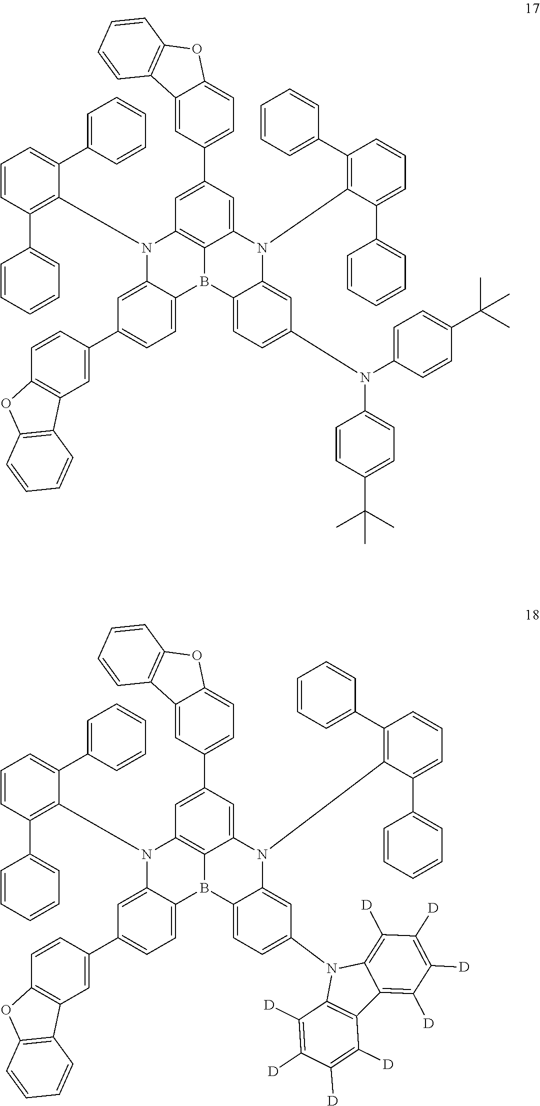 [SMILES: CC(C)(C)c1ccc(N(c2ccc(C(C)(C)C)cc2)c2ccc3c(c2)N(c2c(-c4ccccc4)cccc2-c2ccccc2)c2cc(-c4ccc5oc6ccccc6c5c4)cc4c2B3c2ccc(-c3ccc5oc6ccccc6c5c3)cc2N4c2c(-c3ccccc3)cccc2-c2ccccc2)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc(-c2ccc4oc5ccccc5c4c2)cc1N3c1c(-c2ccccc2)cccc1-c1ccccc1]

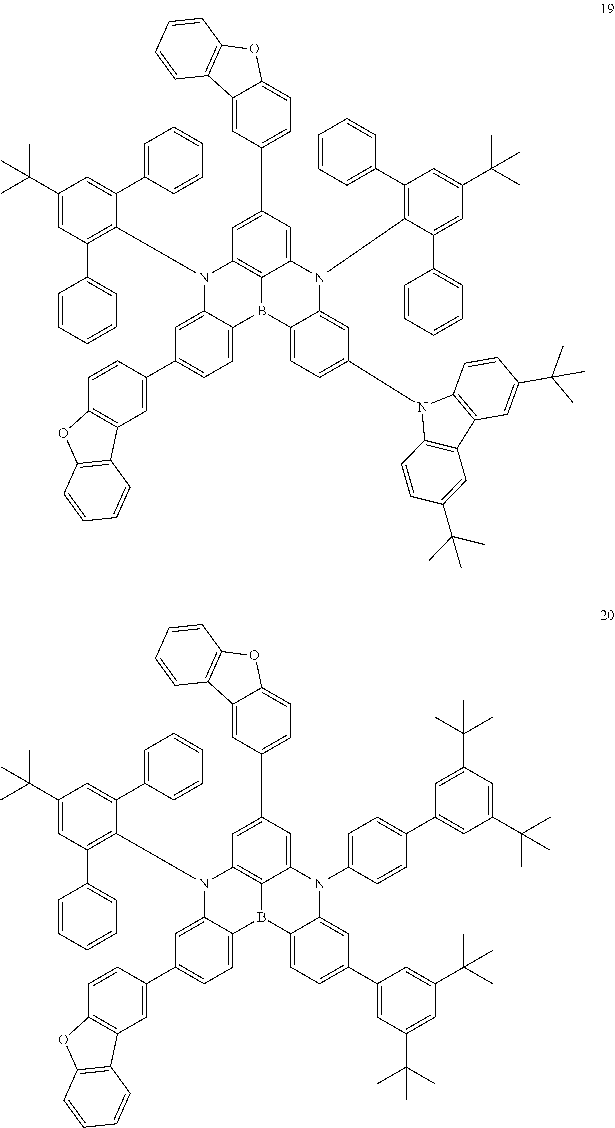

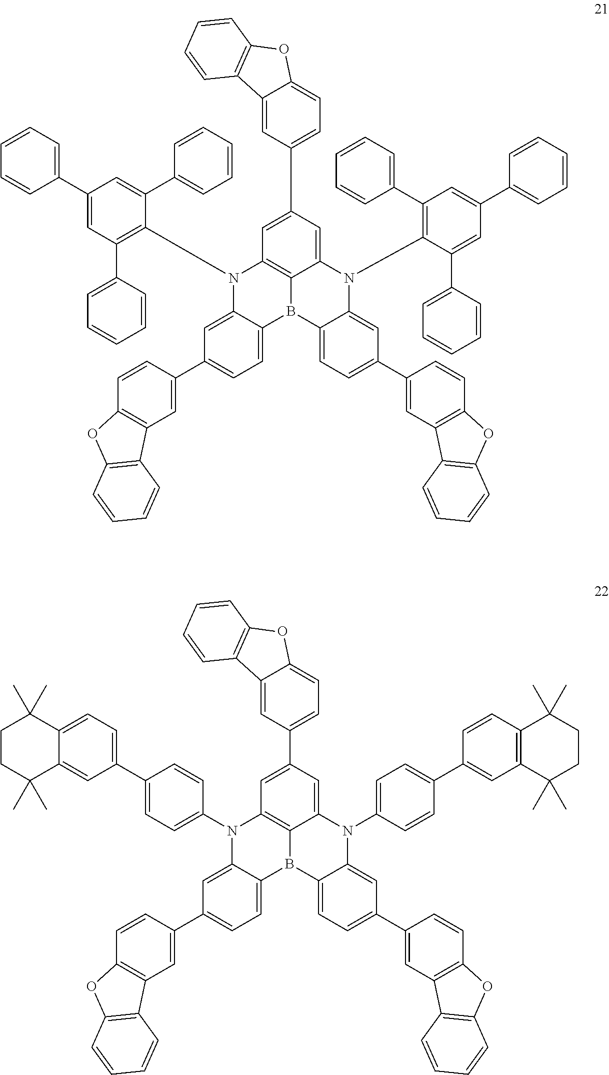 [SMILES: c1ccc(-c2cc(-c3ccccc3)c(N3c4cc(-c5ccc6oc7ccccc7c6c5)ccc4B4c5ccc(-c6ccc7oc8ccccc8c7c6)cc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC1(C)CCC(C)(C)c2cc(-c3ccc(N4c5cc(-c6ccc7oc8ccccc8c7c6)ccc5B5c6ccc(-c7ccc8oc9ccccc9c8c7)cc6N(c6ccc(-c7ccc8c(c7)C(C)(C)CCC8(C)C)cc6)c6cc(-c7ccc8oc9ccccc9c8c7)cc4c65)cc3)ccc21]

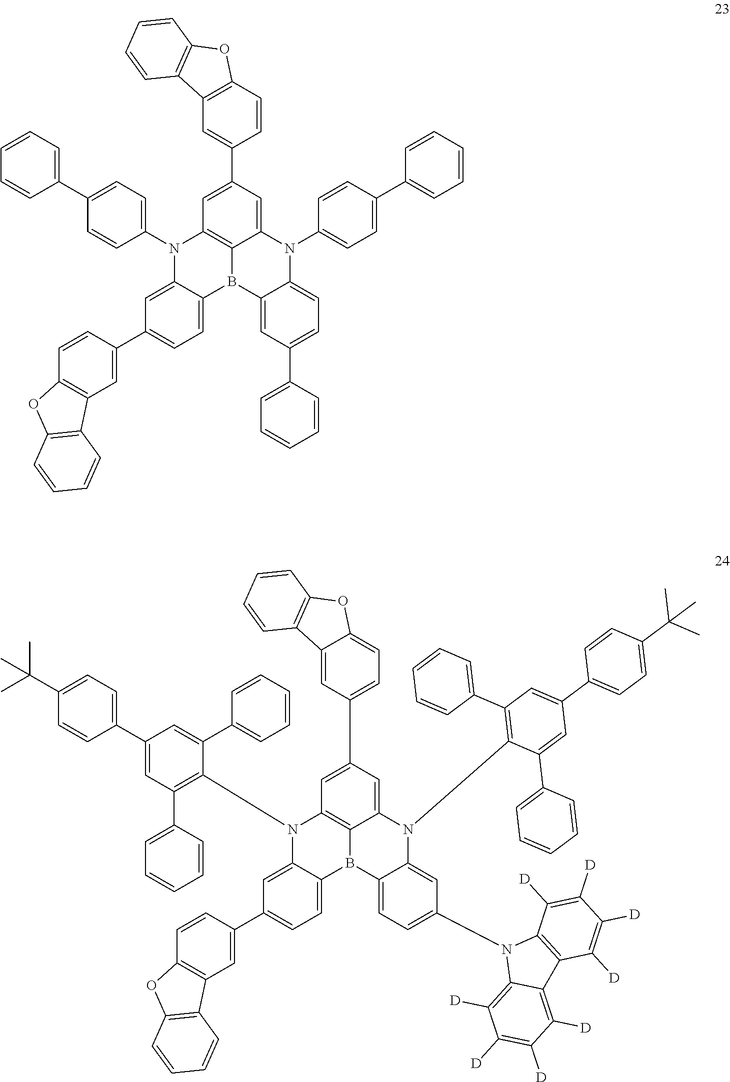 [SMILES: c1ccc(-c2ccc(N3c4ccc(-c5ccccc5)cc4B4c5ccc(-c6ccc7oc8ccccc8c7c6)cc5N(c5ccc(-c6ccccc6)cc5)c5cc(-c6ccc7oc8ccccc8c7c6)cc3c54)cc2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4oc5ccccc5c4c3)cc3c1B2c1ccc(-c2ccc4oc5ccccc5c4c2)cc1N3c1c(-c2ccccc2)cc(-c2ccc(C(C)(C)C)cc2)cc1-c1ccccc1]

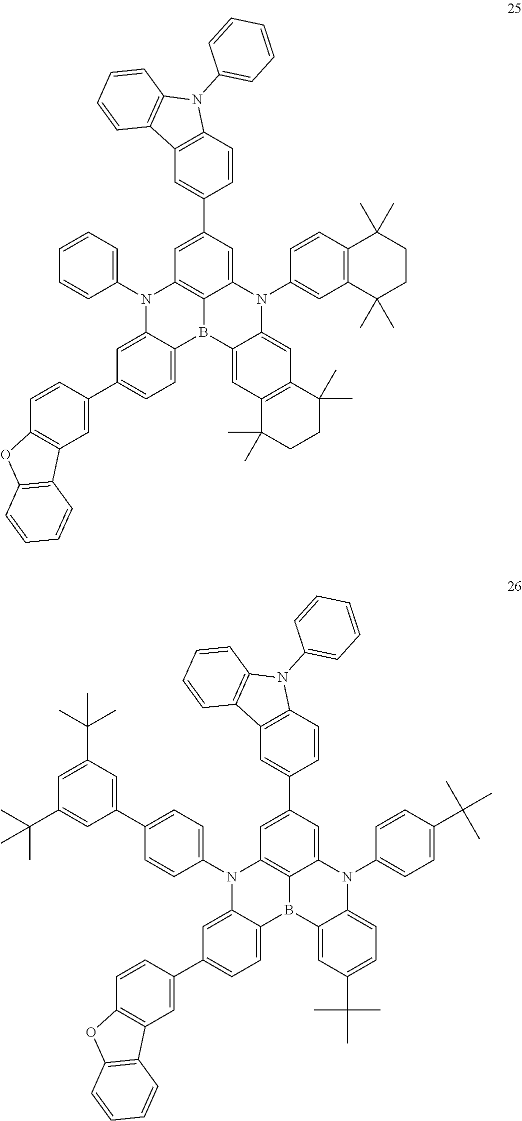 [SMILES: CC1(C)CCC(C)(C)c2cc(N3c4cc5c(cc4B4c6ccc(-c7ccc8oc9ccccc9c8c7)cc6N(c6ccccc6)c6cc(-c7ccc8c(c7)c7ccccc7n8-c7ccccc7)cc3c64)C(C)(C)CCC5(C)C)ccc21 ; CC(C)(C)c1ccc(N2c3ccc(C(C)(C)C)cc3B3c4ccc(-c5ccc6oc7ccccc7c6c5)cc4N(c4ccc(-c5cc(C(C)(C)C)cc(C(C)(C)C)c5)cc4)c4cc(-c5ccc6c(c5)c5ccccc5n6-c5ccccc5)cc2c43)cc1]

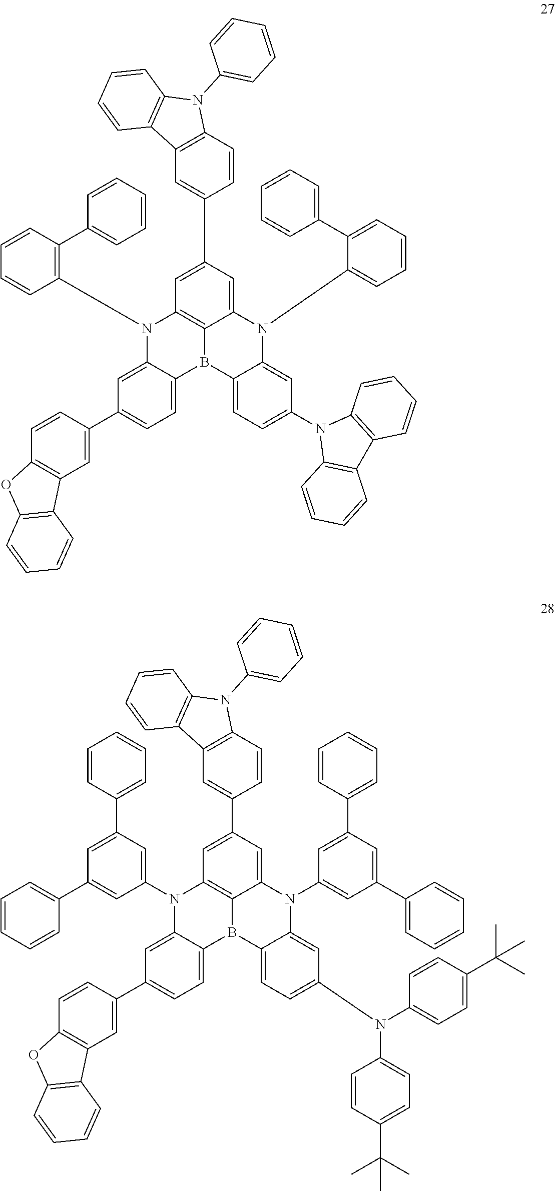 [SMILES: c1ccc(-c2ccccc2N2c3cc(-c4ccc5oc6ccccc6c5c4)ccc3B3c4ccc(-n5c6ccccc6c6ccccc65)cc4N(c4ccccc4-c4ccccc4)c4cc(-c5ccc6c(c5)c5ccccc5n6-c5ccccc5)cc2c43)cc1 ; CC(C)(C)c1ccc(N(c2ccc(C(C)(C)C)cc2)c2ccc3c(c2)N(c2cc(-c4ccccc4)cc(-c4ccccc4)c2)c2cc(-c4ccc5c(c4)c4ccccc4n5-c4ccccc4)cc4c2B3c2ccc(-c3ccc5oc6ccccc6c5c3)cc2N4c2cc(-c3ccccc3)cc(-c3ccccc3)c2)cc1]

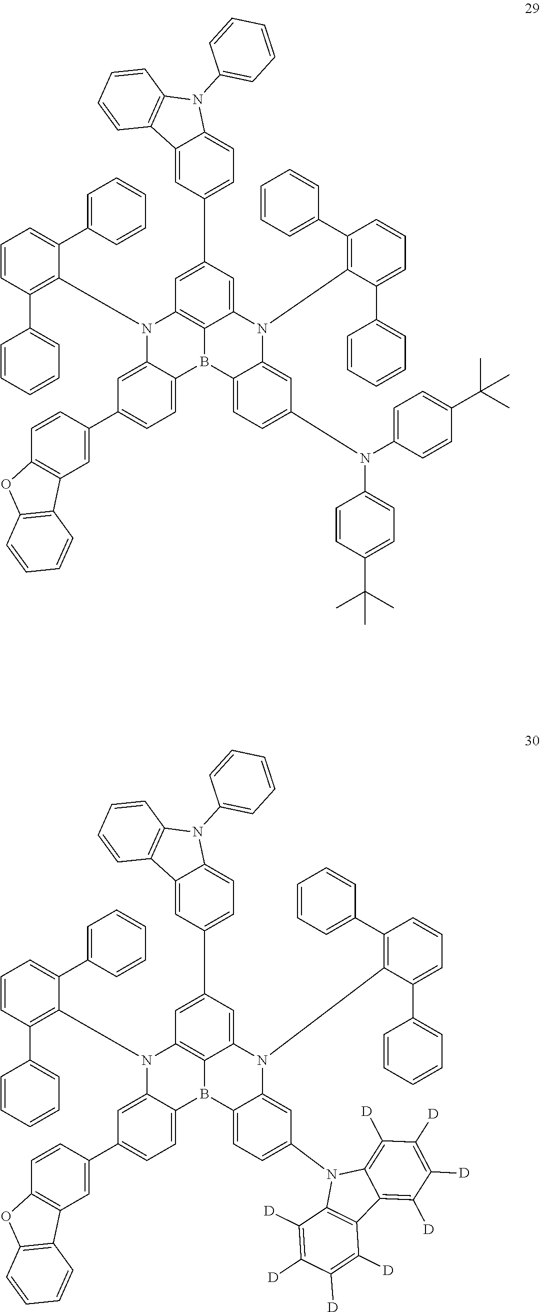 [SMILES: CC(C)(C)c1ccc(N(c2ccc(C(C)(C)C)cc2)c2ccc3c(c2)N(c2c(-c4ccccc4)cccc2-c2ccccc2)c2cc(-c4ccc5c(c4)c4ccccc4n5-c4ccccc4)cc4c2B3c2ccc(-c3ccc5oc6ccccc6c5c3)cc2N4c2c(-c3ccccc3)cccc2-c2ccccc2)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4c(c3)c3ccccc3n4-c3ccccc3)cc3c1B2c1ccc(-c2ccc4oc5ccccc5c4c2)cc1N3c1c(-c2ccccc2)cccc1-c1ccccc1]

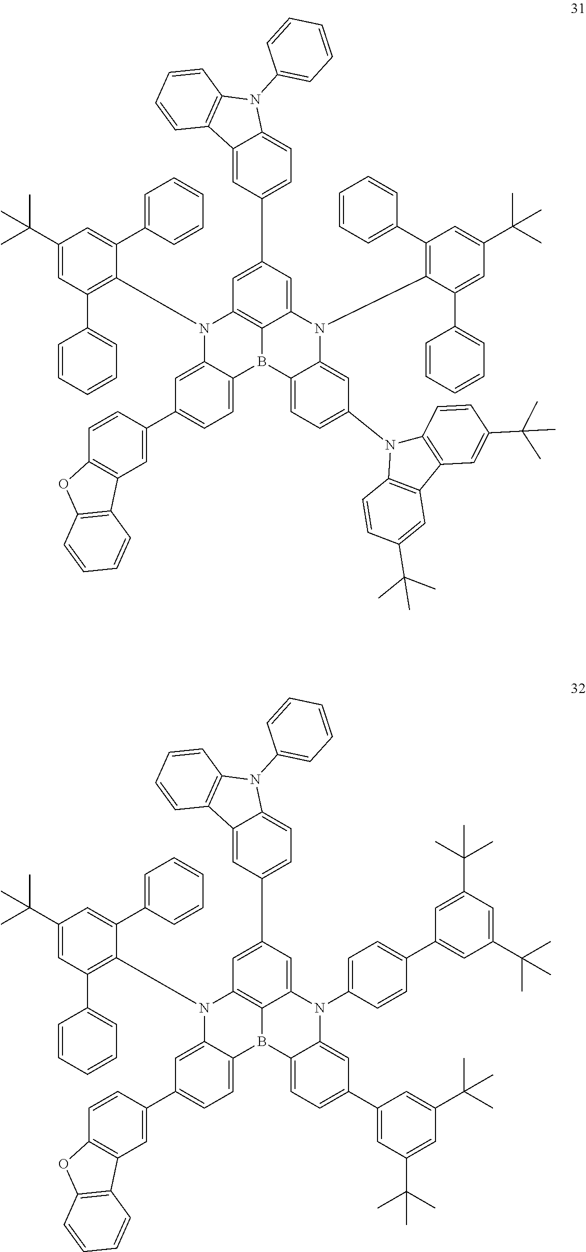

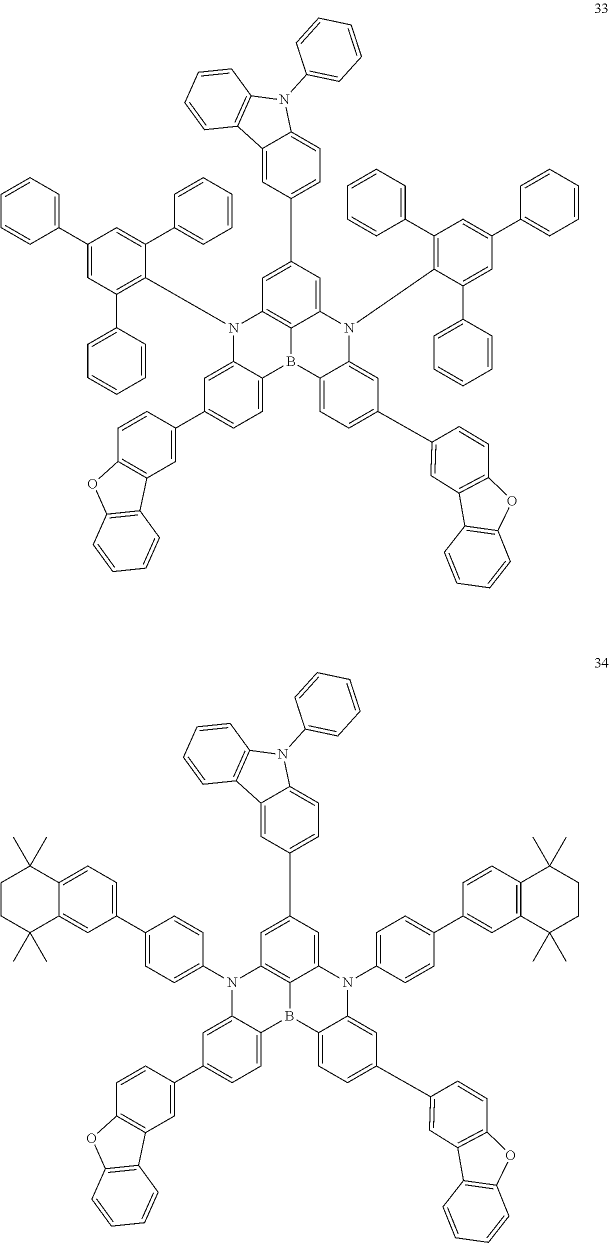 [SMILES: c1ccc(-c2cc(-c3ccccc3)c(N3c4cc(-c5ccc6oc7ccccc7c6c5)ccc4B4c5ccc(-c6ccc7oc8ccccc8c7c6)cc5N(c5c(-c6ccccc6)cc(-c6ccccc6)cc5-c5ccccc5)c5cc(-c6ccc7c(c6)c6ccccc6n7-c6ccccc6)cc3c54)c(-c3ccccc3)c2)cc1 ; CC1(C)CCC(C)(C)c2cc(-c3ccc(N4c5cc(-c6ccc7oc8ccccc8c7c6)ccc5B5c6ccc(-c7ccc8oc9ccccc9c8c7)cc6N(c6ccc(-c7ccc8c(c7)C(C)(C)CCC8(C)C)cc6)c6cc(-c7ccc8c(c7)c7ccccc7n8-c7ccccc7)cc4c65)cc3)ccc21]

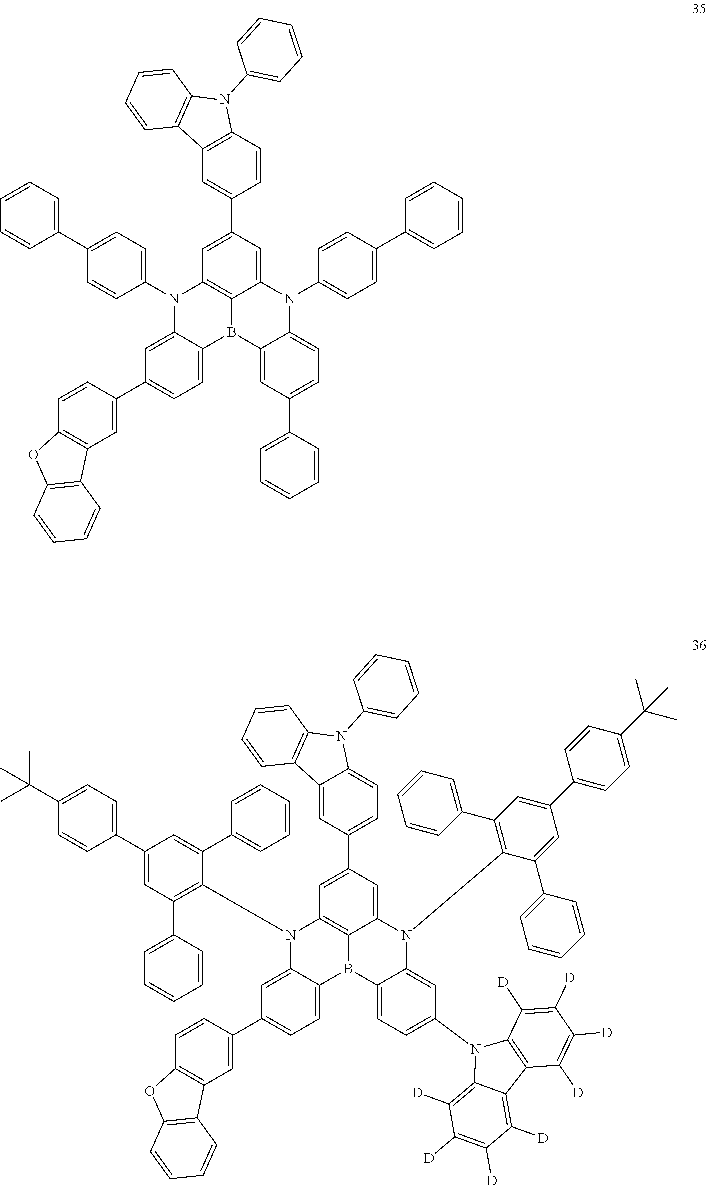 [SMILES: c1ccc(-c2ccc(N3c4ccc(-c5ccccc5)cc4B4c5ccc(-c6ccc7oc8ccccc8c7c6)cc5N(c5ccc(-c6ccccc6)cc5)c5cc(-c6ccc7c(c6)c6ccccc6n7-c6ccccc6)cc3c54)cc2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4c(c3)c3ccccc3n4-c3ccccc3)cc3c1B2c1ccc(-c2ccc4oc5ccccc5c4c2)cc1N3c1c(-c2ccccc2)cc(-c2ccc(C(C)(C)C)cc2)cc1-c1ccccc1]

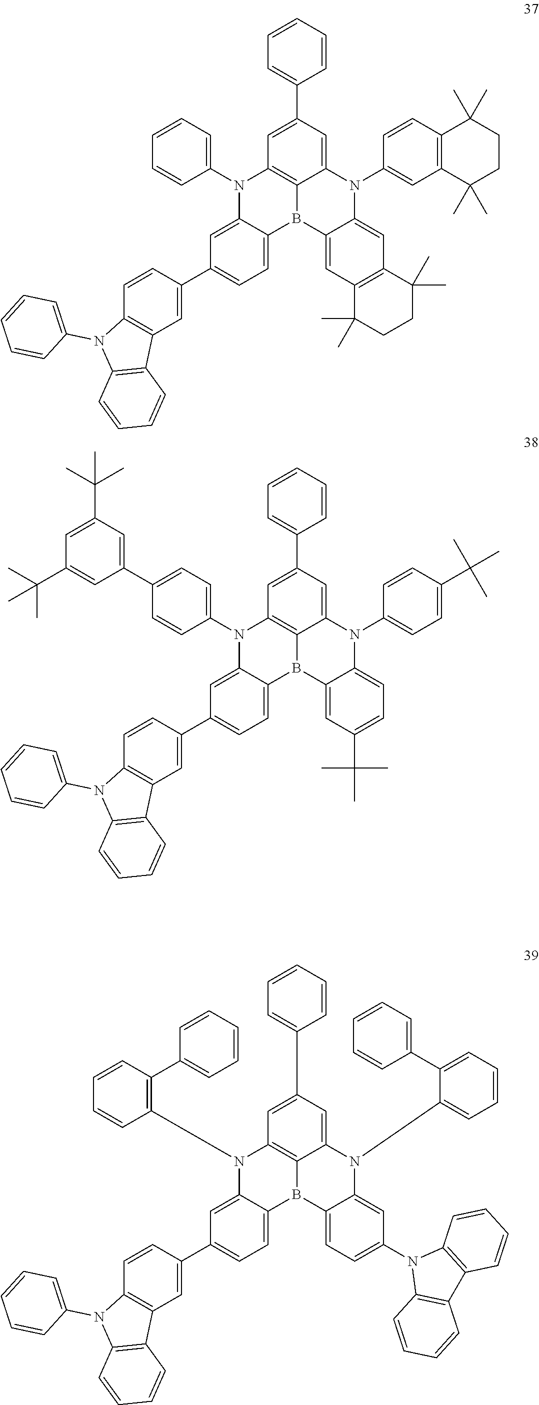

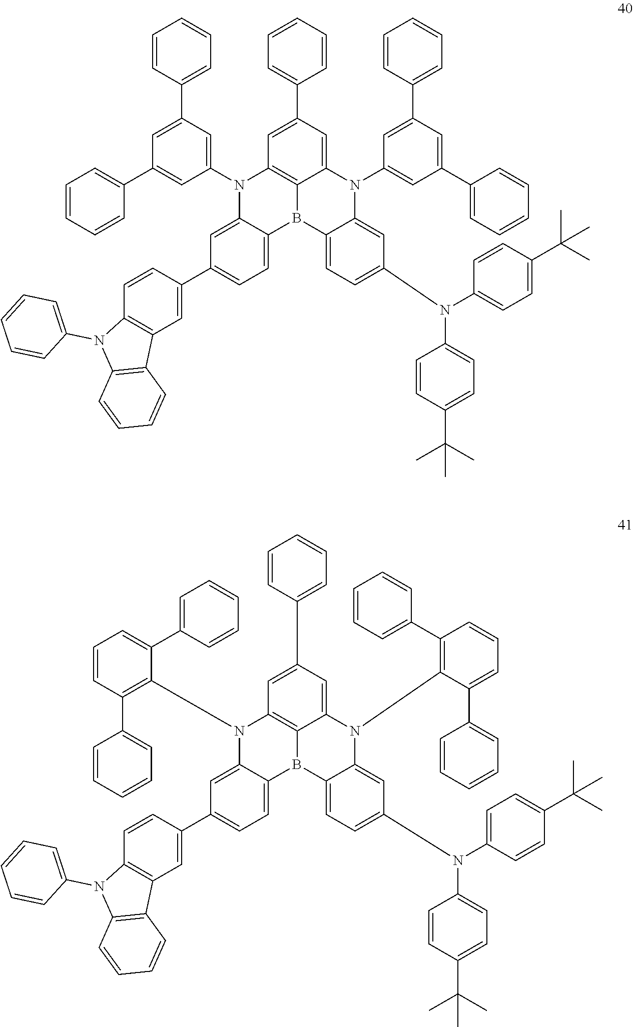 [SMILES: CC(C)(C)c1ccc(N(c2ccc(C(C)(C)C)cc2)c2ccc3c(c2)N(c2cc(-c4ccccc4)cc(-c4ccccc4)c2)c2cc(-c4ccccc4)cc4c2B3c2ccc(-c3ccc5c(c3)c3ccccc3n5-c3ccccc3)cc2N4c2cc(-c3ccccc3)cc(-c3ccccc3)c2)cc1 ; CC(C)(C)c1ccc(N(c2ccc(C(C)(C)C)cc2)c2ccc3c(c2)N(c2c(-c4ccccc4)cccc2-c2ccccc2)c2cc(-c4ccccc4)cc4c2B3c2ccc(-c3ccc5c(c3)c3ccccc3n5-c3ccccc3)cc2N4c2c(-c3ccccc3)cccc2-c2ccccc2)cc1]

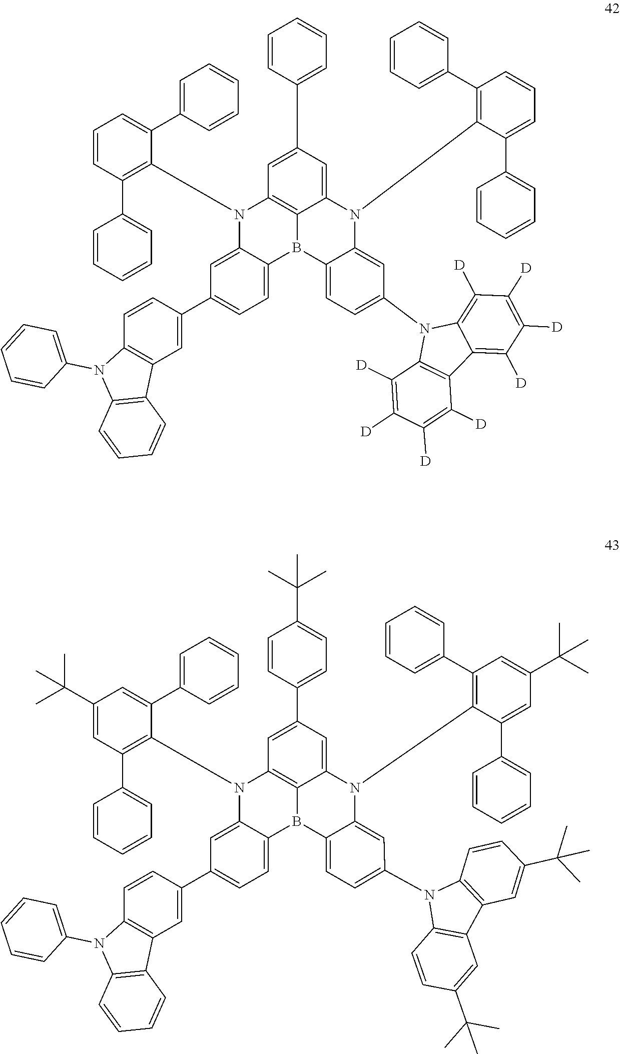 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccccc3)cc3c1B2c1ccc(-c2ccc4c(c2)c2ccccc2n4-c2ccccc2)cc1N3c1c(-c2ccccc2)cccc1-c1ccccc1 ; CC(C)(C)c1ccc(-c2cc3c4c(c2)N(c2c(-c5ccccc5)cc(C(C)(C)C)cc2-c2ccccc2)c2cc(-n5c6ccc(C(C)(C)C)cc6c6cc(C(C)(C)C)ccc65)ccc2B4c2ccc(-c4ccc5c(c4)c4ccccc4n5-c4ccccc4)cc2N3c2c(-c3ccccc3)cc(C(C)(C)C)cc2-c2ccccc2)cc1]

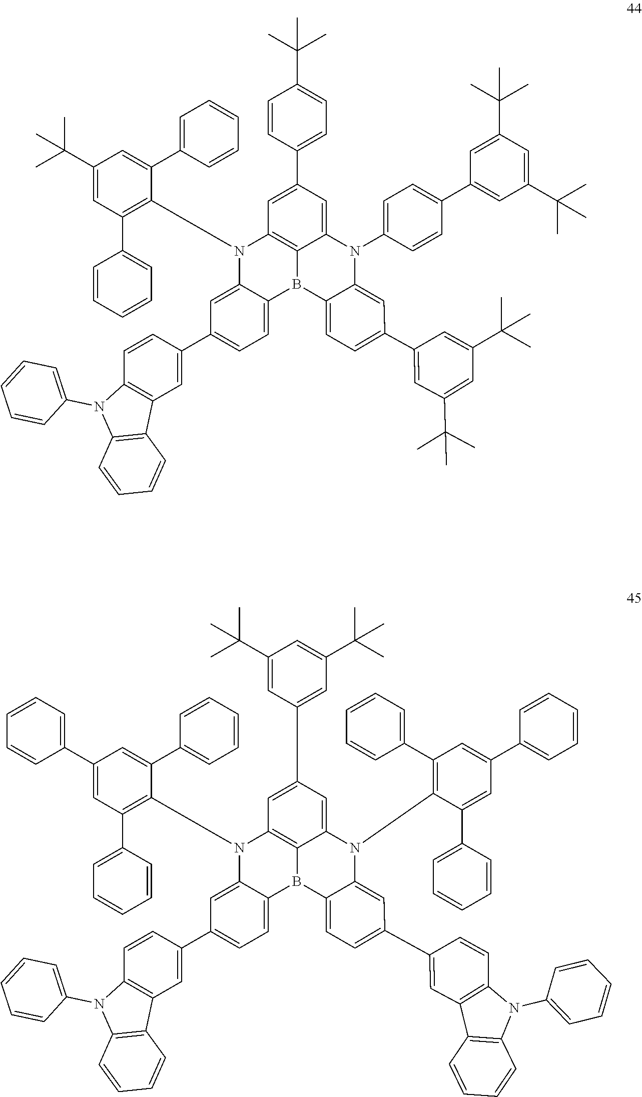 [SMILES: CC(C)(C)c1ccc(-c2cc3c4c(c2)N(c2c(-c5ccccc5)cc(C(C)(C)C)cc2-c2ccccc2)c2cc(-c5ccc6c(c5)c5ccccc5n6-c5ccccc5)ccc2B4c2ccc(-c4cc(C(C)(C)C)cc(C(C)(C)C)c4)cc2N3c2ccc(-c3cc(C(C)(C)C)cc(C(C)(C)C)c3)cc2)cc1 ; CC(C)(C)c1cc(-c2cc3c4c(c2)N(c2c(-c5ccccc5)cc(-c5ccccc5)cc2-c2ccccc2)c2cc(-c5ccc6c(c5)c5ccccc5n6-c5ccccc5)ccc2B4c2ccc(-c4ccc5c(c4)c4ccccc4n5-c4ccccc4)cc2N3c2c(-c3ccccc3)cc(-c3ccccc3)cc2-c2ccccc2)cc(C(C)(C)C)c1]

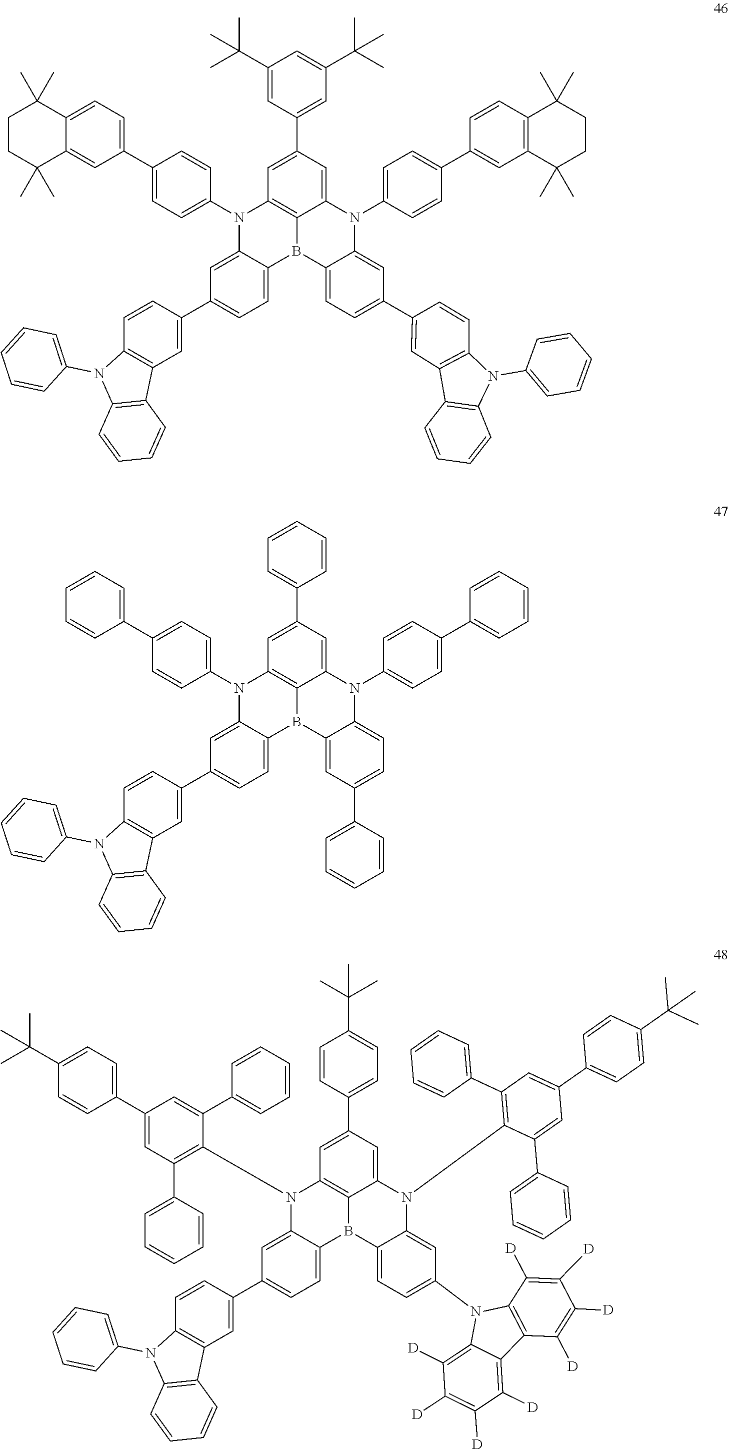

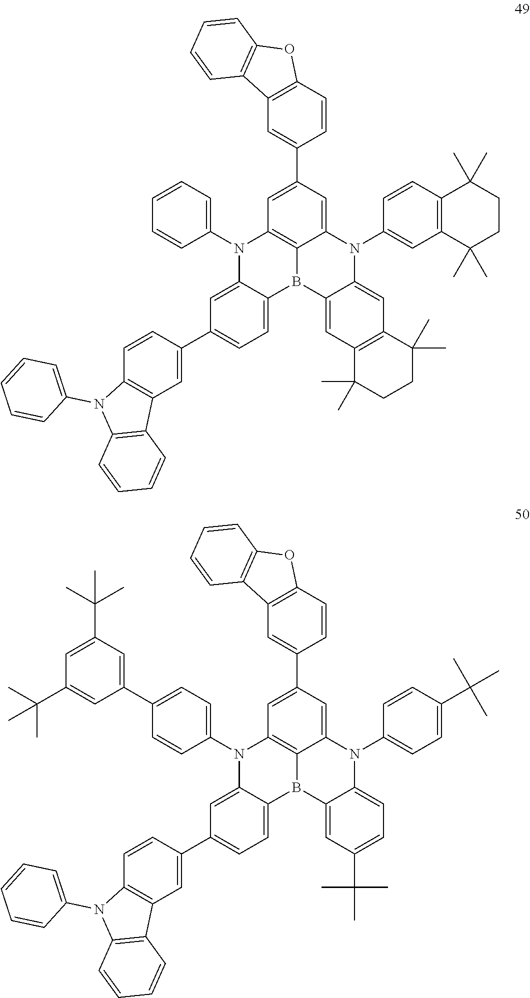 [SMILES: CC1(C)CCC(C)(C)c2cc(N3c4cc5c(cc4B4c6ccc(-c7ccc8c(c7)c7ccccc7n8-c7ccccc7)cc6N(c6ccccc6)c6cc(-c7ccc8oc9ccccc9c8c7)cc3c64)C(C)(C)CCC5(C)C)ccc21 ; CC(C)(C)c1ccc(N2c3ccc(C(C)(C)C)cc3B3c4ccc(-c5ccc6c(c5)c5ccccc5n6-c5ccccc5)cc4N(c4ccc(-c5cc(C(C)(C)C)cc(C(C)(C)C)c5)cc4)c4cc(-c5ccc6oc7ccccc7c6c5)cc2c43)cc1]

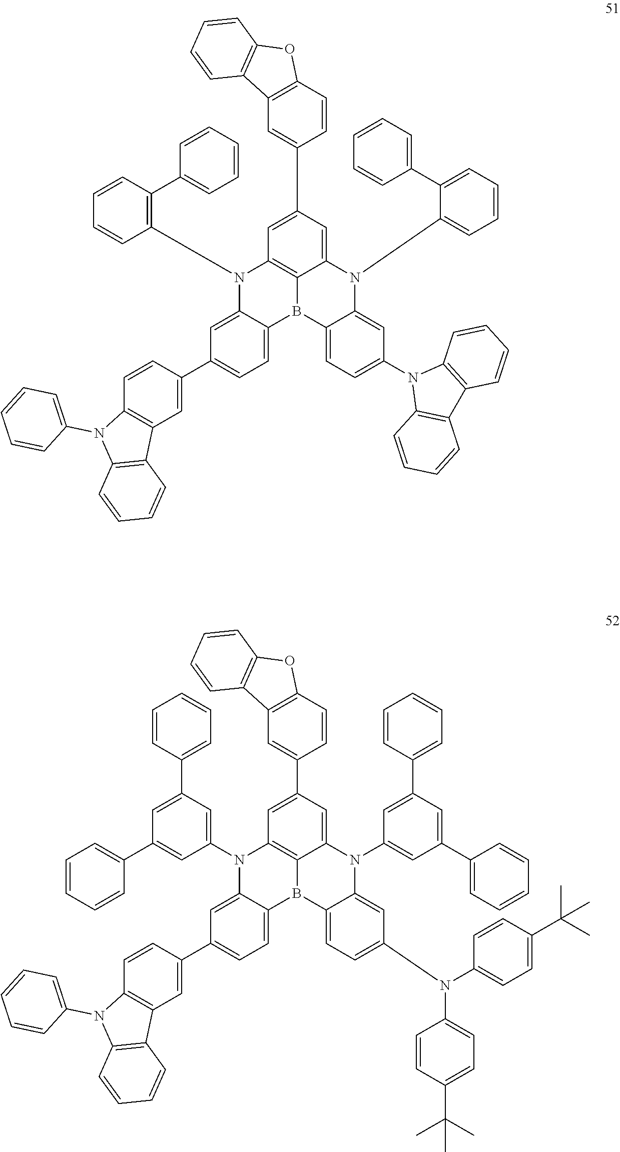 [SMILES: c1ccc(-c2ccccc2N2c3cc(-c4ccc5c(c4)c4ccccc4n5-c4ccccc4)ccc3B3c4ccc(-n5c6ccccc6c6ccccc65)cc4N(c4ccccc4-c4ccccc4)c4cc(-c5ccc6oc7ccccc7c6c5)cc2c43)cc1 ; CC(C)(C)c1ccc(N(c2ccc(C(C)(C)C)cc2)c2ccc3c(c2)N(c2cc(-c4ccccc4)cc(-c4ccccc4)c2)c2cc(-c4ccc5oc6ccccc6c5c4)cc4c2B3c2ccc(-c3ccc5c(c3)c3ccccc3n5-c3ccccc3)cc2N4c2cc(-c3ccccc3)cc(-c3ccccc3)c2)cc1]

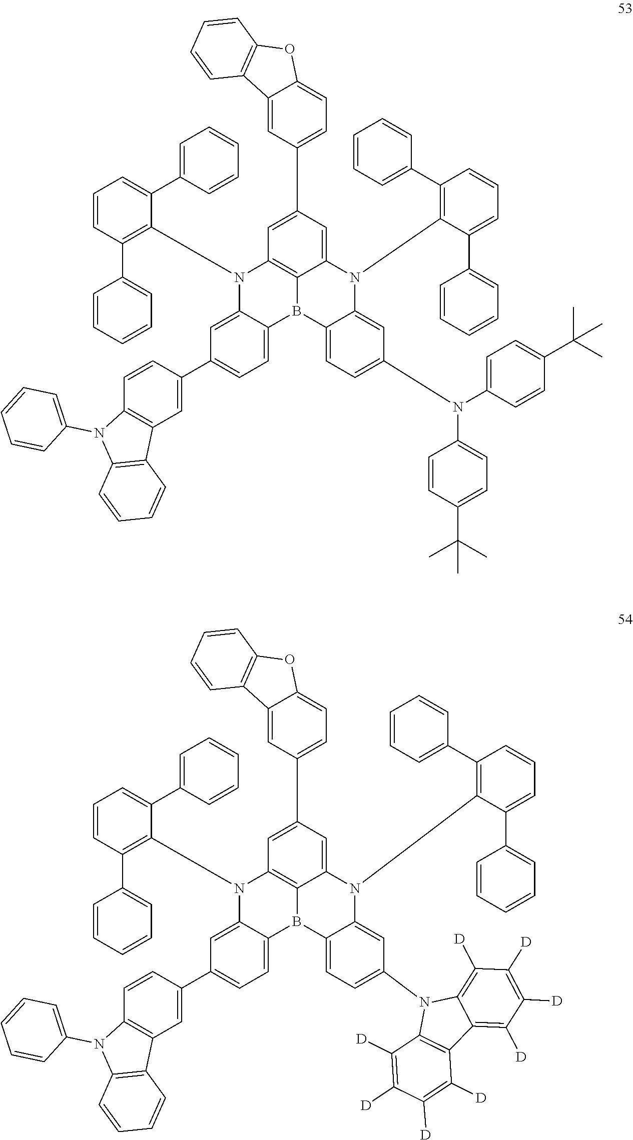 [SMILES: CC(C)(C)c1ccc(N(c2ccc(C(C)(C)C)cc2)c2ccc3c(c2)N(c2c(-c4ccccc4)cccc2-c2ccccc2)c2cc(-c4ccc5oc6ccccc6c5c4)cc4c2B3c2ccc(-c3ccc5c(c3)c3ccccc3n5-c3ccccc3)cc2N4c2c(-c3ccccc3)cccc2-c2ccccc2)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc(-c2ccc4c(c2)c2ccccc2n4-c2ccccc2)cc1N3c1c(-c2ccccc2)cccc1-c1ccccc1]

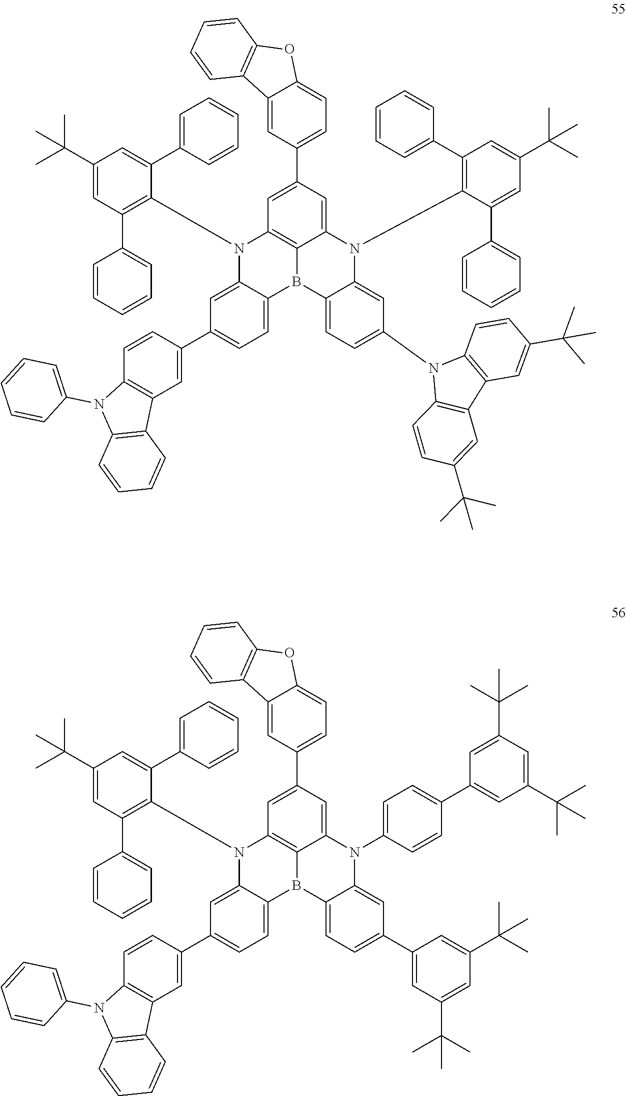 [SMILES: CC(C)(C)c1cc(-c2ccccc2)c(N2c3cc(-c4ccc5c(c4)c4ccccc4n5-c4ccccc4)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-c5ccc6oc7ccccc7c6c5)cc2c43)c(-c2ccccc2)c1 ; CC(C)(C)c1cc(-c2ccc(N3c4cc(-c5cc(C(C)(C)C)cc(C(C)(C)C)c5)ccc4B4c5ccc(-c6ccc7c(c6)c6ccccc6n7-c6ccccc6)cc5N(c5c(-c6ccccc6)cc(C(C)(C)C)cc5-c5ccccc5)c5cc(-c6ccc7oc8ccccc8c7c6)cc3c54)cc2)cc(C(C)(C)C)c1]

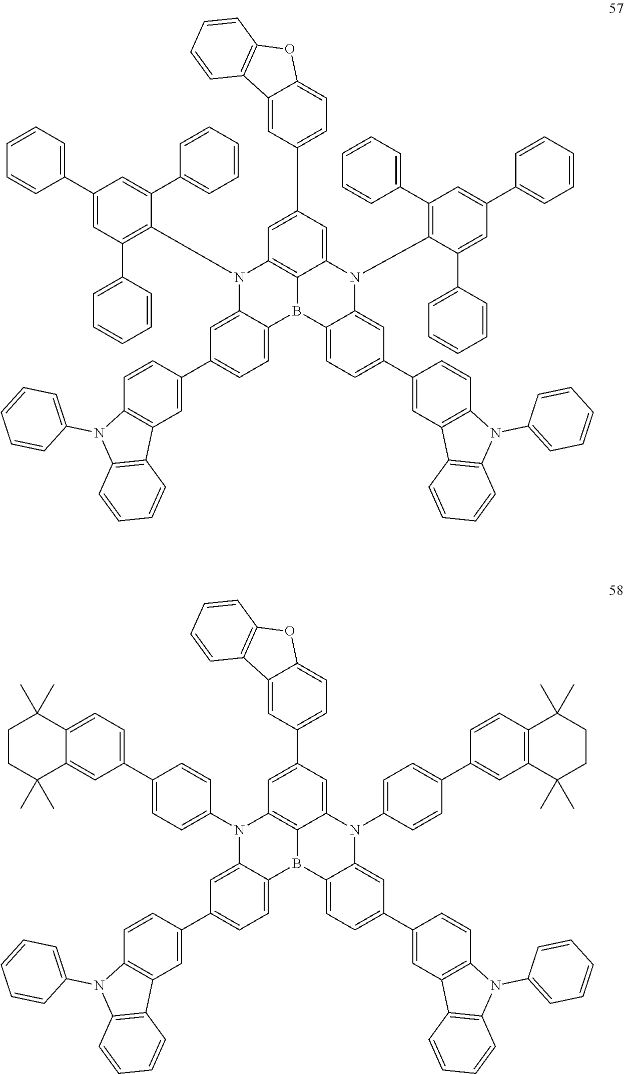 [SMILES: c1ccc(-c2cc(-c3ccccc3)c(N3c4cc(-c5ccc6c(c5)c5ccccc5n6-c5ccccc5)ccc4B4c5ccc(-c6ccc7c(c6)c6ccccc6n7-c6ccccc6)cc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC1(C)CCC(C)(C)c2cc(-c3ccc(N4c5cc(-c6ccc7c(c6)c6ccccc6n7-c6ccccc6)ccc5B5c6ccc(-c7ccc8c(c7)c7ccccc7n8-c7ccccc7)cc6N(c6ccc(-c7ccc8c(c7)C(C)(C)CCC8(C)C)cc6)c6cc(-c7ccc8oc9ccccc9c8c7)cc4c65)cc3)ccc21]

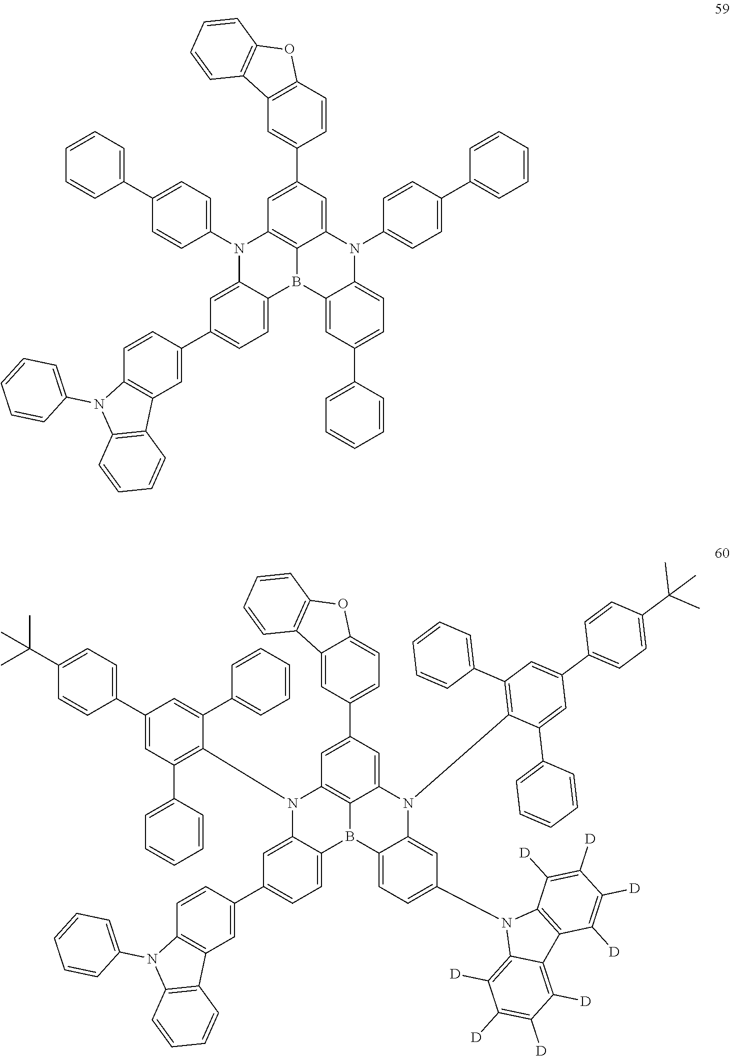 [SMILES: c1ccc(-c2ccc(N3c4ccc(-c5ccccc5)cc4B4c5ccc(-c6ccc7c(c6)c6ccccc6n7-c6ccccc6)cc5N(c5ccc(-c6ccccc6)cc5)c5cc(-c6ccc7oc8ccccc8c7c6)cc3c54)cc2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4oc5ccccc5c4c3)cc3c1B2c1ccc(-c2ccc4c(c2)c2ccccc2n4-c2ccccc2)cc1N3c1c(-c2ccccc2)cc(-c2ccc(C(C)(C)C)cc2)cc1-c1ccccc1]

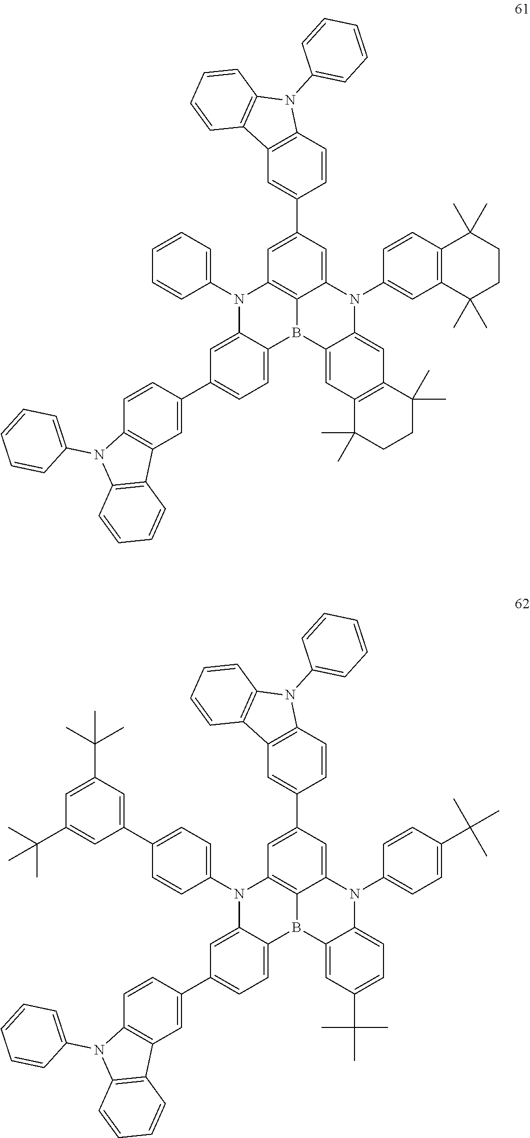 [SMILES: CC1(C)CCC(C)(C)c2cc(N3c4cc5c(cc4B4c6ccc(-c7ccc8c(c7)c7ccccc7n8-c7ccccc7)cc6N(c6ccccc6)c6cc(-c7ccc8c(c7)c7ccccc7n8-c7ccccc7)cc3c64)C(C)(C)CCC5(C)C)ccc21 ; CC(C)(C)c1ccc(N2c3ccc(C(C)(C)C)cc3B3c4ccc(-c5ccc6c(c5)c5ccccc5n6-c5ccccc5)cc4N(c4ccc(-c5cc(C(C)(C)C)cc(C(C)(C)C)c5)cc4)c4cc(-c5ccc6c(c5)c5ccccc5n6-c5ccccc5)cc2c43)cc1]

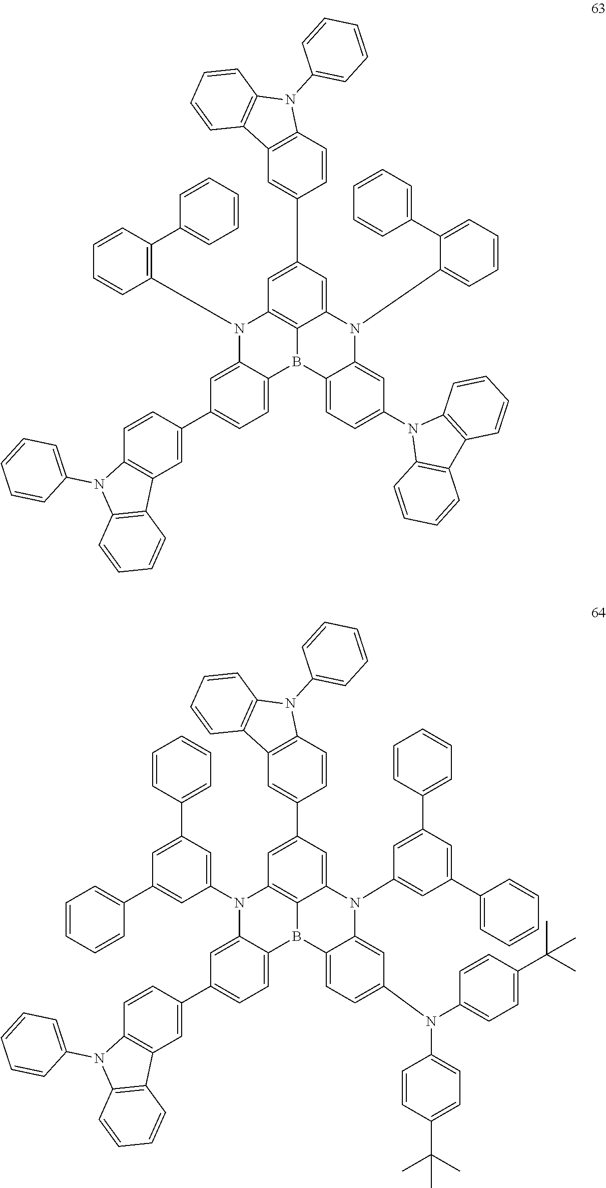 [SMILES: c1ccc(-c2ccccc2N2c3cc(-c4ccc5c(c4)c4ccccc4n5-c4ccccc4)ccc3B3c4ccc(-n5c6ccccc6c6ccccc65)cc4N(c4ccccc4-c4ccccc4)c4cc(-c5ccc6c(c5)c5ccccc5n6-c5ccccc5)cc2c43)cc1 ; CC(C)(C)c1ccc(N(c2ccc(C(C)(C)C)cc2)c2ccc3c(c2)N(c2cc(-c4ccccc4)cc(-c4ccccc4)c2)c2cc(-c4ccc5c(c4)c4ccccc4n5-c4ccccc4)cc4c2B3c2ccc(-c3ccc5c(c3)c3ccccc3n5-c3ccccc3)cc2N4c2cc(-c3ccccc3)cc(-c3ccccc3)c2)cc1]

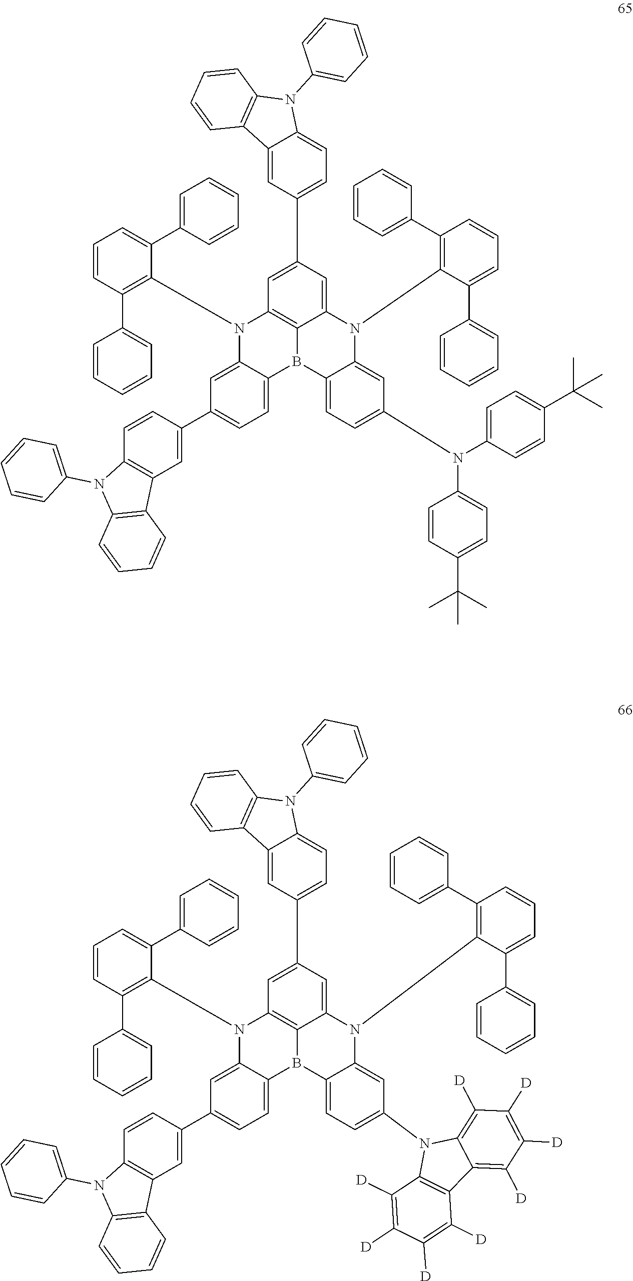 [SMILES: CC(C)(C)c1ccc(N(c2ccc(C(C)(C)C)cc2)c2ccc3c(c2)N(c2c(-c4ccccc4)cccc2-c2ccccc2)c2cc(-c4ccc5c(c4)c4ccccc4n5-c4ccccc4)cc4c2B3c2ccc(-c3ccc5c(c3)c3ccccc3n5-c3ccccc3)cc2N4c2c(-c3ccccc3)cccc2-c2ccccc2)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4c(c3)c3ccccc3n4-c3ccccc3)cc3c1B2c1ccc(-c2ccc4c(c2)c2ccccc2n4-c2ccccc2)cc1N3c1c(-c2ccccc2)cccc1-c1ccccc1]

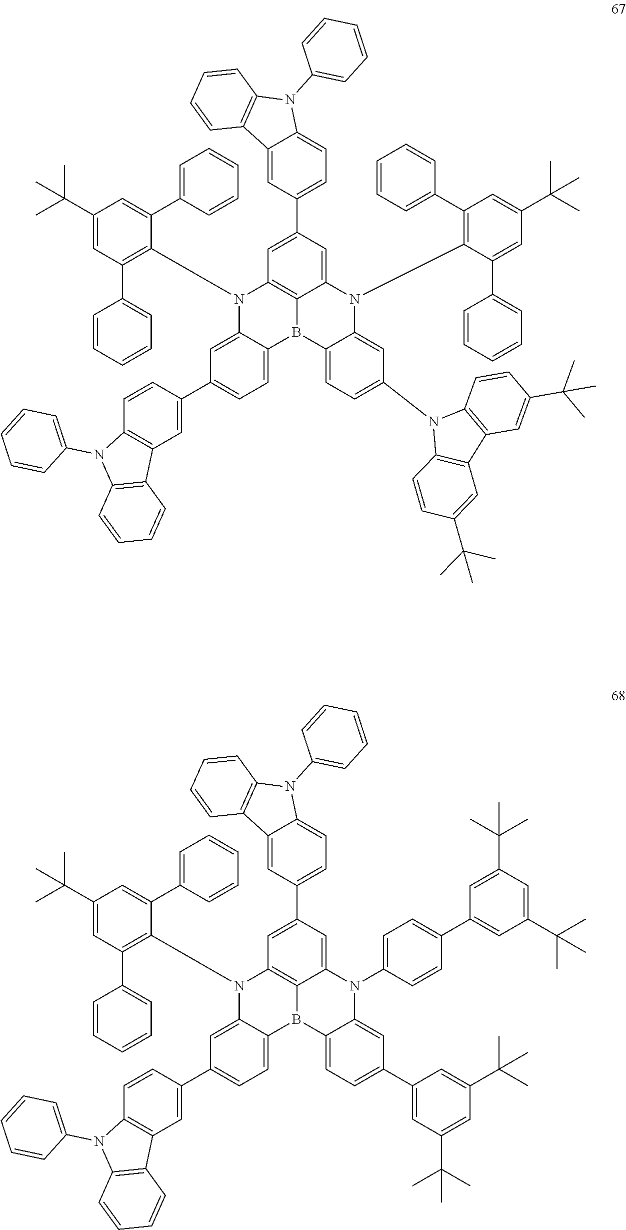 [SMILES: CC(C)(C)c1cc(-c2ccccc2)c(N2c3cc(-c4ccc5c(c4)c4ccccc4n5-c4ccccc4)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-c5ccc6c(c5)c5ccccc5n6-c5ccccc5)cc2c43)c(-c2ccccc2)c1 ; CC(C)(C)c1cc(-c2ccc(N3c4cc(-c5cc(C(C)(C)C)cc(C(C)(C)C)c5)ccc4B4c5ccc(-c6ccc7c(c6)c6ccccc6n7-c6ccccc6)cc5N(c5c(-c6ccccc6)cc(C(C)(C)C)cc5-c5ccccc5)c5cc(-c6ccc7c(c6)c6ccccc6n7-c6ccccc6)cc3c54)cc2)cc(C(C)(C)C)c1]

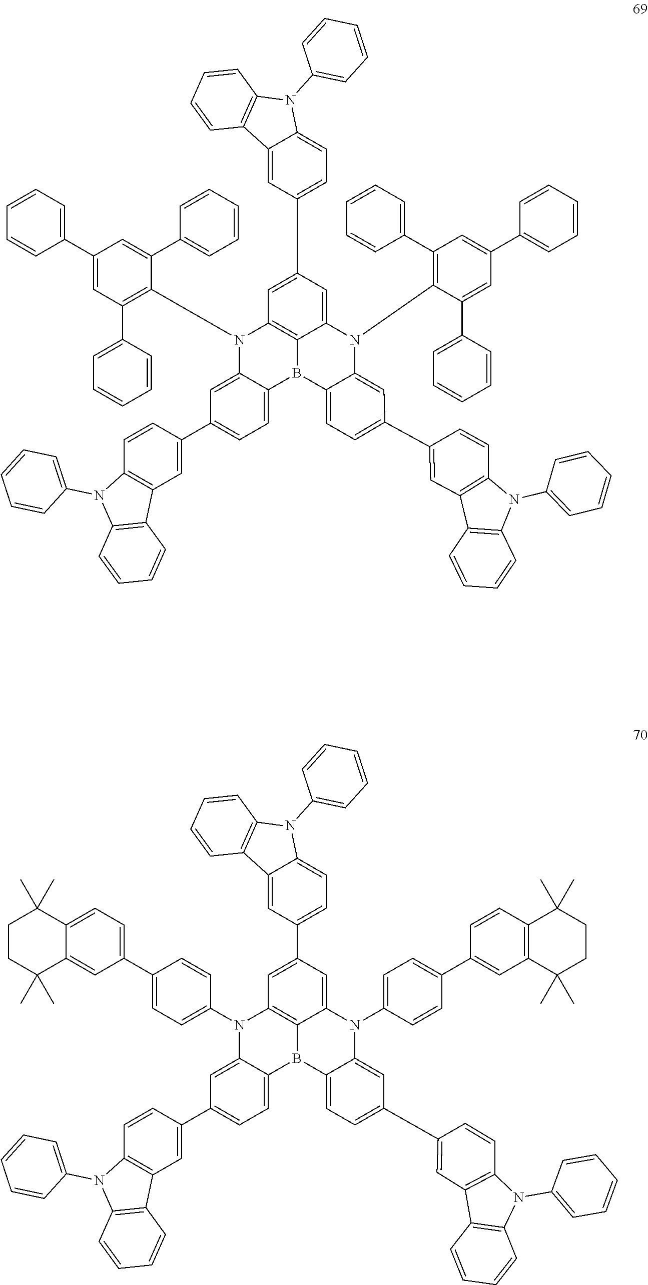 [SMILES: c1ccc(-c2cc(-c3ccccc3)c(N3c4cc(-c5ccc6c(c5)c5ccccc5n6-c5ccccc5)ccc4B4c5ccc(-c6ccc7c(c6)c6ccccc6n7-c6ccccc6)cc5N(c5c(-c6ccccc6)cc(-c6ccccc6)cc5-c5ccccc5)c5cc(-c6ccc7c(c6)c6ccccc6n7-c6ccccc6)cc3c54)c(-c3ccccc3)c2)cc1 ; CC1(C)CCC(C)(C)c2cc(-c3ccc(N4c5cc(-c6ccc7c(c6)c6ccccc6n7-c6ccccc6)ccc5B5c6ccc(-c7ccc8c(c7)c7ccccc7n8-c7ccccc7)cc6N(c6ccc(-c7ccc8c(c7)C(C)(C)CCC8(C)C)cc6)c6cc(-c7ccc8c(c7)c7ccccc7n8-c7ccccc7)cc4c65)cc3)ccc21]

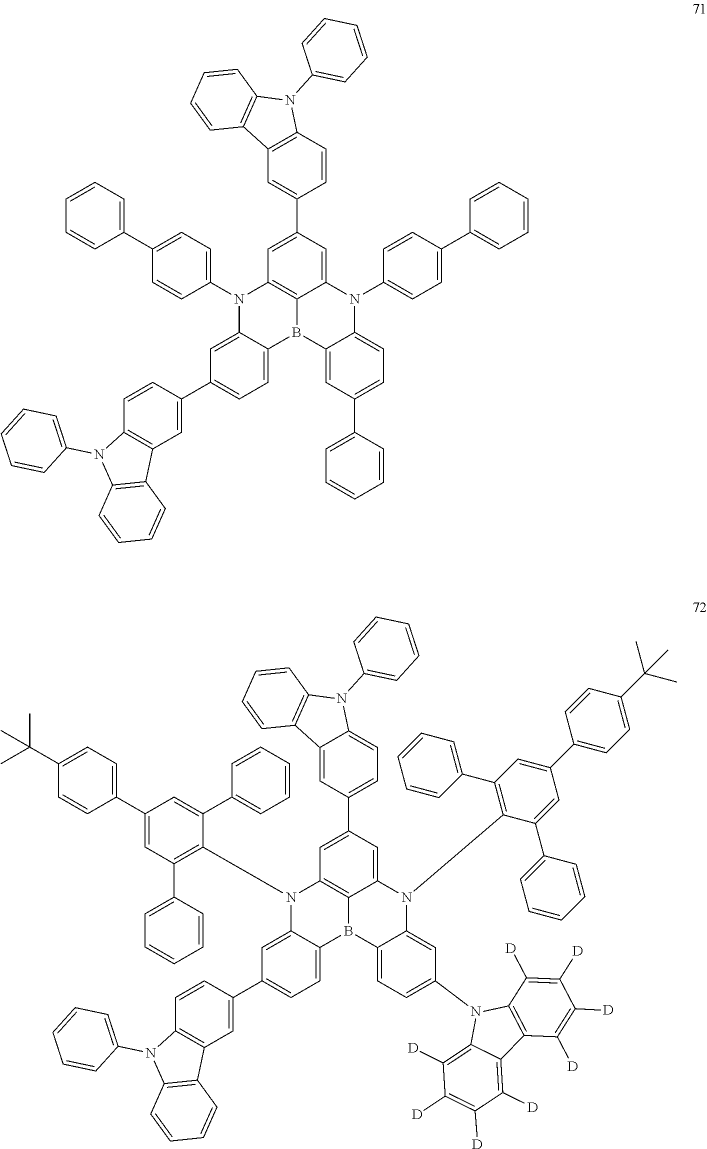 [SMILES: c1ccc(-c2ccc(N3c4ccc(-c5ccccc5)cc4B4c5ccc(-c6ccc7c(c6)c6ccccc6n7-c6ccccc6)cc5N(c5ccc(-c6ccccc6)cc5)c5cc(-c6ccc7c(c6)c6ccccc6n7-c6ccccc6)cc3c54)cc2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4c(c3)c3ccccc3n4-c3ccccc3)cc3c1B2c1ccc(-c2ccc4c(c2)c2ccccc2n4-c2ccccc2)cc1N3c1c(-c2ccccc2)cc(-c2ccc(C(C)(C)C)cc2)cc1-c1ccccc1]

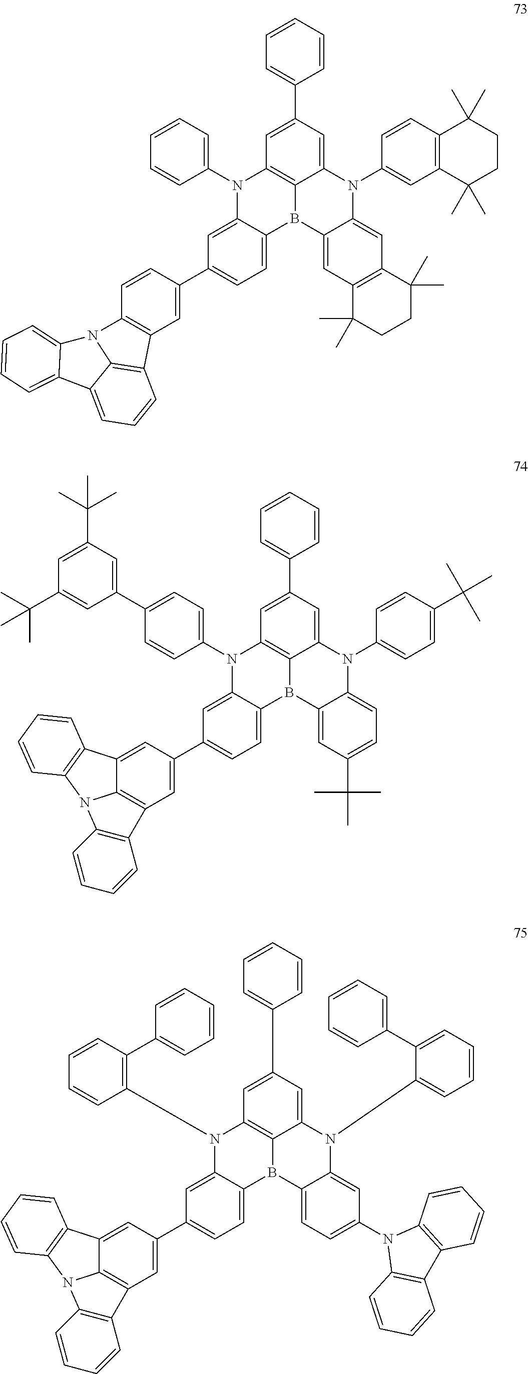 [SMILES: CC1(C)CCC(C)(C)c2cc(N3c4cc5c(cc4B4c6ccc(-c7ccc8c(c7)c7cccc9c%10ccccc%10n8c97)cc6N(c6ccccc6)c6cc(-c7ccccc7)cc3c64)C(C)(C)CCC5(C)C)ccc21 ; CC(C)(C)c1ccc(N2c3ccc(C(C)(C)C)cc3B3c4ccc(-c5cc6c7ccccc7n7c8ccccc8c(c5)c67)cc4N(c4ccc(-c5cc(C(C)(C)C)cc(C(C)(C)C)c5)cc4)c4cc(-c5ccccc5)cc2c43)cc1 ; c1ccc(-c2cc3c4c(c2)N(c2ccccc2-c2ccccc2)c2cc(-n5c6ccccc6c6ccccc65)ccc2B4c2ccc(-c4cc5c6ccccc6n6c7ccccc7c(c4)c56)cc2N3c2ccccc2-c2ccccc2)cc1]

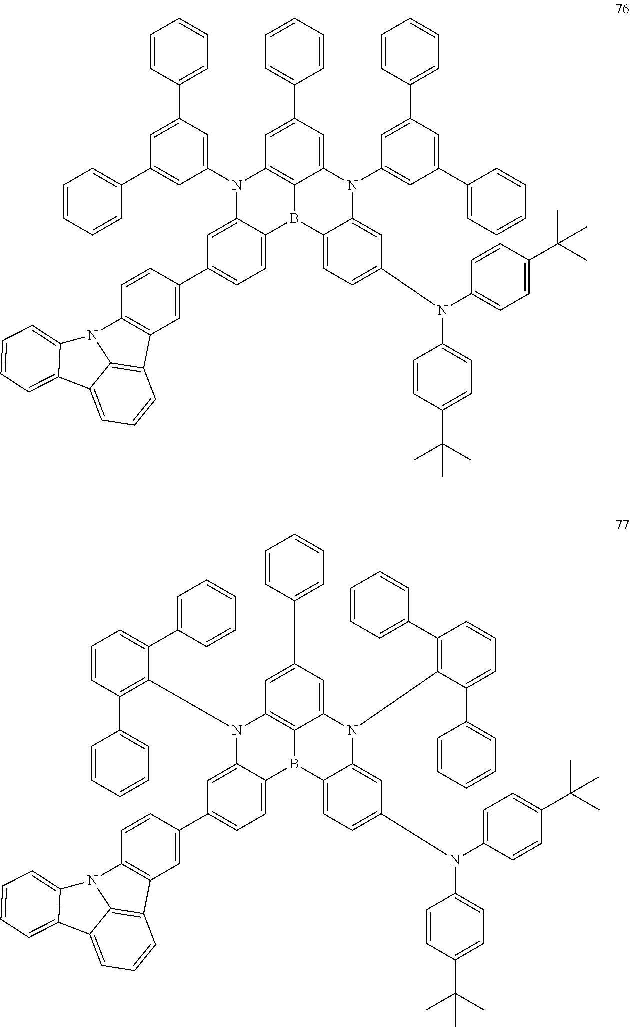 [SMILES: CC(C)(C)c1ccc(N(c2ccc(C(C)(C)C)cc2)c2ccc3c(c2)N(c2cc(-c4ccccc4)cc(-c4ccccc4)c2)c2cc(-c4ccccc4)cc4c2B3c2ccc(-c3ccc5c(c3)c3cccc6c7ccccc7n5c63)cc2N4c2cc(-c3ccccc3)cc(-c3ccccc3)c2)cc1 ; CC(C)(C)c1ccc(N(c2ccc(C(C)(C)C)cc2)c2ccc3c(c2)N(c2c(-c4ccccc4)cccc2-c2ccccc2)c2cc(-c4ccccc4)cc4c2B3c2ccc(-c3ccc5c(c3)c3cccc6c7ccccc7n5c63)cc2N4c2c(-c3ccccc3)cccc2-c2ccccc2)cc1]

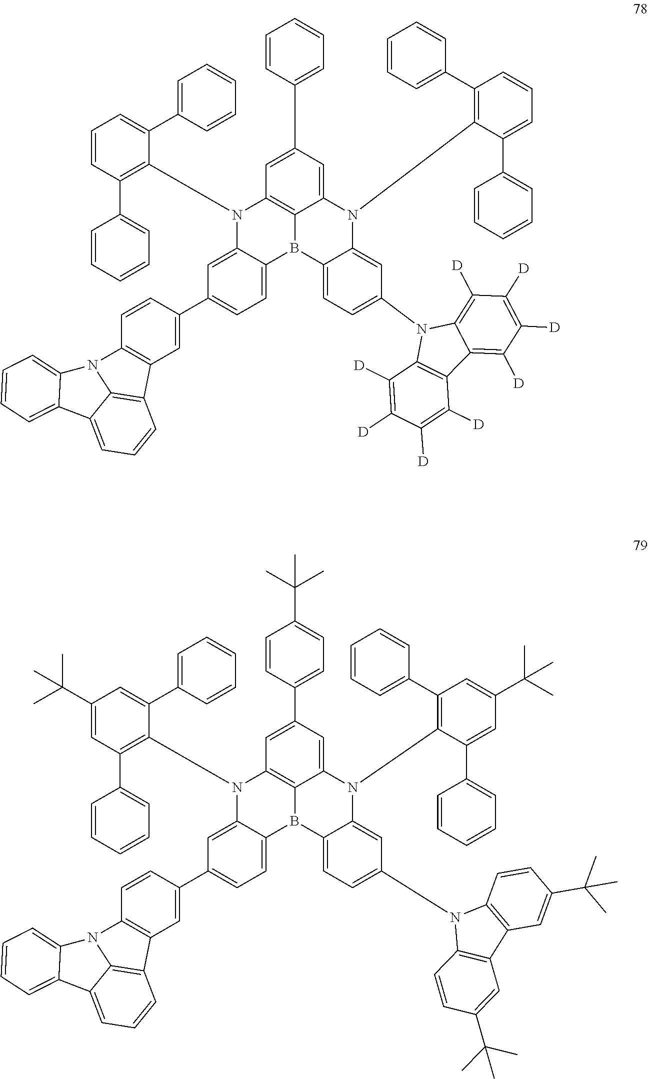 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccccc3)cc3c1B2c1ccc(-c2ccc4c(c2)c2cccc5c6ccccc6n4c52)cc1N3c1c(-c2ccccc2)cccc1-c1ccccc1 ; CC(C)(C)c1ccc(-c2cc3c4c(c2)N(c2c(-c5ccccc5)cc(C(C)(C)C)cc2-c2ccccc2)c2cc(-n5c6ccc(C(C)(C)C)cc6c6cc(C(C)(C)C)ccc65)ccc2B4c2ccc(-c4ccc5c(c4)c4cccc6c7ccccc7n5c64)cc2N3c2c(-c3ccccc3)cc(C(C)(C)C)cc2-c2ccccc2)cc1]

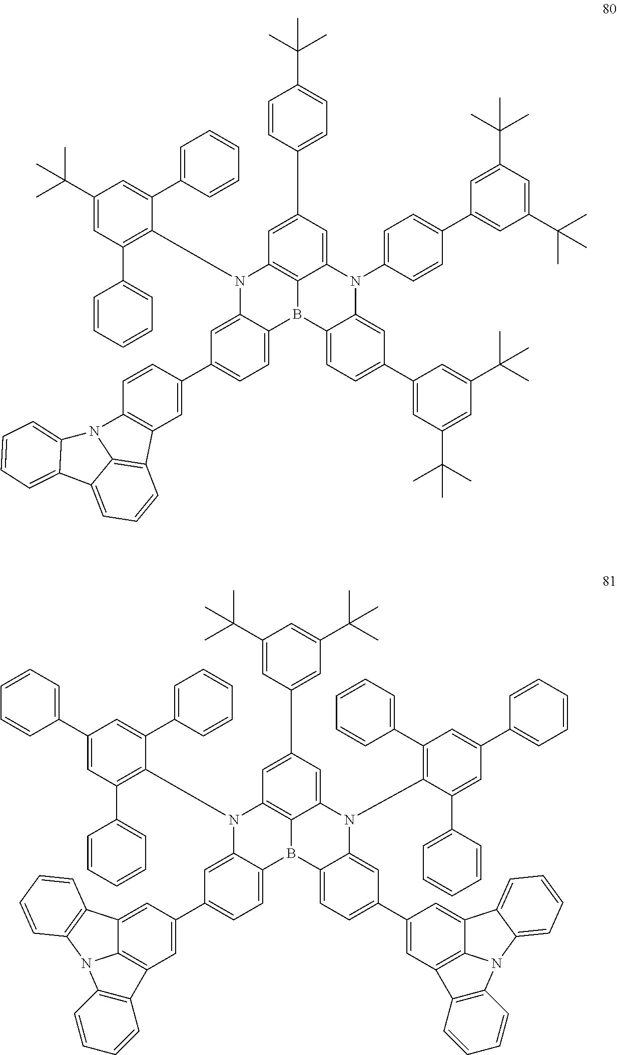 [SMILES: CC(C)(C)c1ccc(-c2cc3c4c(c2)N(c2c(-c5ccccc5)cc(C(C)(C)C)cc2-c2ccccc2)c2cc(-c5ccc6c(c5)c5cccc7c8ccccc8n6c75)ccc2B4c2ccc(-c4cc(C(C)(C)C)cc(C(C)(C)C)c4)cc2N3c2ccc(-c3cc(C(C)(C)C)cc(C(C)(C)C)c3)cc2)cc1 ; CC(C)(C)c1cc(-c2cc3c4c(c2)N(c2c(-c5ccccc5)cc(-c5ccccc5)cc2-c2ccccc2)c2cc(-c5cc6c7ccccc7n7c8ccccc8c(c5)c67)ccc2B4c2ccc(-c4cc5c6ccccc6n6c7ccccc7c(c4)c56)cc2N3c2c(-c3ccccc3)cc(-c3ccccc3)cc2-c2ccccc2)cc(C(C)(C)C)c1]

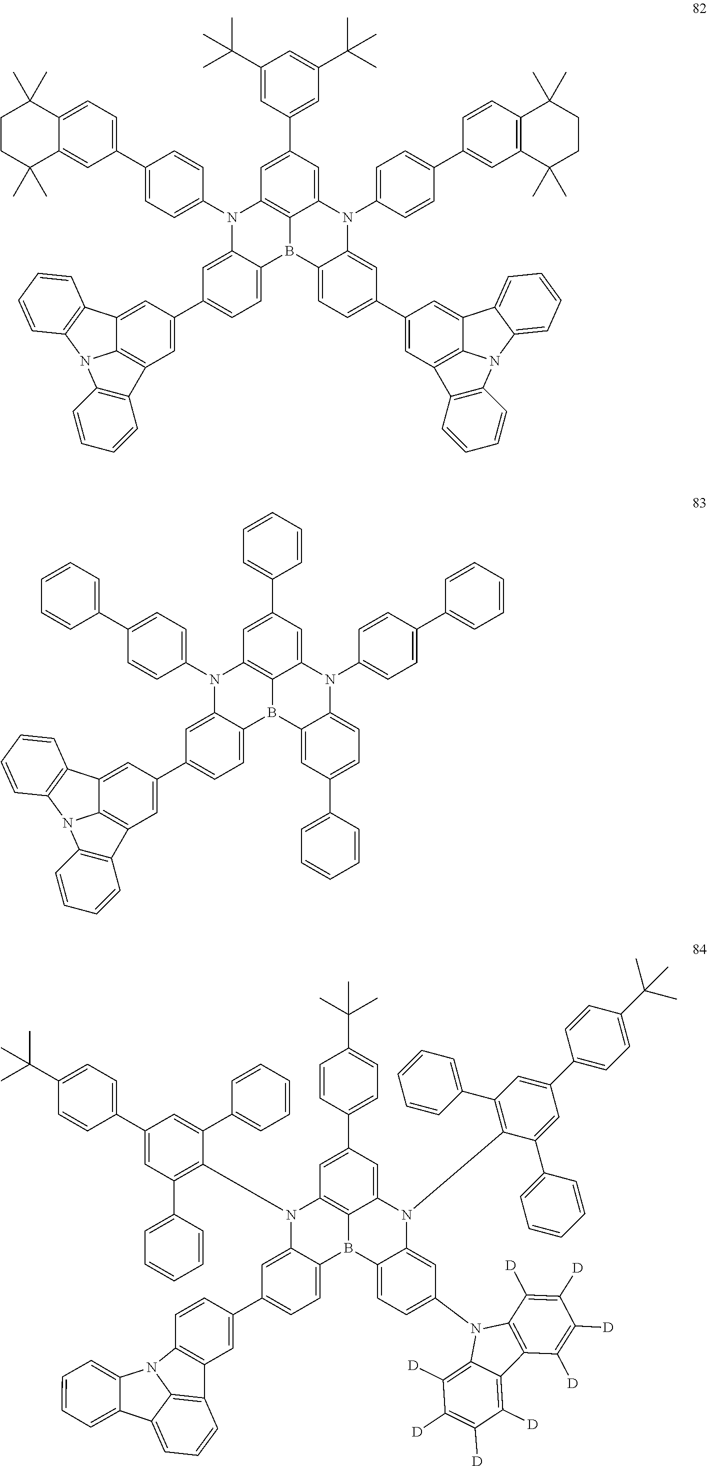

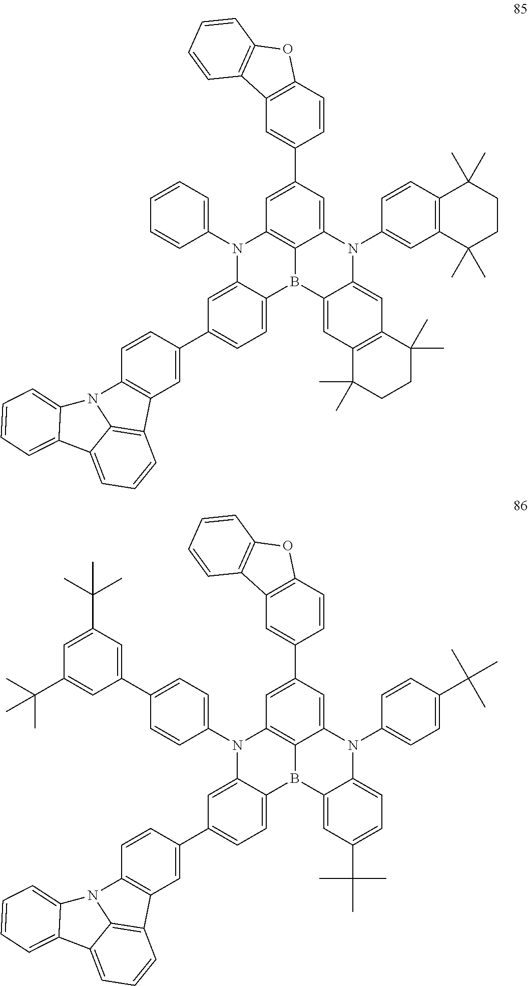 [SMILES: CC1(C)CCC(C)(C)c2cc(N3c4cc5c(cc4B4c6ccc(-c7ccc8c(c7)c7cccc9c%10ccccc%10n8c97)cc6N(c6ccccc6)c6cc(-c7ccc8oc9ccccc9c8c7)cc3c64)C(C)(C)CCC5(C)C)ccc21 ; CC(C)(C)c1ccc(N2c3ccc(C(C)(C)C)cc3B3c4ccc(-c5ccc6c(c5)c5cccc7c8ccccc8n6c75)cc4N(c4ccc(-c5cc(C(C)(C)C)cc(C(C)(C)C)c5)cc4)c4cc(-c5ccc6oc7ccccc7c6c5)cc2c43)cc1]

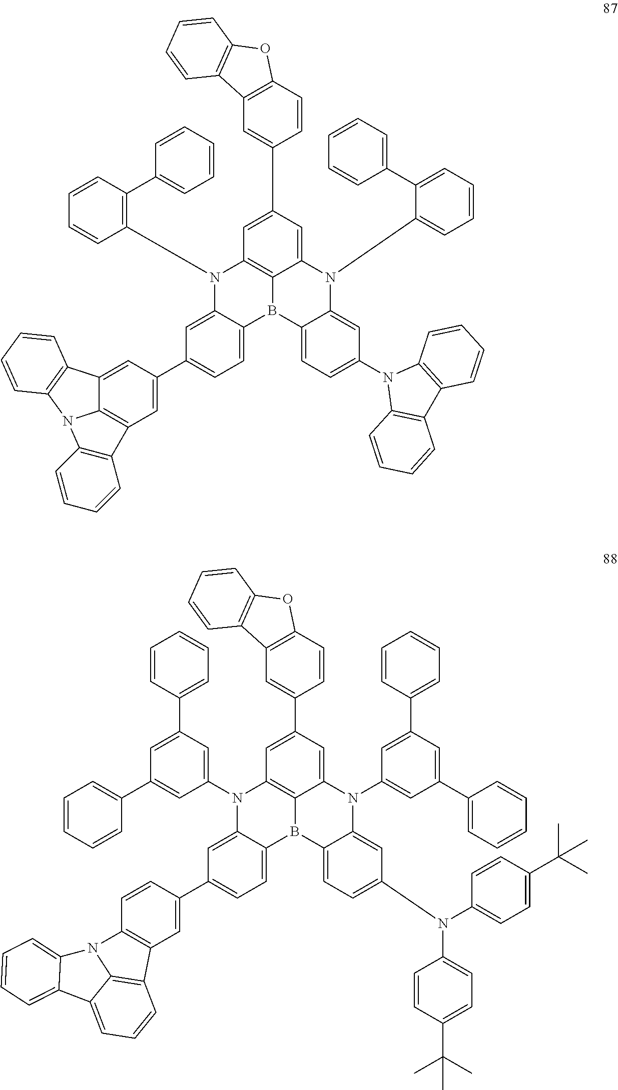 [SMILES: c1ccc(-c2ccccc2N2c3cc(-c4cc5c6ccccc6n6c7ccccc7c(c4)c56)ccc3B3c4ccc(-n5c6ccccc6c6ccccc65)cc4N(c4ccccc4-c4ccccc4)c4cc(-c5ccc6oc7ccccc7c6c5)cc2c43)cc1 ; CC(C)(C)c1ccc(N(c2ccc(C(C)(C)C)cc2)c2ccc3c(c2)N(c2cc(-c4ccccc4)cc(-c4ccccc4)c2)c2cc(-c4ccc5oc6ccccc6c5c4)cc4c2B3c2ccc(-c3ccc5c(c3)c3cccc6c7ccccc7n5c63)cc2N4c2cc(-c3ccccc3)cc(-c3ccccc3)c2)cc1]

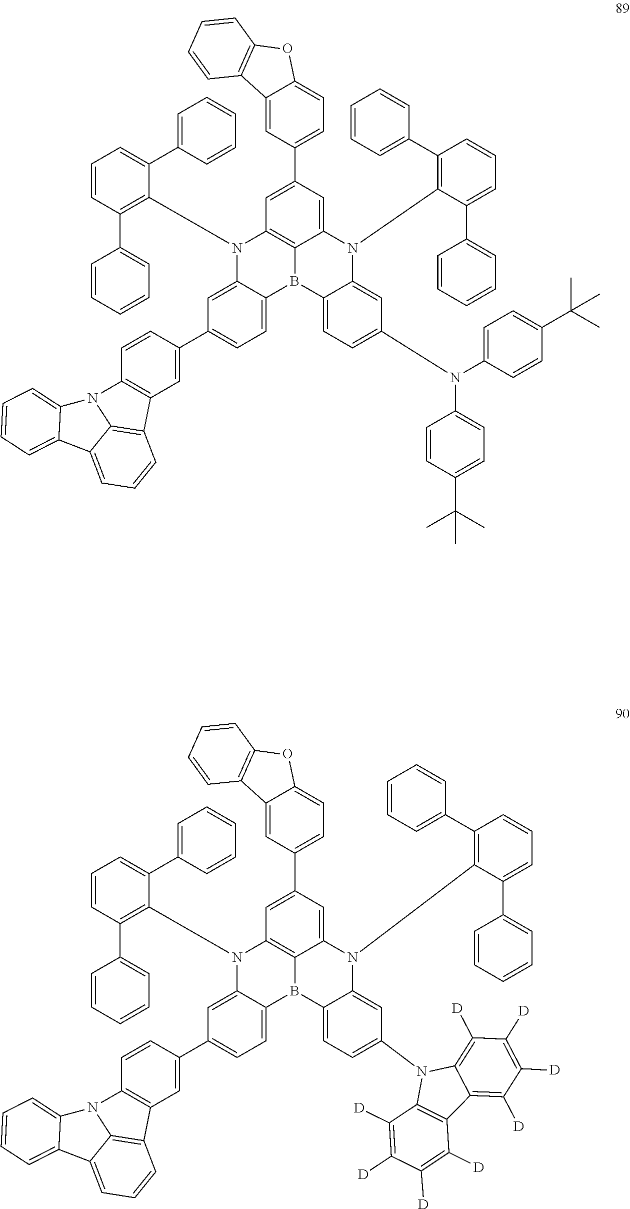 [SMILES: CC(C)(C)c1ccc(N(c2ccc(C(C)(C)C)cc2)c2ccc3c(c2)N(c2c(-c4ccccc4)cccc2-c2ccccc2)c2cc(-c4ccc5oc6ccccc6c5c4)cc4c2B3c2ccc(-c3ccc5c(c3)c3cccc6c7ccccc7n5c63)cc2N4c2c(-c3ccccc3)cccc2-c2ccccc2)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc(-c2ccc4c(c2)c2cccc5c6ccccc6n4c52)cc1N3c1c(-c2ccccc2)cccc1-c1ccccc1]

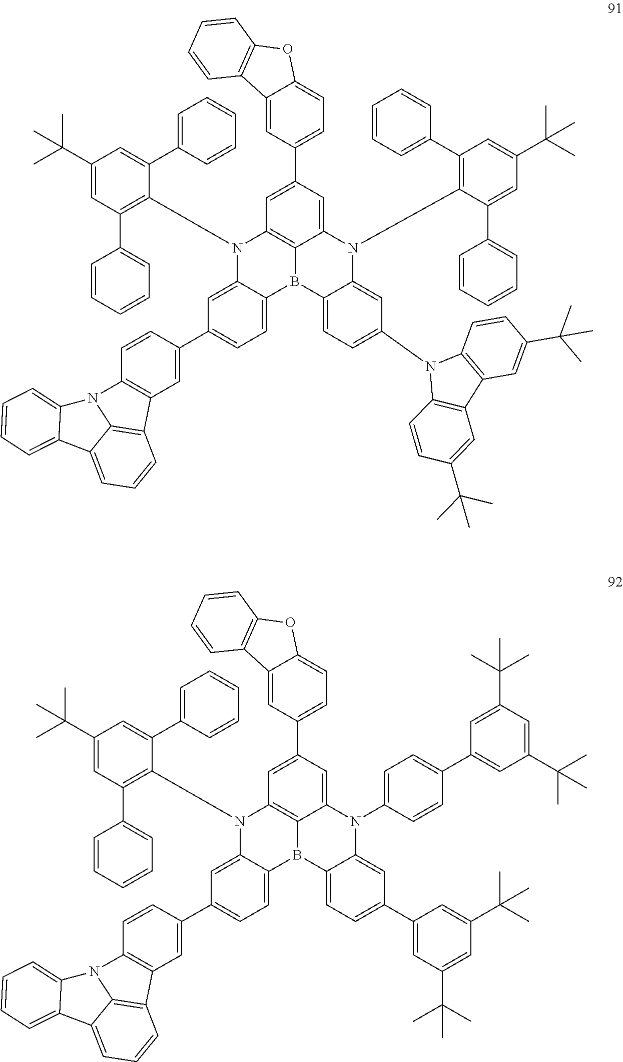 [SMILES: CC(C)(C)c1cc(-c2ccccc2)c(N2c3cc(-c4ccc5c(c4)c4cccc6c7ccccc7n5c64)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-c5ccc6oc7ccccc7c6c5)cc2c43)c(-c2ccccc2)c1 ; CC(C)(C)c1cc(-c2ccc(N3c4cc(-c5cc(C(C)(C)C)cc(C(C)(C)C)c5)ccc4B4c5ccc(-c6ccc7c(c6)c6cccc8c9ccccc9n7c86)cc5N(c5c(-c6ccccc6)cc(C(C)(C)C)cc5-c5ccccc5)c5cc(-c6ccc7oc8ccccc8c7c6)cc3c54)cc2)cc(C(C)(C)C)c1]

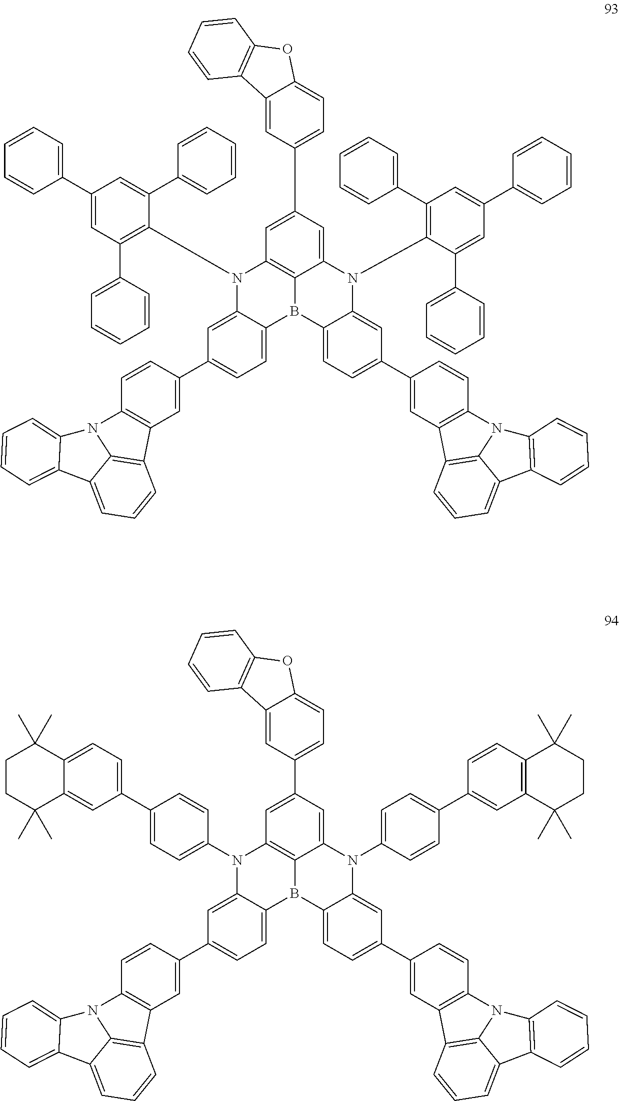 [SMILES: c1ccc(-c2cc(-c3ccccc3)c(N3c4cc(-c5ccc6c(c5)c5cccc7c8ccccc8n6c75)ccc4B4c5ccc(-c6ccc7c(c6)c6cccc8c9ccccc9n7c86)cc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC1(C)CCC(C)(C)c2cc(-c3ccc(N4c5cc(-c6ccc7c(c6)c6cccc8c9ccccc9n7c86)ccc5B5c6ccc(-c7ccc8c(c7)c7cccc9c%10ccccc%10n8c97)cc6N(c6ccc(-c7ccc8c(c7)C(C)(C)CCC8(C)C)cc6)c6cc(-c7ccc8oc9ccccc9c8c7)cc4c65)cc3)ccc21]

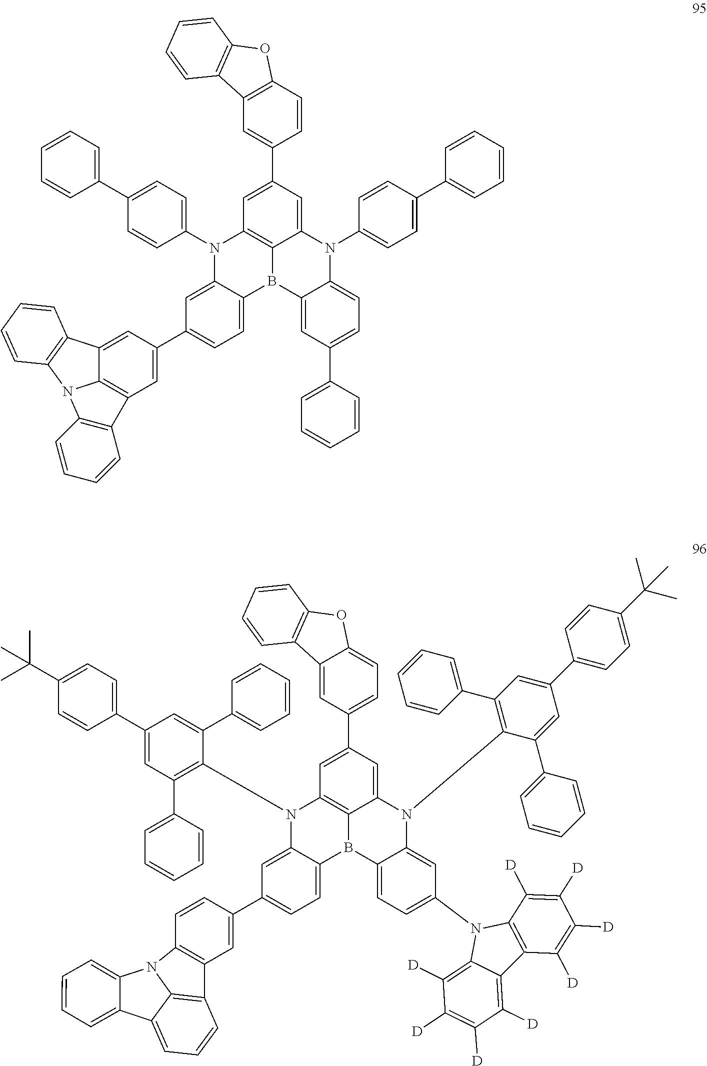 [SMILES: c1ccc(-c2ccc(N3c4ccc(-c5ccccc5)cc4B4c5ccc(-c6cc7c8ccccc8n8c9ccccc9c(c6)c78)cc5N(c5ccc(-c6ccccc6)cc5)c5cc(-c6ccc7oc8ccccc8c7c6)cc3c54)cc2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4oc5ccccc5c4c3)cc3c1B2c1ccc(-c2ccc4c(c2)c2cccc5c6ccccc6n4c52)cc1N3c1c(-c2ccccc2)cc(-c2ccc(C(C)(C)C)cc2)cc1-c1ccccc1]

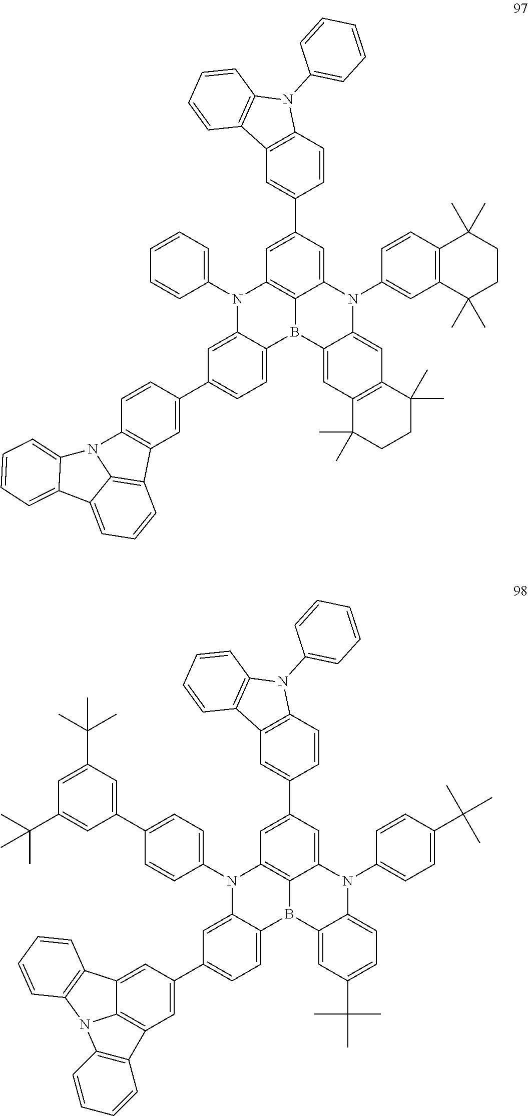 [SMILES: CC1(C)CCC(C)(C)c2cc(N3c4cc5c(cc4B4c6ccc(-c7ccc8c(c7)c7cccc9c%10ccccc%10n8c97)cc6N(c6ccccc6)c6cc(-c7ccc8c(c7)c7ccccc7n8-c7ccccc7)cc3c64)C(C)(C)CCC5(C)C)ccc21 ; CC(C)(C)c1ccc(N2c3ccc(C(C)(C)C)cc3B3c4ccc(-c5cc6c7ccccc7n7c8ccccc8c(c5)c67)cc4N(c4ccc(-c5cc(C(C)(C)C)cc(C(C)(C)C)c5)cc4)c4cc(-c5ccc6c(c5)c5ccccc5n6-c5ccccc5)cc2c43)cc1]

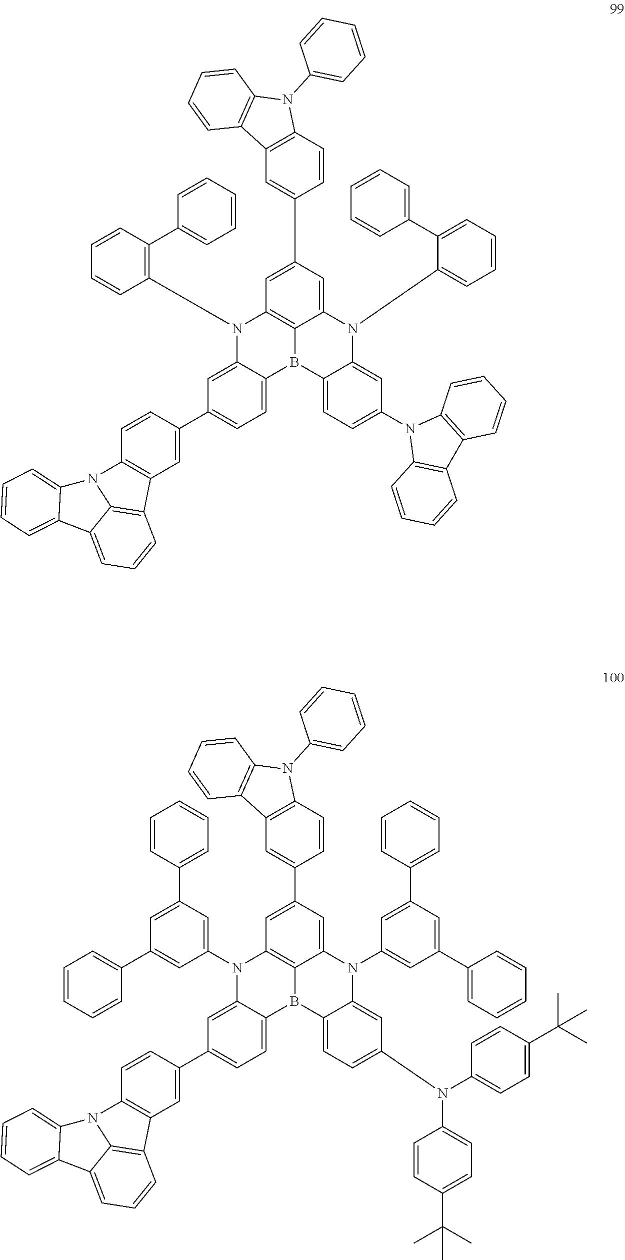 [SMILES: c1ccc(-c2ccccc2N2c3cc(-c4ccc5c(c4)c4cccc6c7ccccc7n5c64)ccc3B3c4ccc(-n5c6ccccc6c6ccccc65)cc4N(c4ccccc4-c4ccccc4)c4cc(-c5ccc6c(c5)c5ccccc5n6-c5ccccc5)cc2c43)cc1 ; CC(C)(C)c1ccc(N(c2ccc(C(C)(C)C)cc2)c2ccc3c(c2)N(c2cc(-c4ccccc4)cc(-c4ccccc4)c2)c2cc(-c4ccc5c(c4)c4ccccc4n5-c4ccccc4)cc4c2B3c2ccc(-c3ccc5c(c3)c3cccc6c7ccccc7n5c63)cc2N4c2cc(-c3ccccc3)cc(-c3ccccc3)c2)cc1]

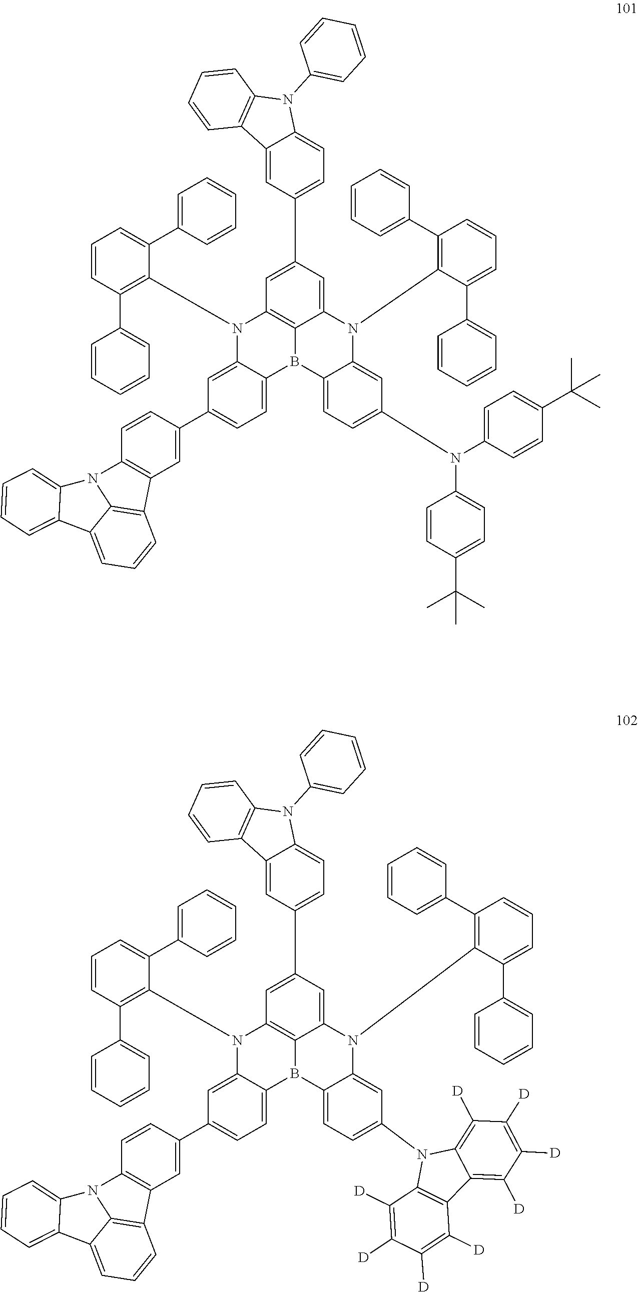 [SMILES: CC(C)(C)c1ccc(N(c2ccc(C(C)(C)C)cc2)c2ccc3c(c2)N(c2c(-c4ccccc4)cccc2-c2ccccc2)c2cc(-c4ccc5c(c4)c4ccccc4n5-c4ccccc4)cc4c2B3c2ccc(-c3ccc5c(c3)c3cccc6c7ccccc7n5c63)cc2N4c2c(-c3ccccc3)cccc2-c2ccccc2)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4c(c3)c3ccccc3n4-c3ccccc3)cc3c1B2c1ccc(-c2ccc4c(c2)c2cccc5c6ccccc6n4c52)cc1N3c1c(-c2ccccc2)cccc1-c1ccccc1]

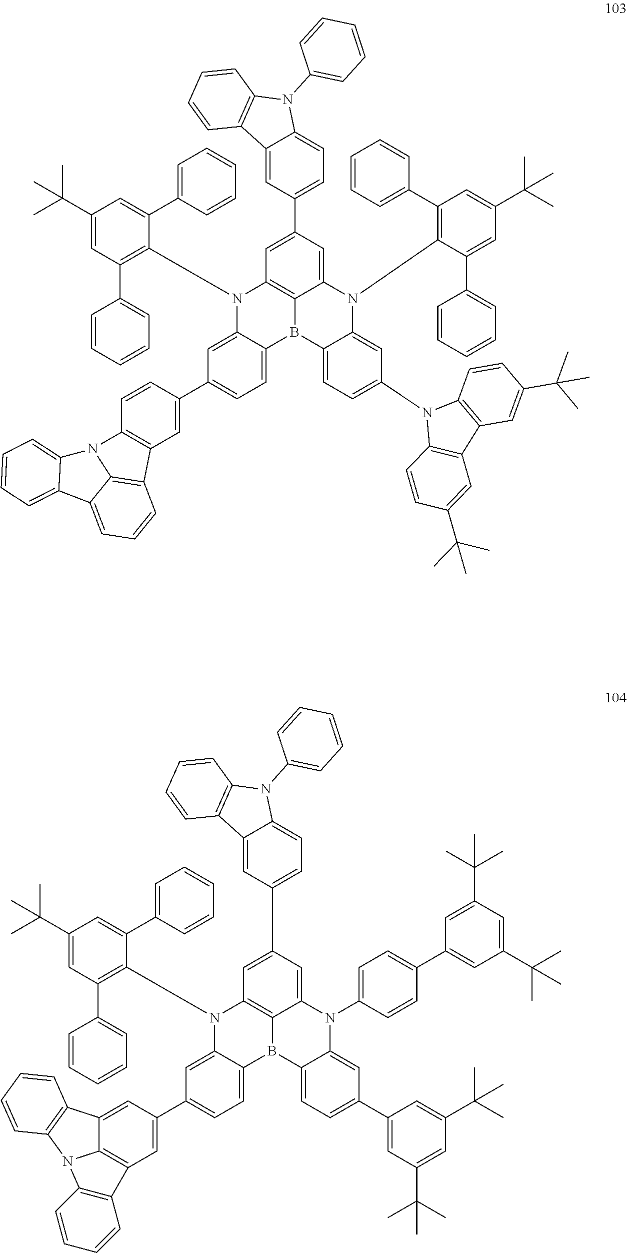 [SMILES: CC(C)(C)c1cc(-c2ccccc2)c(N2c3cc(-c4ccc5c(c4)c4cccc6c7ccccc7n5c64)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-c5ccc6c(c5)c5ccccc5n6-c5ccccc5)cc2c43)c(-c2ccccc2)c1 ; CC(C)(C)c1cc(-c2ccc(N3c4cc(-c5cc(C(C)(C)C)cc(C(C)(C)C)c5)ccc4B4c5ccc(-c6cc7c8ccccc8n8c9ccccc9c(c6)c78)cc5N(c5c(-c6ccccc6)cc(C(C)(C)C)cc5-c5ccccc5)c5cc(-c6ccc7c(c6)c6ccccc6n7-c6ccccc6)cc3c54)cc2)cc(C(C)(C)C)c1]

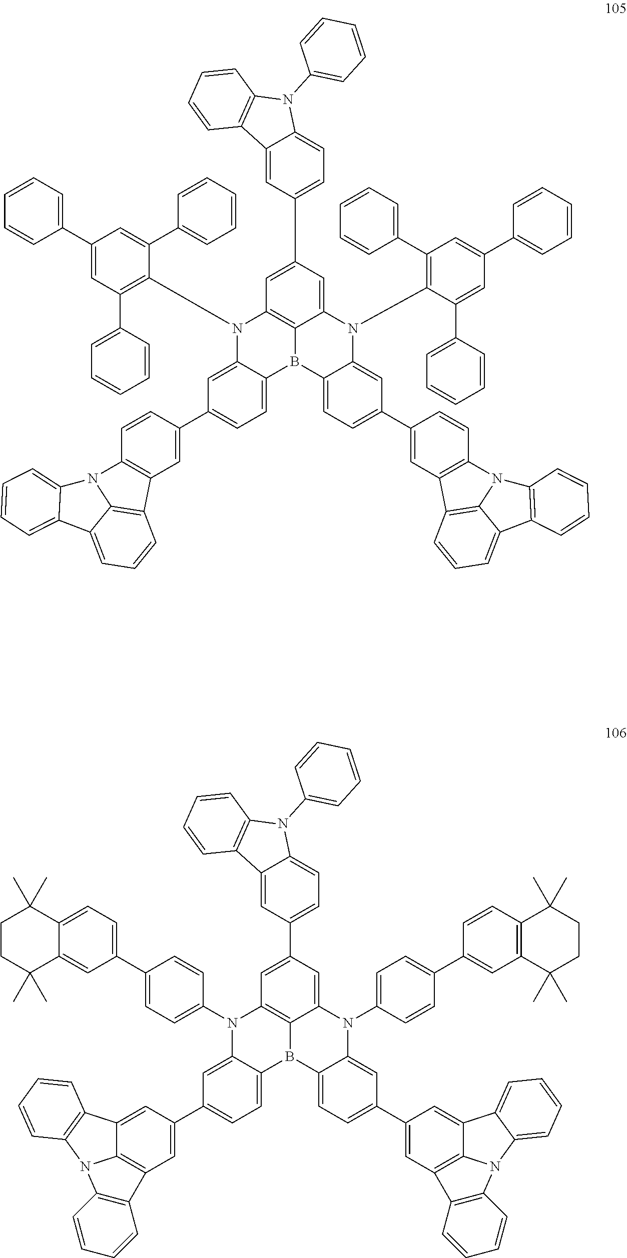 [SMILES: c1ccc(-c2cc(-c3ccccc3)c(N3c4cc(-c5ccc6c(c5)c5cccc7c8ccccc8n6c75)ccc4B4c5ccc(-c6ccc7c(c6)c6cccc8c9ccccc9n7c86)cc5N(c5c(-c6ccccc6)cc(-c6ccccc6)cc5-c5ccccc5)c5cc(-c6ccc7c(c6)c6ccccc6n7-c6ccccc6)cc3c54)c(-c3ccccc3)c2)cc1 ; CC1(C)CCC(C)(C)c2cc(-c3ccc(N4c5cc(-c6cc7c8ccccc8n8c9ccccc9c(c6)c78)ccc5B5c6ccc(-c7cc8c9ccccc9n9c%10ccccc%10c(c7)c89)cc6N(c6ccc(-c7ccc8c(c7)C(C)(C)CCC8(C)C)cc6)c6cc(-c7ccc8c(c7)c7ccccc7n8-c7ccccc7)cc4c65)cc3)ccc21]

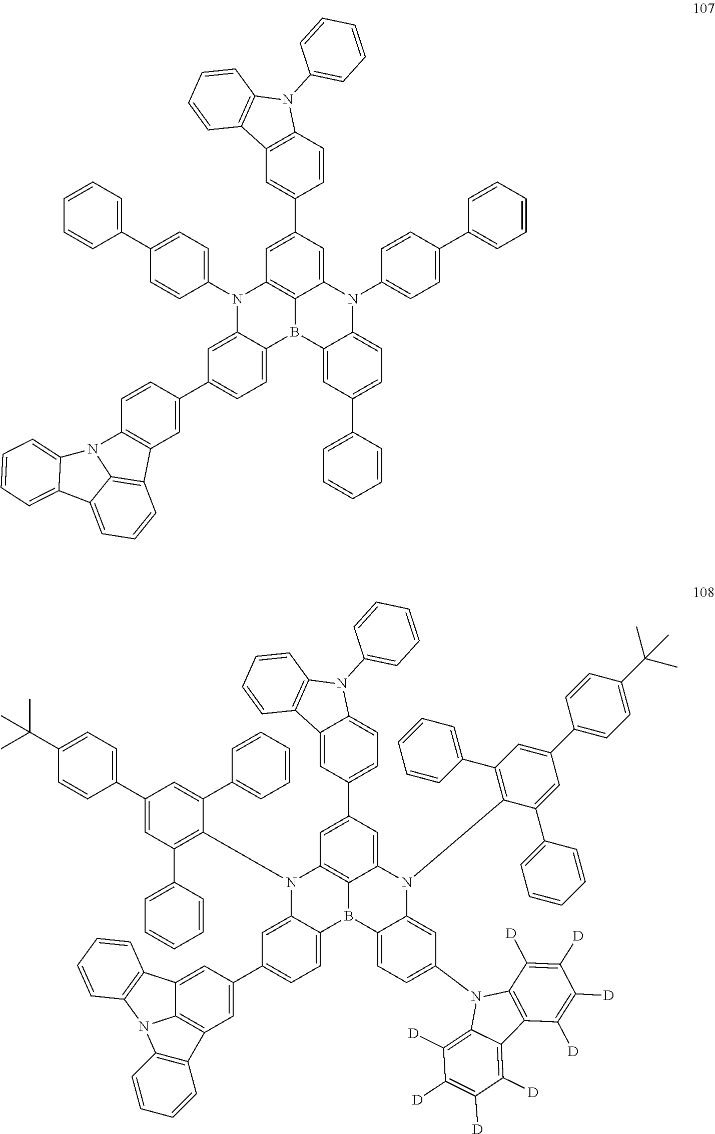 [SMILES: c1ccc(-c2ccc(N3c4ccc(-c5ccccc5)cc4B4c5ccc(-c6ccc7c(c6)c6cccc8c9ccccc9n7c86)cc5N(c5ccc(-c6ccccc6)cc5)c5cc(-c6ccc7c(c6)c6ccccc6n7-c6ccccc6)cc3c54)cc2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4c(c3)c3ccccc3n4-c3ccccc3)cc3c1B2c1ccc(-c2cc4c5ccccc5n5c6ccccc6c(c2)c45)cc1N3c1c(-c2ccccc2)cc(-c2ccc(C(C)(C)C)cc2)cc1-c1ccccc1]

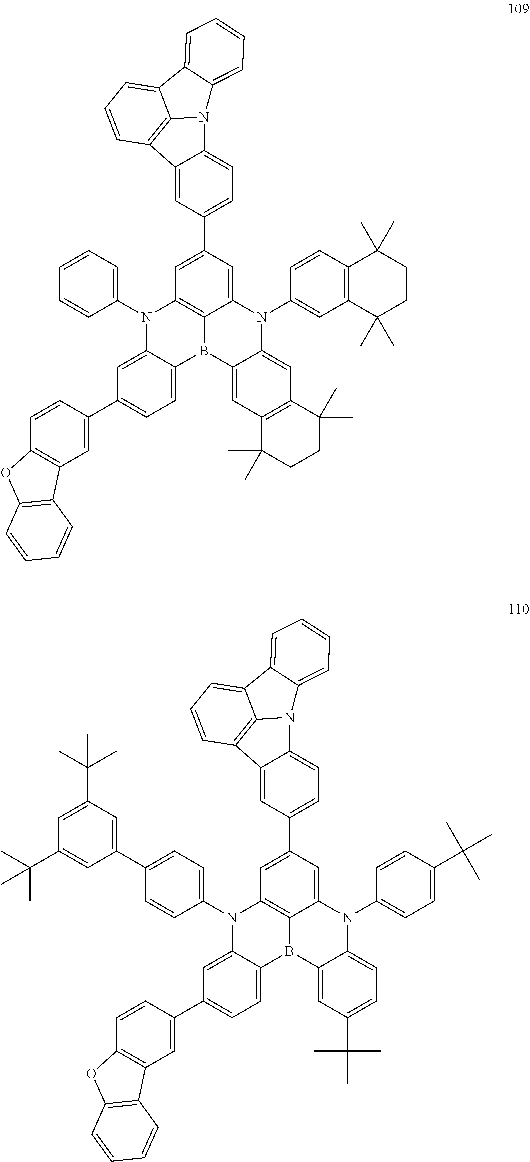 [SMILES: CC1(C)CCC(C)(C)c2cc(N3c4cc5c(cc4B4c6ccc(-c7ccc8oc9ccccc9c8c7)cc6N(c6ccccc6)c6cc(-c7ccc8c(c7)c7cccc9c%10ccccc%10n8c97)cc3c64)C(C)(C)CCC5(C)C)ccc21 ; CC(C)(C)c1ccc(N2c3ccc(C(C)(C)C)cc3B3c4ccc(-c5ccc6oc7ccccc7c6c5)cc4N(c4ccc(-c5cc(C(C)(C)C)cc(C(C)(C)C)c5)cc4)c4cc(-c5ccc6c(c5)c5cccc7c8ccccc8n6c75)cc2c43)cc1]

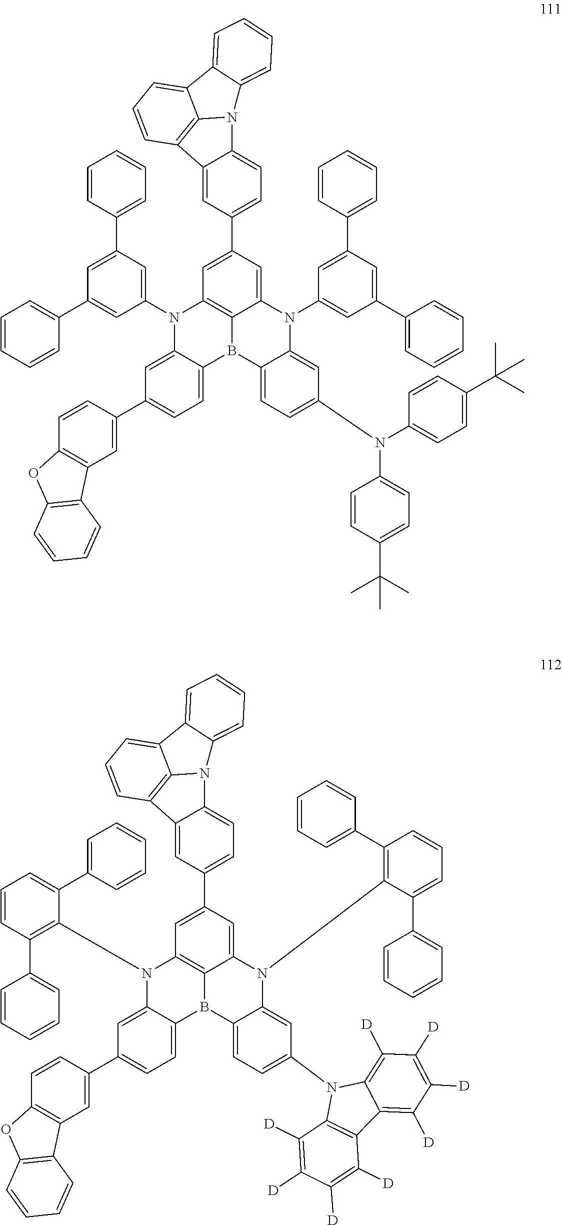 [SMILES: CC(C)(C)c1ccc(N(c2ccc(C(C)(C)C)cc2)c2ccc3c(c2)N(c2cc(-c4ccccc4)cc(-c4ccccc4)c2)c2cc(-c4ccc5c(c4)c4cccc6c7ccccc7n5c64)cc4c2B3c2ccc(-c3ccc5oc6ccccc6c5c3)cc2N4c2cc(-c3ccccc3)cc(-c3ccccc3)c2)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4c(c3)c3cccc5c6ccccc6n4c53)cc3c1B2c1ccc(-c2ccc4oc5ccccc5c4c2)cc1N3c1c(-c2ccccc2)cccc1-c1ccccc1]

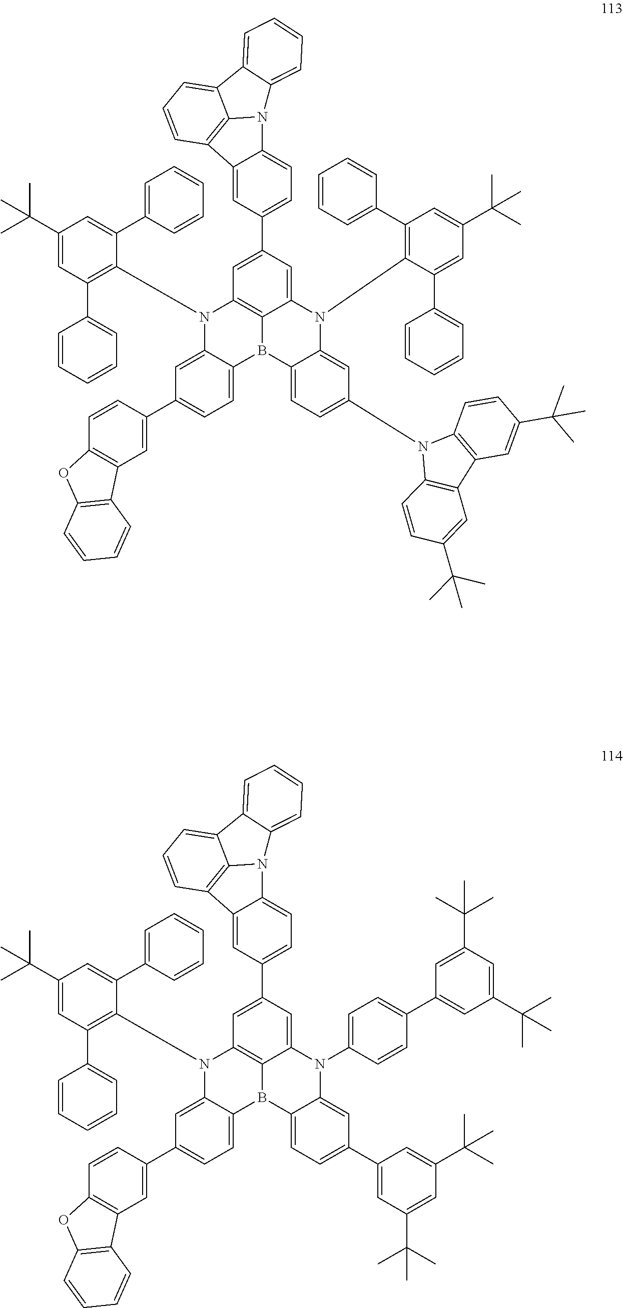

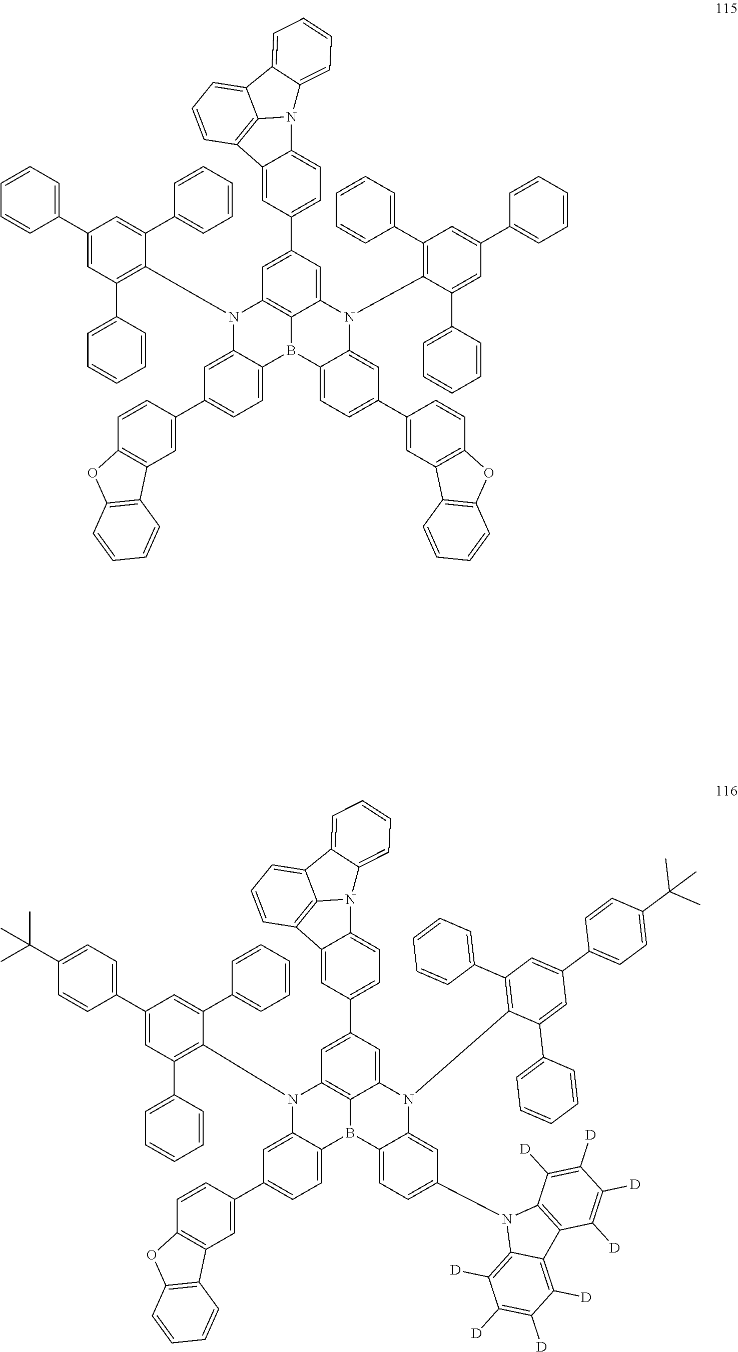 [SMILES: c1ccc(-c2cc(-c3ccccc3)c(N3c4cc(-c5ccc6oc7ccccc7c6c5)ccc4B4c5ccc(-c6ccc7oc8ccccc8c7c6)cc5N(c5c(-c6ccccc6)cc(-c6ccccc6)cc5-c5ccccc5)c5cc(-c6ccc7c(c6)c6cccc8c9ccccc9n7c86)cc3c54)c(-c3ccccc3)c2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4c(c3)c3cccc5c6ccccc6n4c53)cc3c1B2c1ccc(-c2ccc4oc5ccccc5c4c2)cc1N3c1c(-c2ccccc2)cc(-c2ccc(C(C)(C)C)cc2)cc1-c1ccccc1]

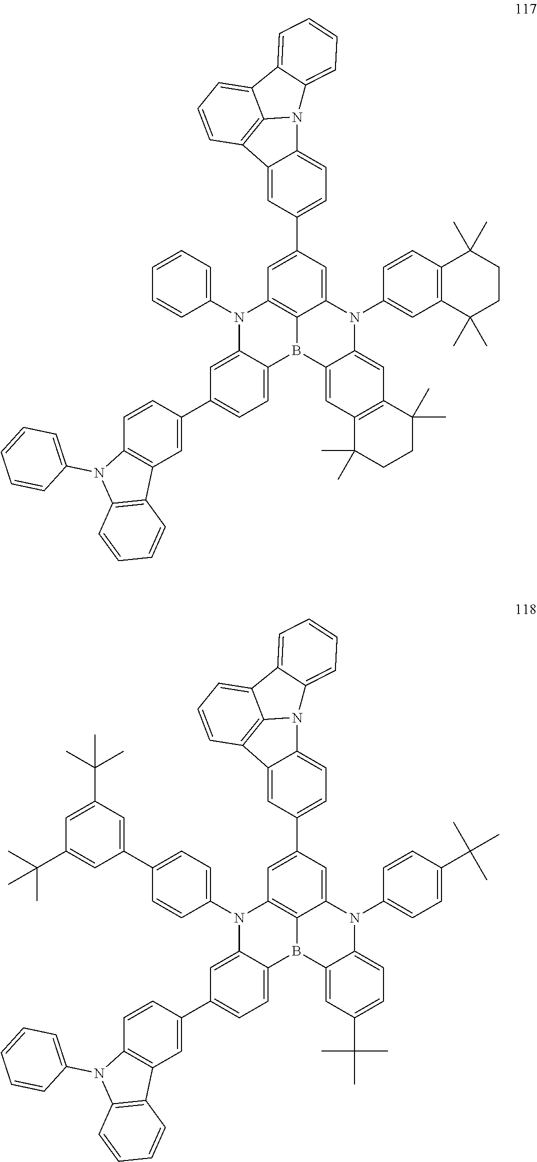 [SMILES: CC1(C)CCC(C)(C)c2cc(N3c4cc5c(cc4B4c6ccc(-c7ccc8c(c7)c7ccccc7n8-c7ccccc7)cc6N(c6ccccc6)c6cc(-c7ccc8c(c7)c7cccc9c%10ccccc%10n8c97)cc3c64)C(C)(C)CCC5(C)C)ccc21 ; CC(C)(C)c1ccc(N2c3ccc(C(C)(C)C)cc3B3c4ccc(-c5ccc6c(c5)c5ccccc5n6-c5ccccc5)cc4N(c4ccc(-c5cc(C(C)(C)C)cc(C(C)(C)C)c5)cc4)c4cc(-c5ccc6c(c5)c5cccc7c8ccccc8n6c75)cc2c43)cc1]

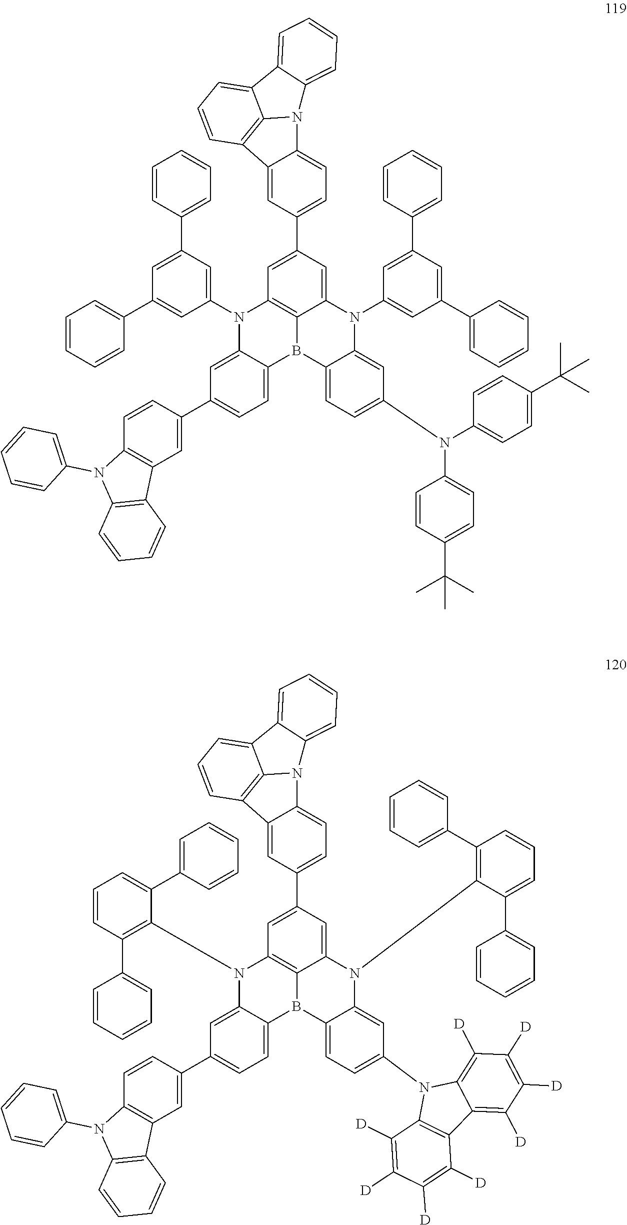 [SMILES: CC(C)(C)c1ccc(N(c2ccc(C(C)(C)C)cc2)c2ccc3c(c2)N(c2cc(-c4ccccc4)cc(-c4ccccc4)c2)c2cc(-c4ccc5c(c4)c4cccc6c7ccccc7n5c64)cc4c2B3c2ccc(-c3ccc5c(c3)c3ccccc3n5-c3ccccc3)cc2N4c2cc(-c3ccccc3)cc(-c3ccccc3)c2)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4c(c3)c3cccc5c6ccccc6n4c53)cc3c1B2c1ccc(-c2ccc4c(c2)c2ccccc2n4-c2ccccc2)cc1N3c1c(-c2ccccc2)cccc1-c1ccccc1]

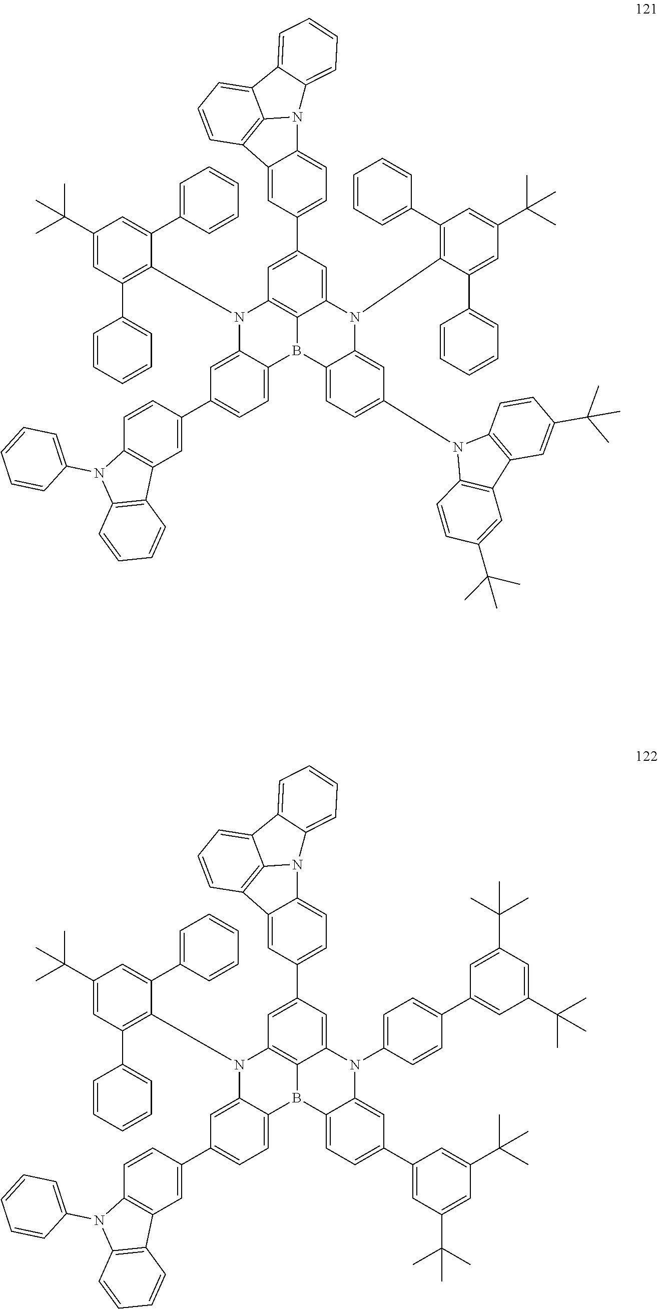 [SMILES: CC(C)(C)c1cc(-c2ccccc2)c(N2c3cc(-c4ccc5c(c4)c4ccccc4n5-c4ccccc4)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-c5ccc6c(c5)c5cccc7c8ccccc8n6c75)cc2c43)c(-c2ccccc2)c1 ; CC(C)(C)c1cc(-c2ccc(N3c4cc(-c5cc(C(C)(C)C)cc(C(C)(C)C)c5)ccc4B4c5ccc(-c6ccc7c(c6)c6ccccc6n7-c6ccccc6)cc5N(c5c(-c6ccccc6)cc(C(C)(C)C)cc5-c5ccccc5)c5cc(-c6ccc7c(c6)c6cccc8c9ccccc9n7c86)cc3c54)cc2)cc(C(C)(C)C)c1]

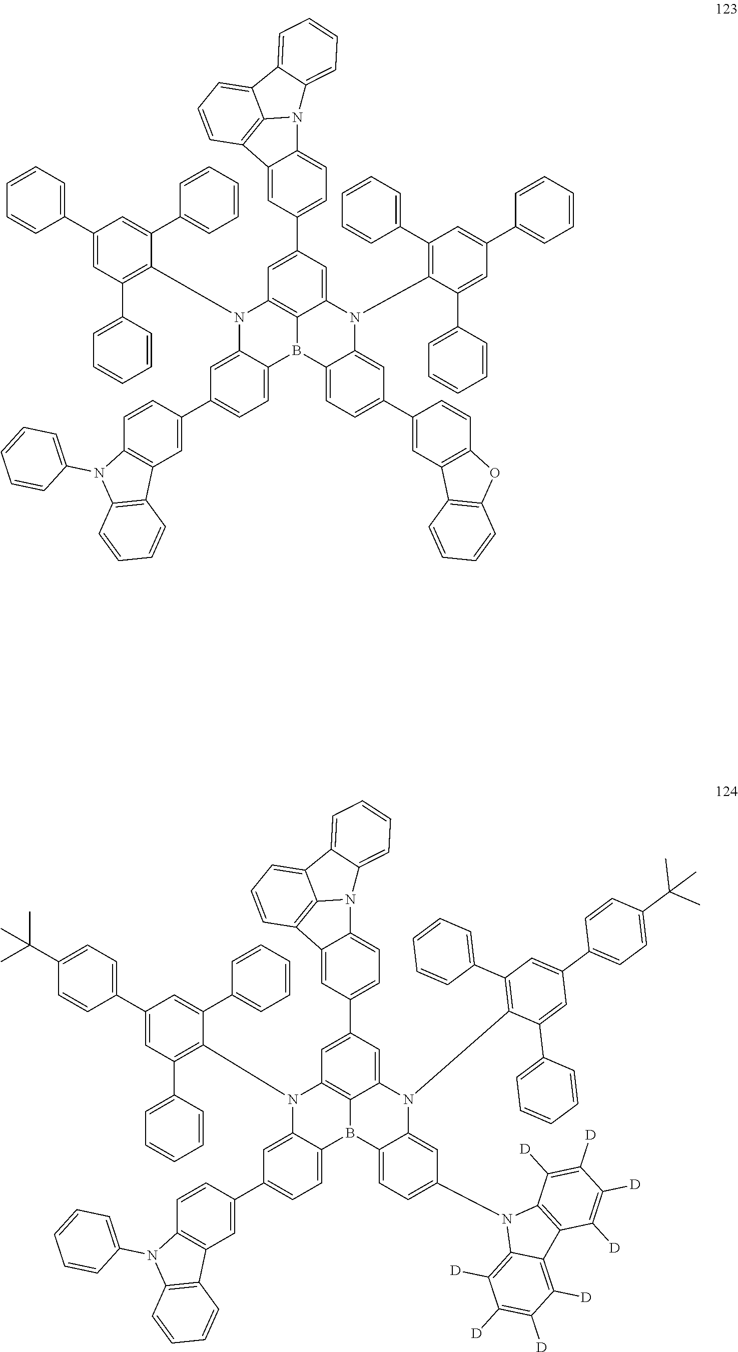 [SMILES: c1ccc(-c2cc(-c3ccccc3)c(N3c4cc(-c5ccc6oc7ccccc7c6c5)ccc4B4c5ccc(-c6ccc7c(c6)c6ccccc6n7-c6ccccc6)cc5N(c5c(-c6ccccc6)cc(-c6ccccc6)cc5-c5ccccc5)c5cc(-c6ccc7c(c6)c6cccc8c9ccccc9n7c86)cc3c54)c(-c3ccccc3)c2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4c(c3)c3cccc5c6ccccc6n4c53)cc3c1B2c1ccc(-c2ccc4c(c2)c2ccccc2n4-c2ccccc2)cc1N3c1c(-c2ccccc2)cc(-c2ccc(C(C)(C)C)cc2)cc1-c1ccccc1]

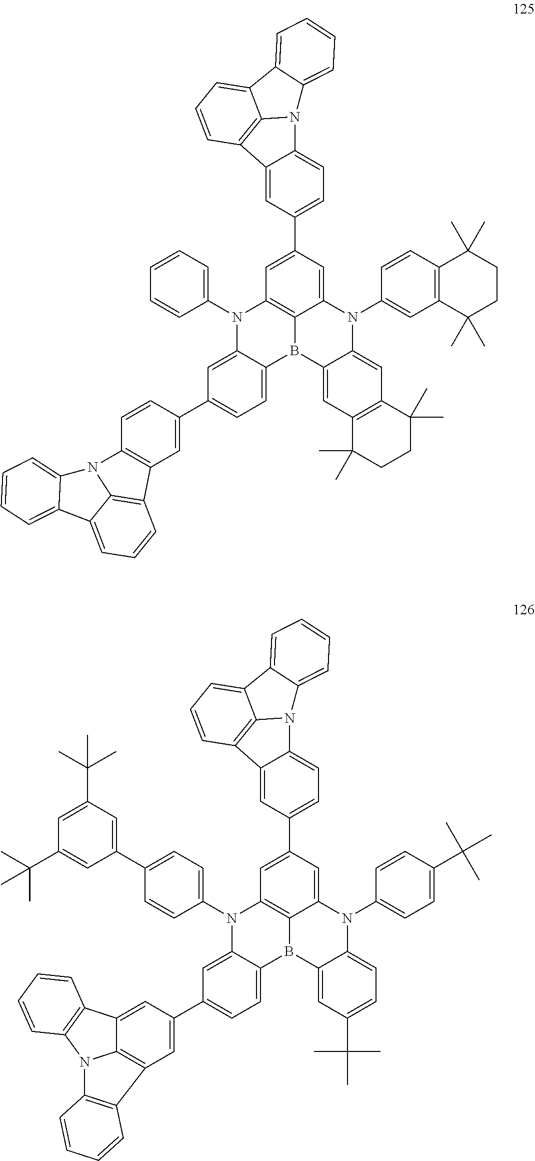 [SMILES: CC1(C)CCC(C)(C)c2cc(N3c4cc5c(cc4B4c6ccc(-c7ccc8c(c7)c7cccc9c%10ccccc%10n8c97)cc6N(c6ccccc6)c6cc(-c7ccc8c(c7)c7cccc9c%10ccccc%10n8c97)cc3c64)C(C)(C)CCC5(C)C)ccc21 ; CC(C)(C)c1ccc(N2c3ccc(C(C)(C)C)cc3B3c4ccc(-c5cc6c7ccccc7n7c8ccccc8c(c5)c67)cc4N(c4ccc(-c5cc(C(C)(C)C)cc(C(C)(C)C)c5)cc4)c4cc(-c5ccc6c(c5)c5cccc7c8ccccc8n6c75)cc2c43)cc1]

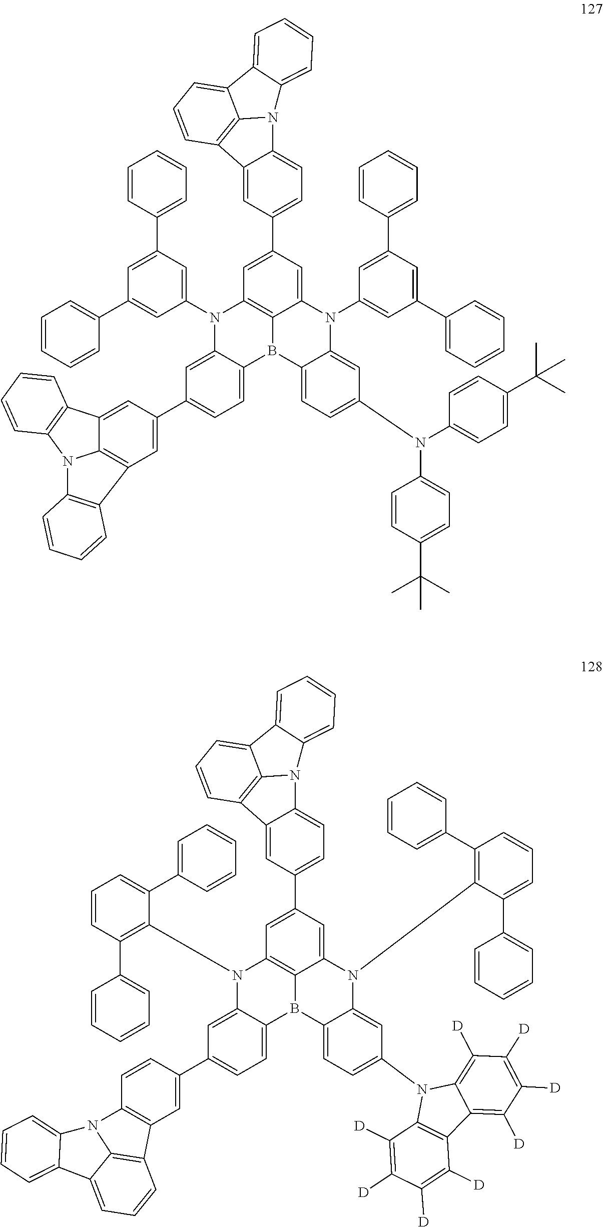 [SMILES: CC(C)(C)c1ccc(N(c2ccc(C(C)(C)C)cc2)c2ccc3c(c2)N(c2cc(-c4ccccc4)cc(-c4ccccc4)c2)c2cc(-c4ccc5c(c4)c4cccc6c7ccccc7n5c64)cc4c2B3c2ccc(-c3cc5c6ccccc6n6c7ccccc7c(c3)c56)cc2N4c2cc(-c3ccccc3)cc(-c3ccccc3)c2)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4c(c3)c3cccc5c6ccccc6n4c53)cc3c1B2c1ccc(-c2ccc4c(c2)c2cccc5c6ccccc6n4c52)cc1N3c1c(-c2ccccc2)cccc1-c1ccccc1]

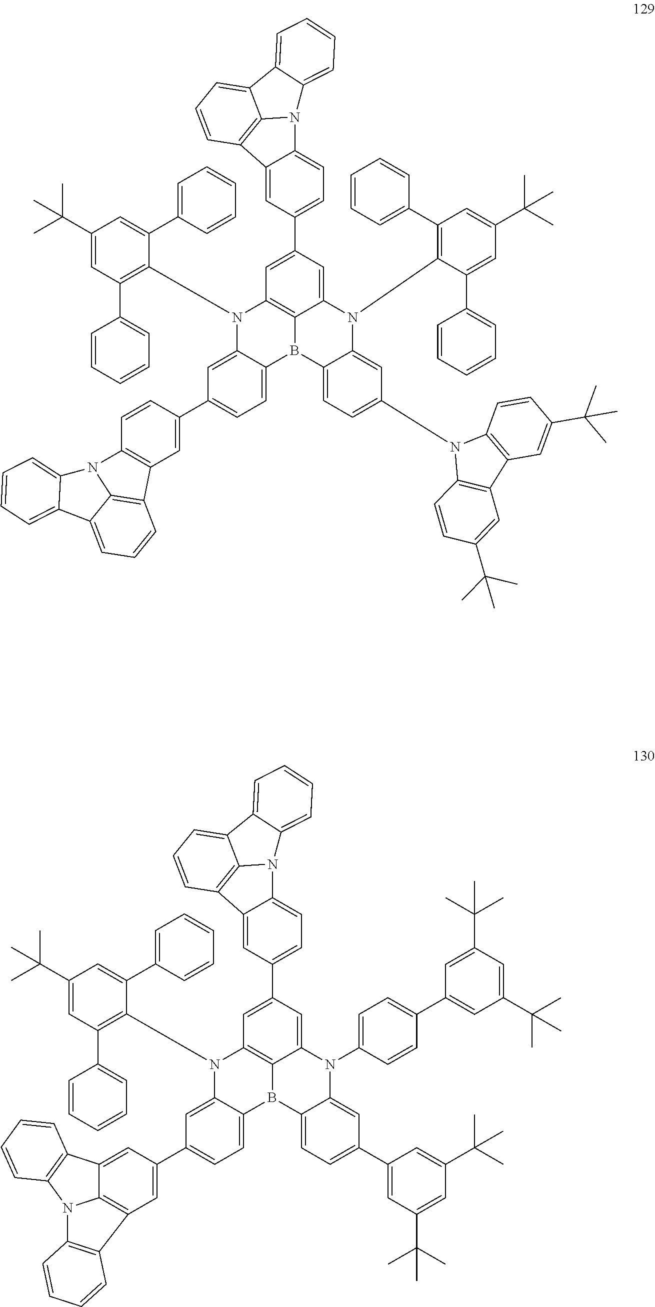 [SMILES: CC(C)(C)c1cc(-c2ccccc2)c(N2c3cc(-c4ccc5c(c4)c4cccc6c7ccccc7n5c64)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-c5ccc6c(c5)c5cccc7c8ccccc8n6c75)cc2c43)c(-c2ccccc2)c1 ; CC(C)(C)c1cc(-c2ccc(N3c4cc(-c5cc(C(C)(C)C)cc(C(C)(C)C)c5)ccc4B4c5ccc(-c6cc7c8ccccc8n8c9ccccc9c(c6)c78)cc5N(c5c(-c6ccccc6)cc(C(C)(C)C)cc5-c5ccccc5)c5cc(-c6ccc7c(c6)c6cccc8c9ccccc9n7c86)cc3c54)cc2)cc(C(C)(C)C)c1]

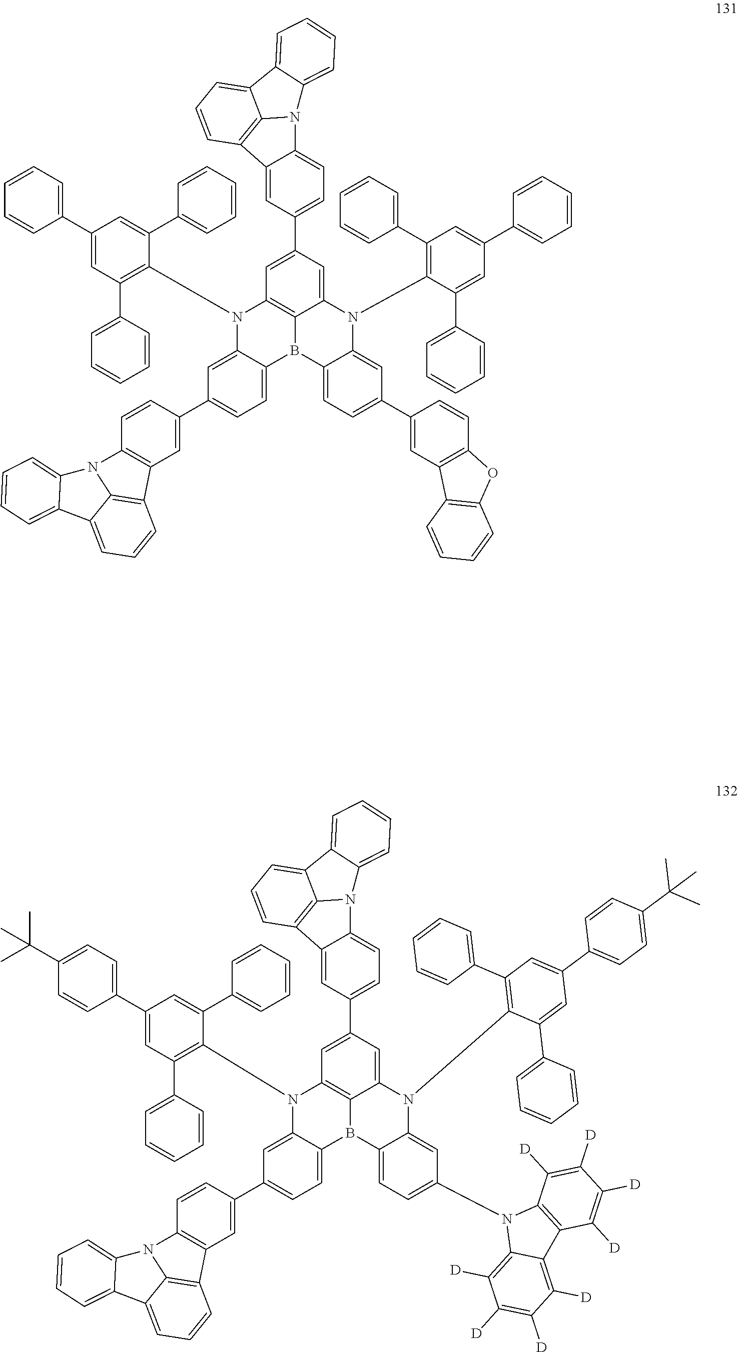 [SMILES: c1ccc(-c2cc(-c3ccccc3)c(N3c4cc(-c5ccc6oc7ccccc7c6c5)ccc4B4c5ccc(-c6ccc7c(c6)c6cccc8c9ccccc9n7c86)cc5N(c5c(-c6ccccc6)cc(-c6ccccc6)cc5-c5ccccc5)c5cc(-c6ccc7c(c6)c6cccc8c9ccccc9n7c86)cc3c54)c(-c3ccccc3)c2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4c(c3)c3cccc5c6ccccc6n4c53)cc3c1B2c1ccc(-c2ccc4c(c2)c2cccc5c6ccccc6n4c52)cc1N3c1c(-c2ccccc2)cc(-c2ccc(C(C)(C)C)cc2)cc1-c1ccccc1]

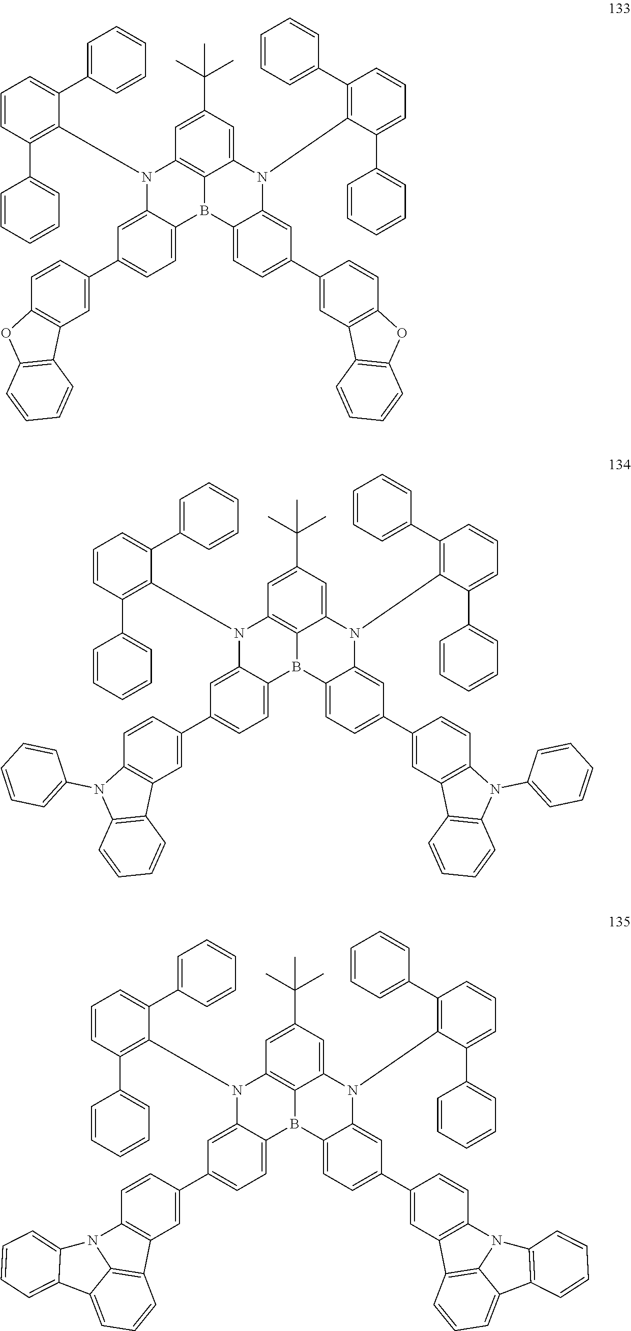 [SMILES: CC(C)(C)c1cc2c3c(c1)N(c1c(-c4ccccc4)cccc1-c1ccccc1)c1cc(-c4ccc5oc6ccccc6c5c4)ccc1B3c1ccc(-c3ccc4oc5ccccc5c4c3)cc1N2c1c(-c2ccccc2)cccc1-c1ccccc1 ; CC(C)(C)c1cc2c3c(c1)N(c1c(-c4ccccc4)cccc1-c1ccccc1)c1cc(-c4ccc5c(c4)c4ccccc4n5-c4ccccc4)ccc1B3c1ccc(-c3ccc4c(c3)c3ccccc3n4-c3ccccc3)cc1N2c1c(-c2ccccc2)cccc1-c1ccccc1 ; CC(C)(C)c1cc2c3c(c1)N(c1c(-c4ccccc4)cccc1-c1ccccc1)c1cc(-c4ccc5c(c4)c4cccc6c7ccccc7n5c64)ccc1B3c1ccc(-c3ccc4c(c3)c3cccc5c6ccccc6n4c53)cc1N2c1c(-c2ccccc2)cccc1-c1ccccc1]

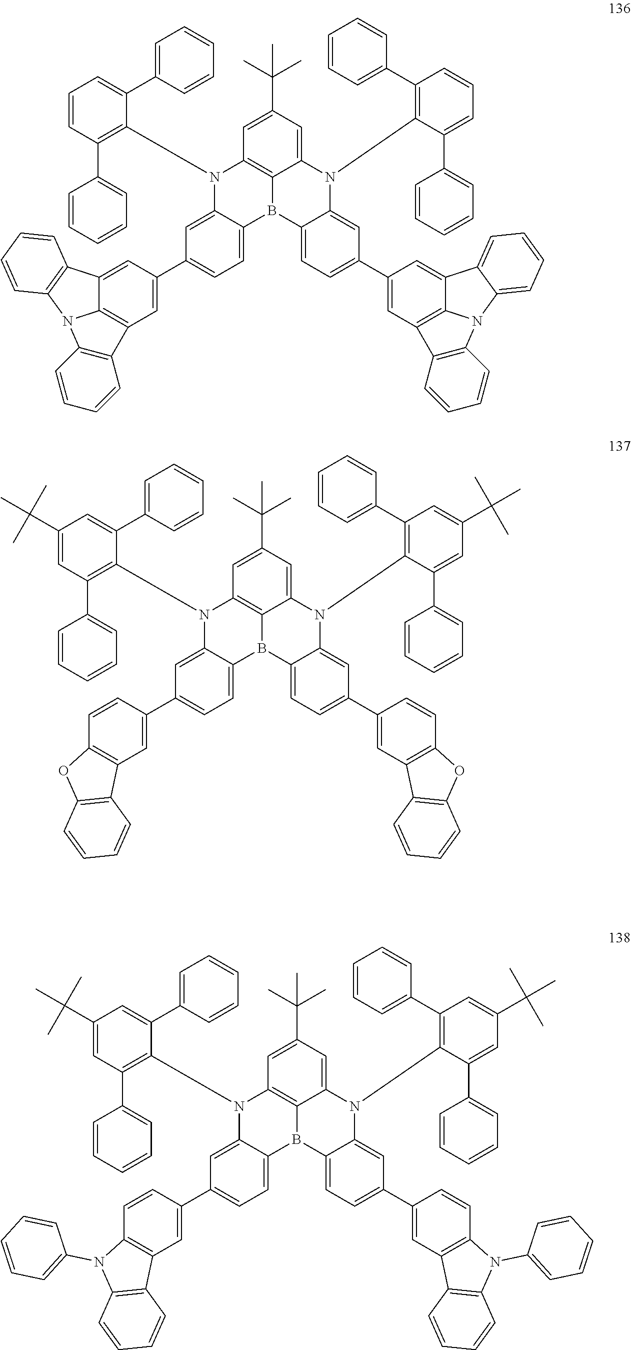

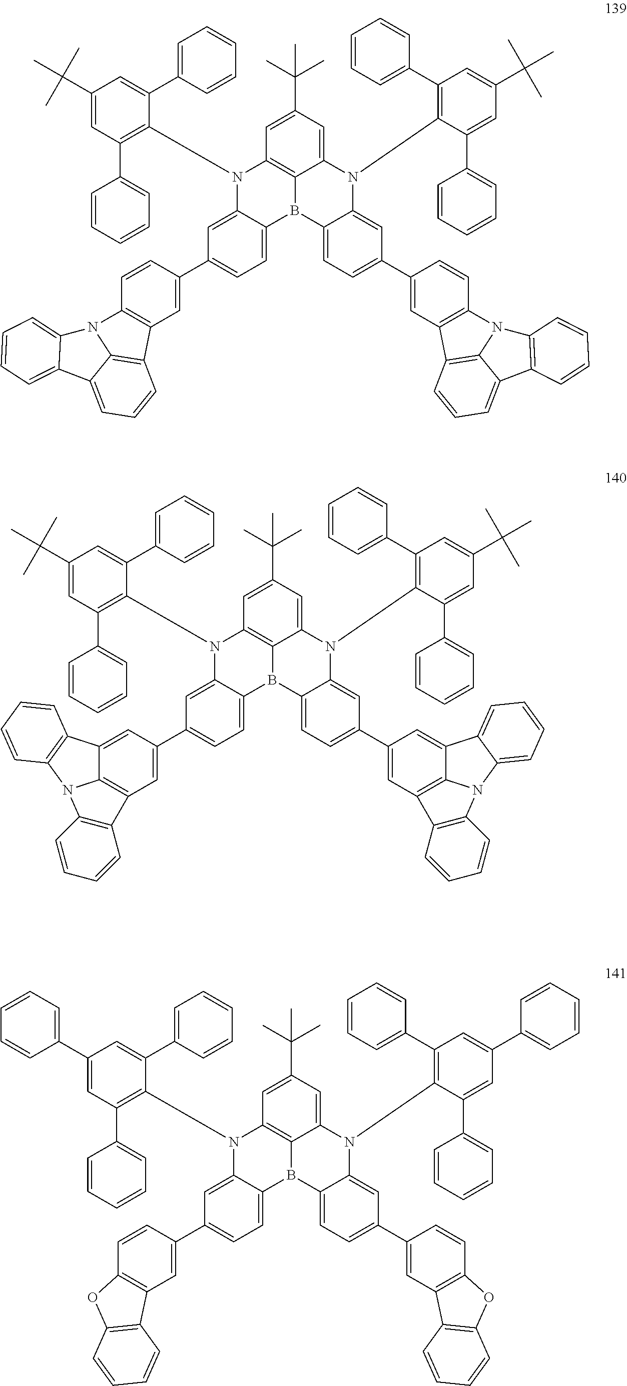

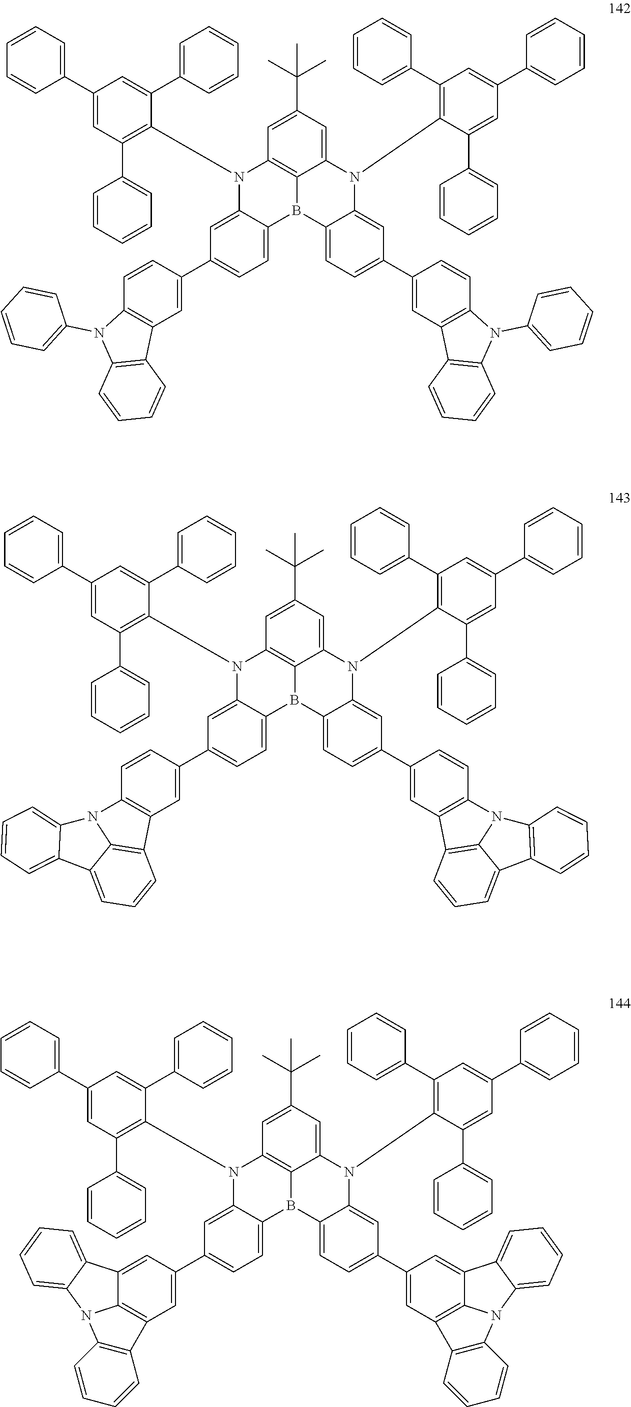

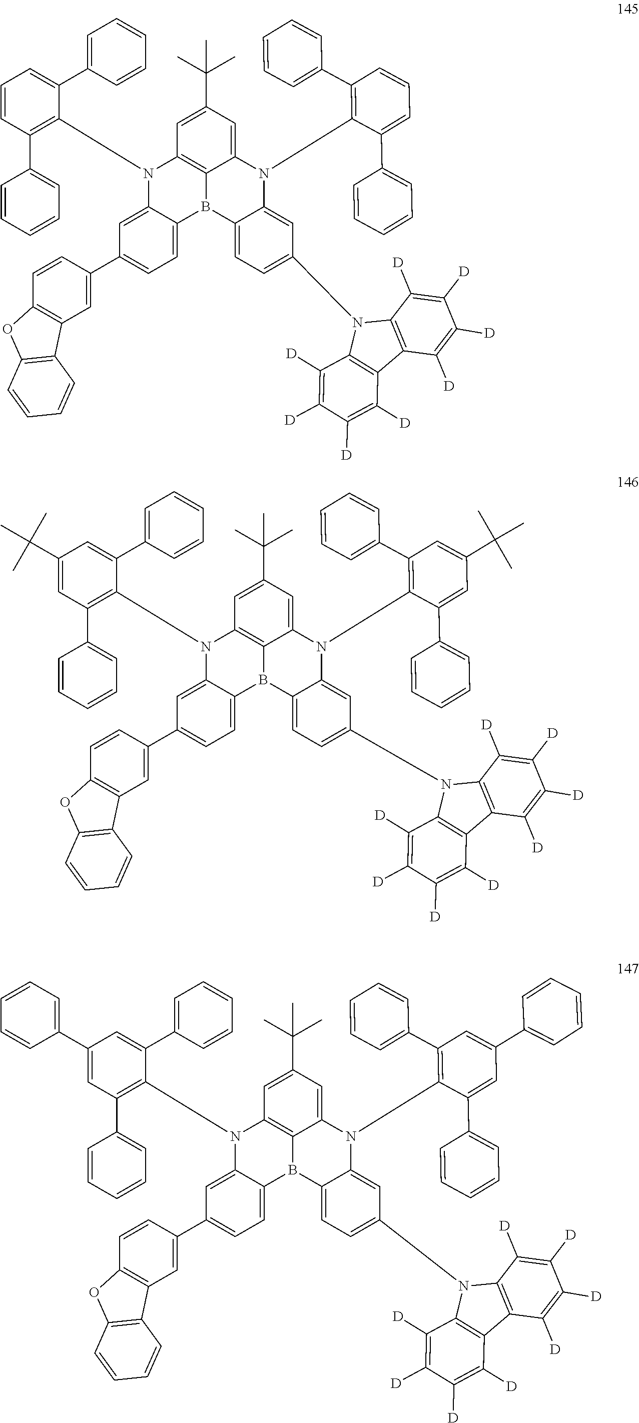

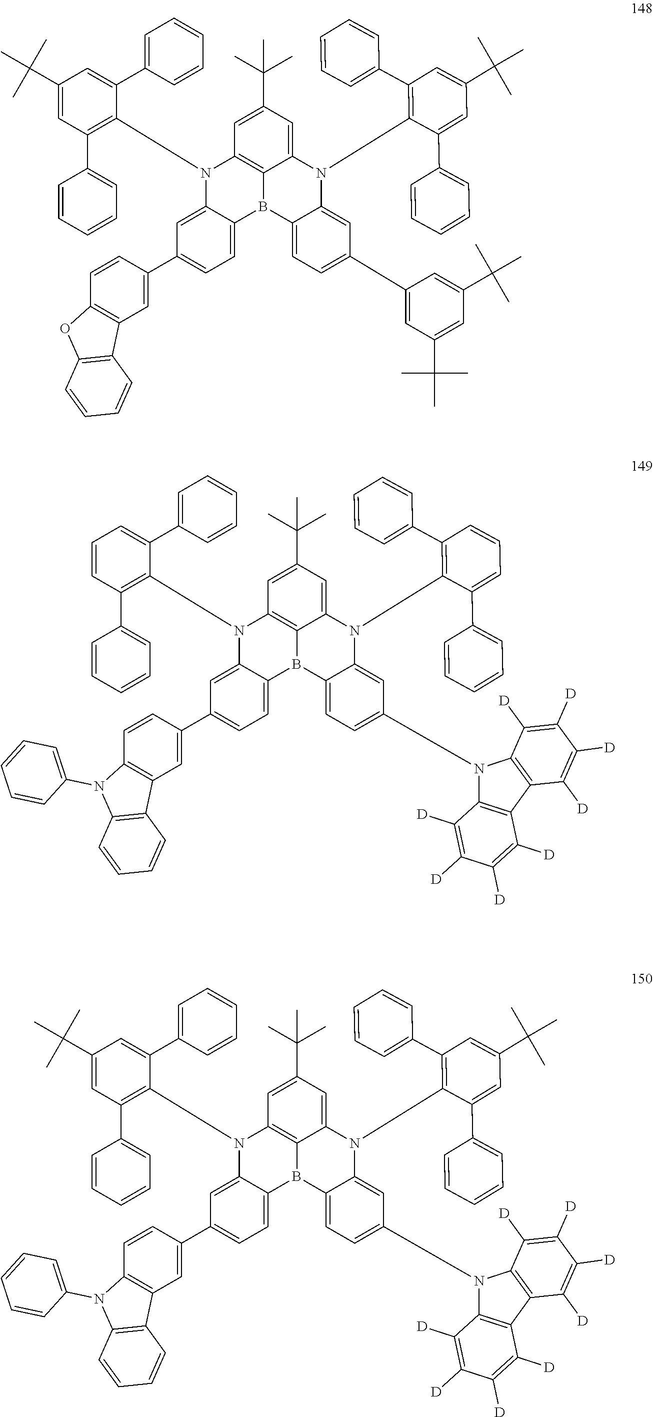

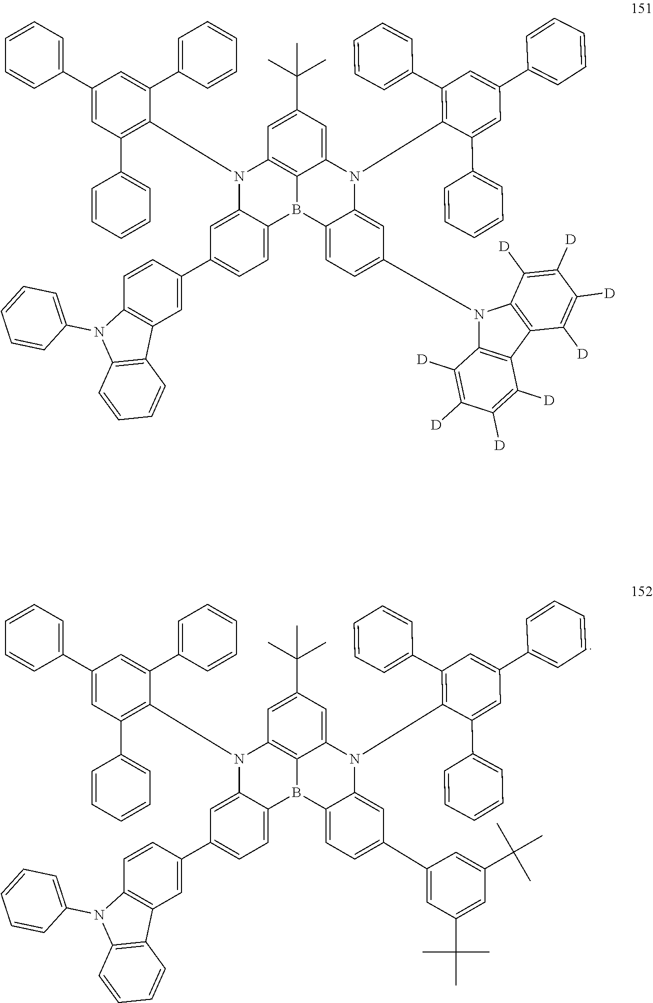 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(C(C)(C)C)cc3c1B2c1ccc(-c2ccc4c(c2)c2ccccc2n4-c2ccccc2)cc1N3c1c(-c2ccccc2)cc(-c2ccccc2)cc1-c1ccccc1 ; CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(-c3ccc5c(c3)c3ccccc3n5-c3ccccc3)cc2N4c2c(-c3ccccc3)cc(-c3ccccc3)cc2-c2ccccc2)cc(C(C)(C)C)c1]

In the structures of the compounds of Compound Group 1, D refers to a deuterium atom.

The light emitting spectrum of the first compound of an embodiment, represented by Formula 1 may have a full width at half maximum of about 10-50 nm, about 20-40 nm. Because the light emitting spectrum of the first compound of an embodiment, represented by Formula 1 has the full width at half maximum in the range, when applied to a device, emission efficiency may be improved. In some embodiments, when utilized as a material for a blue light emitting device, device lifetime may be improved (increased).

The first compound of an embodiment, represented by Formula 1 may be a material for emitting thermally activated delayed fluorescence. In some embodiments, the first compound of an embodiment, represented by Formula 1 may be a thermally activated delayed fluorescence dopant having a difference (ΔE_{ST}) between the lowest triplet excitation energy level (T1 level) and the lowest singlet excitation energy level (S1 level) of about 0.3 eV or less. For example, ΔE_{ST} of the first compound of an embodiment, represented by Formula 1 may be about 0.1 eV or less.

The first compound of an embodiment, represented by Formula 1 may be a light emitting material having the central wavelength of emitting light in a wavelength region of about 430 nm to about 490 nm. For example, the first compound of an embodiment, represented by Formula 1 may be a blue thermally activated delayed fluorescence (TADF) dopant. However, an embodiment of the present disclosure is not limited thereto. In an embodiment utilizing the first compound as a light emitting material, the first compound may be utilized as a dopant material emitting light in one or more suitable wavelength regions including a red light emitting dopant, a green light emitting dopant, etc.

In the light emitting device ED of an embodiment, an emission layer EML may emit delayed fluorescence. For example, the emission layer EML may emit thermally activated delayed fluorescence (TADF).

In some embodiments, the emission layer EML of the light emitting device ED may emit blue light. For example, the emission layer EML of the light emitting device ED may emit blue light in a region of about 490 nm or less. However, an embodiment of the present disclosure is not limited thereto. The emission layer EML may emit green light or red light.

In the light emitting device ED of an embodiment, the emission layer EML may include a host for emitting delayed fluorescence and a dopant for emitting delayed fluorescence and may include the first compound as a dopant for emitting delayed fluorescence. The emission layer EML may include at least one of the fused polycyclic compounds represented in Compound Group 1 as a thermally activated delayed fluorescence dopant.

In the light emitting device ED of an embodiment, the emission layer EML may include a host. The host may play the role of not emitting light but transferring energy to a dopant in the light emitting device ED. The emission layer EML may include one or more types (kinds) of hosts. For example, the emission layer EML may include two different types (kinds) of hosts. In an embodiment in which the emission layer EML includes two types (kinds) of hosts, the two types (kinds) of hosts may include a hole transport host and an electron transport host. However, an embodiment of the present disclosure is not limited thereto, and the emission layer EML may include one type or kind of a host or a mixture of two or more types (kinds) of different hosts.

In an embodiment, the emission layer EML may include two different hosts. The host may include a second compound and a third compound which is different from the second compound. The host may include a second compound having a hole transport moiety and a third compound having an electron transport moiety. In the light emitting device ED of an embodiment, the second compound and the third compound may form an exciplex in the host.

In an embodiment, the host may include a second compound represented by Formula H-1, and a third compound represented by Formula H-2. The second compound may be a hole transport host, and the third compound may be an electron transport host.

The emission layer EML according to an embodiment may include a second compound including a moiety derived from a carbazole group. The second compound may be represented by Formula H-1.

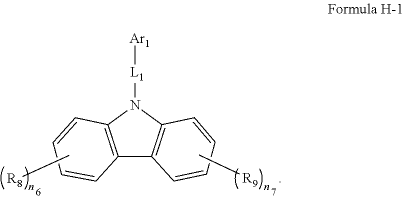

In Formula H-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, Ar₁ may be a substituted or unsubstituted aryl group of 6 to 30 ring-forming carbon atoms, or a substituted or unsubstituted heteroaryl group of 2 to 30 ring-forming carbon atoms.

In Formula H-1, R₈ and R₉ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₈ and R₉ may each independently be a hydrogen atom, a deuterium atom.

In Formula H-1, n₆ and n₇ may each independently be an integer of 0 to 4. In some embodiments, when each of n₆ and n₇ is an integer of 2 or more, each of multiple R₈ and multiple R₉ may be all the same, or at least one may be different. For example, in Formula H-1, n₆ and n₇ may be 0. In this embodiment, the carbazole group of Formula H-1 corresponds to an unsubstituted one.

In Formula H-1, L₁ may be a direct linkage, a phenylene group, a divalent biphenyl group, a divalent carbazole group, etc., but an embodiment of the present disclosure is not limited thereto. In some embodiments, Ar₁ may be a substituted or unsubstituted carbazole group, a substituted or unsubstituted dibenzofuran group, a substituted or unsubstituted dibenzothiophene group, a substituted or unsubstituted biphenyl group, etc., but an embodiment of the present disclosure is not limited thereto.

In the light emitting device ED of an embodiment, the emission layer EML may include a compound represented by Formula H-2 as the third compound.

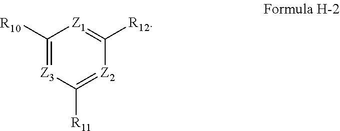

In Formula H-2, at least one among Z₁ to Z₃ may be N. The remainder other than N among Z1 to Z3, may be CR₁₃. For example, the third compound represented by Formula H-2 may include a pyridine moiety, a pyrimidine moiety, or a triazine moiety.

In Formula H-2, R₁₀ to R₁₃ may each independently be a hydrogen atom, a deuterium atom, a cyano group, a substituted or unsubstituted silyl group, a substituted or unsubstituted aryl group of 6 to 30 ring-forming carbon atoms, or a substituted or unsubstituted heteroaryl group of 2 to 30 ring-forming carbon atoms.

In Formula H-2, R₁₀ to R₁₃ may each independently be a substituted or unsubstituted phenyl group, a substituted or unsubstituted carbazole group, etc., but an embodiment of the present disclosure is not limited thereto.

When the emission layer EML of the light emitting device ED of an embodiment includes the second compound represented by Formula H-1 and the third compound represented by Formula H-2, concurrently (e.g., simultaneously), excellent or suitable emission efficiency and long-life characteristics may be shown. For example, in the emission layer EML of the light emitting device ED of an embodiment, the host may be an exciplex formed by the second compound represented by Formula H-1 and the third compound represented by Formula H-2.

Among the two host materials included in the emission layer EML concurrently (e.g., simultaneously), the second compound may be a hole transport host, and the third compound may be an electron transport host. The light emitting device ED of an embodiment includes both (e.g., simultaneously) a second compound having excellent or suitable hole transport properties and a third compound having excellent or suitable electron transport properties in the emission layer EML, and may efficiently transfer energy to a dopant compound.

The light emitting device ED of an embodiment may further include a fourth compound in addition to the first compound represented by Formula 1 in the emission layer EML. The emission layer EML may include an organometallic complex including platinum (Pt) as a central metal element and ligands bonded to the central metal element, as the fourth compound. In the light emitting device ED of an embodiment, the emission layer EML may include a compound represented by Formula D-2 as the fourth compound.

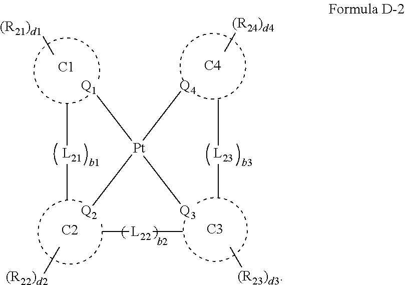

In Formula D-2, Q₁ to Q₄ may each independently be C or N.

In Formula D-2, C1 to C4 may each independently be a substituted or unsubstituted hydrocarbon ring of 5 to 30 ring-forming carbon atoms, or a substituted or unsubstituted heterocycle of 2 to 30 ring-forming carbon atoms.

In Formula D-2, L₂₁ to L₂₃ may each independently be a direct linkage, *—O—*, *—S—*,

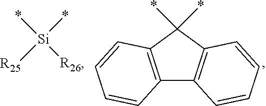

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₂₁ to L₂₃, “-*” may be a part connected with C1 to C4.

In Formula D-2, b1 to b3 may each independently be 0 or 1. When b1 is 0, C1 and C2 may not be connected with each other. When b2 is 0, C2 and C3 may not be connected with each other. When b3 is 0, C3 and C4 may not be connected with each other.

In Formula D-2, R₂₁ to R₂₆ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 1 to 30 ring-forming carbon atoms, and/or combined with an adjacent group to form a ring. For example, R₂₁ to R₂₆ may each independently be a methyl group or a t-butyl group.

In Formula D-2, d1 to d4 may each independently be an integer of 0 to 4. In some embodiments, when each of d1 to d4 is an integer of 2 or more, multiple R₂₁ to R₂₄ may be all the same, or at least one thereof may be different.

In Formula D-2, C1 to C4 may each independently be a substituted or unsubstituted hydrocarbon ring or a substituted or unsubstituted heterocycle, represented by any one of C-1 to C-3.

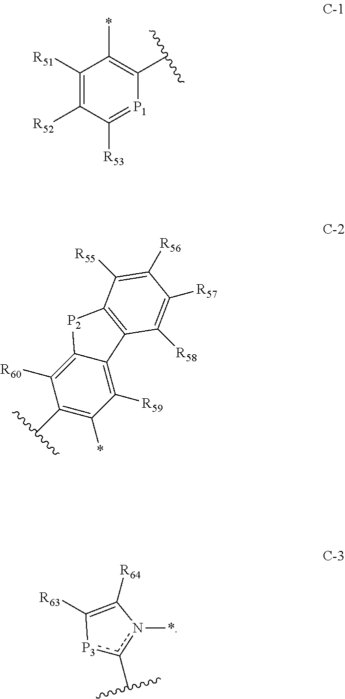

In C-1 to C-3, P₁ may be “C—*” or CR₅₄, P₂ may be “N—*” or NR₆₁, and P₃ may be “N—*” or NR₆₂. R₅₁ to R₆₄ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 6 to 30 ring-forming carbon atoms, and/or combined with an adjacent group to form a ring.

In some embodiments, in C-1 to C-3,

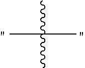

is a part connected with a Pt central metal element, and “-*” is a part connected with a neighboring ring group (C1 to C4) or a linker (L₂₁ to L₂₄).

The fourth compound represented by Formula D-2 may be a phosphorescence dopant.

In an embodiment, the first compound may be a light emitting dopant emitting blue light, and the emission layer EML may emit fluorescence. In some embodiments, for example, the emission layer EML may emit blue light of delayed fluorescence.

In an embodiment, the fourth compound included in the emission layer EML may be a sensitizer. In the light emitting device ED of an embodiment, the fourth compound included in the emission layer EML may play the role of a sensitizer and transferring energy from the host to the first compound which is a light emitting dopant. For example, the fourth compound which plays the role of an auxiliary dopant may accelerate the energy transfer to the first compound which is a light emitting dopant to increase the light emitting ratio of the first compound. Accordingly, the emission efficiency of the emission layer EML of an embodiment may be improved (increased). In some embodiments, when the energy transfer to the first compound increases, excitons formed in the emission layer EML may not be accumulated in the emission layer EML but may emit light rapidly, thereby reducing the deterioration of a device. Accordingly, the lifetime of the light emitting device ED of an embodiment may increase.

In the light emitting device ED of an embodiment, when the emission layer EML includes the first compound, the second compound, the third compound, and the fourth compound, the amount of the first compound may be about 1 wt % to about 5 wt %, and the amount of the fourth compound may be about 10 wt % to about 15 wt % based on the total weight of the first compound, the second compound, the third compound, and the fourth compound.

When the amounts of the first compound and the fourth compound satisfy the above-described ratios, the first compound may efficiently transfer energy to the fourth compound, and accordingly, the emission efficiency and device life may increase.

In the emission layer EML, the amount of the second compound and third compound may be a remaining amount excluding the first compound and the fourth compound. For example, in the emission layer EML, the amount of the second compound and third compound may be about 80 wt % to about 89 wt % based on the total weight of the first compound, the second compound, the third compound, and the fourth compound. Among the total weight of the second compound and third compound, the weight ratio of the second compound and the third compound may be about 3:7 to about 7:3. For example, of the total weight of the second compound and third compound, the weight ratio of the second compound and the third compound may be about 5:5.

When the amount of the second compound and third compound satisfies the above-described ratio, charge balance properties in the emission layer EML may be improved, and the emission efficiency and device life may increase. When the amount of the second compound and third compound deviates from the above-described ratio range, charge balance in the emission layer EML may be broken (unfavorable), emission efficiency may be degraded, and the device may easily deteriorate.

When the first compound, the second compound, the third compound, and the fourth compound, included in the emission layer EML satisfy the above-described amount ratio ranges, excellent or suitable emission efficiency and a long lifetime may be achieved.

The light emitting device ED of an embodiment includes all of the four compounds i.e., the first compound, the second compound, the third compound, and the fourth compound, and the emission layer EML may include the combination of two host materials and two dopant materials. In the light emitting device ED of an embodiment, the emission layer EML may include two different hosts, a first compound emitting delayed fluorescence, and a fourth compound including an organometallic complex, concurrently (e.g., simultaneously), and excellent or suitable emission efficiency properties may be shown.

In an embodiment, the second compound represented by Formula H-1 may be represented by any one of the compounds in Compound Group 2. The emission layer EML may include at least one of the compounds represented in Compound Group 2 as a hole transport host material.

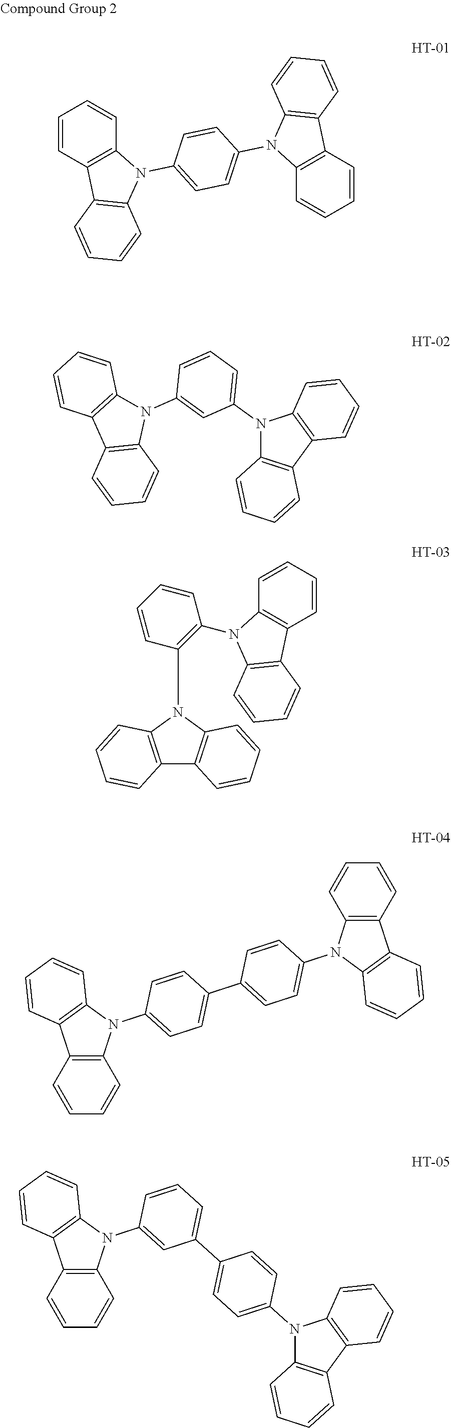

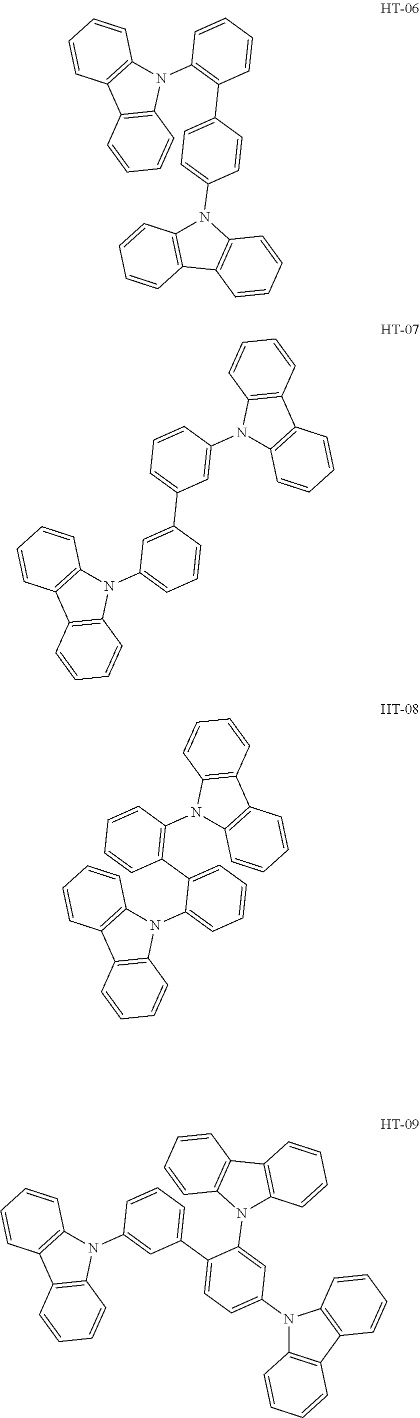

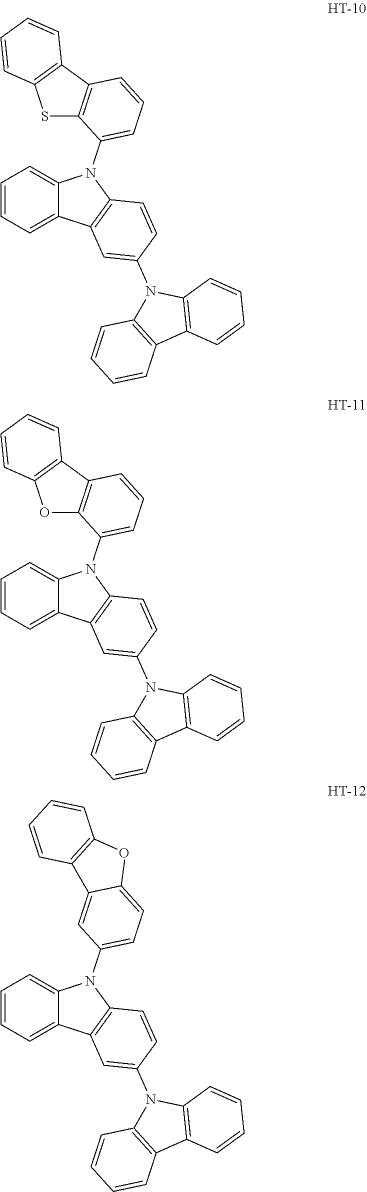

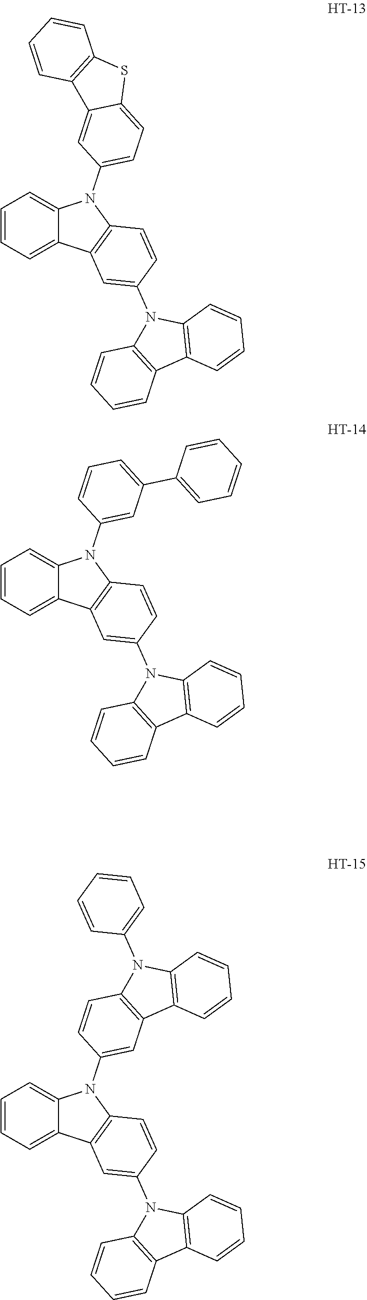 [SMILES: c1ccc2c(c1)sc1ccc(-n3c4ccccc4c4cc(-n5c6ccccc6c6ccccc65)ccc43)cc12 ; c1ccc(-c2cccc(-n3c4ccccc4c4cc(-n5c6ccccc6c6ccccc65)ccc43)c2)cc1 ; c1ccc(-n2c3ccccc3c3cc(-n4c5ccccc5c5cc(-n6c7ccccc7c7ccccc76)ccc54)ccc32)cc1]

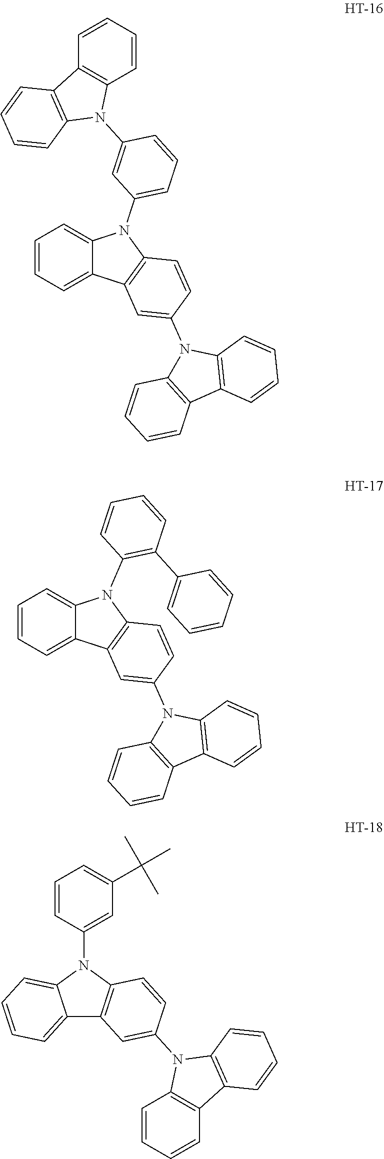

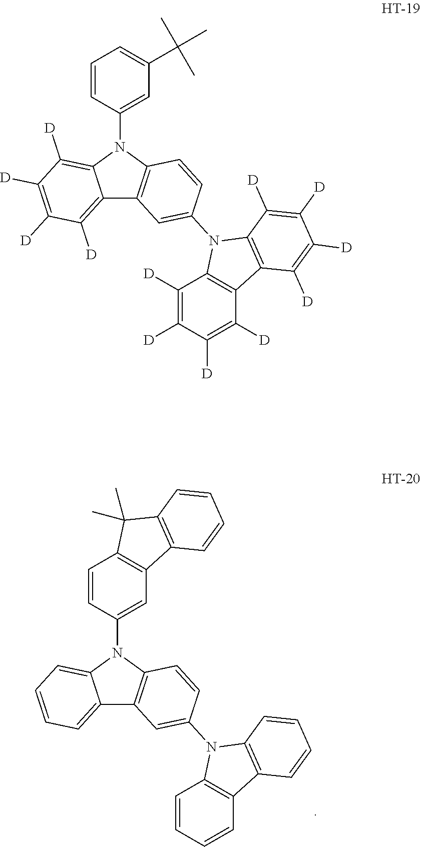 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; CC1(C)c2ccccc2-c2cc(-n3c4ccccc4c4cc(-n5c6ccccc6c6ccccc65)ccc43)ccc21]

In an embodiment, the third compound represented by Formula H-2 may be represented by any one of the compounds in Compound Group 3. The emission layer EML may include at least one of the compounds represented in Compound Group 3 as an electron transport host material.

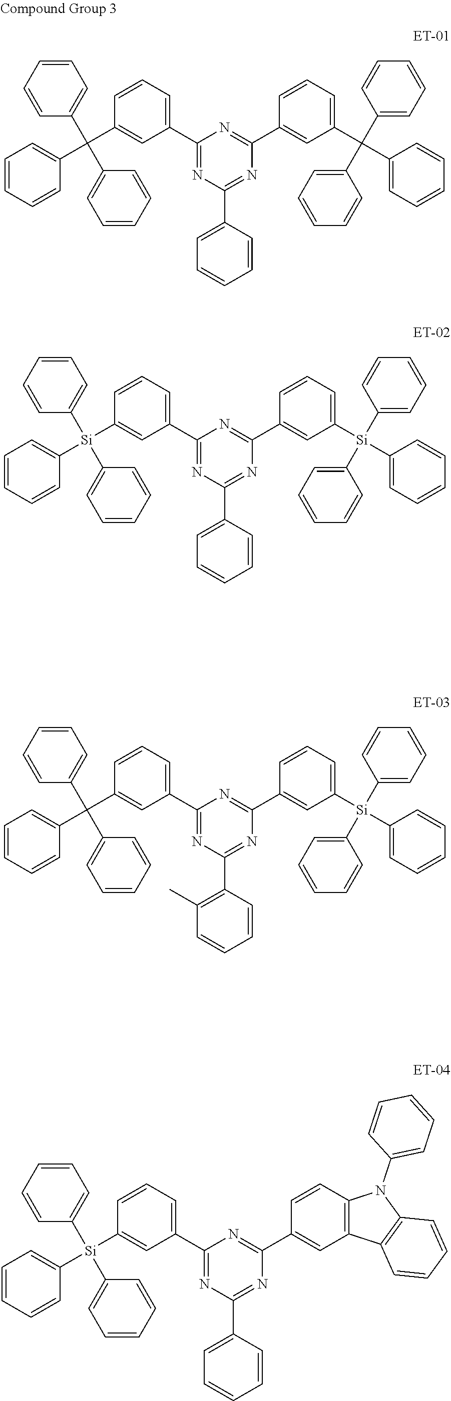 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc([Si](c3ccccc3)(c3ccccc3)c3ccccc3)c2)n1 ; c1ccc(-c2nc(-c3cccc([Si](c4ccccc4)(c4ccccc4)c4ccccc4)c3)nc(-c3ccc4c(c3)c3ccccc3n4-c3ccccc3)n2)cc1]

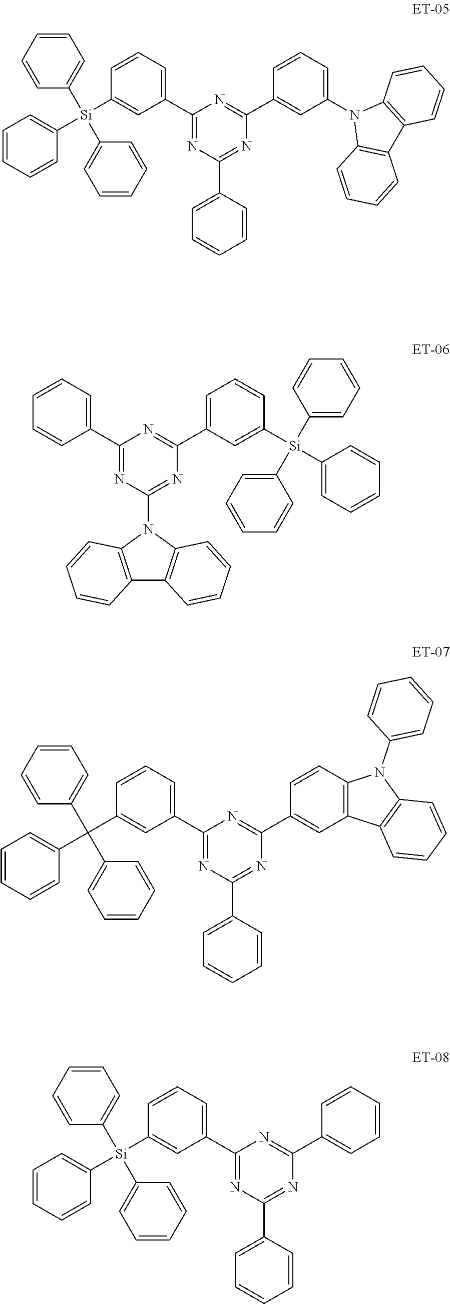 [SMILES: c1ccc(-c2nc(-c3cccc(-n4c5ccccc5c5ccccc54)c3)nc(-c3cccc([Si](c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-n3c4ccccc4c4ccccc43)n2)cc1 ; c1ccc(-c2nc(-c3cccc(C(c4ccccc4)(c4ccccc4)c4ccccc4)c3)nc(-c3ccc4c(c3)c3ccccc3n4-c3ccccc3)n2)cc1 ; c1ccc(-c2nc(-c3ccccc3)nc(-c3cccc([Si](c4ccccc4)(c4ccccc4)c4ccccc4)c3)n2)cc1]

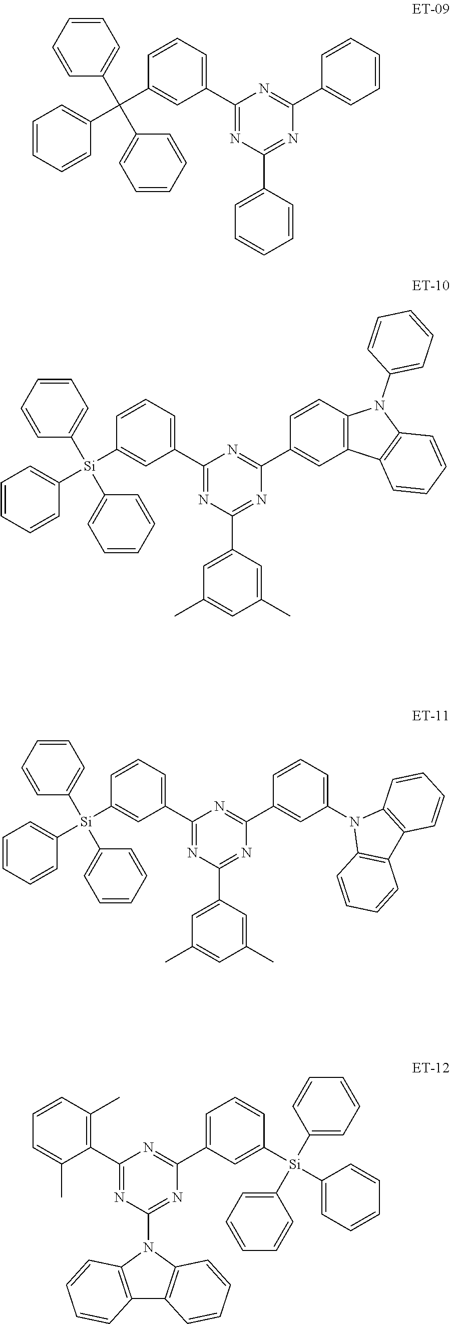 [SMILES: c1ccc(-c2nc(-c3ccccc3)nc(-c3cccc(C(c4ccccc4)(c4ccccc4)c4ccccc4)c3)n2)cc1 ; Cc1cc(C)cc(-c2nc(-c3cccc([Si](c4ccccc4)(c4ccccc4)c4ccccc4)c3)nc(-c3ccc4c(c3)c3ccccc3n4-c3ccccc3)n2)c1 ; Cc1cc(C)cc(-c2nc(-c3cccc(-n4c5ccccc5c5ccccc54)c3)nc(-c3cccc([Si](c4ccccc4)(c4ccccc4)c4ccccc4)c3)n2)c1 ; Cc1cccc(C)c1-c1nc(-c2cccc([Si](c3ccccc3)(c3ccccc3)c3ccccc3)c2)nc(-n2c3ccccc3c3ccccc32)n1]

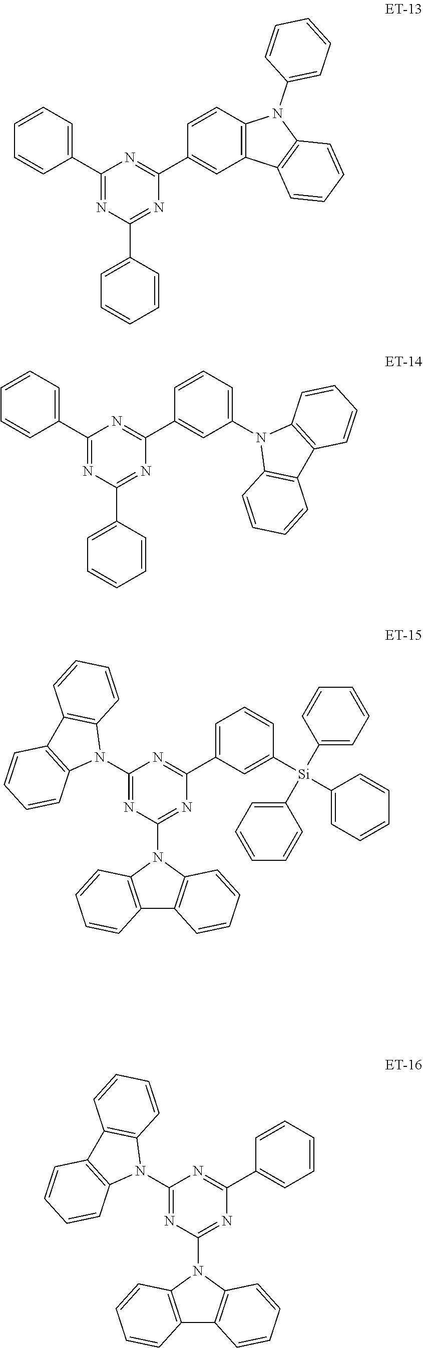 [SMILES: c1ccc(-c2nc(-c3ccccc3)nc(-c3ccc4c(c3)c3ccccc3n4-c3ccccc3)n2)cc1 ; c1ccc(-c2nc(-c3ccccc3)nc(-c3cccc(-n4c5ccccc5c5ccccc54)c3)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2nc(-n3c4ccccc4c4ccccc43)nc(-n3c4ccccc4c4ccccc43)n2)cc1]

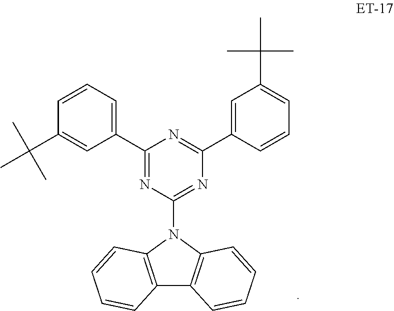 [SMILES: CC(C)(C)c1cccc(-c2nc(-c3cccc(C(C)(C)C)c3)nc(-n3c4ccccc4c4ccccc43)n2)c1]

In an embodiment, the emission layer EML may include at least one of the compounds represented in Compound Group 4 as the fourth compound material. The emission layer EML may include at least one of the compounds represented in Compound Group 4 as a sensitizer material.

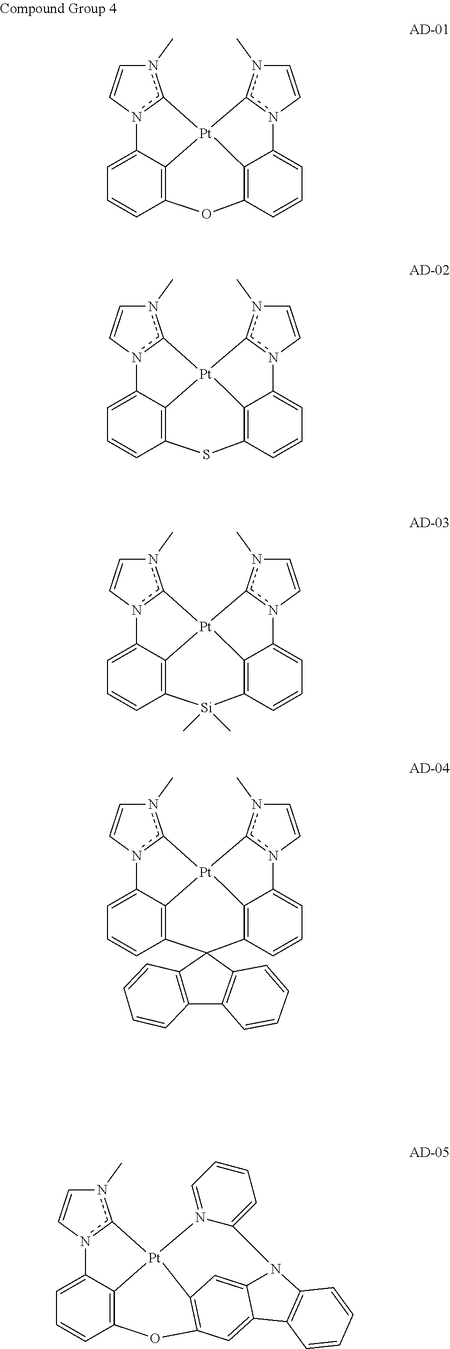

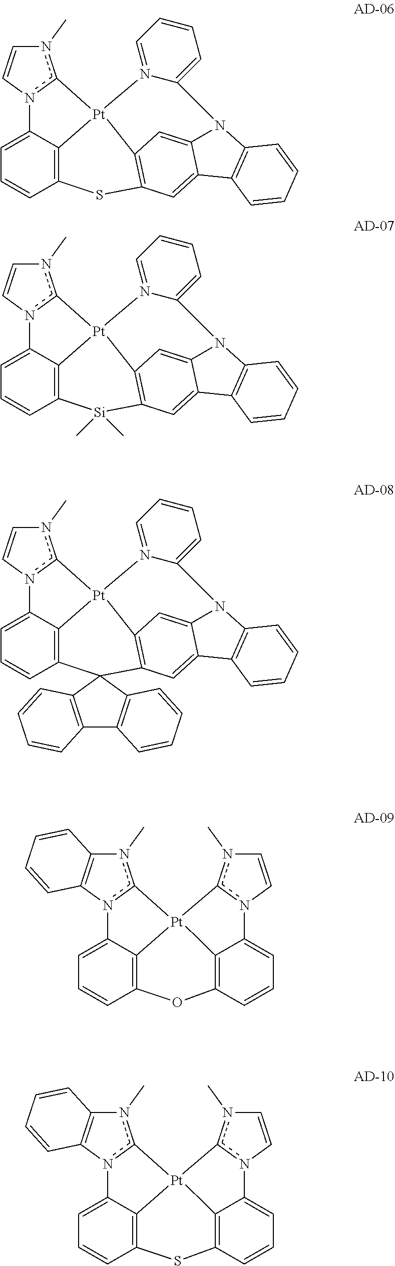

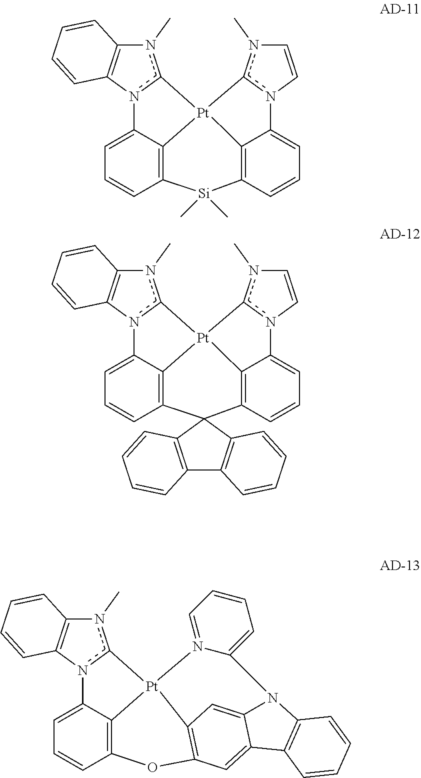

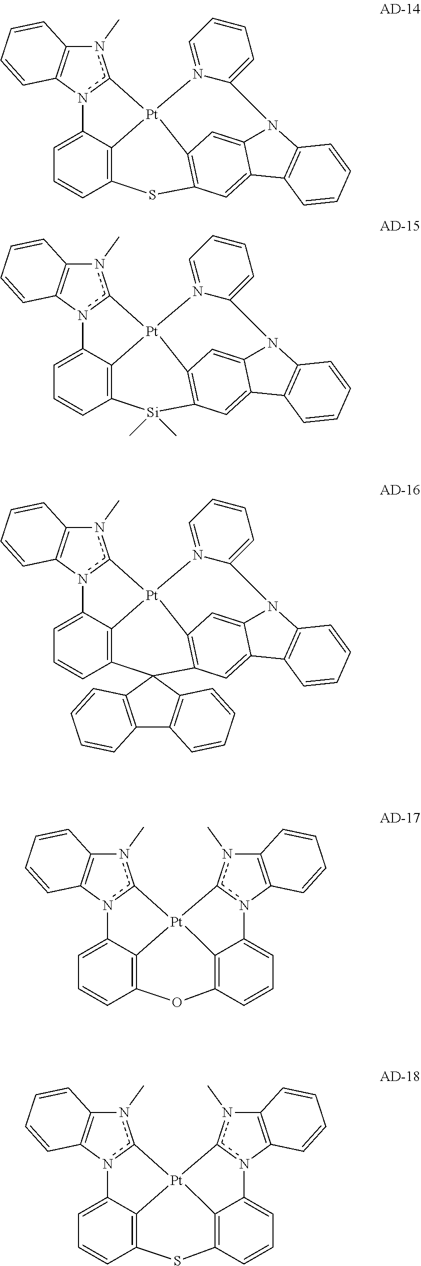

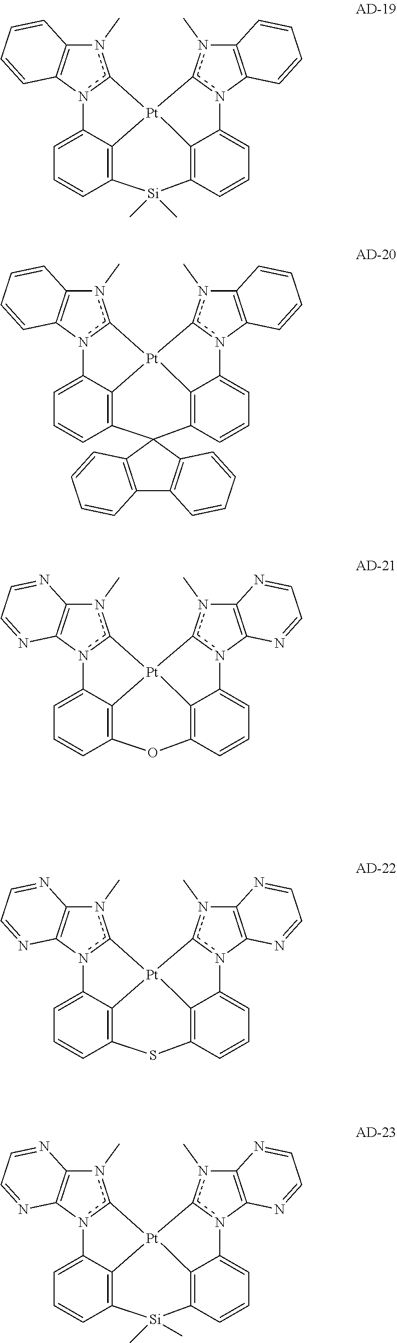

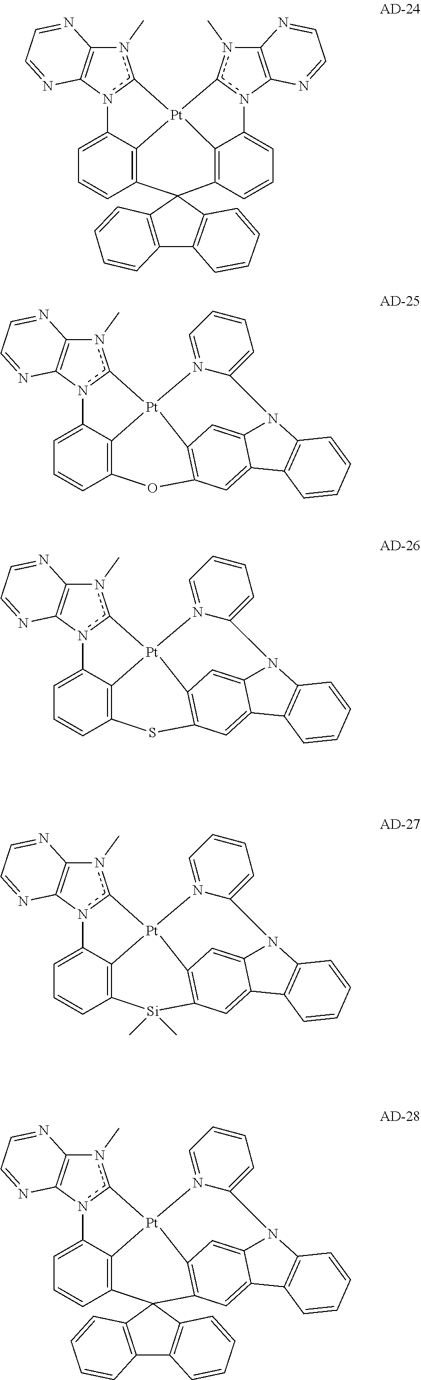

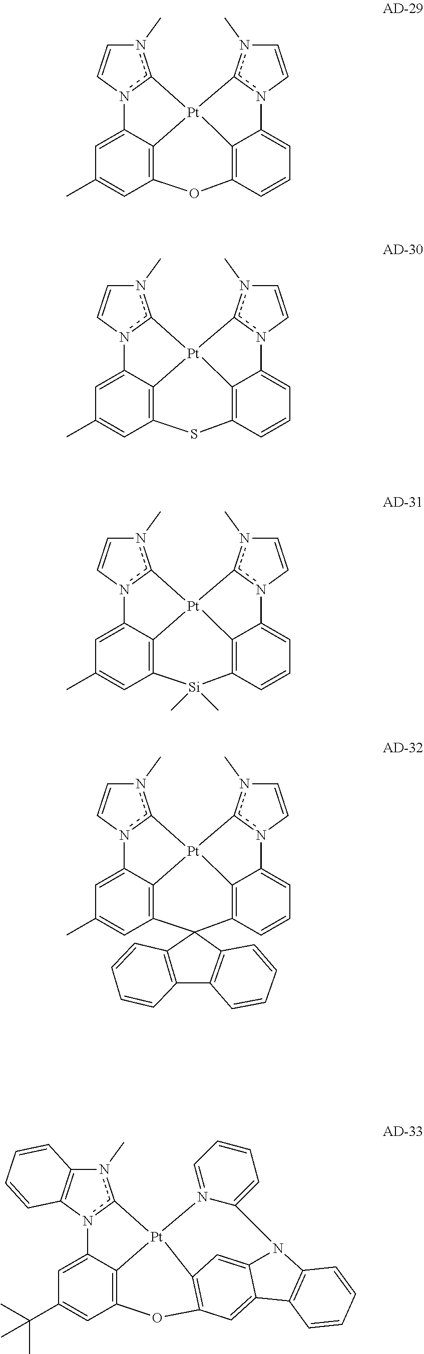

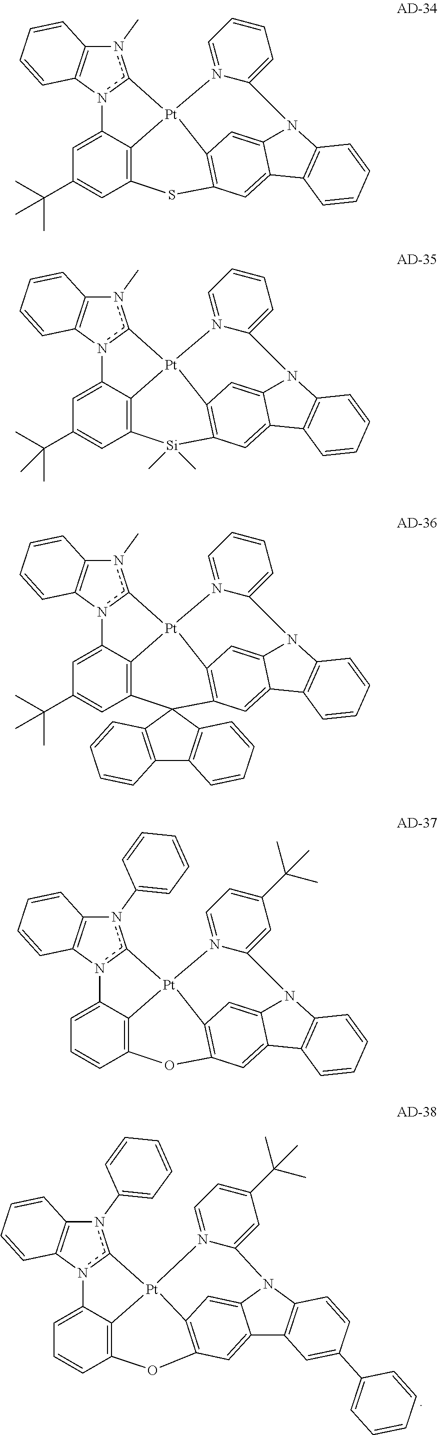

In some embodiments, the light emitting device ED of an embodiment may include multiple emission layers. The multiple emission layers may be provided by stacking (e.g., laminated) in order (e.g., in suitable order), for example, the light emitting device ED including the multiple stacked emission layers may emit white light. The light emitting device including the multiple emission layers may be a light emitting device with a tandem structure. When the light emitting device ED includes multiple emission layers, at least one emission layer EML may include all the first compound, the second compound, the third compound and the fourth compound as described above.

In the light emitting device ED of an embodiment, the emission layer EML may include anthracene derivatives, pyrene derivatives, fluoranthene derivatives, chrysene derivatives, dihydrobenzanthracene derivatives, or triphenylene derivatives. For example, the emission layer EML may include anthracene derivatives or pyrene derivatives.

In the light emitting devices ED of embodiments, shown in FIG. 3 to FIG. 6, the emission layer EML may further include additional suitable hosts and dopants in addition to the above-described host and dopant, and the emission layer EML may include a compound represented by Formula E-1. The compound represented by Formula E-1 may be utilized as a fluorescence host material.

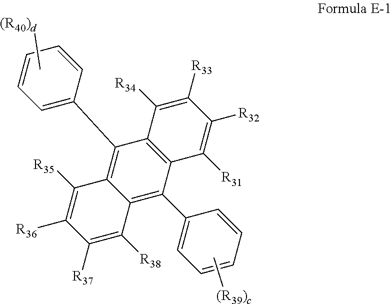

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In some embodiments, R₃₁ to R₄₀ may be combined with an adjacent group to form a saturated hydrocarbon ring, an unsaturated hydrocarbon ring, a saturated heterocycle or an unsaturated heterocycle.

In Formula E-1, “c” and “d” may each independently be an integer of 0 to 5.

Formula E-1 may be represented by any one of Compound E1 to Compound E19.

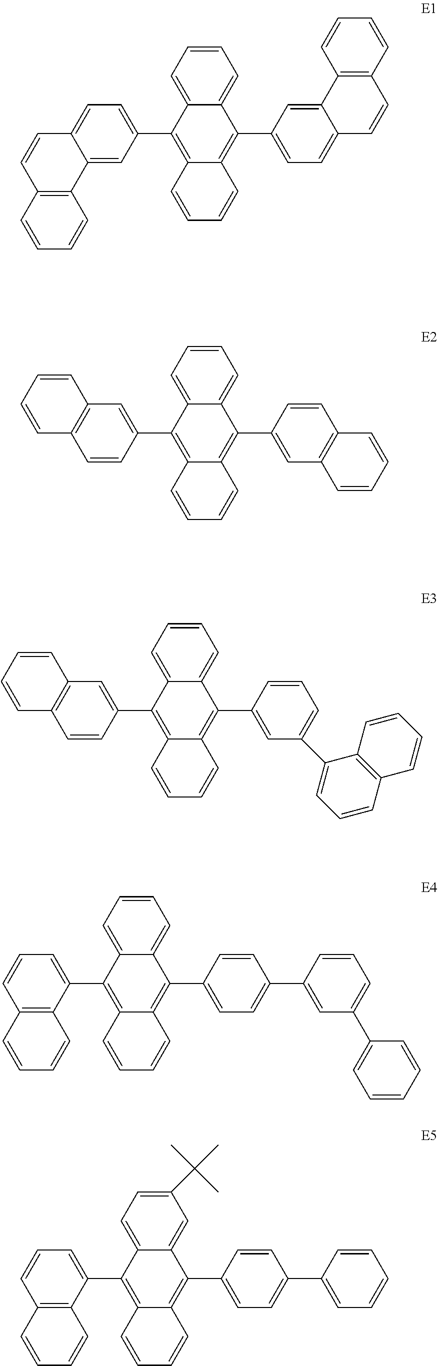

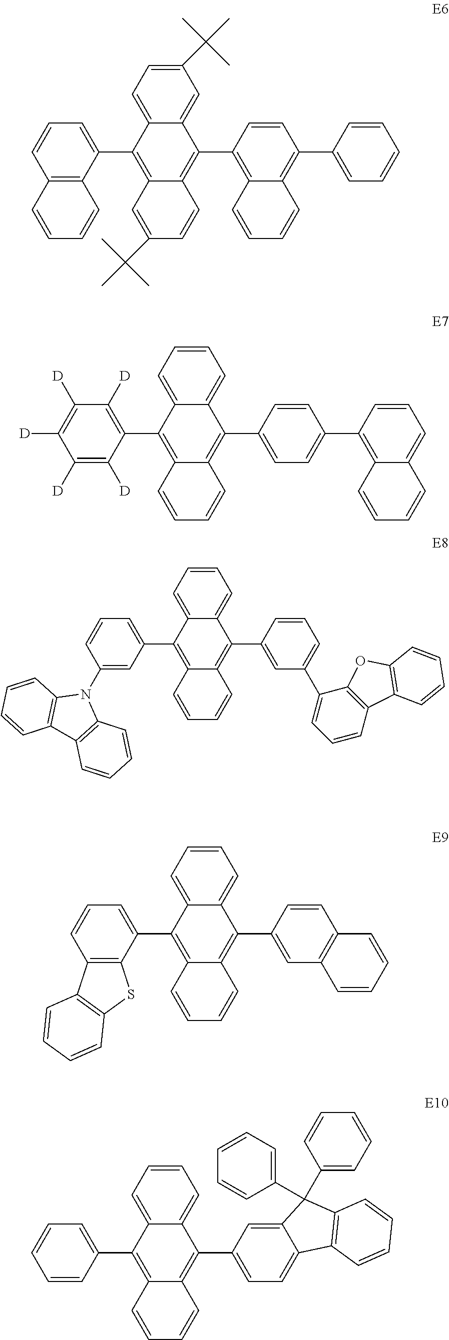

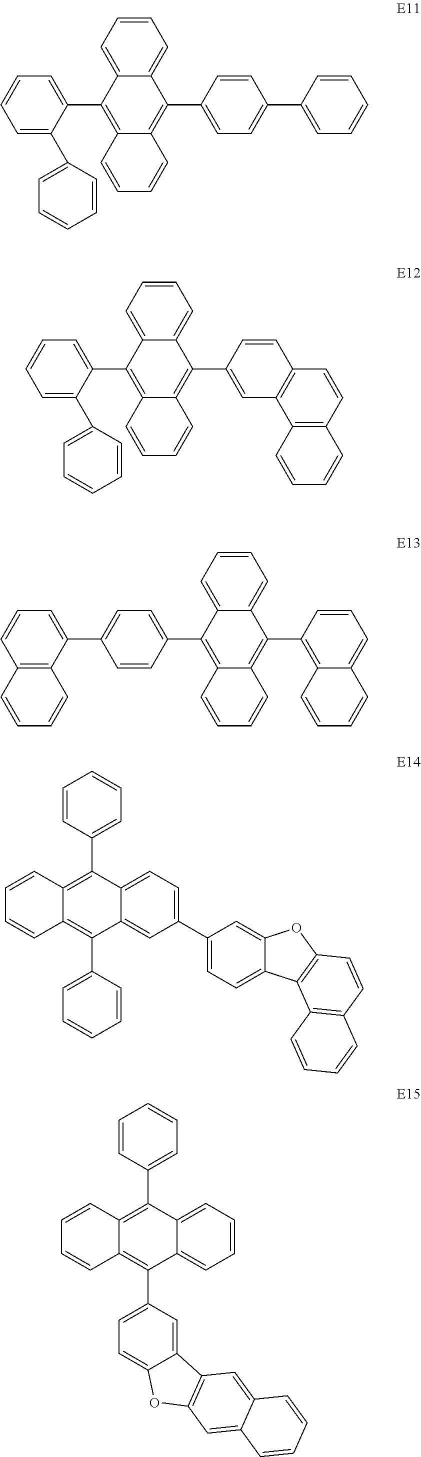

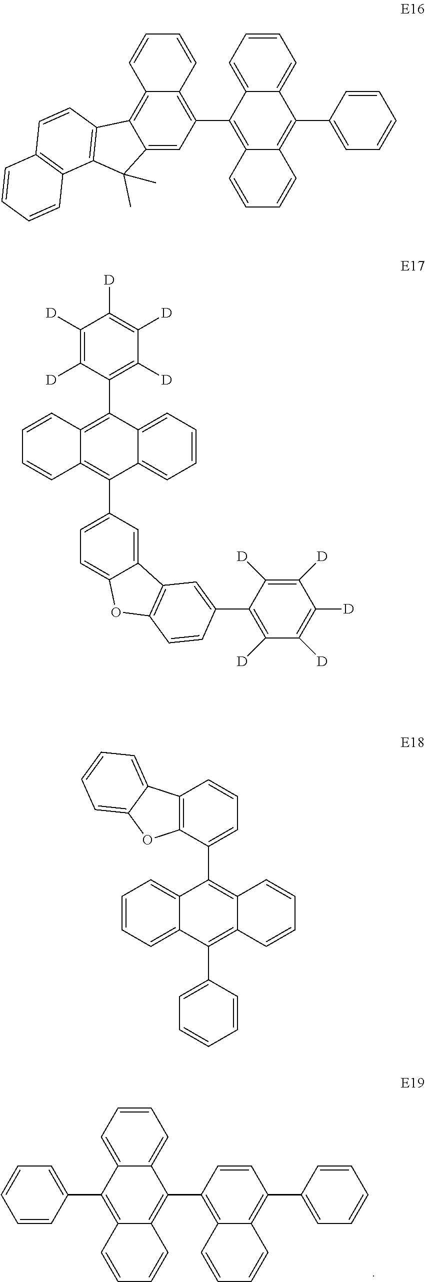

In an embodiment, the emission layer EML may further include a compound represented by Formula E-2a or Formula E-2b. The compound represented by Formula E-2a or Formula E-2b may be utilized as a phosphorescence host material.

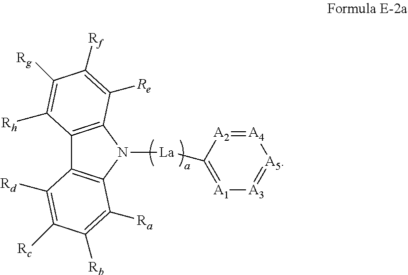

In Formula E-2b, “a” may be an integer of 0 to 10, Lₐ may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” is an integer of 2 or more, multiple Lₐ may each independently be a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₅ may each independently be N or CRi. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Rₐ to Rᵢ may be combined with an adjacent group to form a hydrocarbon ring or a heterocycle including N, O, S, etc. as a ring-forming atom.

In some embodiments, in Formula E-2a, two or three selected from A₁ to A₅ may be N, and the remainder may be CRᵢ.

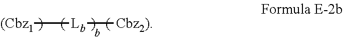

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and when “b” is an integer of 2 or more, multiple L_{b} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one of the compounds in Compound Group E-2. However, the compounds shown in Compound Group E-2 are only illustrations, and the compound represented by Formula E-2a or Formula E-2b is not limited to the compounds represented in Compound Group E-2.

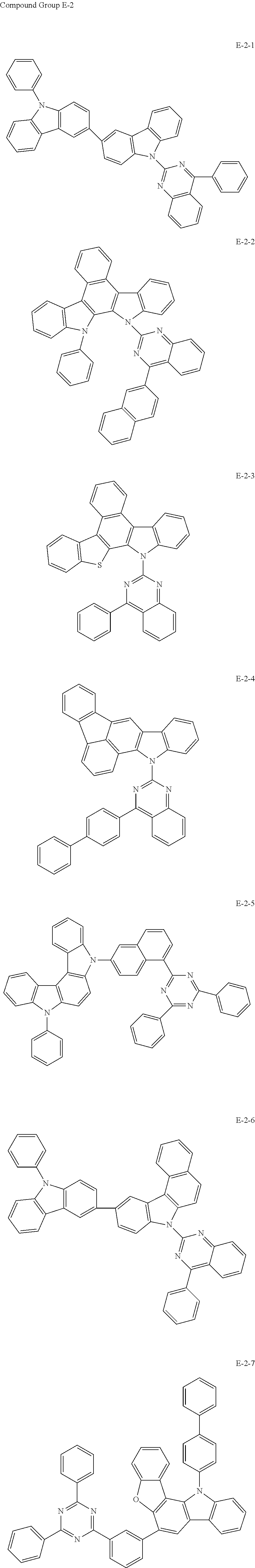

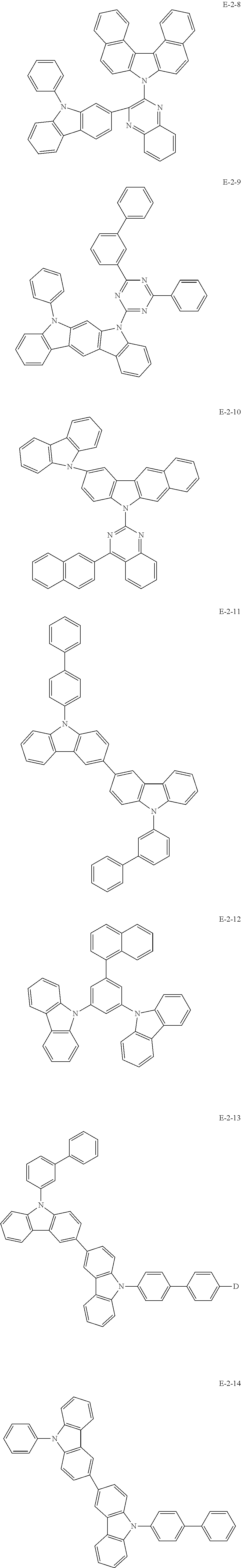

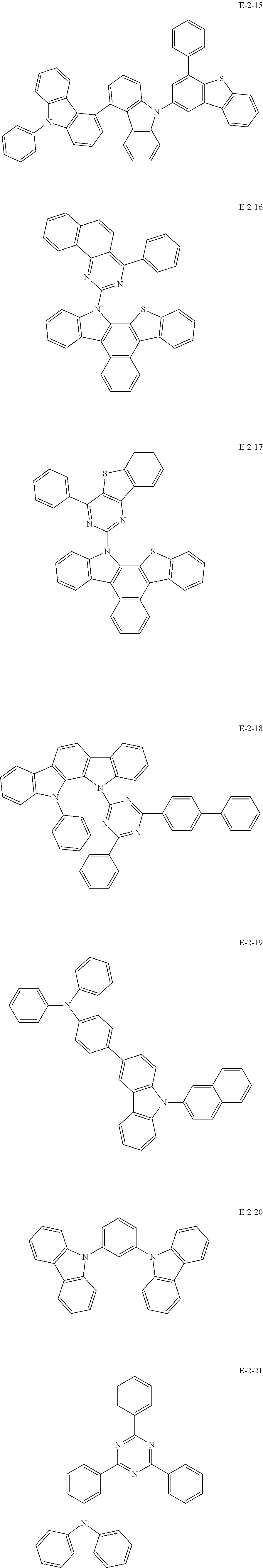

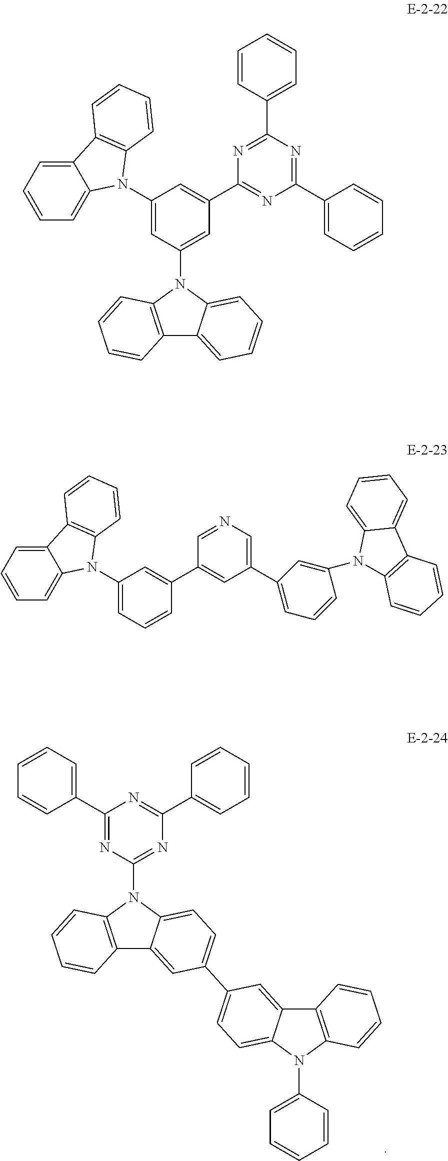 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a common material generally available in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, an embodiment of the present disclosure is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

The emission layer EML may further include a compound represented by Formula M-a or Formula M-b. The compound represented by Formula M-a or Formula M-b may be utilized as a phosphorescence dopant material.

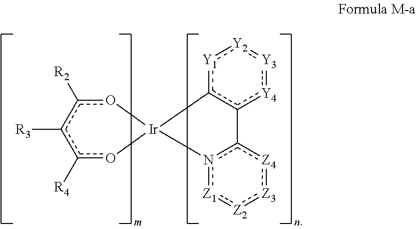

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, “m” is 0 or 1, and “n” is 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be represented by any one of Compounds M-a1 to M-a25. However, Compounds M-a1 to M-a25 are merely examples, and the compound represented by Formula M-a is not limited to the compounds represented by Compounds M-a1 to M-a25.

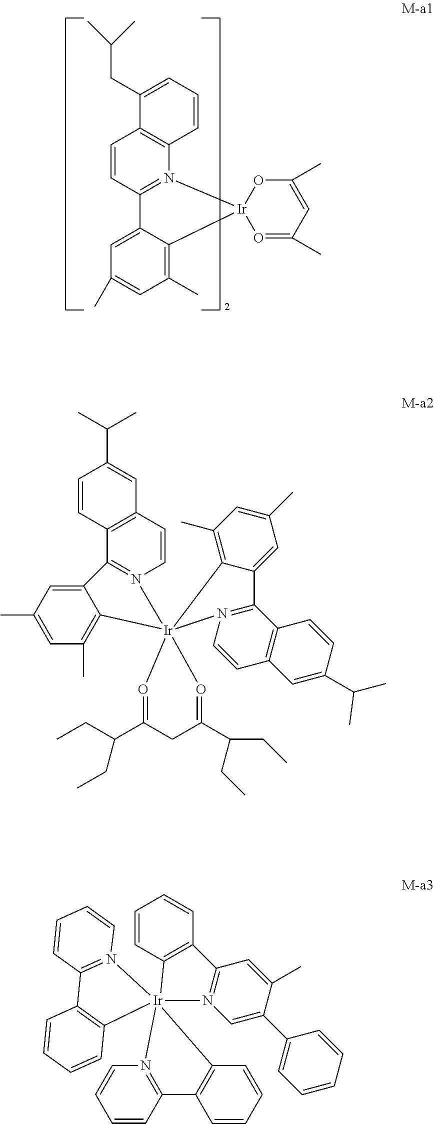

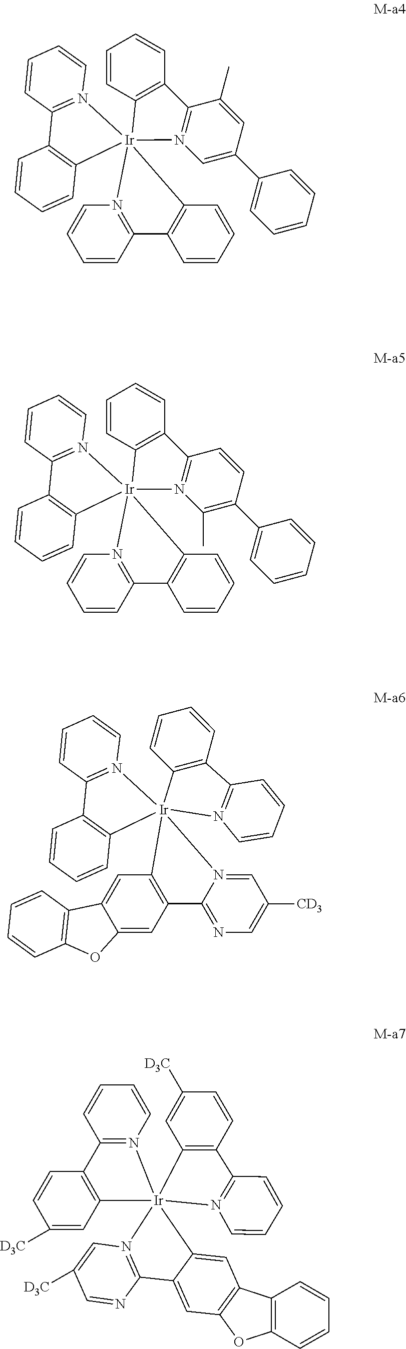

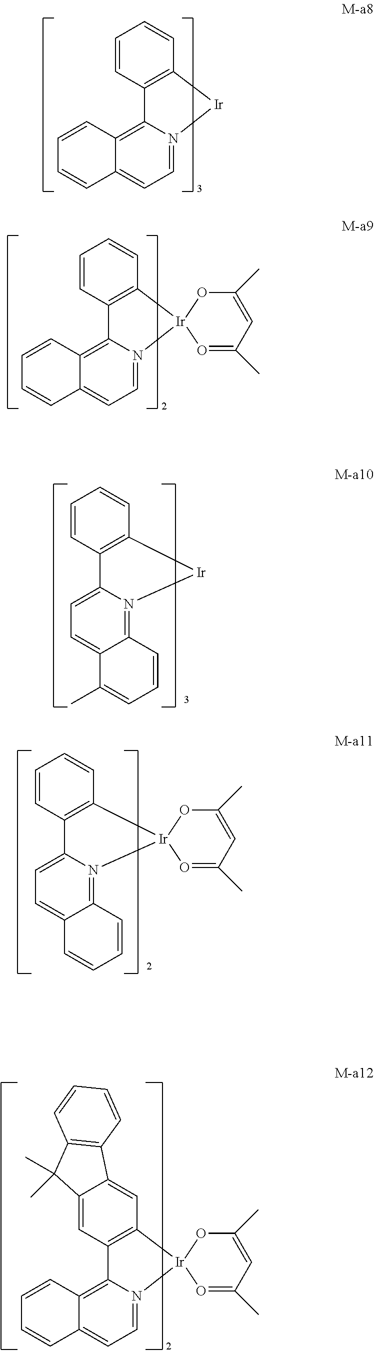

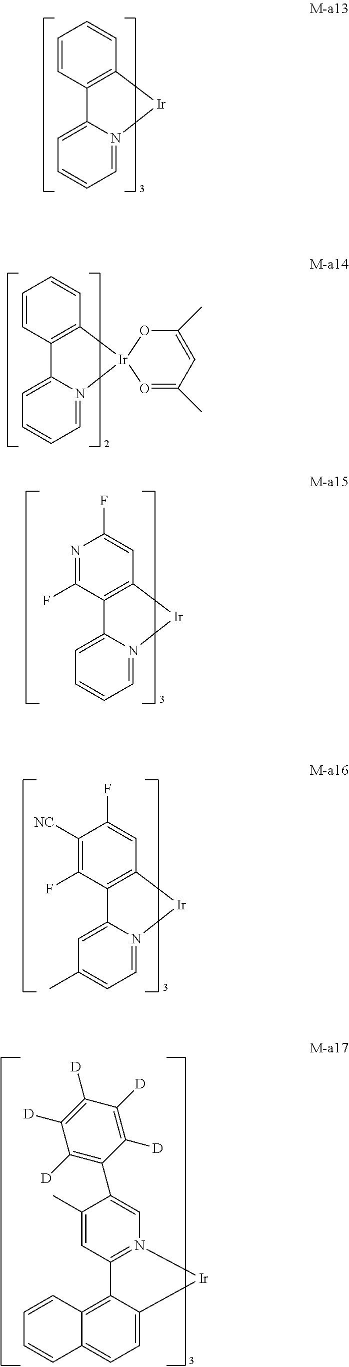

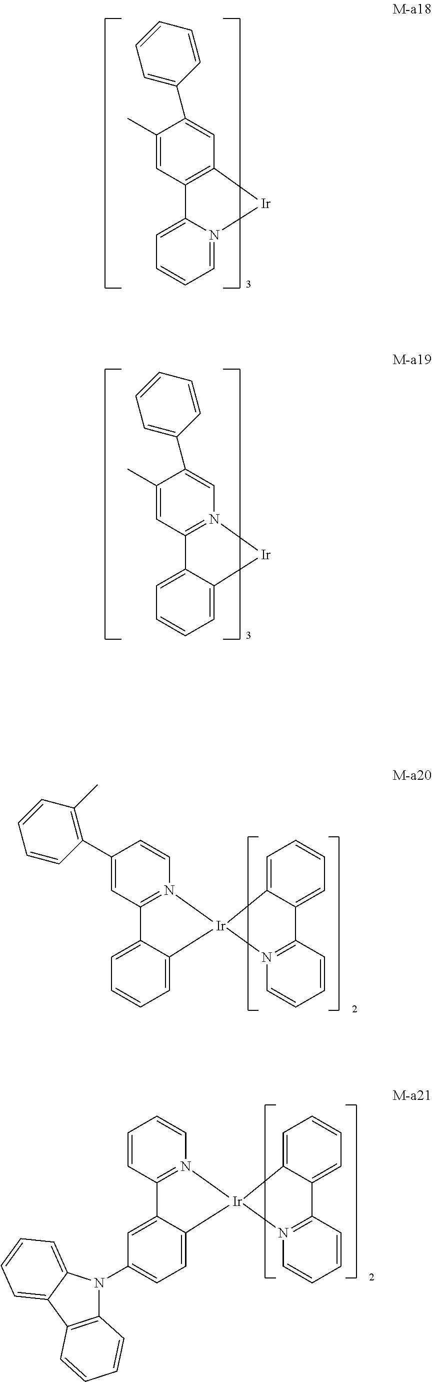

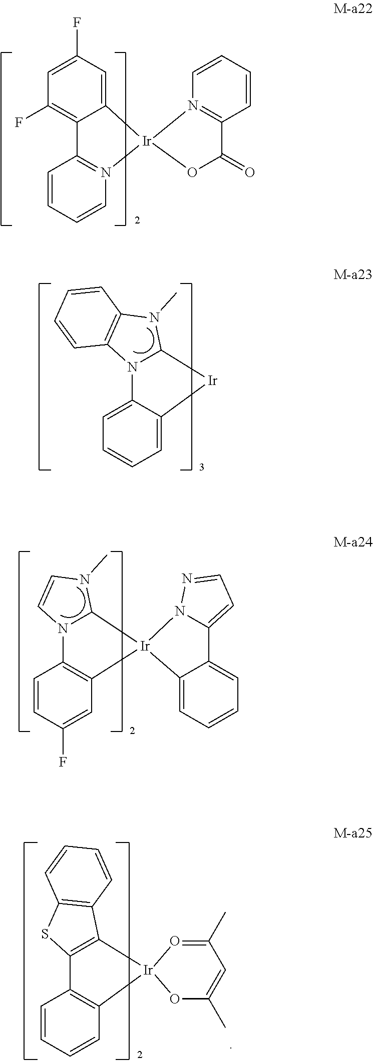

The emission layer EML may further include a compound represented by any one of Formula F-a to Formula F-c. The compounds represented by Formula F-a to Formula F-c may be utilized as fluorescence dopant materials.

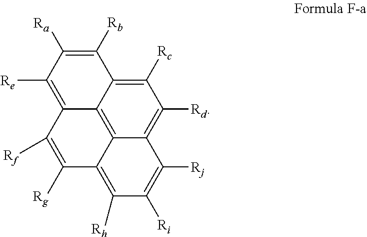

In Formula F-a, two R groups selected from Rₐ to Rⱼ may each independently be substituted with *—NAr₁Ar₂. The remainder of the R groups not substituted with *—NAr₁Ar₂ of Rₐ to Rⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one among Ar₁ and Ar₂ may be a heteroaryl group including O or S as a ring-forming atom.

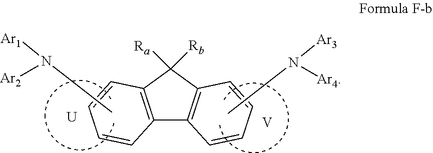

In Formula F-b, Ar₁ to Ar₃ may be a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In some embodiments, when the number of both (e.g., simultaneously) U and V is 0, the fused ring of Formula F-b may be a ring compound with three rings. In some embodiments, when the number of both (e.g., simultaneously) U and V is 1, a fused ring having the fluorene core of Formula F-b may be a ring compound with five rings.

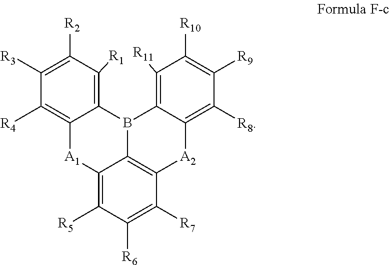

In Formula F-c, A₁ and A₂ may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ and A₂ may each independently be NRₘ, A₁ may be combined with R₄ or R₅ to form a ring. In some embodiments, A₂ may be combined with R₇ or R₈ to form a ring.

In an embodiment, the emission layer EML may include as a generally available dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and/or 1,4-bis(N,N-diphenylamino)pyrene), etc.

The emission layer EML may include a generally available phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), or platinum octaethyl porphyrin (PtOEP) may be utilized as the phosphorescence dopant. However, an embodiment of the present disclosure is not limited thereto.

The emission layer EML may include a quantum dot material. The core of the quantum dot may be selected from a II-VI group compound, a III-VI group compound, a I-III-VI group compound, a III-V group compound, a III-II-V group compound, a IV-VI group compound, a IV group element, a IV group compound, and/or one or more combinations thereof.

The II-VI group compound may be selected from the group including (e.g., consisting of): a binary compound selected from the group including (e.g., consisting of) CdSe, CdTe, CdS, ZnS, ZnSe, ZnTe, ZnO, HgS, HgSe, HgTe, MgSe, MgS, and/or one or more mixtures thereof; a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or one or more mixtures thereof; and a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and/or one or more mixtures thereof.

The III-V group compound may include a binary compound such as In₂S₃, and In₂Se₃, a ternary compound such as InGaS₃, and InGaSe₃, or one or more combinations thereof.

The I-III-VI group compound may be selected from a ternary compound selected from the group including (e.g., consisting of) AgInS, AgInS₂, CuInS, CuInS₂, AgGaS₂, CuGaS₂, CuGaO₂, AgGaO₂, AgAlO₂ and/or one or more mixtures thereof, or a quaternary compound such as AgInGaS₂, and/or CuInGaS₂.

The III-V group compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and/or one or more mixtures thereof, and a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In some embodiments, the III-V group compound may further include a II group metal. For example, InZnP, etc. may be selected as a III-II-V group compound.

The IV-VI group compound may be selected from the group including (e.g., consisting of) a binary compound selected from the group including (e.g., consisting of) SnS, SnSe, SnTe, PbS, PbSe, PbTe, and/or one or more mixtures thereof, a ternary compound selected from the group including (e.g., consisting of) SnSeS, SnSeTe, SnSTe, PbSeS, PbSeTe, PbSTe, SnPbS, SnPbSe, SnPbTe, and/or one or more mixtures thereof, and a quaternary compound selected from the group including (e.g., consisting of) SnPbSSe, SnPbSeTe, SnPbSTe, and/or one or more mixtures thereof. The IV group element may be selected from the group including (e.g., consisting of) Si, Ge, and/or one or more mixtures thereof. The IV group compound may be a binary compound selected from the group including (e.g., consisting of) SiC, SiGe, and/or one or more mixtures thereof.

In an embodiment, the binary compound, the ternary compound or the quaternary compound may be present at substantially uniform concentration in a particle or may be present at a partially different concentration distribution state in substantially the same particle. In some embodiments, a core/shell structure in which one quantum dot wraps another quantum dot may be possible. The interface of the core and the shell may have a concentration gradient in which the concentration of an element present in the shell is decreased toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or one or more combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, or a ternary compound such as MgAl₂O₄, CoFe₂O₄, NiFe₂O₄ and CoMn₂O₄, but an embodiment of the present disclosure is not limited thereto.

In some embodiments, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but an embodiment of the present disclosure is not limited thereto.

The quantum dot may have a full width of half maximum (FWHM) of emission wavelength spectrum of about 45 nm or less, about 40 nm or less, or, about 30 nm or less. Within this range, color purity or color reproducibility may be improved. In some embodiments, light emitted via such a quantum dot is emitted in all directions, and light viewing angle properties may be improved.

In some embodiments, the shape of the quantum dot may be generally utilized shapes in the art, without specific limitation. For example, the shape of a substantially spherical, pyramidal, multi-arm, or cubic nanoparticle, nanotube, nanowire, nanofiber, nanoplate particle, etc. may be utilized.

The quantum dot may control the color of light emitted according to the particle size, and accordingly, the quantum dot may have one or more suitable emission colors such as blue, red and/or green.

In the light emitting devices ED of embodiments, as shown in FIG. 3 to FIG. 6, the electron transport region ETR is provided on the emission layer EML. The electron transport region ETR may include at least one of an electron blocking layer HBL, an electron transport layer ETL or an electron injection layer EIL. However, an embodiment of the present disclosure is not limited thereto.

The electron transport region ETR may have a single layer formed utilizing a single material, a single layer formed utilizing multiple different materials, or a multilayer structure having multiple layers formed utilizing multiple different materials.

For example, the electron transport region ETR may have a single layer structure of an electron injection layer EIL or an electron transport layer ETL, or a single layer structure formed utilizing an electron injection material and an electron transport material. Further, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-1.

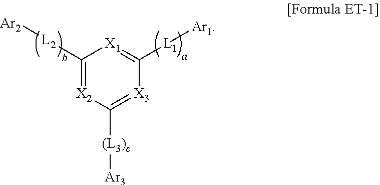

In Formula ET-1, at least one of X₁ to X₃ is N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, “a” to “c” may each independently be an integer of 0 to 10. In Formula ET-1, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” to “c” are integers of 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, an embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and/or one or more mixtures thereof, without limitation.

The electron transport region ETR may include at least one of Compounds ET1 to ET36.

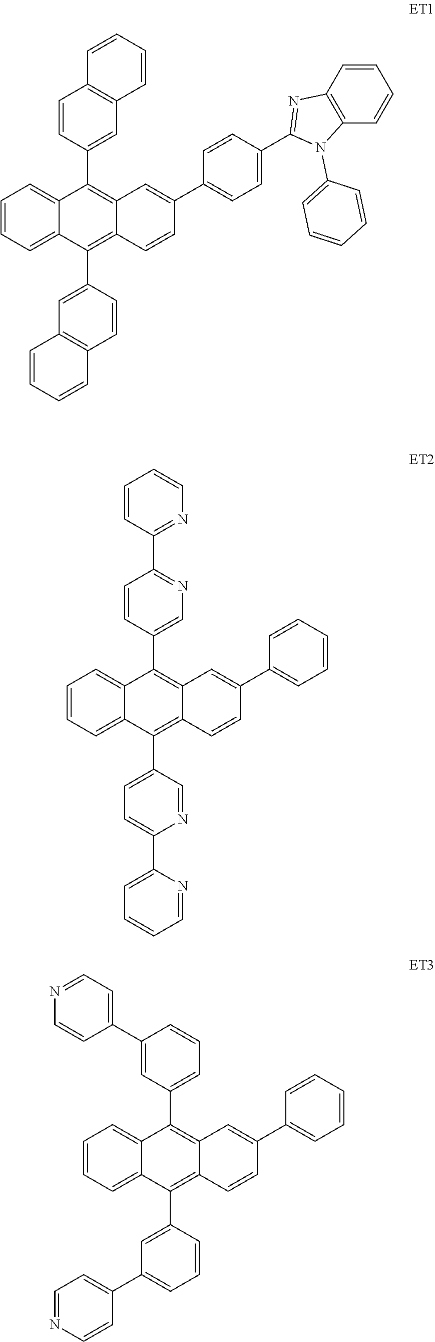 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

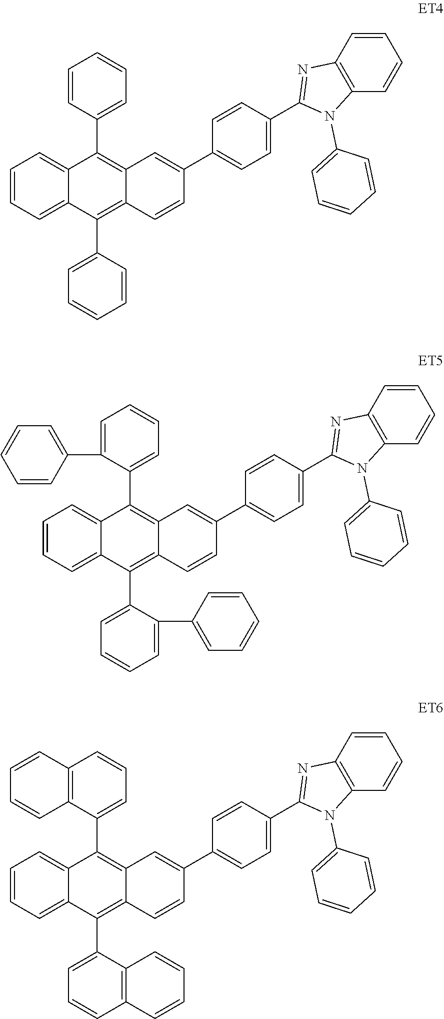 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

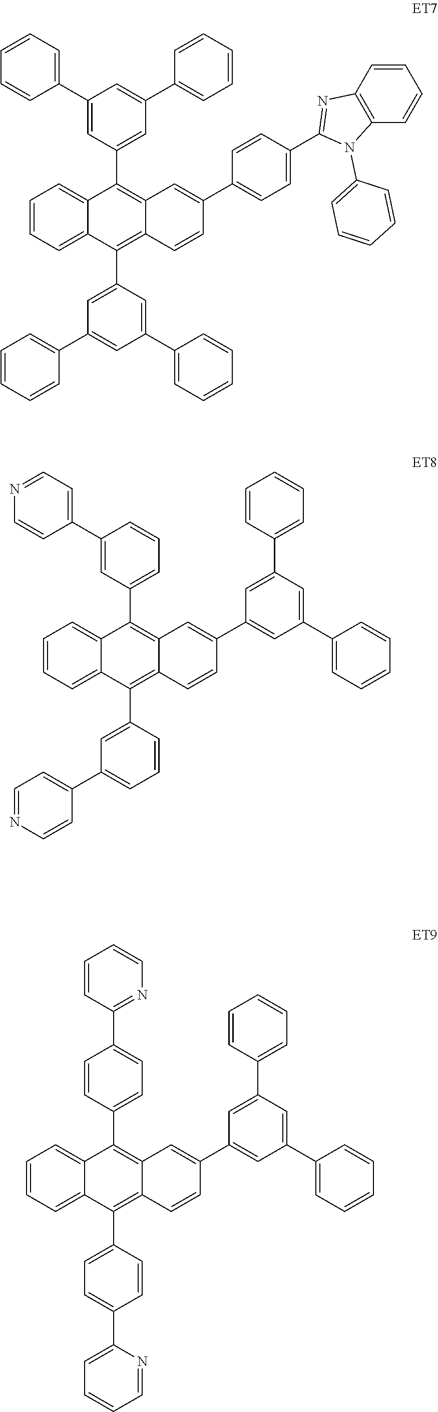 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccncc6)c5)c5ccccc5c(-c5cccc(-c6ccncc6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

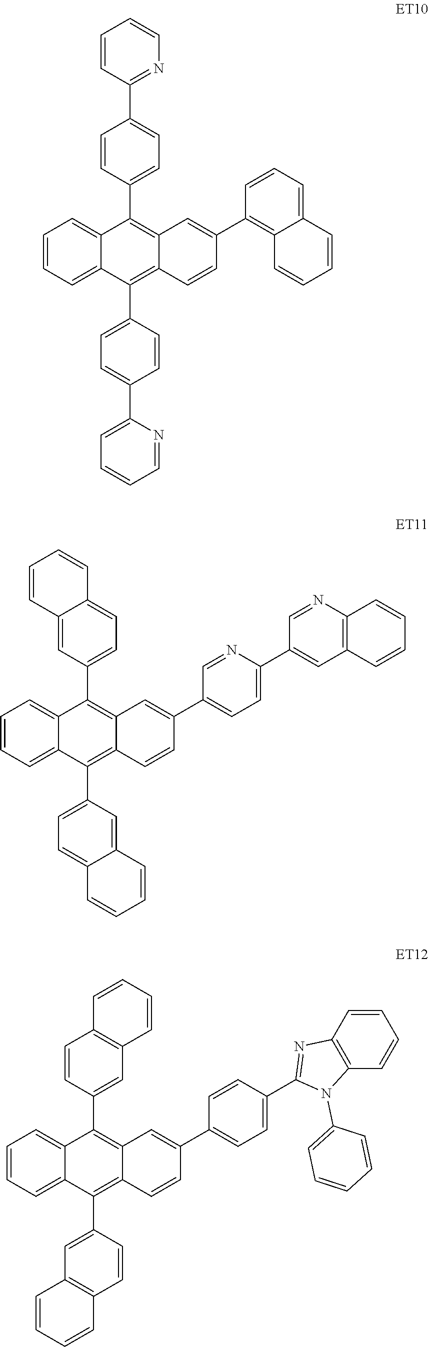 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

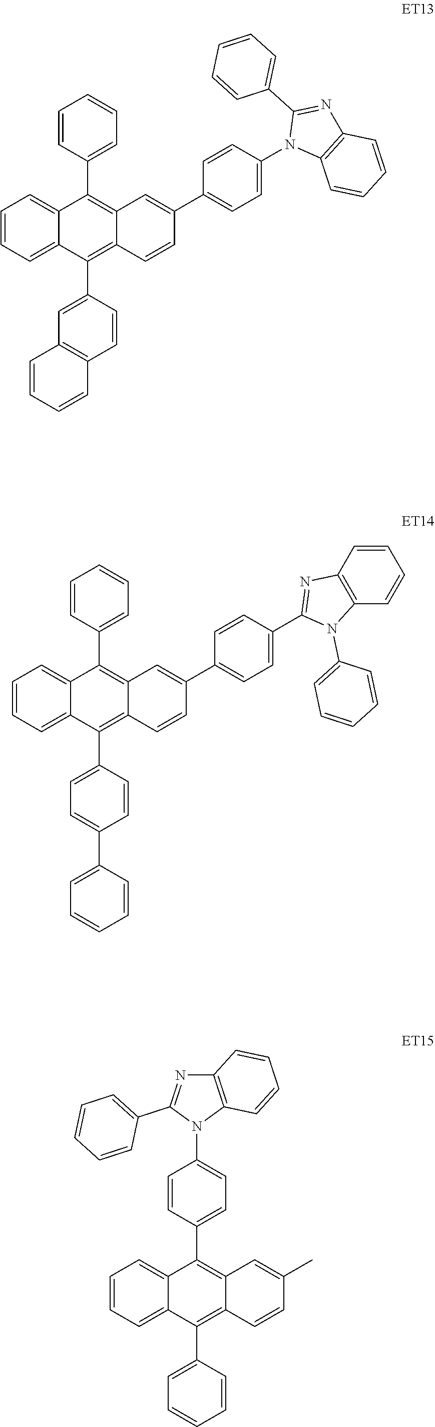 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(-n4c(-c5ccccc5)nc5ccccc54)cc3)c2c1]

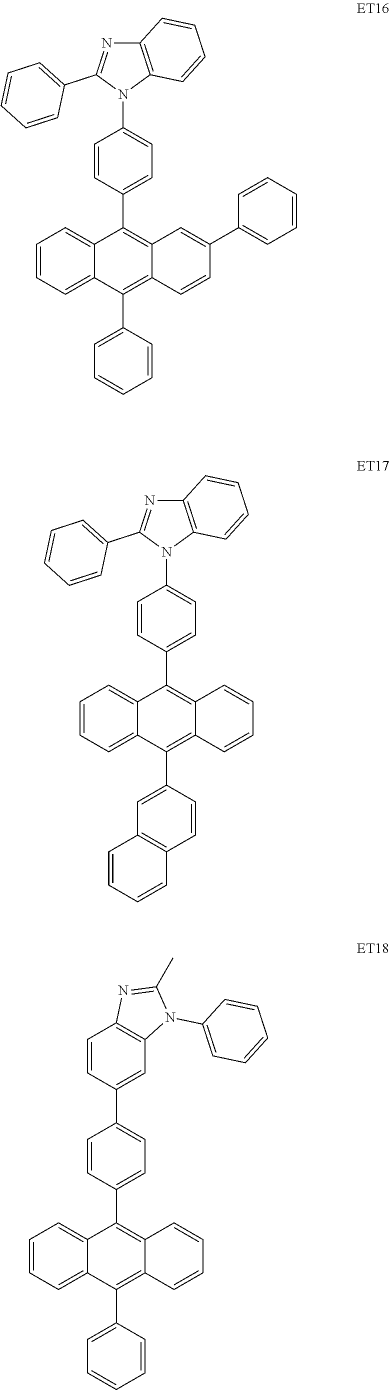 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

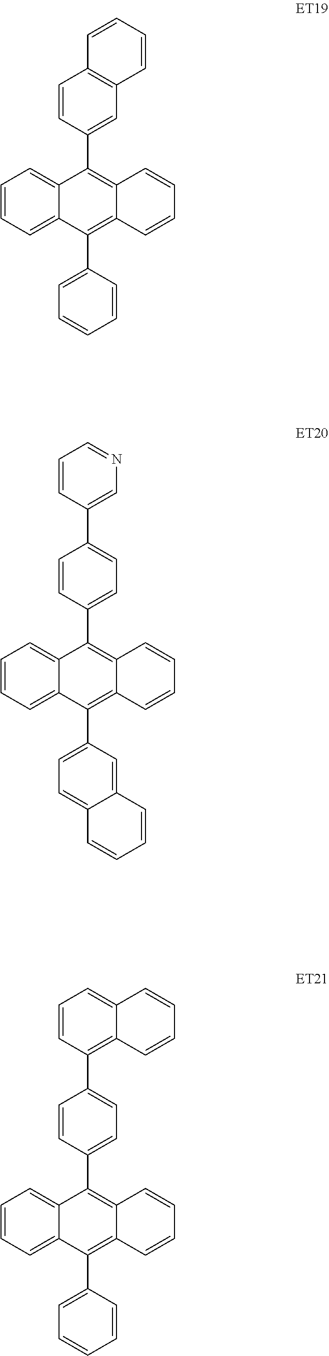

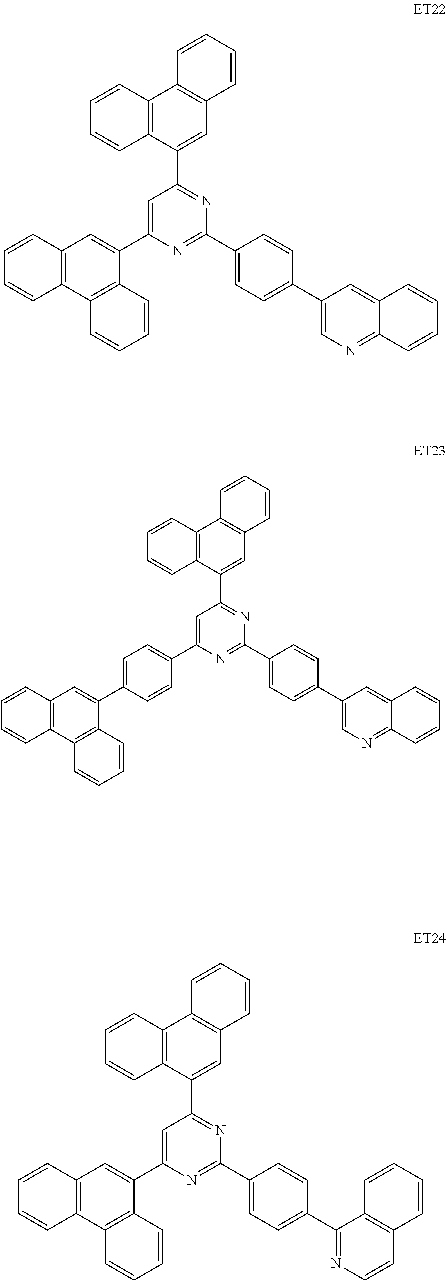 [SMILES: c1ccc2ncc(-c3ccc(-c4nc(-c5cc6ccccc6c6ccccc56)cc(-c5cc6ccccc6c6ccccc56)n4)cc3)cc2c1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

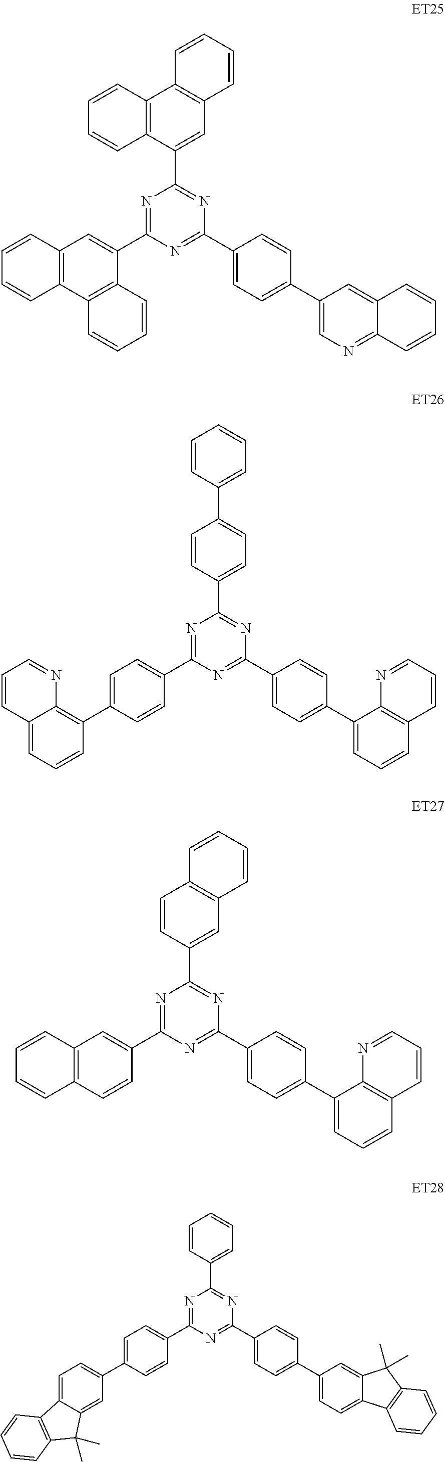 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

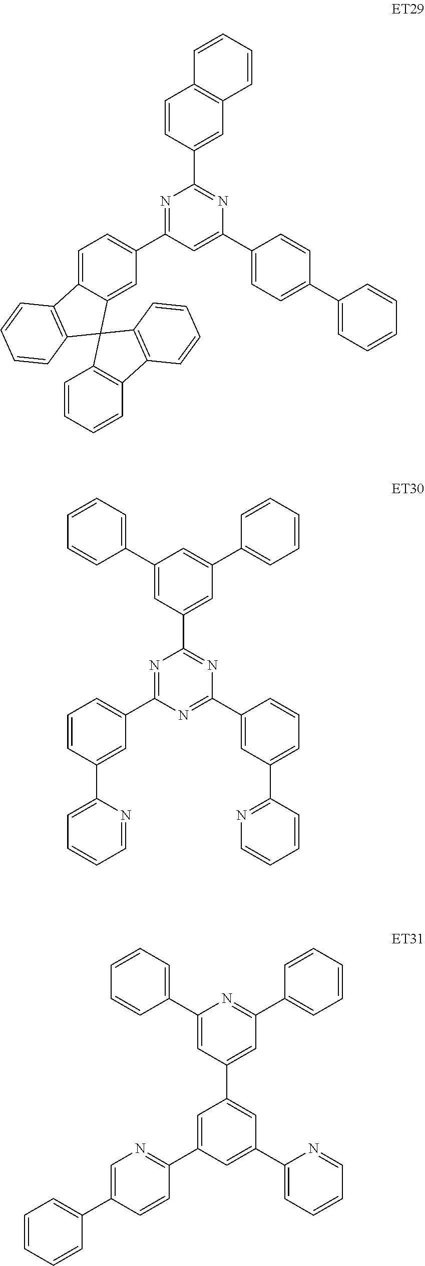 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

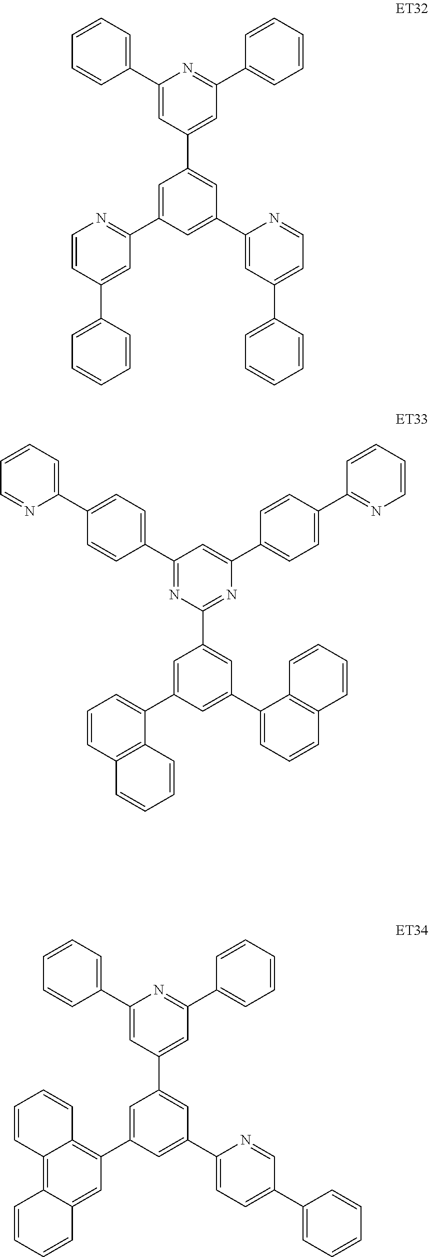 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

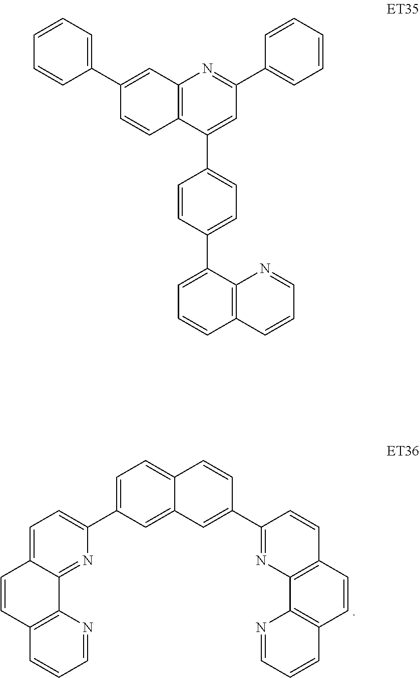 [SMILES: c1ccc(-c2ccc3c(-c4ccc(-c5cccc6cccnc56)cc4)cc(-c4ccccc4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI and/or KI, a lanthanide metal such as Yb, or a co-depositing material of the metal halide and the lanthanide metal. For example, the electron transport region ETR may include KI:Yb, RbI:Yb, etc., as the co-depositing material. In some embodiments, the electron transport region ETR may utilize a metal oxide such as Li₂O and BaO, or 8-hydroxy-lithium quinolate (Liq). However, an embodiment of the present disclosure is not limited thereto. The electron transport region ETR also may be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, an embodiment of the present disclosure is not limited thereto.

The electron transport region ETR may include the compounds of the electron transport region in at least one of an electron injection layer EIL, an electron transport layer ETL, and/or a hole blocking layer HBL.

When the electron transport region ETR includes the electron transport layer ETL, the thickness of the electron transport layer ETL may be from about 100 Å to about 1,000 Å, for example, from about 150 Å to about 500 Å. When the thickness of the electron transport layer ETL satisfies the above-described range, satisfactory (suitable) electron transport properties may be obtained without substantial increase of a driving voltage. When the electron transport region ETR includes the electron injection layer EIL, the thickness of the electron injection layer EIL may be from about 1 Å to about 100 Å, or from about 3 Å to about 90 Å. When the thickness of the electron injection layer EIL satisfies the above described range, satisfactory (suitable) electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but an embodiment of the present disclosure is not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, one or more compounds including thereof, or one or more mixtures thereof (for example, AgMg, AgYb, or MgAg). In some embodiments, the second electrode EL2 may have a multilayered structure including a reflective layer or a transflective layer formed utilizing the above-described materials and a transparent conductive layer formed utilizing ITO, IZO, ZnO, ITZO, etc. For example, the second electrode EL2 may include the aforementioned metal materials, combinations of two or more metal materials selected from the aforementioned metal materials, or oxides of the aforementioned metal materials.

The second electrode EL2 may be connected with an auxiliary electrode. When the second electrode EL2 is connected with the auxiliary electrode, the resistance of the second electrode EL2 may decrease.

In some embodiments, on the second electrode EL2 in the light emitting device ED of an embodiment, a capping layer CPL may be further disposed. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNx, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or includes an epoxy resin, or acrylate such as methacrylate. In some embodiments, a capping layer CPL may include at least one of Compounds P1 to P5, but an embodiment of the present disclosure is not limited thereto.

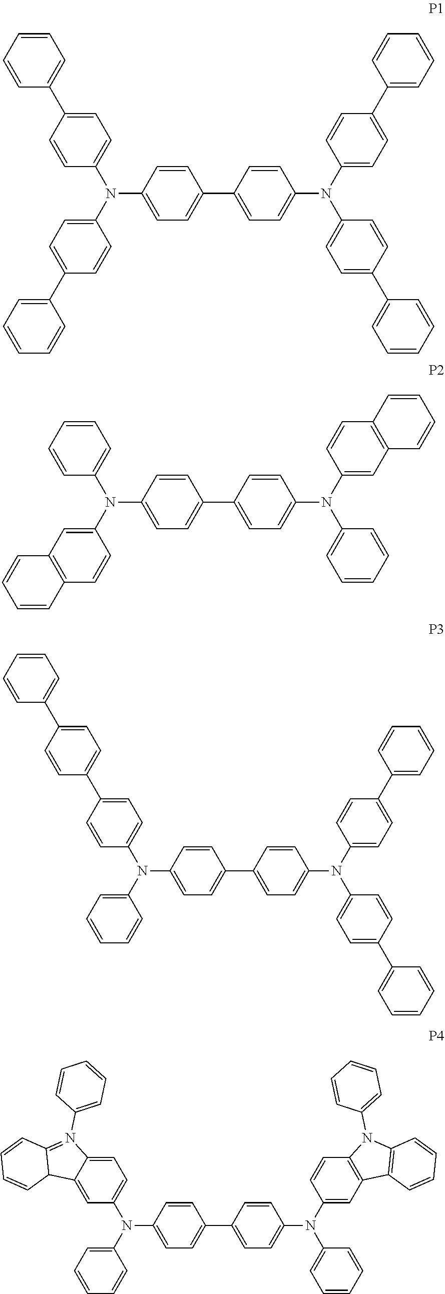

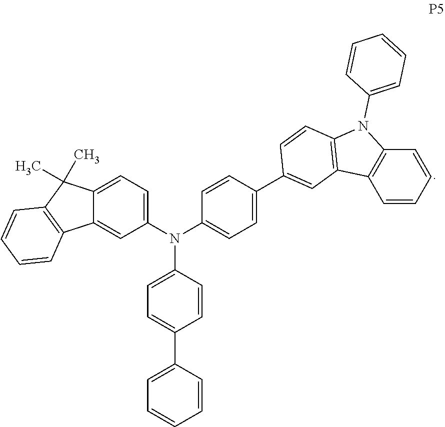 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL with respect to light in a wavelength range of about 550 nm to about 660 nm may be about 1.6 or more.

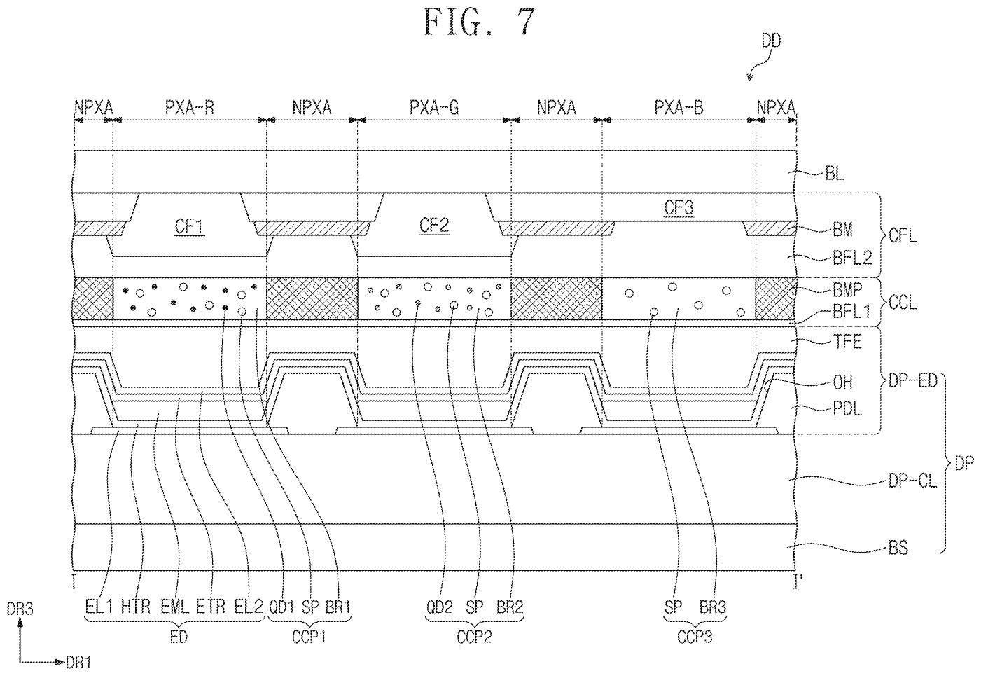

FIG. 7 to FIG. 10 are cross-sectional views on display apparatuses according to embodiments. In the explanation on the display apparatuses of embodiments, referring to FIG. 7 to FIG. 10, the overlapping parts with the explanation on FIG. 1 to FIG. 6 are as previously described, and the different features will be primarily described.

Referring to FIG. 7, the display apparatus DD according to an embodiment may include a display panel DP including a display device layer DP-ED, a light controlling layer CCL disposed on the display panel DP and a color filter layer CFL.

In an embodiment shown in FIG. 7, the display panel DP includes a base layer BS, a circuit layer DP-CL provided on the base layer BS and a display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the same structures of the light emitting devices of FIG. 3 to FIG. 6 may be applied to the structure of the light emitting device ED shown in FIG. 7.

Referring to FIG. 7, the emission layer EML may be disposed in an opening part OH defined in a pixel definition layer PDL. For example, the emission layer EML divided by the pixel definition layer PDL and correspondingly provided to each of luminous areas PXA-R, PXA-G and PXA-B may emit light in substantially the same wavelength region. In the display apparatus DD of an embodiment, the emission layer EML may emit blue light. In some embodiments, the emission layer EML may be provided as a common layer for all luminous areas PXA-R, PXA-G and PXA-B.

The light controlling layer CCL may be disposed on the display panel DP. The light controlling layer CCL may include a light converter. The light converter may be a quantum dot or a phosphor. The light converter may transform the wavelength of light provided and then emit light. For example, the light controlling layer CCL may be a layer including a quantum dot or a layer including a phosphor.

The light controlling layer CCL may include multiple light controlling parts CCP1, CCP2 and CCP3. The light controlling parts CCP1, CCP2 and CCP3 may be separated from one another.

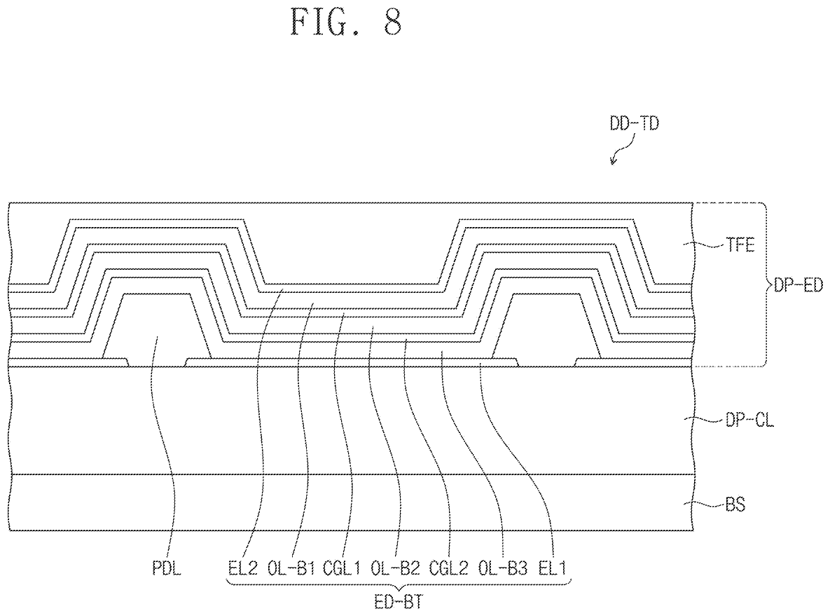

Referring to FIG. 7, a partition pattern BMP may be disposed between the separated light controlling parts CCP1, CCP2 and CCP3, but an embodiment of the present disclosure is not limited thereto. In FIG. 8, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 converting first color light provided from the light emitting device ED into second color light, a second light controlling part CCP2 including a second quantum dot QD2 converting first color light into third color light, and a third light controlling part CCP3 transmitting first color light.

In an embodiment, the first light controlling part CCP1 may provide red light which is the second color light, and the second light controlling part CCP2 may provide green light which is the third color light. The third color controlling part CCP3 may transmit and provide blue light which is the first color light provided from the light emitting device ED. For example, the first quantum dot QD1 may be a red quantum dot, and the second quantum dot QD2 may be a green quantum dot. On the quantum dots QD1 and QD2, the same contents as those described above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a quantum dot but include the scatterer SP.

The scatterer SP may be an inorganic particle. For example, the scatterer SP may include at least one of TiO₂, ZnO, Al₂O₃, SiO₂, and/or hollow silica. The scatterer SP may include at least one of TiO₂, ZnO, Al₂O₃, SiO₂, and/or hollow silica, or may be one or more mixtures of two or more materials selected from TiO₂, ZnO, Al₂O₃, SiO₂, and/or hollow silica.

Each of the first light controlling part CCP1, the second light controlling part CCP2, and the third light controlling part CCP3 may include a corresponding one of base resins BR1, BR2 and/or BR3 dispersing the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3. The base resins BR1, BR2 and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may be acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may be disposed on the light controlling parts CCP1, CCP2 and CCP3 to block or reduce the exposure of the light controlling parts CCP1, CCP2 and CCP3 to humidity/oxygen. In some embodiments, the barrier layer BFL1 may cover the light controlling parts CCP1, CCP2 and CCP3. In some embodiments, the barrier layer BFL2 may be provided between the light controlling parts CCP1, CCP2 and CCP3 and a color filter layer CFL.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride or a metal thin film securing light transmittance. In some embodiments, the barrier layers BFL1 and BFL2 may further include an organic layer. The barrier layers BFL1 and BFL2 may be composed of a single layer of multiple layers.

In the display apparatus DD of an embodiment, the color filter layer CFL may be disposed on the light controlling layer CCL. For example, the color filter layer CFL may be disposed directly on the light controlling layer CCL. In this case, the barrier layer BFL2 may not be provided.

The color filter layer CFL may include a light blocking part BM and filters CF1, CF2 and CF3. The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye. However, an embodiment of the present disclosure is not limited thereto, and the third filter CF3 may not include (e.g., may exclude) the pigment or dye. The third filter CF3 may include a polymer photosensitive resin and not include (e.g., may exclude) a pigment or dye. The third filter CF3 may be transparent. The third filter CF3 may be formed utilizing a transparent photosensitive resin.

In some embodiments, the first filter CF1 and the second filter CF2 may be yellow filters. The first filter CF1 and the second filter CF2 may be provided in one body without distinction.

The light blocking part BM may be a black matrix. The light blocking part BM may be formed by including an organic light blocking material or an inorganic light blocking material including a black pigment or black dye. The light blocking part BM may prevent or reduce light leakage phenomenon and divide the boundaries among adjacent filters CF1, CF2 and CF3. In some embodiments, in an embodiment, the light blocking part BM may be formed as a blue filter.

Each of the first to third filters CF1, CF2 and CF3 may be disposed corresponding to each of a red luminous area PXA-R, green luminous area PXA-G, and blue luminous area PXA-B.

On the color filter layer CFL, a base substrate BL may be disposed. The base substrate BL may be a member providing a base surface on which the color filter layer CFL, the light controlling layer CCL, etc. are disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, the base substrate BL may not be provided.

FIG. 8 is a cross-sectional view showing a portion of the display apparatus according to an embodiment. In a display apparatus DD-TD of an embodiment, the light emitting device ED-BT may include multiple light emitting structures OL-B1, OL-B2 and OL-B3. The light emitting device ED-BT may include oppositely disposed first electrode EL1 and second electrode EL2, and the multiple light emitting structures OL-B1, OL-B2 and OL-B3 stacked in order in a thickness direction and provided between the first electrode EU and the second electrode EL2. Each of the light emitting structures OL-B1, OL-B2 and OL-B3 may include an emission layer EML (FIG. 7), and a hole transport region HTR and an electron transport region ETR disposed with the emission layer EML (FIG. 7) therebetween.

For example, the light emitting device ED-BT included in the display apparatus DD-TD of an embodiment may be a light emitting device of a tandem structure including multiple emission layers.

In an embodiment shown in FIG. 8, light emitted from the light emitting structures OL-B1, OL-B2 and OL-B3 may be all blue light. However, an embodiment of the present disclosure is not limited thereto, and the wavelength regions of light emitted from the light emitting structures OL-B1, OL-B2 and OL-B3 may be different from each other. For example, the light emitting device ED-BT including the multiple light emitting structures OL-B1, OL-B2 and OL-B3 emitting light in different wavelength regions may emit white light.

Between neighboring light emitting structures OL-B1, OL-B2 and OL-B3, charge generating layers CGL1 and CGL2 may be disposed. The charge generating layers CGL1 and CGL2 may include a p-type or kind charge generating layer and/or an n-type or kind charge generating layer.

In at least one of the light emitting structures OL-B1, OL-B2 and/or OL-B3, included in the display apparatus DD-TD of an embodiment, at least one of the first compound, the second compound, the third compound and/or the fourth compound may be included.

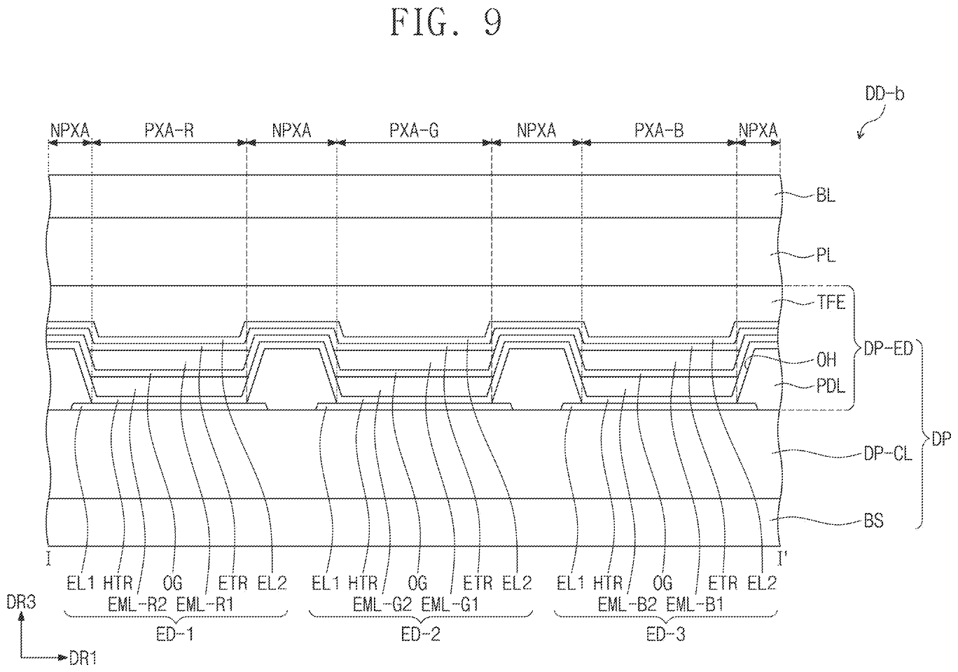

Referring to FIG. 9, a display apparatus DD-b according to an embodiment may include light emitting elements ED-1, ED-2 and/or ED-3, formed by stacking two emission layers. Compared to the display apparatus DD of an embodiment, shown in FIG. 2, an embodiment shown in FIG. 9 is different in that first to third light emitting elements ED-1, ED-2 and ED-3 include two emission layers stacked in a thickness direction, each. In the first to third light emitting elements ED-1, ED-2 and ED-3, two emission layers may emit light in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. For example, the emission auxiliary part OG may include an electron transport region, a charge generating layer, and a hole transport region stacked in order. The emission auxiliary part OG may be provided as a common layer in all of the first to third light emitting elements ED-1, ED-2 and ED-3. However, an embodiment of the present disclosure is not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be disposed between the hole transport region HTR and the emission auxiliary part OG. The second red emission layer EML-R2, the second green emission layer EML-G2 and the second blue emission layer EML-B2 may be disposed between the emission auxiliary part OG and the electron transport region ETR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, stacked in order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, stacked in order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order.

In some embodiments, an optical auxiliary layer PL may be disposed on a display device layer DP-ED. The optical auxiliary layer PL may include a polarization layer. The optical auxiliary layer PL may be disposed on a display panel DP and may control reflected light at the display panel DP by external light. In an embodiment, the optical auxiliary layer PL may not be provided from the display apparatus.

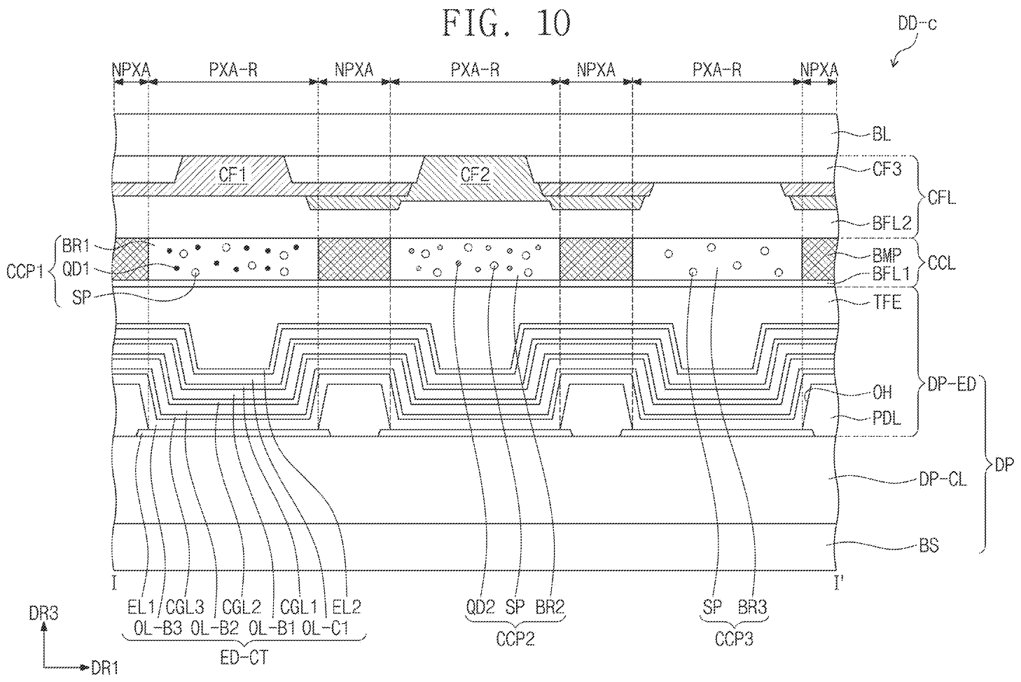

Different from FIG. 8 and FIG. 9, a display apparatus DD-c in FIG. 10 is shown to include four light emitting structures OL-B1, OL-B2, OL-B3 and OL-C1. A light emitting element ED-CT may include oppositely disposed first electrode EL1 and second electrode EL2, and first to fourth light emitting structures OL-B1, OL-B2, OL-B3 and OL-C1 stacked in order in a thickness direction between the first electrode EL1 and the second electrode EL2. Between the first to fourth light emitting structures OL-B1, OL-B2, OL-B3 and OL-C1, charge generating layers CGL1, CGL2 and CGL3 may be disposed. Among the four light emitting structures, the first to third light emitting structures OL-B1, OL-B2 and OL-B3 emit blue light, and the fourth light emitting structure OL-C1 may emit green light. However, an embodiment of the present disclosure is not limited thereto, and the first to fourth light emitting structures OL-B1, OL-B2, OL-B3 and OL-C1 may emit different wavelengths of light.

Charge generating layers CGL1, CGL2 and CGL3 disposed among neighboring light emitting structures OL-B1, OL-B2, OL-B3 and OL-C1 may include a p-type or kind charge generating layer and/or an n-type or kind charge generating layer.

In at least one of the light emitting structures OL-B1, OL-B2, OL-B3 and OL-C1, included in the display apparatus DD-c of an embodiment, at least one of the first compound, the second compound, the third compound and the fourth compound may be included.

Hereinafter, the fused polycyclic compound utilized as a first compound and the light emitting device according to an embodiment of the present disclosure will be further described by referring to embodiments and comparative embodiments. Some embodiments are merely examples to assist the understanding of the present disclosure, and the scope of the present disclosure is not limited thereto.

### EXAMPLES

### 1. Synthesis of Fused Polycyclic Compound

First, the synthetic method of the fused polycyclic compound according to an embodiment will be described, for example, by illustrating the synthetic methods of Compounds 31, 42, 54, 133, 145 and 152 The synthetic methods of the fused polycyclic compounds described hereinafter are merely embodiments/examples, and the scope of the present disclosure is not limited thereto.

### (1) Synthesis of Compound 31

Compound 31 according to an embodiment may be synthesized, for example, by the following reaction.

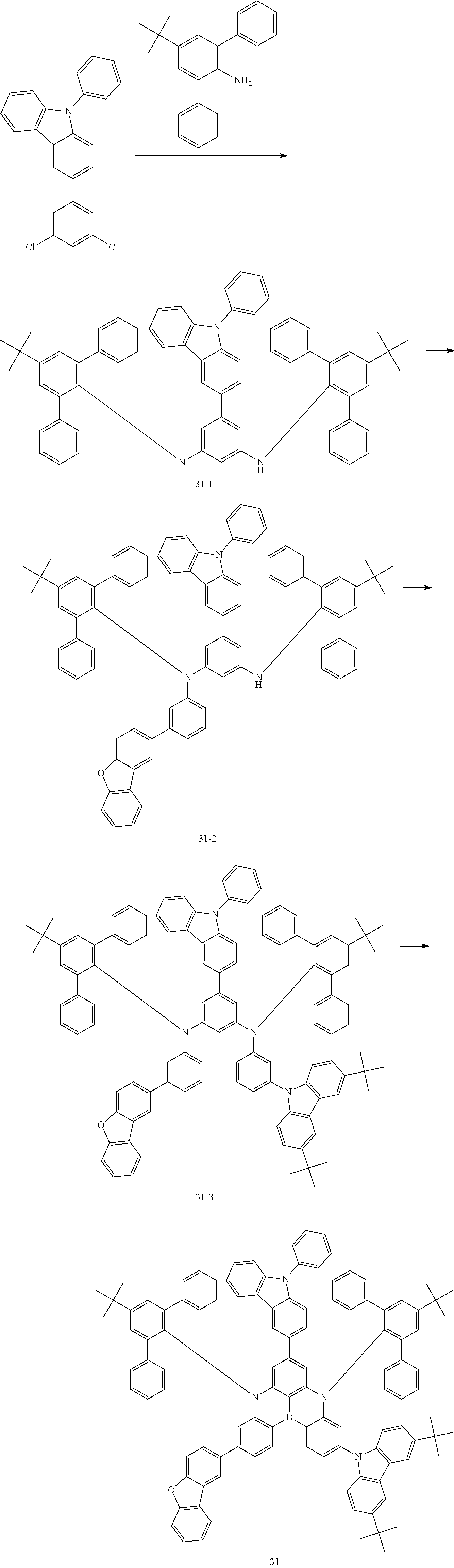

### Synthesis of Intermediate 31-1

3-(3,5-dichlorophenyl)-9-phenyl-9H-carbazole (1 eq), 5′-(tert-butyl)-[1,1′:3′,1″-terphenyl]-2′-amine (2 eq), tris(dibenzylideneacetone)dipalladium(0) (0.1 eq), tri-tert-butylphosphine (0.2 eq), and sodium tert-butoxide (3 eq) were dissolved in toluene, and stirred at about 110 degrees centigrade for about 12 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing methylene chloride (MC) and n-hexane to obtain Intermediate 31-1 (yield: 68%).

### Synthesis of Intermediate 31-2

Intermediate 31-1 (1 eq), 2-(3-bromophenyl)dibenzo[b,d]furan (1 eq), tris(dibenzylideneacetone)dipalladium(0) (0.05 eq), tri-tert-butylphosphine (0.1 eq), and sodium tert-butoxide (3 eq) were dissolved in toluene and stirred at about 90 degrees centigrade for about 12 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 31-2 (yield: 38%).

### Synthesis of Intermediate 31-3

Intermediate 31-2 (1 eq), 9-(3-bromophenyl)-3,6-di-tert-butyl-9H-carbazole (1.5 eq), tris(dibenzylideneacetone)dipalladium(0) (0.05 eq), tri-tert-butylphosphine (0.1 eq), and sodium tert-butoxide (3 eq) were dissolved in o-xylene and stirred at about 150 degrees centigrade for about 24 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 31-3 (yield: 44%).

### Synthesis of Compound 31

Intermediate 31-3 (1 eq) was dissolved in ortho dichlorobenzene and cooled to about 0 degrees centigrade. Under a nitrogen atmosphere, BBr₃ (2 eq) was slowly added thereto dropwise, and the temperature was raised to about 150 degrees centigrade, followed by stirring for about 24 hours. After cooling, to a flask containing the reaction mixture, triethylamine was slowly added dropwisely to terminate the reaction, and ethyl alcohol was added to the reaction product to precipitate. The precipitate was filtered to obtain a reaction product. The solid content (e.g., amount) thus obtained was separated by column chromatography utilizing MC and n-hexane, and then, recrystallized utilizing toluene and acetone to obtain Compound 31 (yield: 18%).

### (2) Synthesis of Compound 42

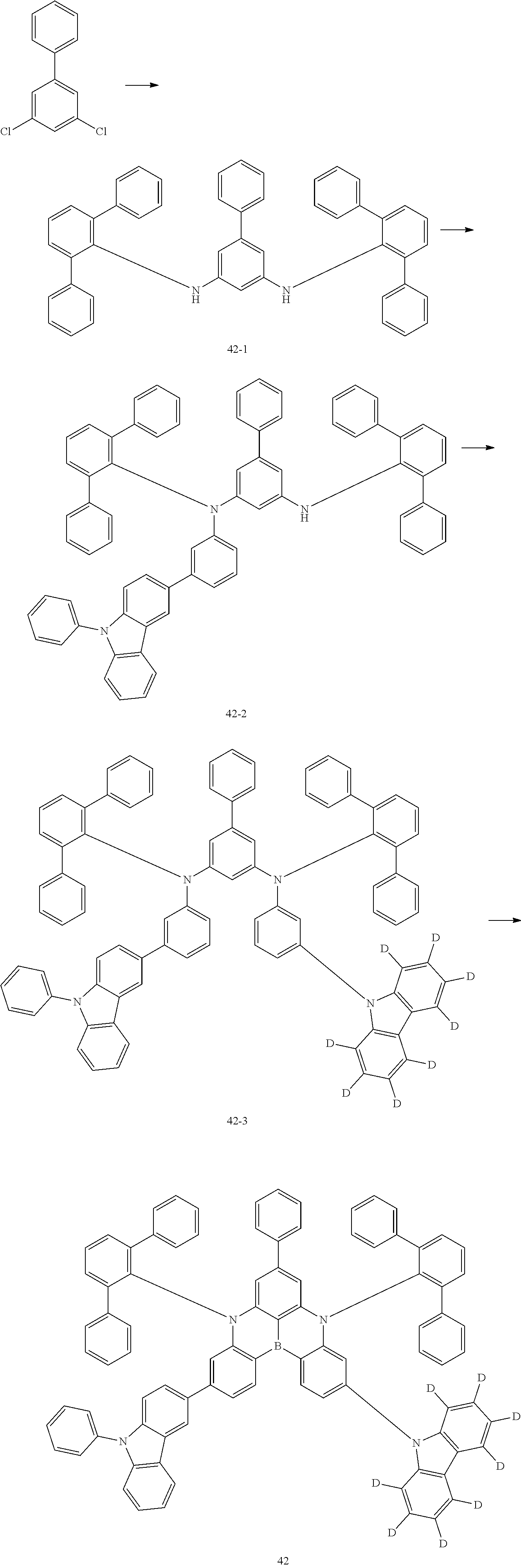

### Synthesis of Intermediate 42-1

3,5-dichloro-1,1′-biphenyl (1 eq), [1,1′:3′,1″-terphenyl]-2′-amine (2 eq), tris(dibenzylideneacetone)dipalladium(0) (0.1 eq), tri-tert-butylphosphine (0.2 eq), and sodium tert-butoxide (3 eq) were dissolved in toluene, and stirred at about 110 degrees centigrade for about 12 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 42-1 (yield: 75%).

### Synthesis of Intermediate 42-2

Intermediate 42-1 (1 eq), 3-(3-bromophenyl)-9-phenyl-9H-carbazole (1 eq), tris(dibenzylideneacetone)dipalladium(0) (0.05 eq), tri-tert-butylphosphine (0.1 eq), and sodium tert-butoxide (3 eq) were dissolved in toluene and stirred at about 90 degrees centigrade for about 12 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 42-2 (yield: 40%).

### Synthesis of Intermediate 42-3

Intermediate 42-2 (1 eq), 9-(3-bromophenyl)-9H-carbazole-D8 (1.5 eq), tris(dibenzylideneacetone)dipalladium(0) (0.05 eq), tri-tert-butylphosphine (0.1 eq), and sodium tert-butoxide (3 eq) were dissolved in o-xylene and stirred at about 150 degrees centigrade for about 24 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 42-3 (yield: 36%).

### Synthesis of Compound 42

Intermediate 42-3 (1 eq) was dissolved in ortho dichlorobenzene and cooled to about 0 degrees centigrade. Under a nitrogen atmosphere, BBr₃ (2 eq) was slowly added thereto dropwise, and after finishing the dropwise addition, the temperature was raised to about 150 degrees, followed by stirring for about 24 hours. After cooling, to a flask containing the reaction mixture, triethylamine was slowly added dropwise to terminate the reaction, and ethyl alcohol was added to the reaction product to precipitate. The precipitate was filtered to obtain a reaction product. The solid content (e.g., amount) thus obtained was separated by column chromatography utilizing MC and n-hexane, and then, recrystallized utilizing toluene and acetone to obtain Compound 42 (yield: 14%).

### (3) Synthesis of Compound 54

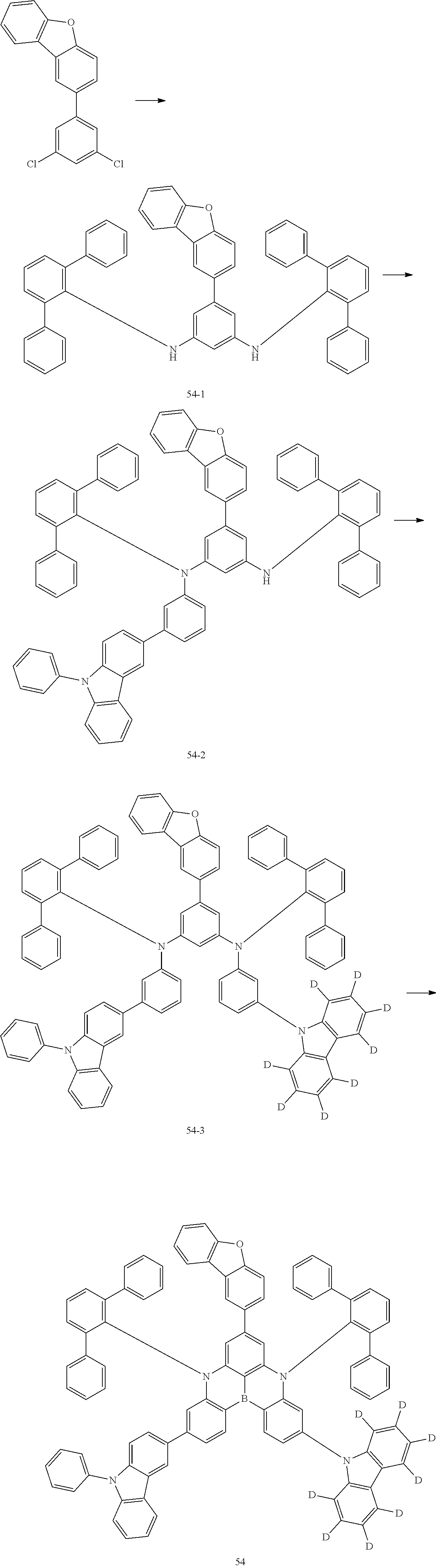

### Synthesis of Intermediate 54-1

2-(3,5-dichlorophenyl)dibenzo[b,d]furan (1 eq), [1,1′:3′,1″-terphenyl]-2′-amine (2 eq), tris(dibenzylideneacetone)dipalladium(0) (0.1 eq), tri-tert-butylphosphine (0.2 eq), and sodium tert-butoxide (3 eq) were dissolved in toluene, and stirred at about 110 degrees centigrade for about 12 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 54-1 (yield: 66%).

### Synthesis of Intermediate 54-2

Intermediate 54-1 (1 eq), 3-(3-bromophenyl)-9-phenyl-9H-carbazole (1 eq), tris(dibenzylideneacetone)dipalladium(0) (0.05 eq), tri-tert-butylphosphine (0.1 eq), and sodium tert-butoxide (3 eq) were dissolved in toluene and stirred at about 90 degrees centigrade for about 12 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 54-2 (yield: 33%).

### Synthesis of Intermediate 54-3

Intermediate 54-2 (1 eq), 9-(3-bromophenyl)-9H-carbazole-D8 (1.5 eq), tris(dibenzylideneacetone)dipalladium(0) (0.05 eq), tri-tert-butylphosphine (0.1 eq), and sodium tert-butoxide (3 eq) were dissolved in o-xylene and stirred at about 150 degrees centigrade for about 24 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 54-3 (yield: 45%).

### Synthesis of Compound 54

Intermediate 54-3 (1 eq) was dissolved in ortho dichlorobenzene and cooled to about 0 degrees centigrade. Under a nitrogen atmosphere, BBr₃ (2 eq) was slowly added thereto dropwisely, and after finishing the dropwise addition, the temperature was raised to about 150 degrees centigrade, followed by stirring for about 24 hours. After cooling, to a flask containing the reaction mixture, triethylamine was slowly added dropwisely to terminate the reaction, and ethyl alcohol was added to the reaction product to precipitate. The precipitate was filtered to obtain a reaction product. The solid content (e.g., amount) thus obtained was separated by column chromatography utilizing MC and n-hexane, and then, recrystallized utilizing toluene and acetone to obtain Compound 54 (yield: 20%).

### (4) Synthesis of Compound 133

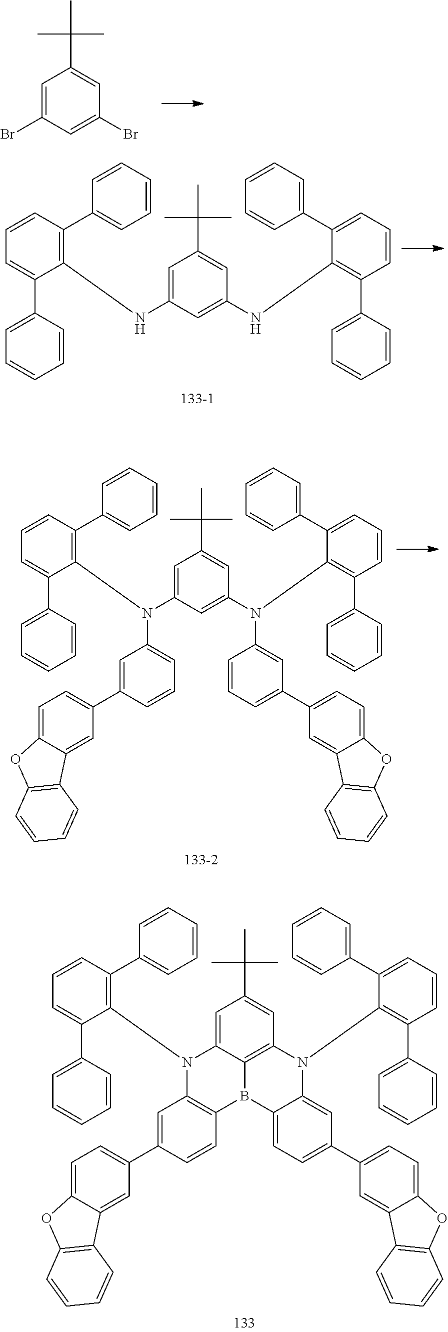

### Synthesis of Intermediate 133-1

1,3-dibromo-5-(tert-butyl)benzene (1 eq), [1,1′:3′,1″-terphenyl]-2′-amine (2 eq), tris(dibenzylideneacetone)dipalladium(0) (0.1 eq), tri-tert-butylphosphine (0.2 eq), and sodium tert-butoxide (3 eq) were dissolved in toluene, and stirred at about 110 degrees centigrade for about 12 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 133-1 (yield: 53%).

### Synthesis of Intermediate 133-2

Intermediate 133-1 (1 eq), 2-(3-bromophenyl)dibenzo[b,d]furan (3 eq), tris(dibenzylideneacetone)dipalladium(0) (0.05 eq), tri-tert-butylphosphine (0.1 eq), and sodium tert-butoxide (3 eq) were dissolved in o-xylene and stirred at about 150 degrees centigrade for about 36 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 133-2 (yield: 47%).

### Synthesis of Compound 133

Intermediate 133-2 (1 eq) was dissolved in ortho dichlorobenzene and cooled to about 0 degrees centigrade. Under a nitrogen atmosphere, BBr₃ (2 eq) was slowly added thereto dropwisely, and after finishing the dropwise addition, the temperature was raised to about 150 degrees centigrade, followed by stirring for about 24 hours. After cooling, to a flask containing the reaction mixture, triethylamine was slowly added dropwisely to terminate the reaction, and ethyl alcohol was added to the reaction product to precipitate. The precipitate was filtered to obtain a reaction product. The solid content (e.g., amount) thus obtained was separated by column chromatography utilizing MC and n-hexane, and then, recrystallized utilizing toluene and acetone to obtain Compound 133 (yield: 22%).

### (5) Synthesis of Compound 145

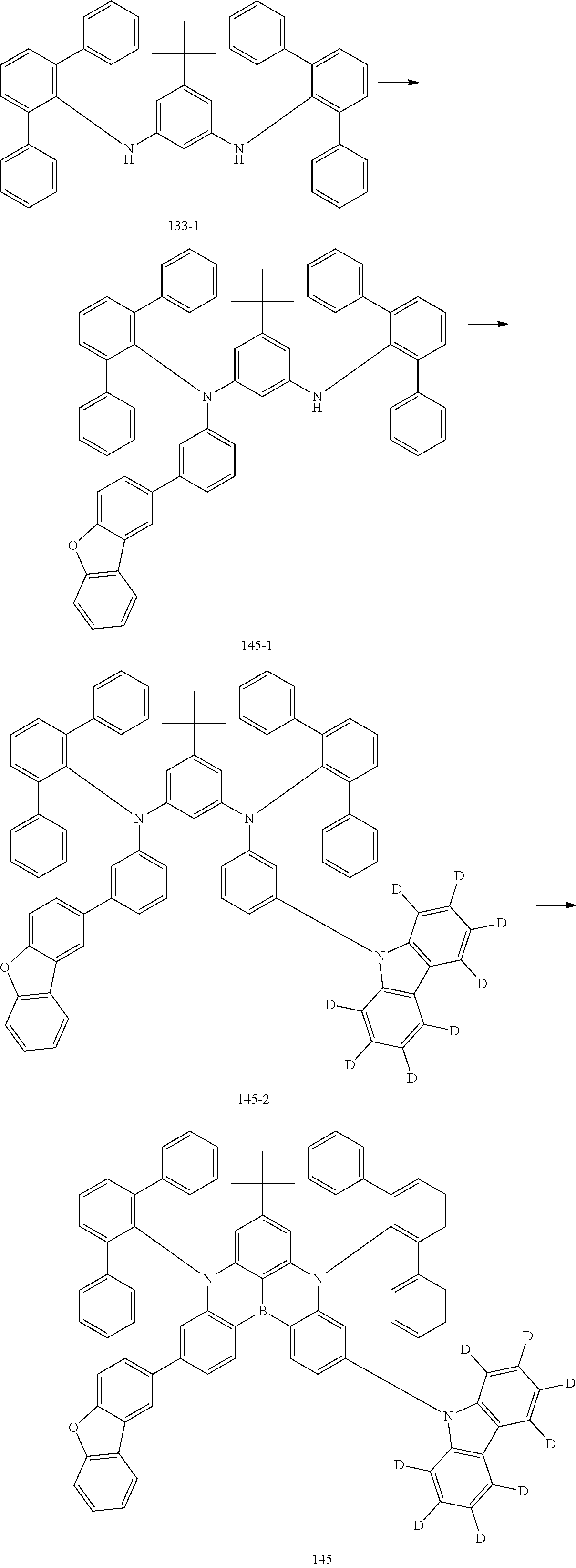

### Synthesis of Intermediate 145-1

Intermediate 133-1 (1 eq), 2-(3-bromophenyl)dibenzo[b,d]furan (1 eq), tris(dibenzylideneacetone)dipalladium(0) (0.1 eq), tri-tert-butylphosphine (0.2 eq), and sodium tert-butoxide (3 eq) were dissolved in toluene, and stirred at about 95 degrees centigrade for about 12 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 145-1 (yield: 37%).

### Synthesis of Intermediate 145-2

Intermediate 145-1 (1 eq), 9-(3-bromophenyl)-9H-carbazole-D8 (2 eq), tris(dibenzylideneacetone)dipalladium(0) (0.1 eq), tri-tert-butylphosphine (0.2 eq), and sodium tert-butoxide (3 eq) were dissolved in o-xylene and stirred at about 150 degrees centigrade for about 24 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 145-2 (yield: 41%).

### Synthesis of Compound 145

Intermediate 145-2 (1 eq) was dissolved in ortho dichlorobenzene and cooled to about 0 degrees centigrade. Under a nitrogen atmosphere, BBr₃ (2 eq) was slowly added thereto dropwisely, and after finishing the dropwise addition, the temperature was raised to about 150 degrees centigrade, followed by stirring for about 24 hours. After cooling, to a flask containing the reaction mixture, triethylamine was slowly added dropwisely to terminate the reaction, and ethyl alcohol was added to the reaction product to precipitate. The precipitate was filtered to obtain a reaction product. The solid content (e.g., amount) thus obtained was separated by column chromatography utilizing MC and n-hexane, and then, recrystallized utilizing toluene and acetone to obtain Compound 145 (yield: 19%).

### (6) Synthesis of Compound 152

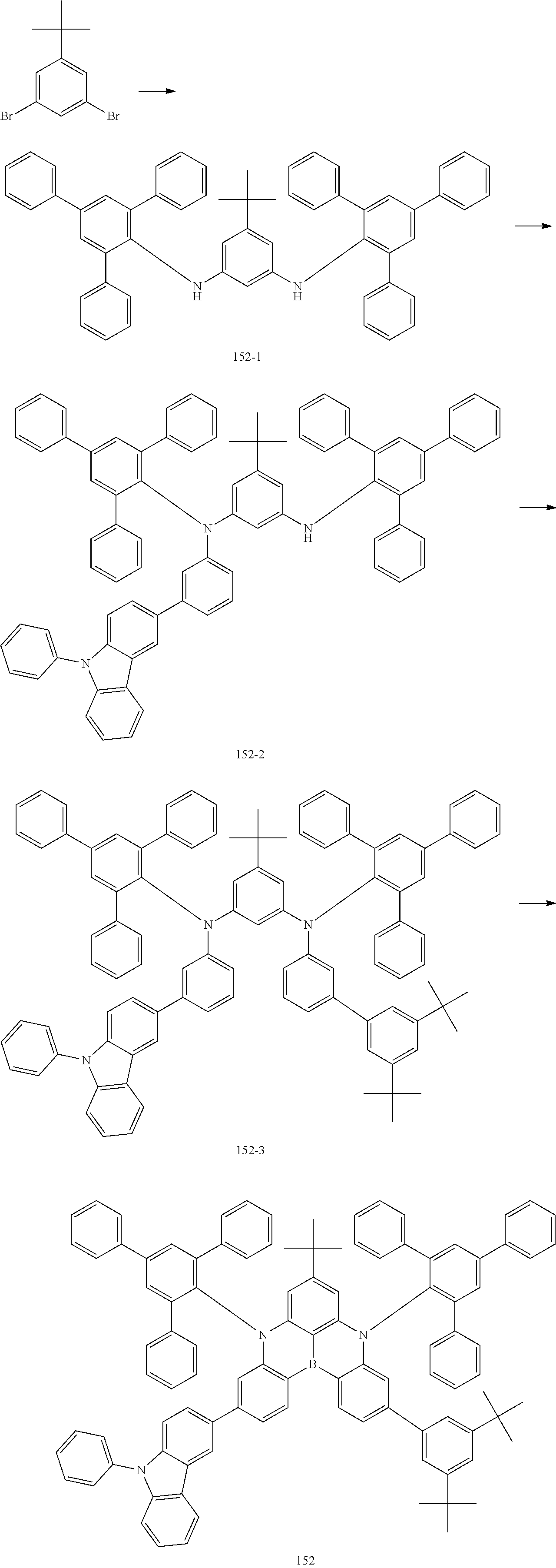

### Synthesis of Intermediate 152-1

1,3-dibromo-5-(tert-butyl)benzene (1 eq), 5′-phenyl-[1,1′:3′,1″-terphenyl]-2′-amine (2 eq), tris(dibenzylideneacetone)dipalladium(0) (0.1 eq), tri-tert-butylphosphine (0.2 eq), and sodium tert-butoxide (3 eq) were dissolved in toluene, and stirred at about 110 degrees centigrade for about 12 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 152-1 (yield: 75%).

### Synthesis of Intermediate 152-2

Intermediate 152-1 (1 eq), 3-(3-bromophenyl)-9-phenyl-9H-carbazole (1 eq), tris(dibenzylideneacetone)dipalladium(0) (0.05 eq), tri-tert-butylphosphine (0.1 eq), and sodium tert-butoxide (3 eq) were dissolved in toluene and stirred at about 90 degrees centigrade for about 12 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 152-2 (yield: 28%).

### Synthesis of Intermediate 152-3

Intermediate 152-2 (1 eq), 3′-bromo-3,5-di-tert-butyl-1,1′-biphenyl (1.5 eq), tris(dibenzylideneacetone)dipalladium(0) (0.1 eq), tri-tert-butylphosphine (0.2 eq), and sodium tert-butoxide (3 eq) were dissolved in o-xylene and stirred at about 150 degrees centigrade for about 24 hours. After cooling, the reaction product was washed with ethyl acetate for three times and water for three times, and an organic layer obtained by separating layers was dried with MgSO₄ and then, dried under a reduced pressure. The crude product thus obtained was separated by column chromatography utilizing MC and n-hexane to obtain Intermediate 152-3 (yield: 50%).

### Synthesis of Compound 152

Intermediate 152-3 (1 eq) was dissolved in ortho dichlorobenzene and cooled to about 0 degrees centigrade. Under a nitrogen atmosphere, BBr₃ (2 eq) was slowly added thereto dropwisely, and after finishing the dropwise addition, the temperature was raised to about 150 degrees centigrade, followed by stirring for about 24 hours. After cooling, to a flask containing the reaction mixture, triethylamine was slowly added dropwise to terminate the reaction, and ethyl alcohol was added to form a precipitate. The precipitate was filtered to obtain a reaction product. The solid content (e.g., amount) thus obtained was separated by column chromatography utilizing MC and n-hexane, and then, recrystallized utilizing toluene and acetone to obtain Compound 152 (yield: 26%).

### 2. Identification of Synthesized Compounds

The molecular weights and NMR analysis results of the compounds synthesized are shown in Table 1.

TABLE 1

| | NMR (500 MHz) | Cal | Meas. |
|---|---|---|---|
| 31 | 8.63-8.58 (1H, d), 8.58-8.51 (1H, d), 8.18-8.12 (2H, | 1521.774 | 1521.769 |
| | m), 8.10-8.07 (2H, s), 7.99-7.93 (2H, m), 7.65-7.53 | | |
| | (15H, m), 7.51-7.40 (16H, m), 7.41-7.25 (8H, m), | | |
| | 7.12-7.06 (6H, d), 6.85-6.81 (2H, s), 6.67-6.60 (2H, | | |
| | s), 1.54-1.51 (18H, s), 1.47-1.42 (18H, s) | | |
| 42 | 8.61-8.56 (1H, d), 8.54-8.44 (1H, d), 8.12-8.08 (2H, | 1215.319 | 1215.317 |
| | m) 7.60-7.42 (17H, m), 7.40-7.34 (11H, m), 7.33- | | |
| | 7.31 (4H, t), 7.30-7.24 (1H, m), 7.14-7.06 (6H, d), | | |
| | 6.88-6.75 (4H, m), 6.69-6.60 (2H, s) | | |
| 54 | 8.54-8.44 (2H, d), 8.11-8.05 (2H, m), 8.01-7.93 (2H, | 1305.398 | 1305.395 |
| | m) 7.62-7.58 (10H, m), 7.56-7.42 (17H, m), 7.40- | | |
| | 7.31 (8H, m), 7.15-7.05 (6H, m), 6.88-6.75 (4H, m), | | |
| | 6.74-6.70 (2H, s) | | |
| 133 | 8.55-8.42 (2H, d), 7.96-7.92 (4H, m), 7.62-7.56 | 113.153 | 113.154 |
| | (12H, m) 7.53-7.44 (12H, m), 7.41-7.31 (6H, m), | | |
| | 7.15-7.06 (6H, d), 6.87-6.77 (4H, m), 6.93-6.88 (2H, | | |
| | s), 1.53-1.50 (9H, s) | | |
| 145 | 8.66-8.61 (1H, d), 8.54-8.44 (1H, d), 8.02-7.96 (2H, | 1120.218 | 1120.216 |
| | m), 7.65-7.56 (10H, m), 7.53-7.44 (10H, m), 7.41- | | |
| | 7.31 (5H, m), 7.23-7.06 (6H, d), 6.87-6.80 (3H, m), | | |
| | 6.77-6.64 (3H, m), 1.58-1.53 (9H, m) | | |
| 152 | 8.73-8.69 (1H, d), 8.60-8.56 (1H, d), 8.13-8.09 (2H, | 1362.589 | 1362.585 |
| | d) 7.77-7.55 (16H, m), 7.51-7.38 (19H, m), 7.48-7.40 | | |
| | (4H, m), 7.36-7.25 (5H, t), 7.17-7.08 (6H, d), 6.96- | | |
| | 6.88 (3H, s), 1.57-1.42 (27H, m) | | |

### Manufacture of Light Emitting Device

Light emitting devices of the Examples were manufactured utilizing Compounds 31, 42, 54, 133, 145 and 152 as the dopant materials of an emission layer.

### Example Compounds

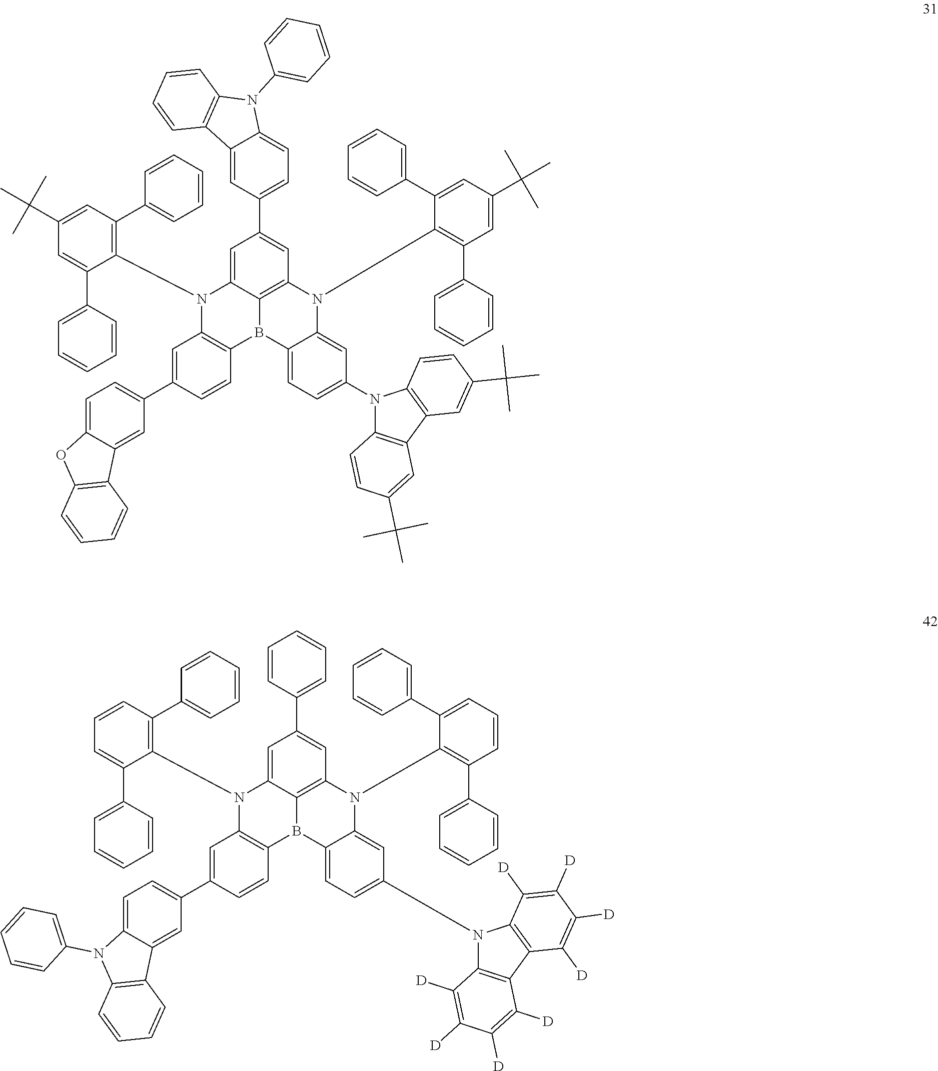 [SMILES: CC(C)(C)c1cc(-c2ccccc2)c(N2c3cc(-c4ccc5oc6ccccc6c5c4)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-c5ccc6c(c5)c5ccccc5n6-c5ccccc5)cc2c43)c(-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccccc3)cc3c1B2c1ccc(-c2ccc4c(c2)c2ccccc2n4-c2ccccc2)cc1N3c1c(-c2ccccc2)cccc1-c1ccccc1]

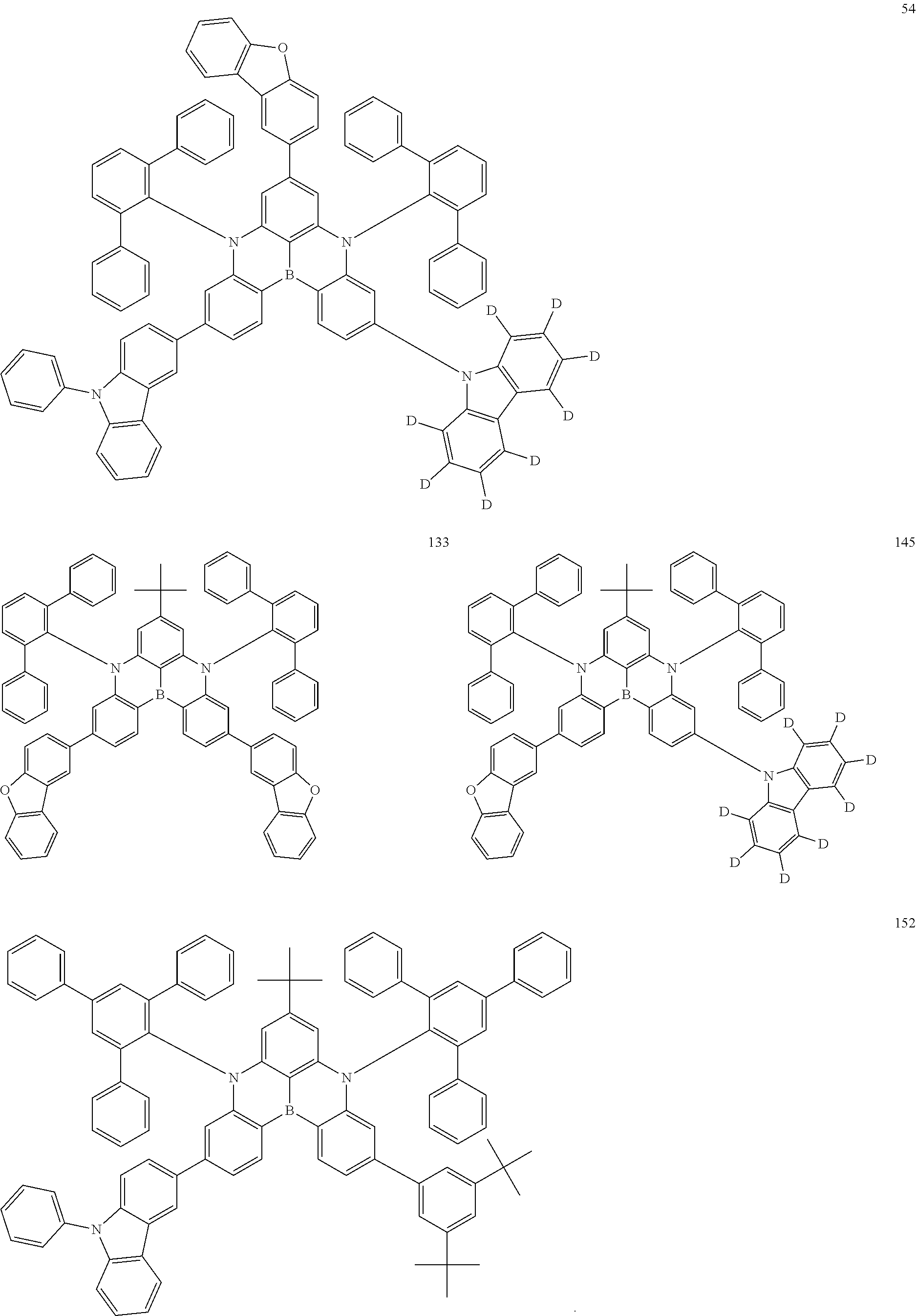

Comparative Compounds X-1 to X-4 were utilized for the manufacture of the devices of the Comparative Examples.

### Comparative Compounds

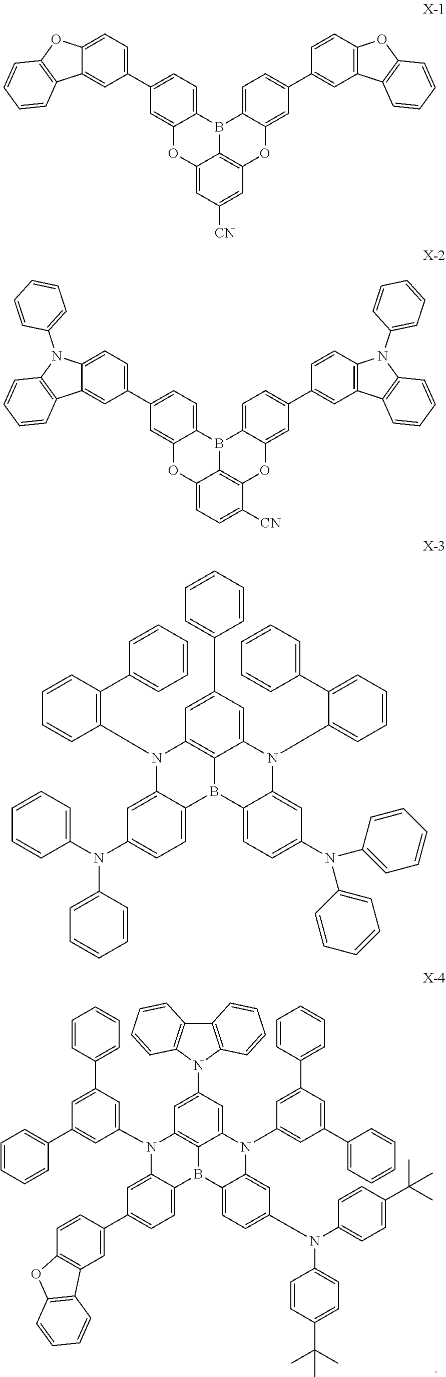 [SMILES: N#Cc1cc2c3c(c1)Oc1cc(-c4ccc5oc6ccccc6c5c4)ccc1B3c1ccc(-c3ccc4oc5ccccc5c4c3)cc1O2 ; N#Cc1ccc2c3c1Oc1cc(-c4ccc5c(c4)c4ccccc4n5-c4ccccc4)ccc1B3c1ccc(-c3ccc4c(c3)c3ccccc3n4-c3ccccc3)cc1O2 ; c1ccc(-c2cc3c4c(c2)N(c2ccccc2-c2ccccc2)c2cc(N(c5ccccc5)c5ccccc5)ccc2B4c2ccc(N(c4ccccc4)c4ccccc4)cc2N3c2ccccc2-c2ccccc2)cc1 ; CC(C)(C)c1ccc(N(c2ccc(C(C)(C)C)cc2)c2ccc3c(c2)N(c2cc(-c4ccccc4)cc(-c4ccccc4)c2)c2cc(-n4c5ccccc5c5ccccc54)cc4c2B3c2ccc(-c3ccc5oc6ccccc6c5c3)cc2N4c2cc(-c3ccccc3)cc(-c3ccccc3)c2)cc1]

The light emitting devices of the Examples and the Comparative Examples were manufactured as follows. An ITO glass substrate was cut into a size of about 50 mm×50 mm×0.7 mm, washed by ultrasonic waves utilizing isopropyl alcohol and distilled water for about 5 minutes each, and cleaned by irradiating ultraviolet rays for about 30 minutes and then, ozone. After that, the ITO glass substrate was installed in a vacuum deposition apparatus. Then, a hole injection layer HIL with a thickness of about 300 Å was formed utilizing NPD, a hole transport layer HTL with a thickness of about 200 Å was formed utilizing HT-1-1, and an emission auxiliary layer with a thickness of about 100 Å was formed utilizing CzSi. Then, a host compound of a mixture of a first host and a second host according to embodiments in a ratio (e.g., amount) of 1:1, a second dopant, and the Example Compound or Comparative Compound were co-deposited in a weight ratio of about 85:14:1 to form an emission layer EML with a thickness of about 200 Å, and a hole blocking layer with a thickness of about 200 Å was formed utilizing TSPO1. Then, an electron transport layer ETL with a thickness of about 300 Å was formed utilizing TPBi, and an electron injection layer EIL with a thickness of about 10 Å was formed utilizing LiF. Then, a second electrode EL2 with a thickness of about 3000 Å was formed utilizing AI. All layers were formed by a vapor deposition method.

The compounds utilized for the manufacture of the light emitting devices of the Examples and Comparative Examples are shown below. The materials were utilized by purchasing commercial products and then separating by sublimation purification.

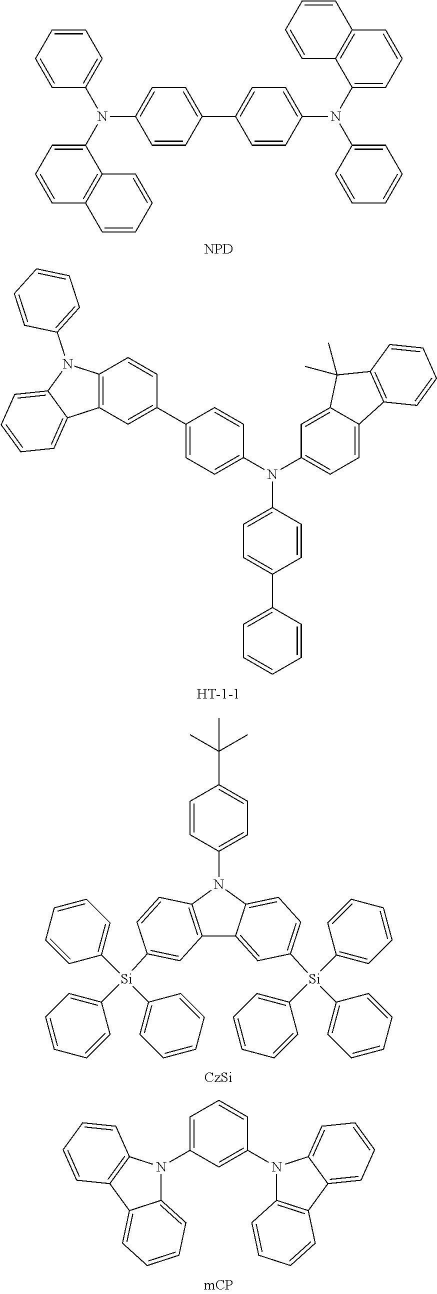

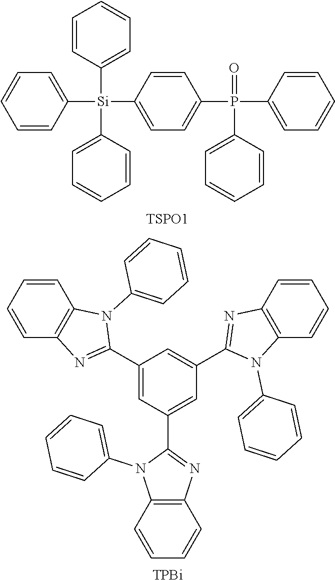

### Evaluation of Properties of Light Emitting Devices

The evaluation of the properties of the light emitting devices was conducted utilizing a light distribution measurement system. In order to evaluate the properties of the light emitting devices according to the Examples and Comparative Examples, a driving voltage, efficiency and an emission wavelength were measured. In Table 2, a current density of about 10 mA/cm², and an emission efficiency (cd/A) at a luminance of about 1000 cd/m² were measured for each of the light emitting devices manufactured. The life ratio is shown by measuring a point where a 95% of a luminance value is shown in contrast to initial luminance and recorded as a relative value with the life of 1 of Comparative Example 1.

TABLE 2

| Device | | | | | Emission | Emission | Life ratio |
|---|---|---|---|---|---|---|---|
| manufacturing | First host/ | TADF | | Driving | efficiency | wavelength | (T₉₅) |
| example | second host | dopant | Sensitizer | voltage | (V) | (Cd/A) | (nm) |
| Example 1 | HT-19/ET-15 | Compound 31 | AD-38 | 4.1 | 27.5 | 461 | 5.2 |
| Example 2 | HT-19/ET-15 | Compound 42 | AD-38 | 4.2 | 26.3 | 463 | 6.8 |
| Example 3 | HT-19/ET-15 | Compound 54 | AD-38 | 4.3 | 25.2 | 461 | 6.9 |
| Example 4 | HT-19/ET-15 | Compound 133 | AD-38 | 4.1 | 27.1 | 464 | 6.6 |
| Example 5 | HT-19/ET-15 | Compound 145 | AD-38 | 4.3 | 26.1 | 460 | 5.1 |
| Example 6 | HT-19/ET-15 | Compound 152 | AD-38 | 4.1 | 25.9 | 463 | 6.1 |
| Example 8 | HT-12/ET-15 | Compound 31 | AD-37 | 4.1 | 27.5 | 460 | 6.6 |
| Example 9 | HT-12/ET-15 | Compound 42 | AD-37 | 4.0 | 26.9 | 462 | 5.5 |
| Example 10 | HT-12/ET-15 | Compound 54 | AD-37 | 4.1 | 26.3 | 460 | 6.3 |
| Example 11 | HT-12/ET-15 | Compound 152 | AD-37 | 4.2 | 27.1 | 461 | 6.1 |
| Example 12 | HT-20/ET-16 | Compound 31 | AD-37 | 4.2 | 26.8 | 461 | 7.1 |
| Example 13 | HT-20/ET-16 | Compound 54 | AD-37 | 4.1 | 26.6 | 460 | 6.6 |
| Example 14 | HT-20/ET-15 | Compound 145 | AD-38 | 4.2 | 26.2 | 461 | 7.2 |
| Example 15 | HT-18/ET-15 | Compound 145 | AD-38 | 4.2 | 26.5 | 460 | 7.1 |
| Example 16 | HT-18/ET-15 | Compound 152 | AD-38 | 4.2 | 26.2 | 462 | 8.0 |
| Example 17 | HT-12/ET-17 | Compound 31 | AD-38 | 4.1 | 25.7 | 461 | 6.1 |
| Example 18 | HT-12/ET-17 | Compound 54 | AD-38 | 4.2 | 25.6 | 462 | 6.4 |
| Example 19 | HT-12/ET-17 | Compound 152 | AD-38 | 4.2 | 26.4 | 461 | 6.0 |
| Comparative | HT-19/ET-15 | Comparative | — | 5.5 | 6.8 | 448 | 1 |
| Example 1 | | Compound X-1 | | | | | |
| Comparative | HT-19/ET-15 | Comparative | — | 5.7 | 7.1 | 445 | 1.4 |
| Example 2 | | Compound X-2 | | | | | |
| Comparative | HT-19/ET-15 | Comparative | AD-38 | 5.3 | 11.2 | 462 | 2.4 |
| Example 3 | | Compound X-1 | | | | | |
| Comparative | HT-19/ET-15 | Comparative | AD-38 | 5.2 | 9.8 | 463 | 2.8 |
| Example 4 | | Compound X-2 | | | | | |
| Comparative | HT-19/ET-15 | Comparative | — | 5.1 | 16.5 | 459 | 1.5 |
| Example 5 | | Compound X-3 | | | | | |
| Comparative | HT-19/ET-15 | Comparative | — | 5.3 | 15.9 | 454 | 1.7 |
| Example 6 | | Compound X-4 | | | | | |
| Comparative | HT-19/ET-15 | Comparative | AD-38 | 4.7 | 20.5 | 464 | 3.5 |
| Example 7 | | Compound X-3 | | | | | |
| Comparative | HT-19/ET-15 | Comparative | AD-38 | 4.6 | 18.9 | 463 | 3.1 |
| Example 8 | | Compound X-4 | | | | | |

Referring to the results of Table 1, it could be confirmed that the Examples of the light emitting devices utilizing the fused polycyclic compound according to an embodiment of the present disclosure as a light emitting material showed a reduced driving voltage and improved emission efficiency and device life, while maintaining the light emitting wavelength of blue light when compared to the Comparative Examples.

The first compound according to an embodiment has a structure in which a substituent having an electron donating group of a fused ring type or kind is bonded through a carbon-carbon bond in a plate-type or kind skeleton structure with a boron element as a center, and additionally has a structure in which the substituent having an electron donating group bonded through the carbon-carbon bond is bonded at the para position to the boron atom. Therefore, the first compound according to an embodiment has a high oscillator strength value and a small LEST value, through the increase of multiple resonance effects due to the increase of the electron donating properties of the substituent having an electron donating group, and improved delayed fluorescence emission properties may be expected. In some embodiments, the first compound may have a strong bond structure through a carbon-carbon bond of the substituent having an electron donating group and through the central core, and the chemical stability of the material itself could be improved. Further, the first compound of an embodiment includes multiple substituents having an electron donating group, and the light absorption of the compound itself could be increased, and accordingly, when the first compound of an embodiment is utilized as a thermally activated delayed fluorescence dopant, energy transfer efficiency with a host material may be improved to further improve emission efficiency. The light emitting device of an embodiment includes the first compound as the light emitting dopant of a thermally activated delayed fluorescence (TADF) emitting device, and high device efficiency, for example, in a blue wavelength region.

It could be confirmed that Comparative Compound X-1 and Comparative Compound X-2 included in Comparative Example 1 to Comparative Example 4 had a plate-type or kind skeleton structure with one boron atom as a center and included multiple substituents having an electron donating group, but included one boron atom and two oxygen atoms as the central elements of the plate-type or kind skeleton structure, and thus, showed degraded emission efficiency and device life when compared to the Example Compounds. In the cases of Comparative Compound X-1 and Comparative Compound X-2, two oxygen atoms which had weak electron donating properties to a skeleton structure were included in a structure, and multiple resonance became weak, and it is thought that emission efficiency and device life were degraded when compared to the Example Compounds. In each of Comparative Compound X-1 and Comparative Compound X-2, an oxygen atom was substituted at the position of a nitrogen atom of the Example Compound, and emission wavelength was rapidly shifted to a short wavelength, and accordingly, the light emitting devices emitted light with a wavelength which was inappropriate (not suitable) to apply in a display apparatus. Comparative Example 1 and Comparative Example 2 did not include a sensitizer in the emission layer, and even further degraded emission efficiency was shown when compared to the Examples, and in Comparative Example 3 and Comparative Example 4, though a sensitizer was included in the emission layer, it could be found that lower emission efficiency was shown when compared to the Examples.

In Comparative Compound X-3 included in Comparative Example 5 and Comparative Example 7, different from the Examples, because it does not have a substituent having an electron donating group having a fused ring type or kind but instead has an unfused substituent, i.e., a diphenyl amine was substituted at the para position to the boron atom, and emission efficiency and device life were degraded when compared to the Example Compounds. In the case of Comparative Compound X-3, because diphenyl amine was introduced instead of a fused ring substituent, and the HOMO level of a material became shallow, and due to the HOMO level difference with a host material, phenomenon of trapping holes injected occurred. This increased the probability of generating not host excitons but dopant excitons (trap assistant recombination), and the concentration increase of T1 excitons produced in a probability of about 75% in the dopant excitons thus produced weakened the C—N bond of the diphenyl amine substituent in a compound structure by the generation of hot excitons. Accordingly, the stability of an emission layer material was reduced, and the life and emission efficiency of a light emitting device were reduced.

In Comparative Compound X-4 included in Comparative Example 6 and Comparative Example 8, different from the Examples, a substituent was connected not by a carbon-carbon bond but by a carbon-nitrogen bond at the para position to the boron atom, and the emission efficiency and device life were degraded when compared to the Example Compounds. The emission wavelength shifted to a short wavelength, and a light emitting device emitted light with a wavelength which was inappropriate (not suitable) to apply to a display device. The carbon-nitrogen bonds increased to reduce the life of a device.

The light emitting device of an embodiment may show improved device properties of high efficiency and long life.

The fused polycyclic compound of an embodiment may be included in the emission layer of a light emitting device and may contribute to the increase of efficiency and lifetime of the light emitting device.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The light emitting device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A light emitting device, comprising:
a first electrode;
a second electrode opposite to the first electrode; and
an emission layer between the first electrode and the second electrode,
wherein the emission layer comprises:
a first compound represented by Formula 1; and
at least one of a second compound represented by Formula H-1, a third compound represented by Formula H-2, or a fourth compound represented by Formula D-2: 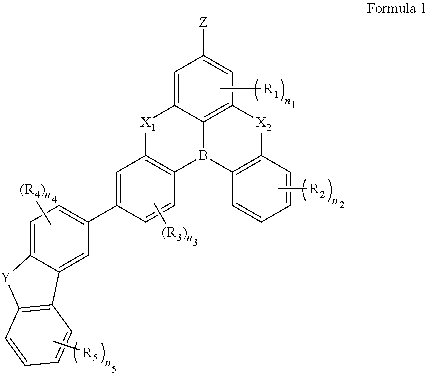
in Formula 1,
X₁ and X₂ are each independently NR₆, O, or S, where at least one of X₁ or X₂ is NR₆,
Y is NR₇, O, or S,
Z is a substituted or unsubstituted t-butyl group, a substituted or unsubstituted aryl group of 6 to 30 ring-forming carbon atoms, or a substituted or unsubstituted heteroaryl group of 2 to 30 ring-forming carbon atoms,
R₁ to R₇ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
n₁ is an integer of 0 to 2,
n₂ and n₅ are each independently an integer of 0 to 4, and
n₃ and n₄ are each independently an integer of 0 to 3, 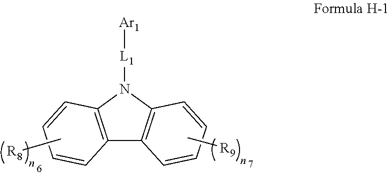
in Formula H-1,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Ar₁ is a substituted or unsubstituted aryl group of 6 to 30 ring-forming carbon atoms, or a substituted or unsubstituted heteroaryl group of 2 to 30 ring-forming carbon atoms,
R₈ and R₉ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
n₆ and n₇ are each independently an integer of 0 to 4, 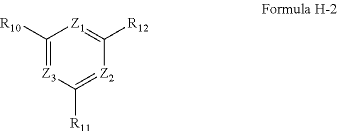
in Formula H-2,
at least one of Z₁ to Z₃ is N, and the Z₁, Z₂ and Z₃ that are not N are CR₁₃, and
R₁₀ to R₁₃ are each independently a hydrogen atom, a deuterium atom, a cyano group, a substituted or unsubstituted silyl group, a substituted or unsubstituted aryl group of 6 to 30 ring-forming carbon atoms, or a substituted or unsubstituted heteroaryl group of 2 to 30 ring-forming carbon atoms, 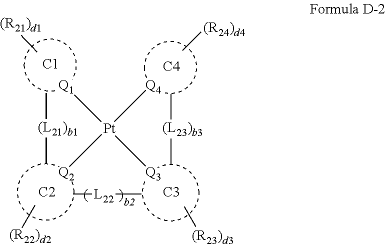
in Formula D-2,
Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
L₂₁ to L₂₃ are each independently a direct linkage, *—O—*, *—S—*, 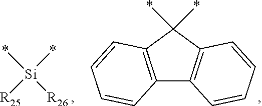
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b1 to b3 are each independently 0 or 1,
R₂₁ to R₂₆ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 1 to 30 ring-forming carbon atoms, and/or combined with an adjacent group to form a ring, and
d1 to d4 are each independently an integer of 0 to 4.

2. The light emitting device of claim 1, wherein the emission layer is configured to emit delayed fluorescence.

3. The light emitting device of claim 1, wherein the emission layer comprises the first compound, the second compound, and the third compound.

4. The light emitting device of claim 1, wherein the emission layer comprises the first compound, the second compound, the third compound, and the fourth compound.

5. The light emitting device of claim 1, wherein the emission layer is configured to emit light having a light emitting central wavelength of about 430 nm to about 490 nm.

6. The light emitting device of claim 1, wherein the first compound represented by Formula 1 is represented by any one of Formula 2-1 to Formula 2-4: 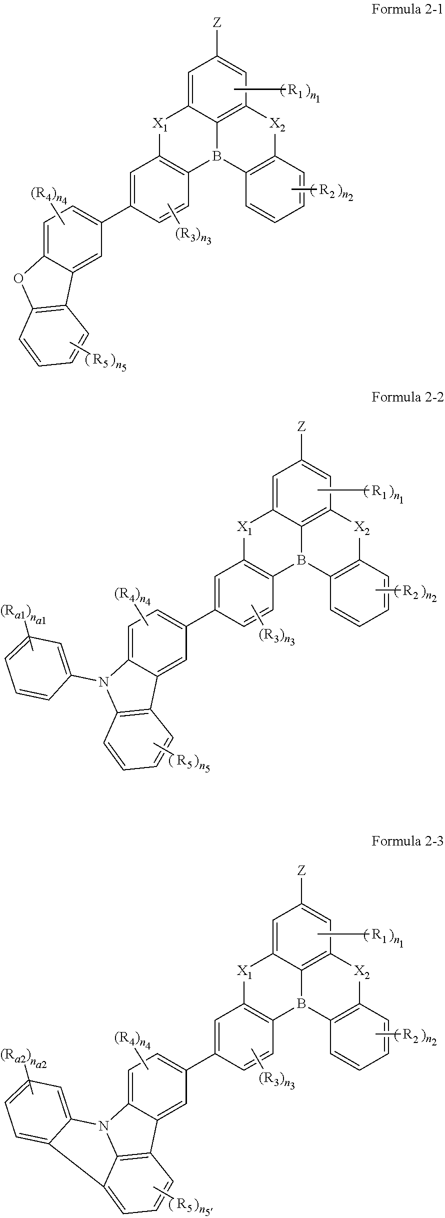 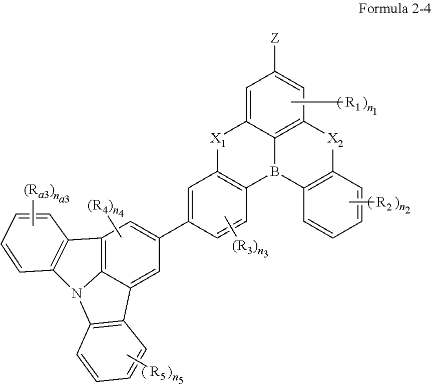
in Formula 2-1 to Formula 2-4,
Rₐ₁ to Rₐ₃ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
nₐ₁ is an integer of 0 to 5,
nₐ₂ and nₐ₃ are each independently an integer of 0 to 4,
n_{a4′} is an integer of 0 to 2,
n_{a5′} is an integer of 0 to 3, and
X₁, X₂, Z, R₁ to R₇, and n₁ to n₅ are the same as defined in Formula 1.

7. The light emitting device of claim 1, wherein the first compound represented by Formula 1 is represented by any one of Formula 3-1 to Formula 3-3: 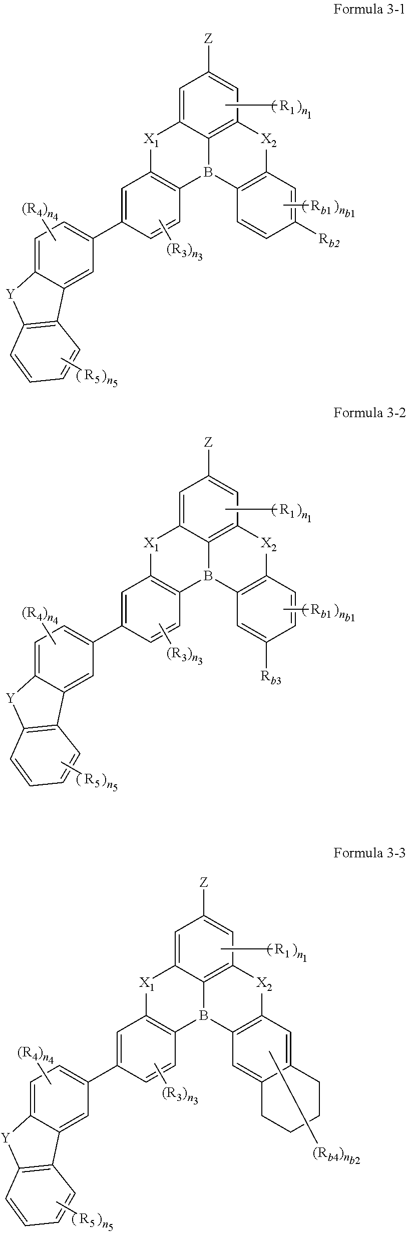
in Formula 3-1 to Formula 3-3,
R_{b1} to R_{b4} are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n_{b1} is an integer of 0 to 3,
n_{b2} is an integer of 0 to 10, and
X₁, X₂, Y, Z, R₁, R₃ to R₇, n₁, and n₃ to n₅ are the same as defined in Formula 1.

8. The light emitting device of claim 7, wherein the first compound represented by Formula 1 is represented by any one of Formula 3-1-1 to Formula 3-3-1: 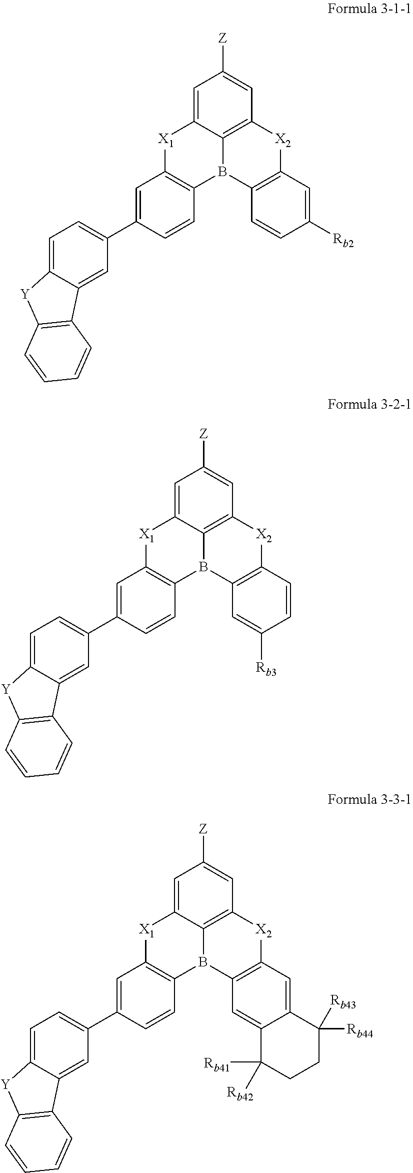
in Formula 3-1-1 to Formula 3-3-1,
R_{b41} to R_{b44} are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
X₁, X₂, Y, Z, R₆, R₇, R_{b2} and R_{b3} are the same as defined in Formula 1 and Formula 3-1 to Formula 3-3.

9. The light emitting device of claim 7, wherein,
in Formula 3-1, R_{b2} is a substituted or unsubstituted amine group, a substituted or unsubstituted phenyl group, a substituted or unsubstituted dibenzofuran group, a substituted or unsubstituted carbazole group, or a substituted or unsubstituted indolocarbazole group,
in Formula 3-2, R_{b3} is a substituted or unsubstituted t-butyl group, or a substituted or unsubstituted phenyl group, and
in Formula 3-3, R_{b4} is a hydrogen atom, a deuterium atom, or a substituted or unsubstituted methyl group.

10. The light emitting device of claim 1, wherein the first compound represented by Formula 1 is represented by Formula 4: 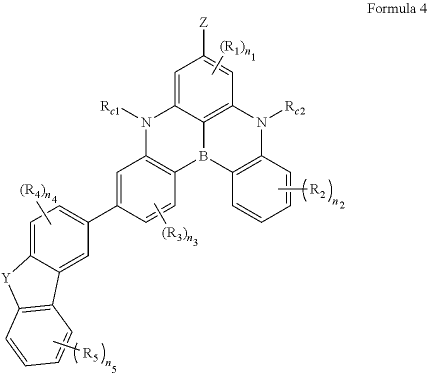
in Formula 4,
R_{c1} and R_{c2} are each independently a substituted or unsubstituted aryl group of 6 to 30 ring-forming carbon atoms, or a substituted or unsubstituted heteroaryl group of 2 to 30 ring-forming carbon atoms, and
Y, Z, R₁ to R₇, and n₁ to n₅ are the same as defined in Formula 1.

11. The light emitting device of claim 10, wherein in Formula 4, each of R_{c1} and R_{c2} is represented by any one of Formula 5-1 to Formula 5-6: 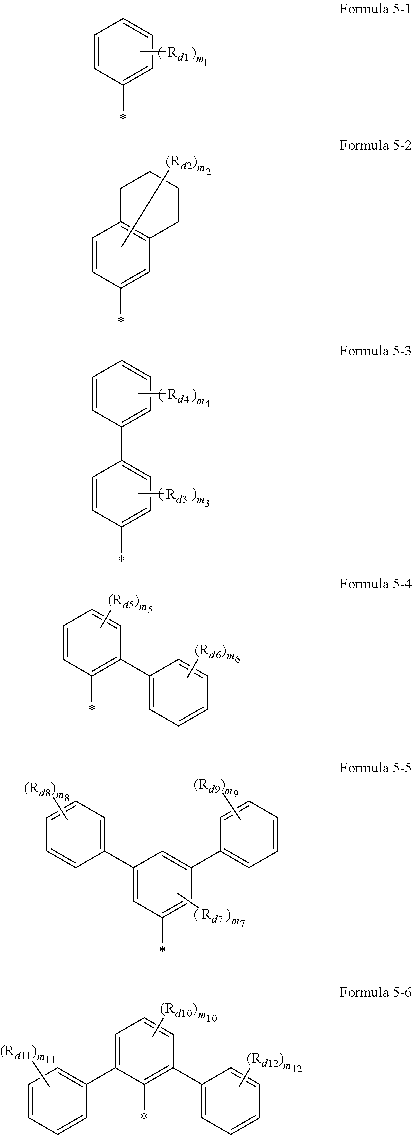
in Formula 5-1 to Formula 5-6,
R_{d1} to R_{d12} are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m₁, m₄, m₆, m₈, m₉, m₁₁ and m₁₂ are each independently an integer of 0 to 5,
m₂ is an integer of 0 to 11,
m₃ and m₅ are each independently an integer of 0 to 4, and
m₇ and m₁₀ are each independently an integer of 0 to 3.

12. The light emitting device of claim 1, wherein the first compound represented by Formula 1 is represented by any one of Formula 6-1 to Formula 6-5: 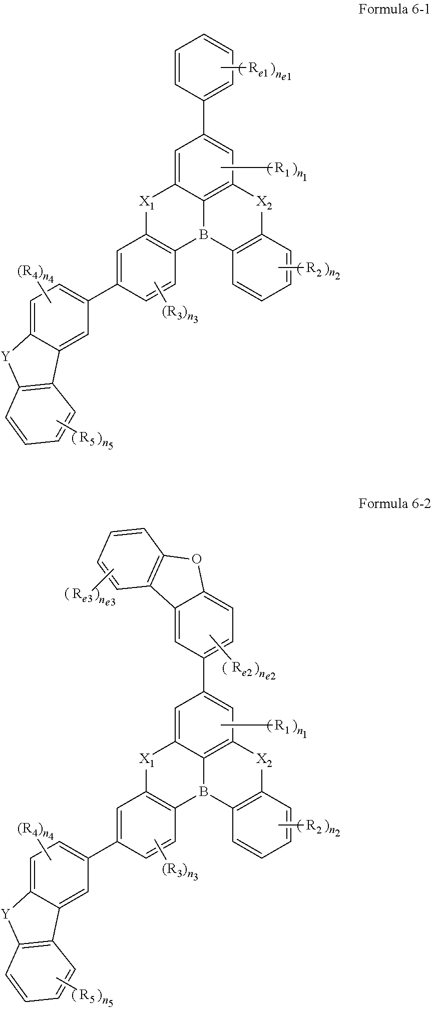 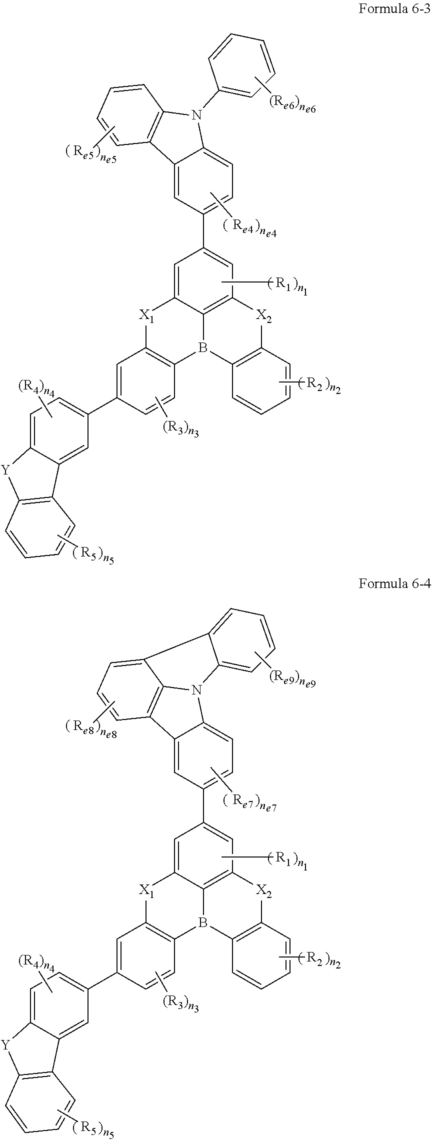 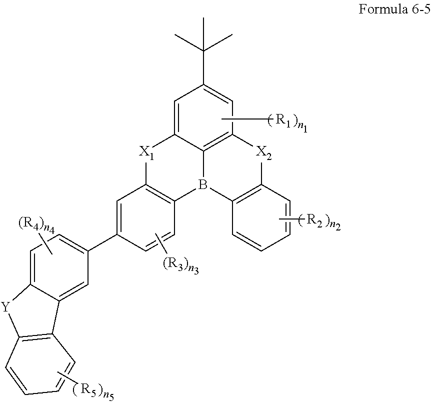
in Formula 6-1 to Formula 6-5,
Rₑ₁ to Rₑ₉ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
nₑ₁ and nₑ₆ are each independently an integer of 0 to 5,
nₑ₂, nₑ₄, nₑ₇ and nₑ₈ are each independently an integer of 0 to 3,
nₑ₃, nₑ₅ and nₑ₉ are each independently an integer of 0 to 4, and
X₁, X₂, Y, R₁ to R₇, and n₁ to n₅ are the same as defined in Formula 1.

13. The light emitting device of claim 1, further comprising a capping layer on the second electrode, and the capping layer has a refractive index of about 1.6 or more.

14. The light emitting device of claim 1, wherein the first compound comprises at least one of the compounds in Compound Group 1:

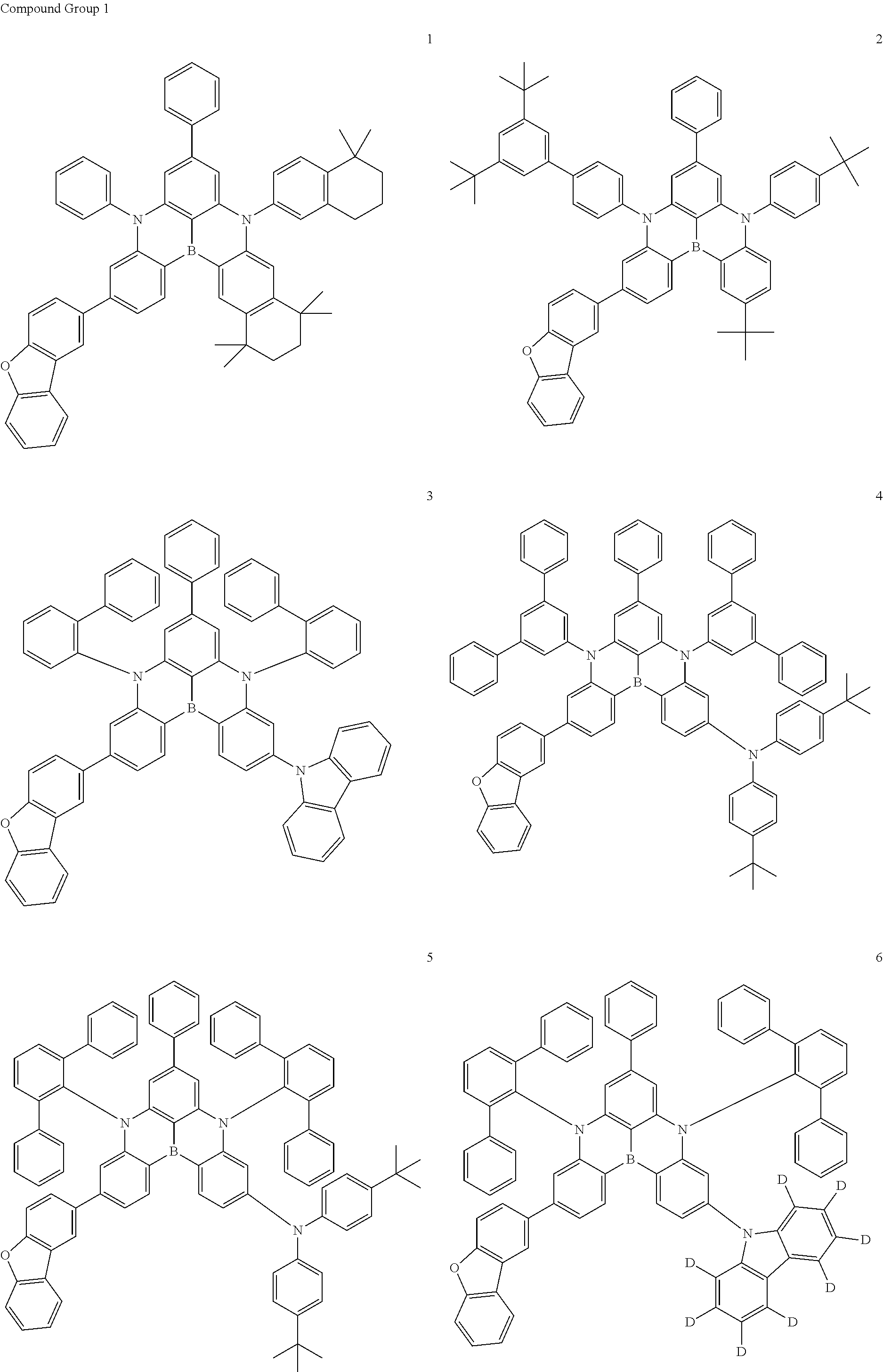

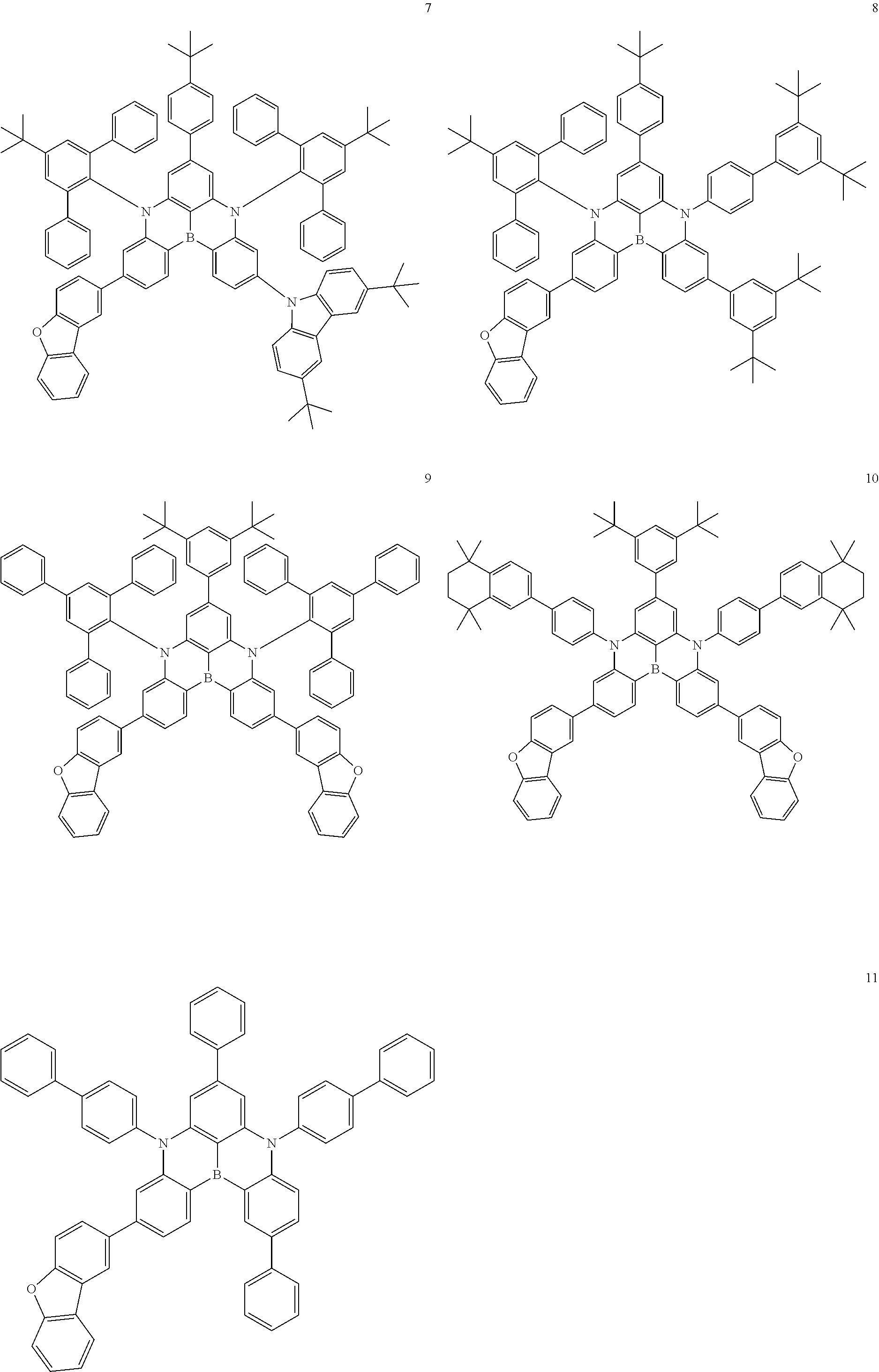

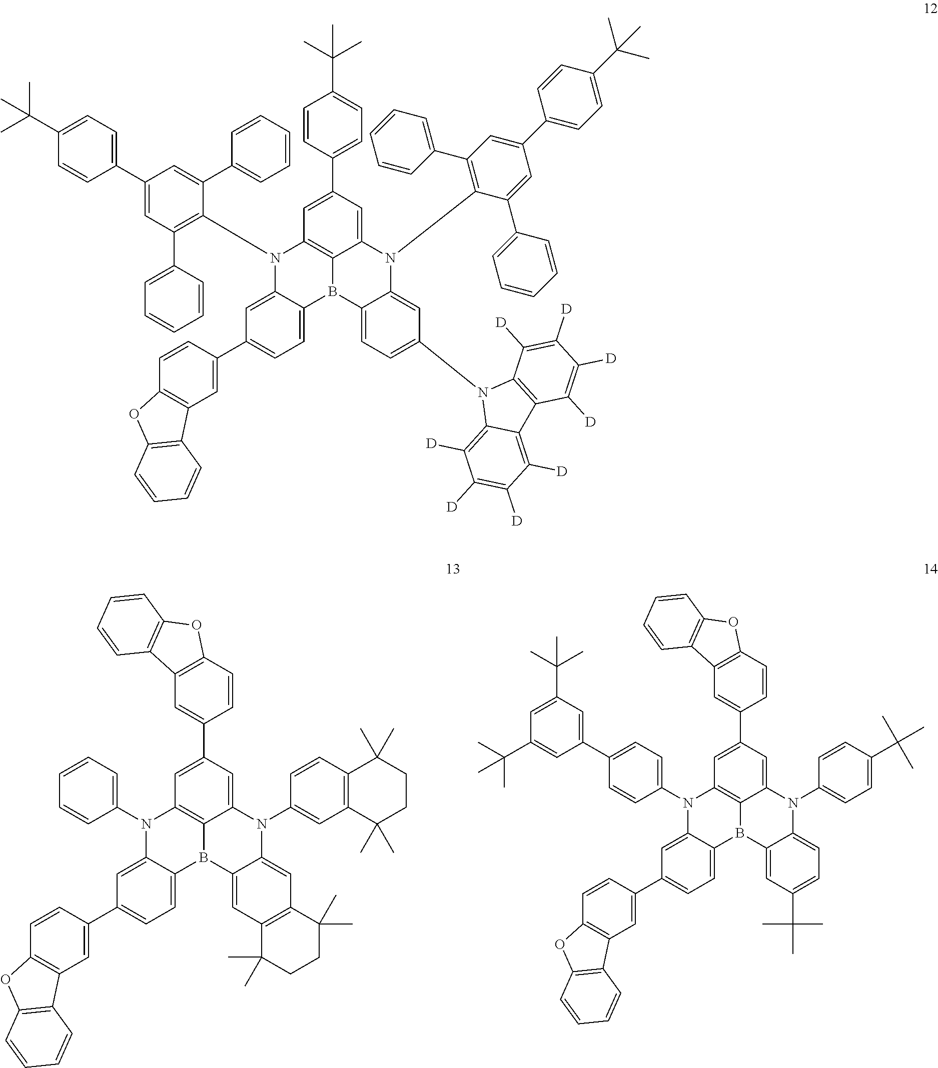

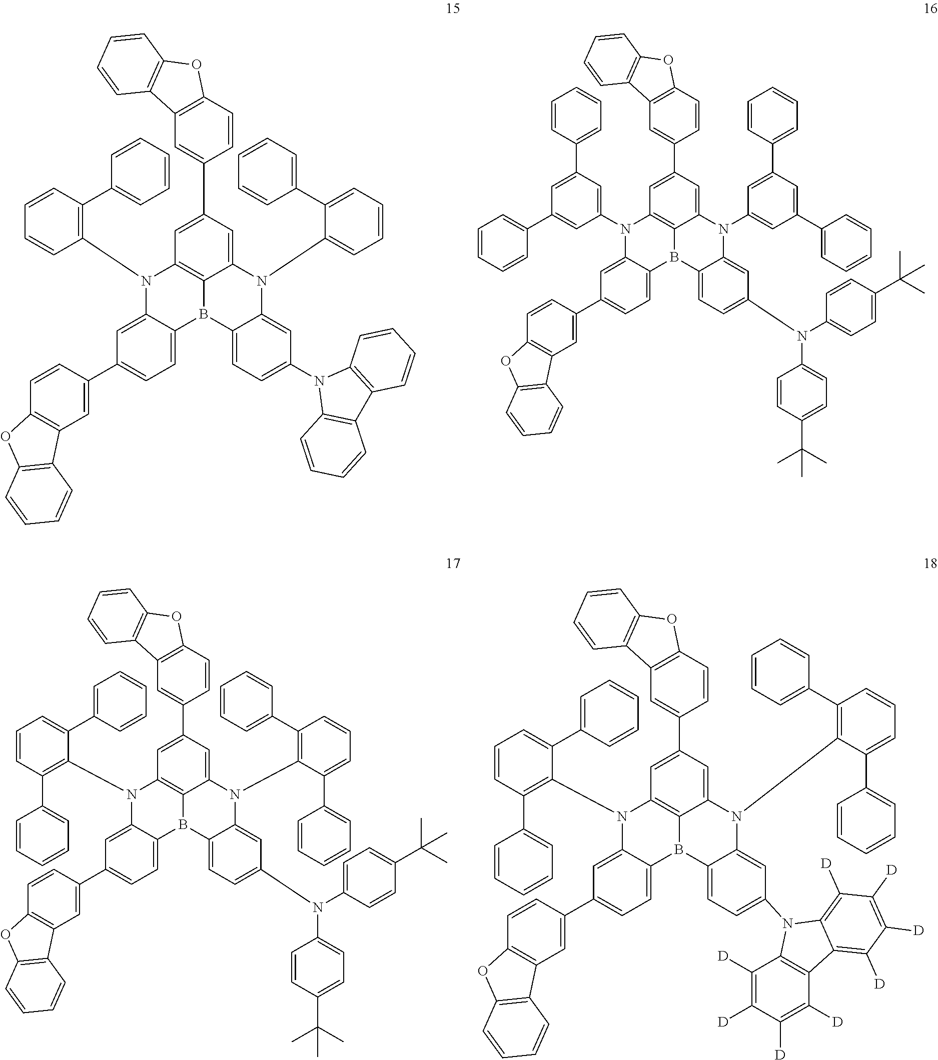

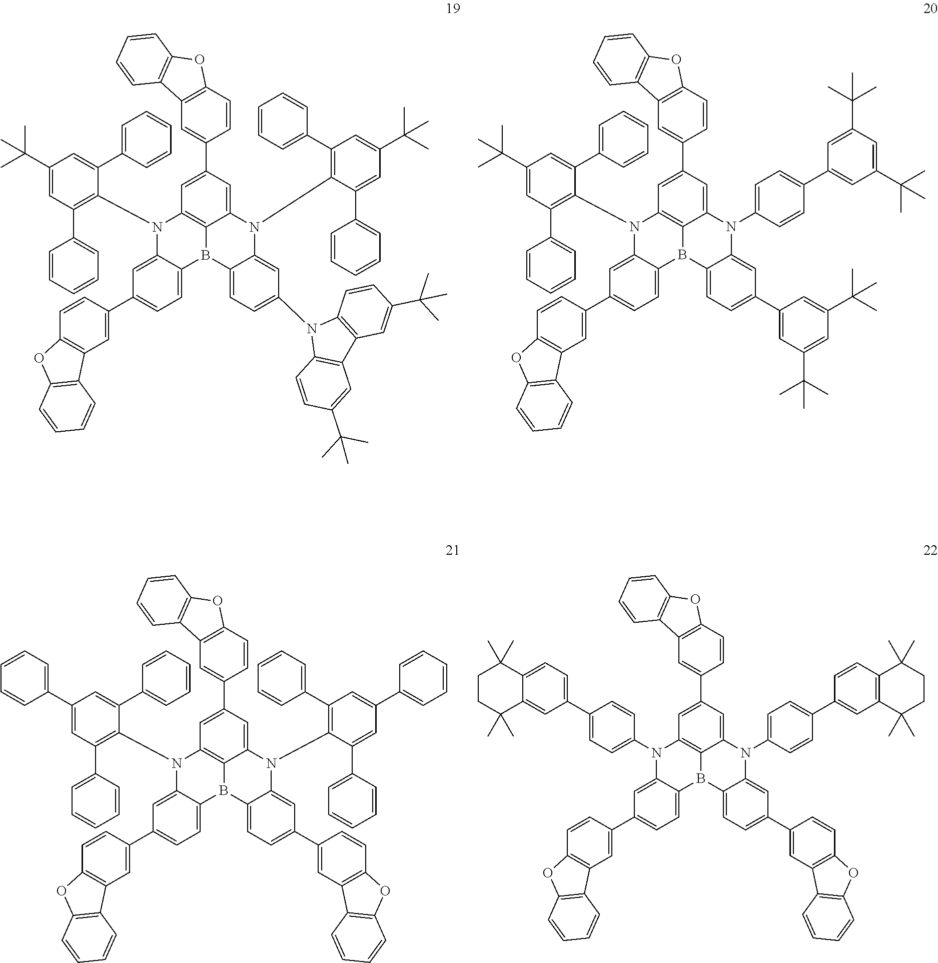

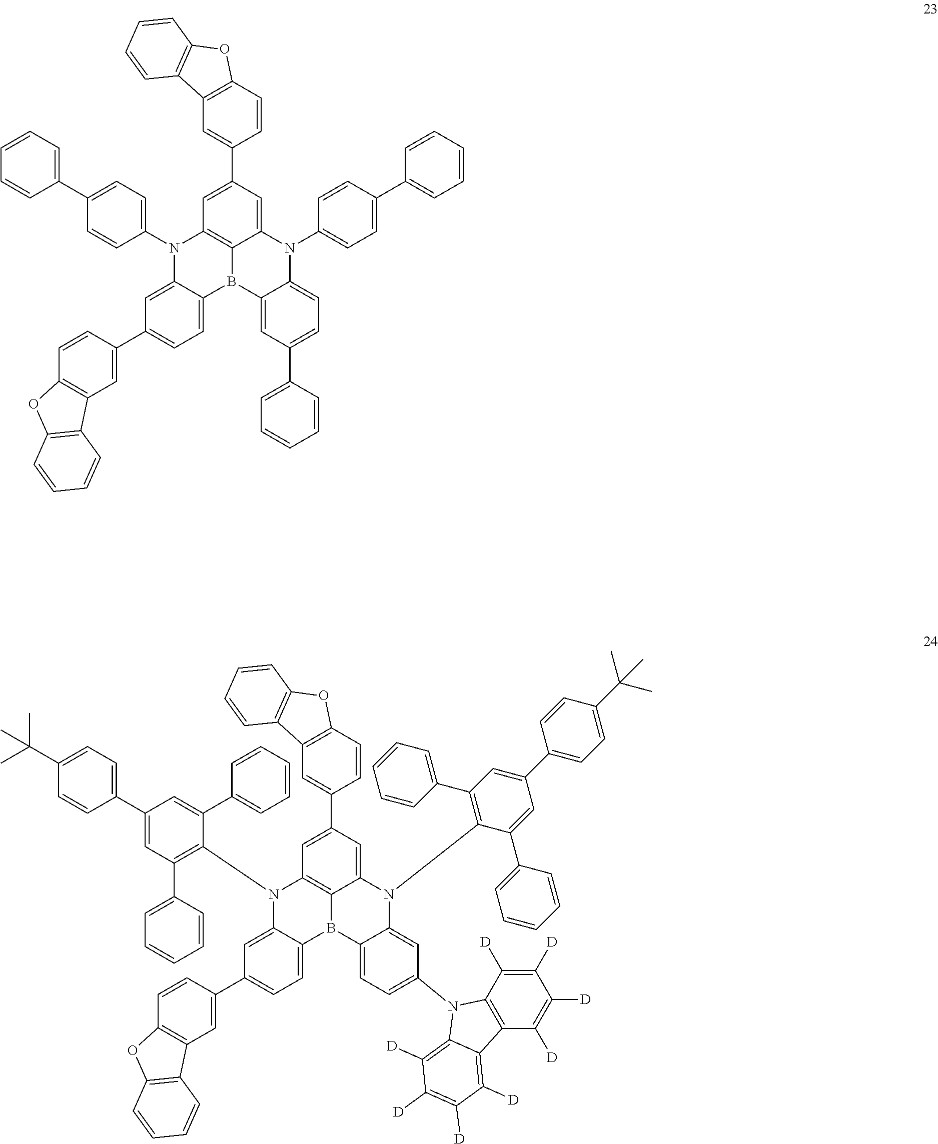 [SMILES: c1ccc(-c2ccc(N3c4ccc(-c5ccccc5)cc4B4c5ccc(-c6ccc7oc8ccccc8c7c6)cc5N(c5ccc(-c6ccccc6)cc5)c5cc(-c6ccc7oc8ccccc8c7c6)cc3c54)cc2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4oc5ccccc5c4c3)cc3c1B2c1ccc(-c2ccc4oc5ccccc5c4c2)cc1N3c1c(-c2ccccc2)cc(-c2ccc(C(C)(C)C)cc2)cc1-c1ccccc1]

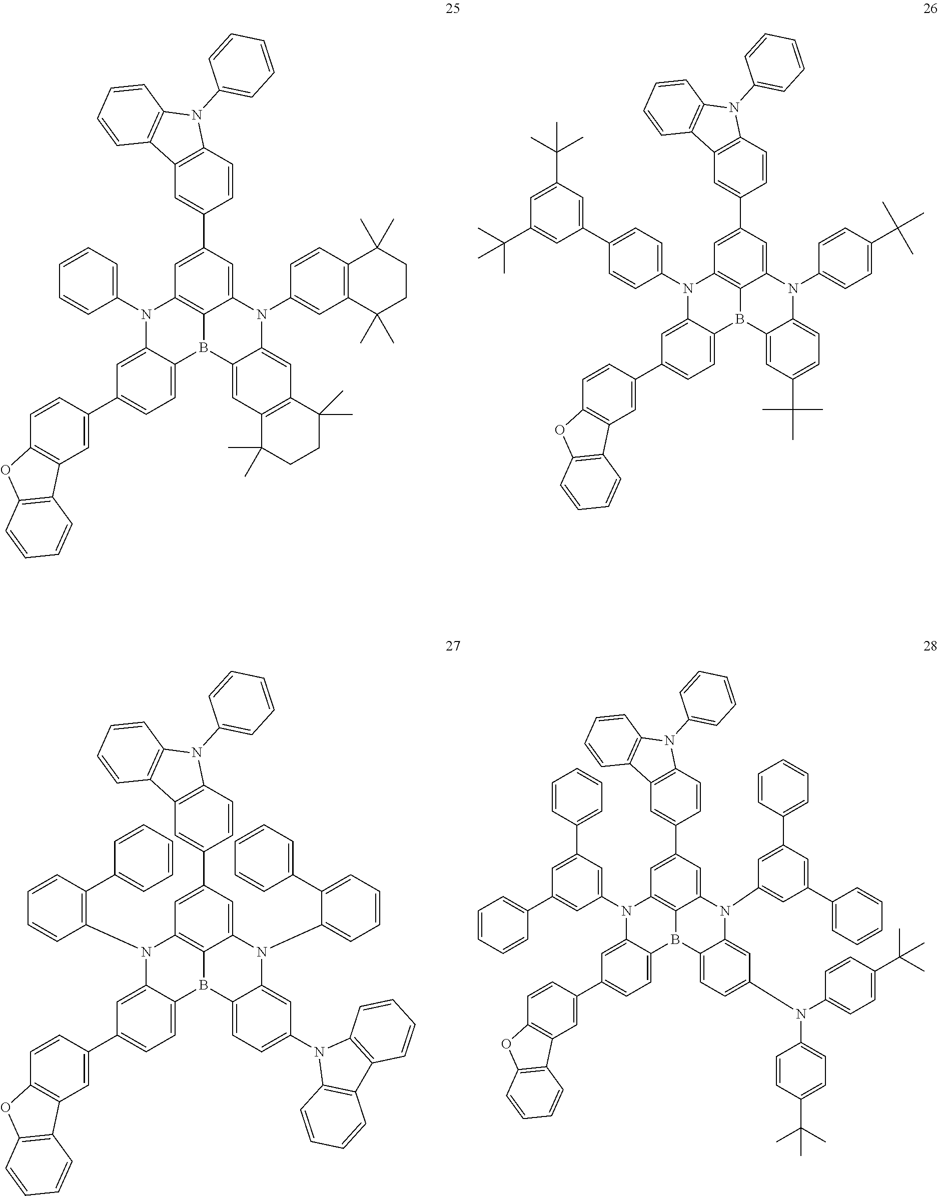

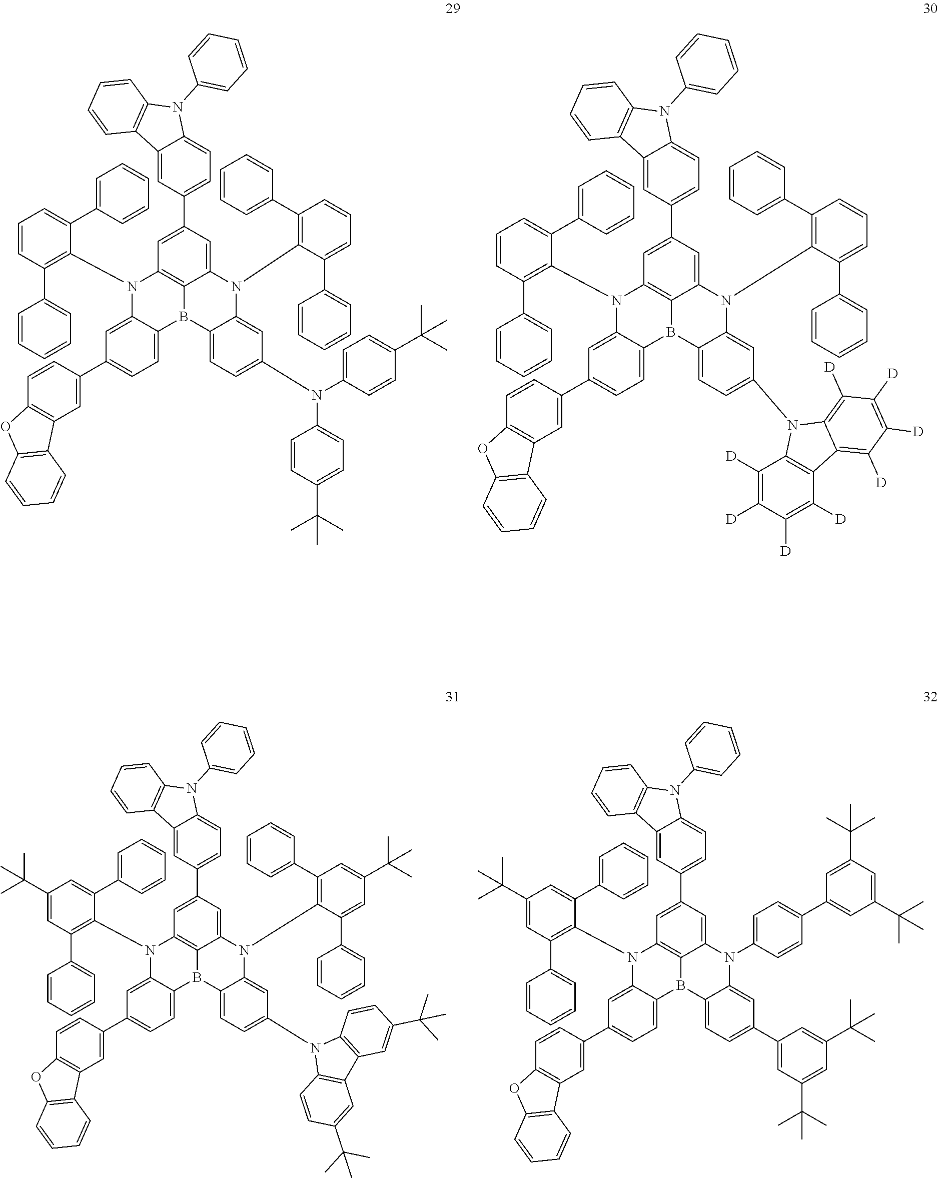

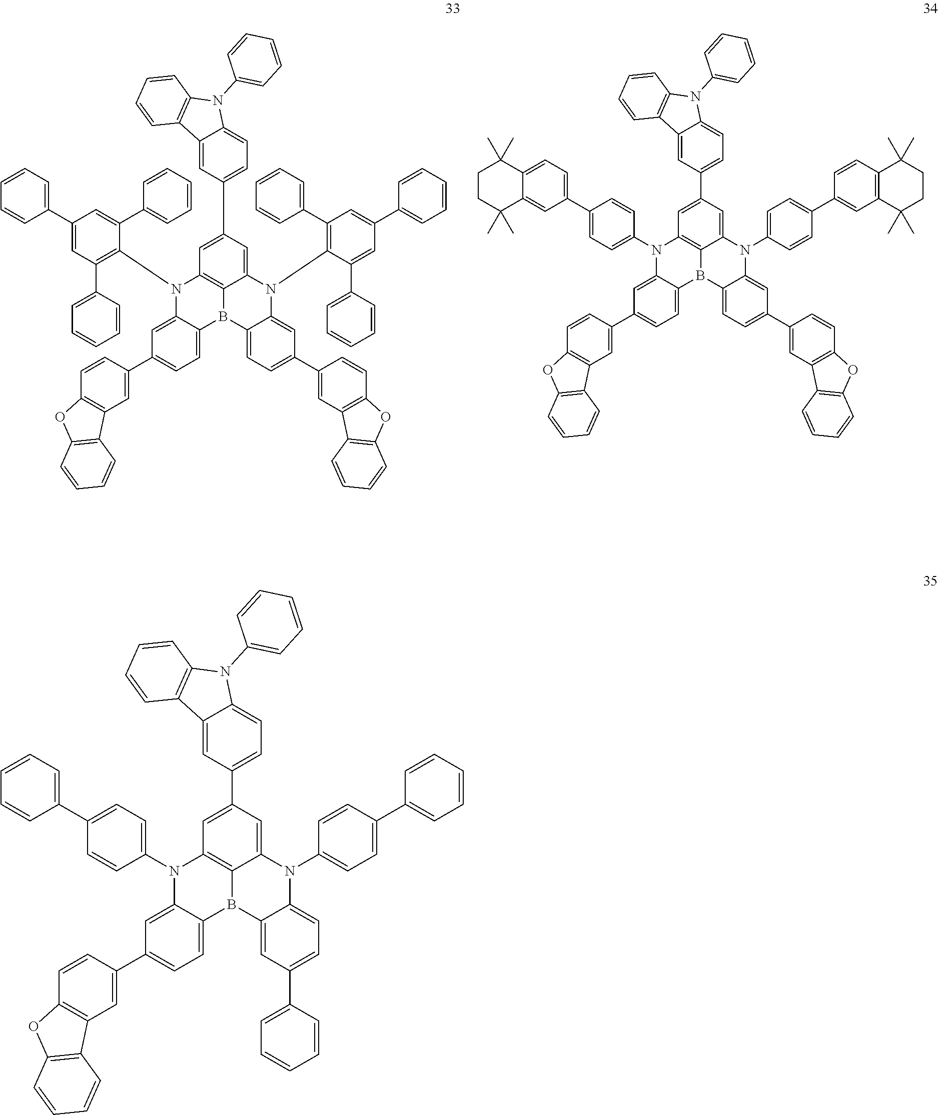

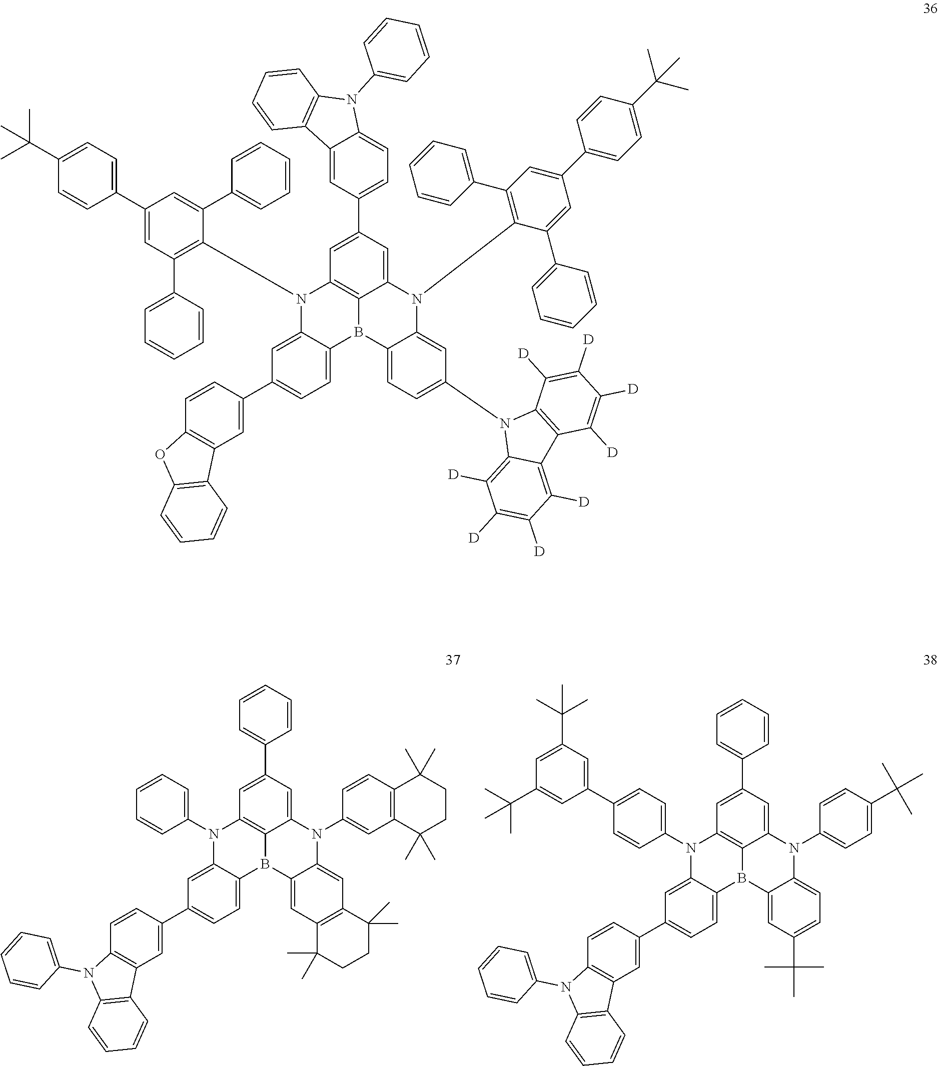

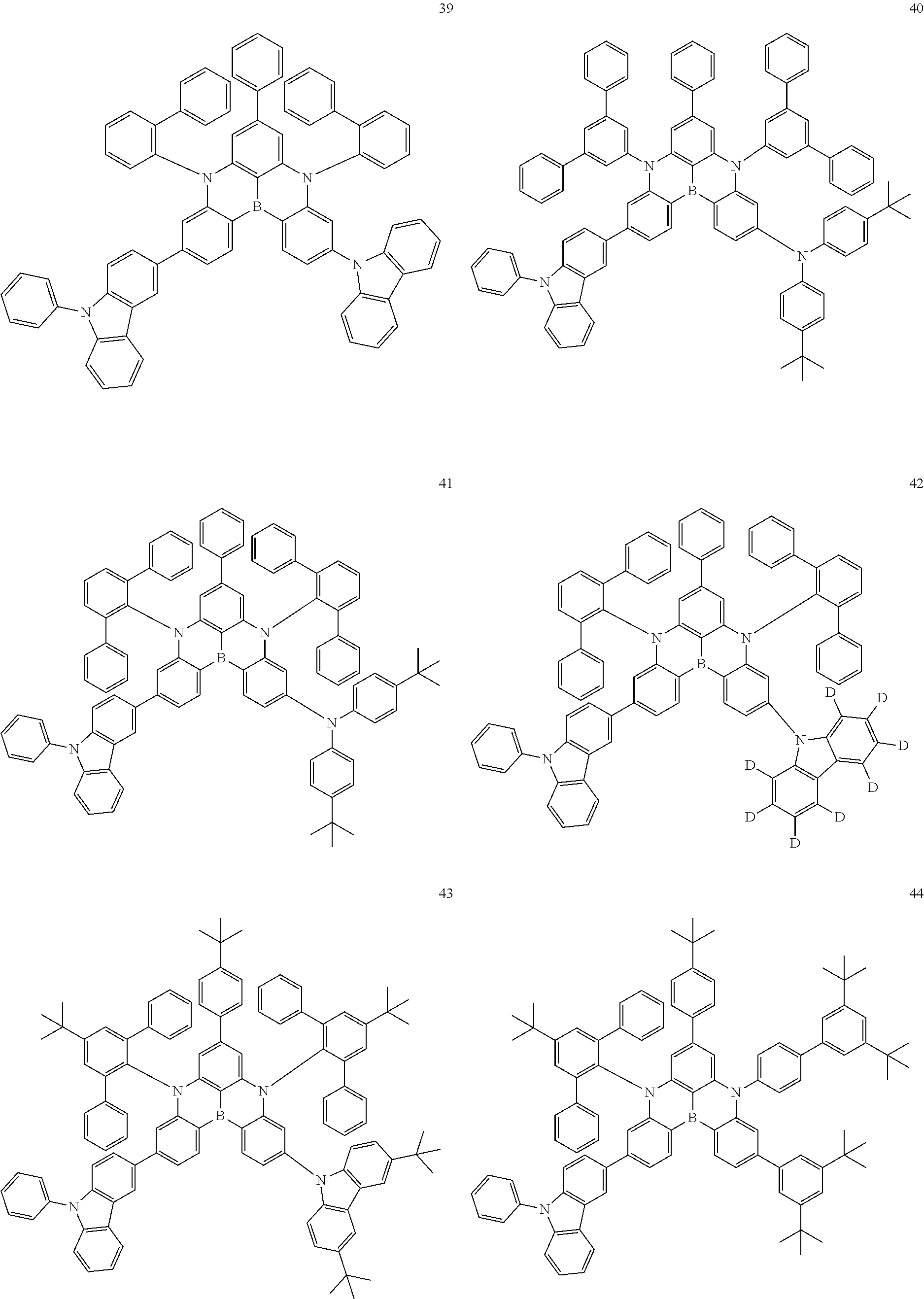

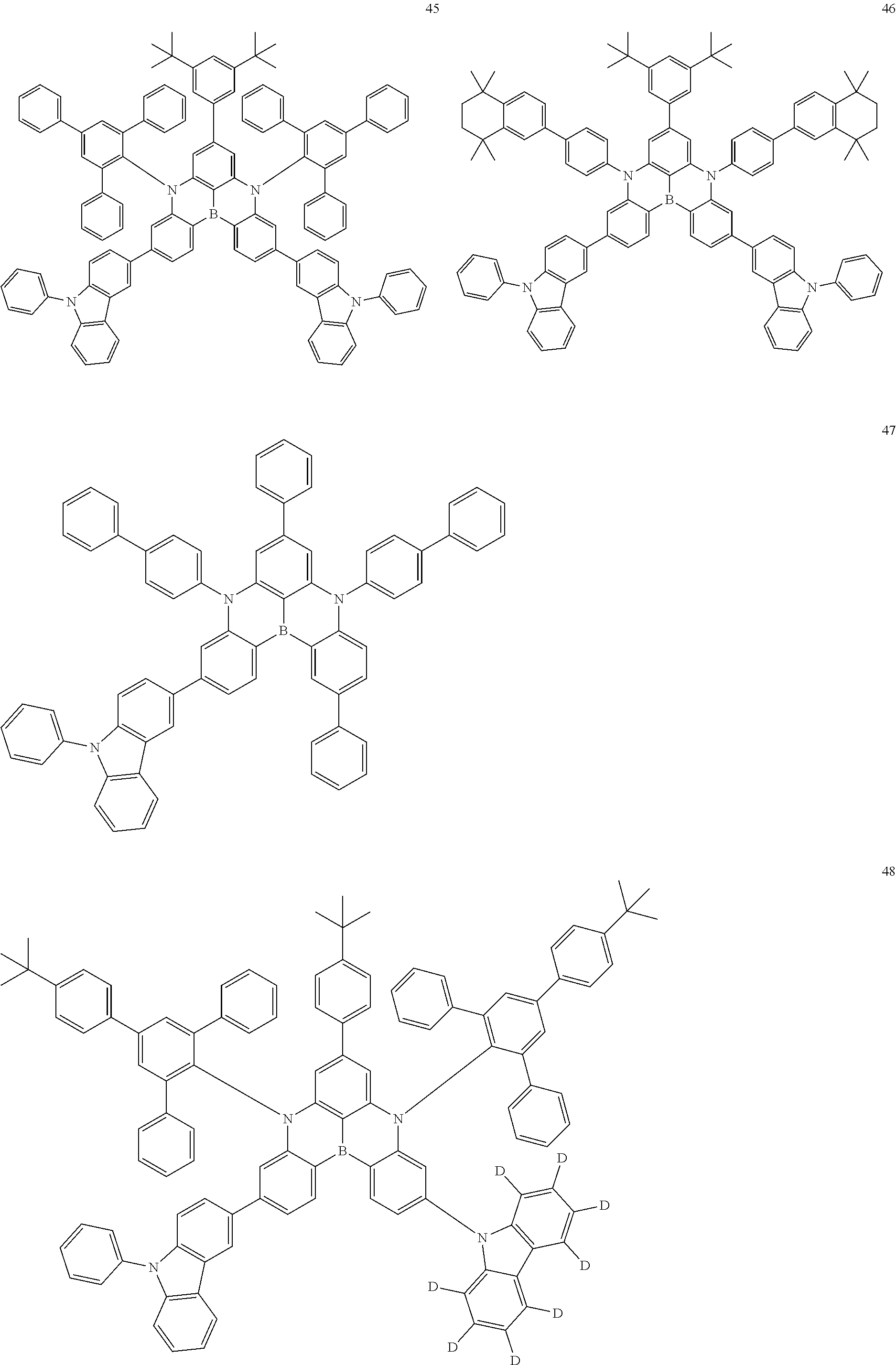

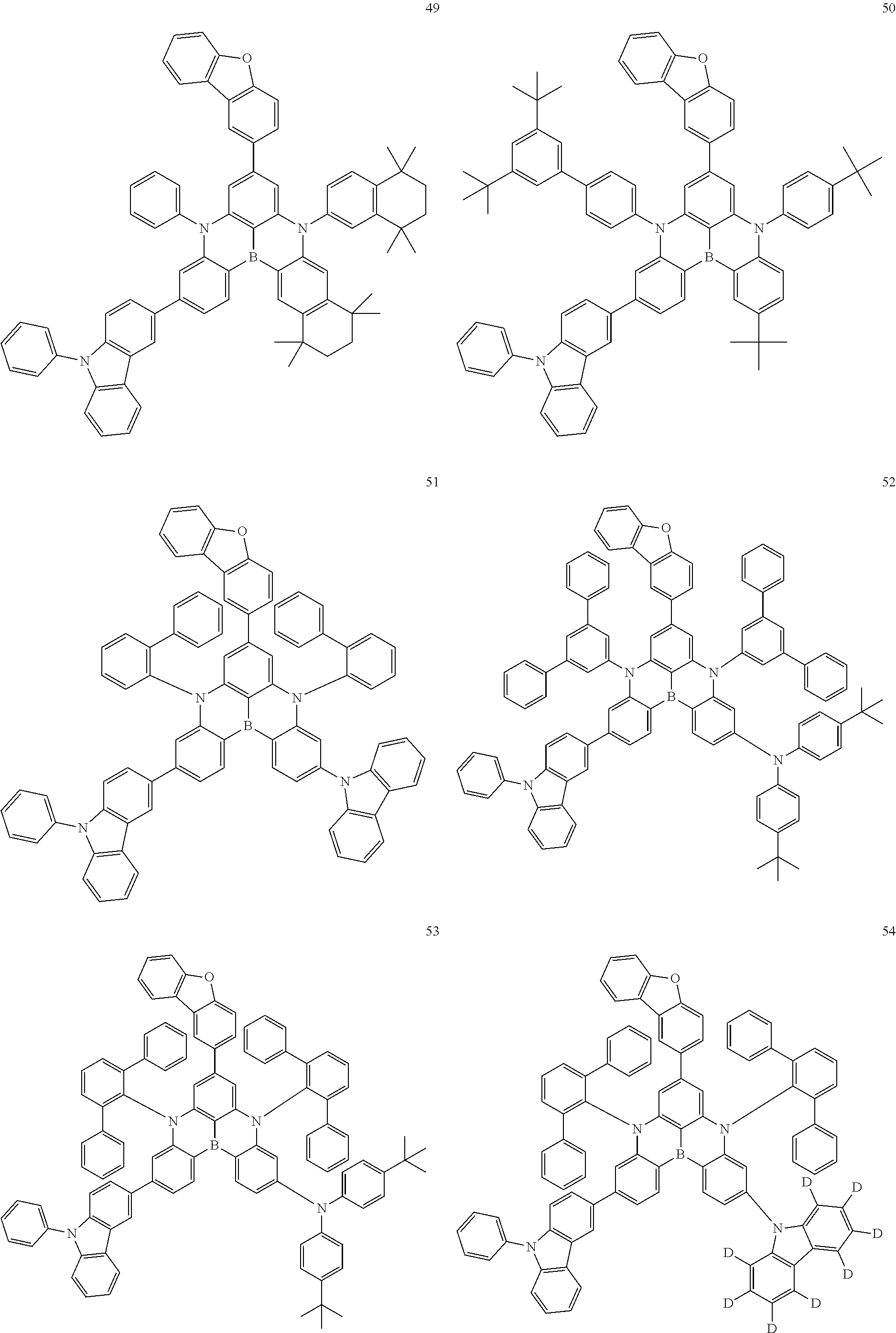

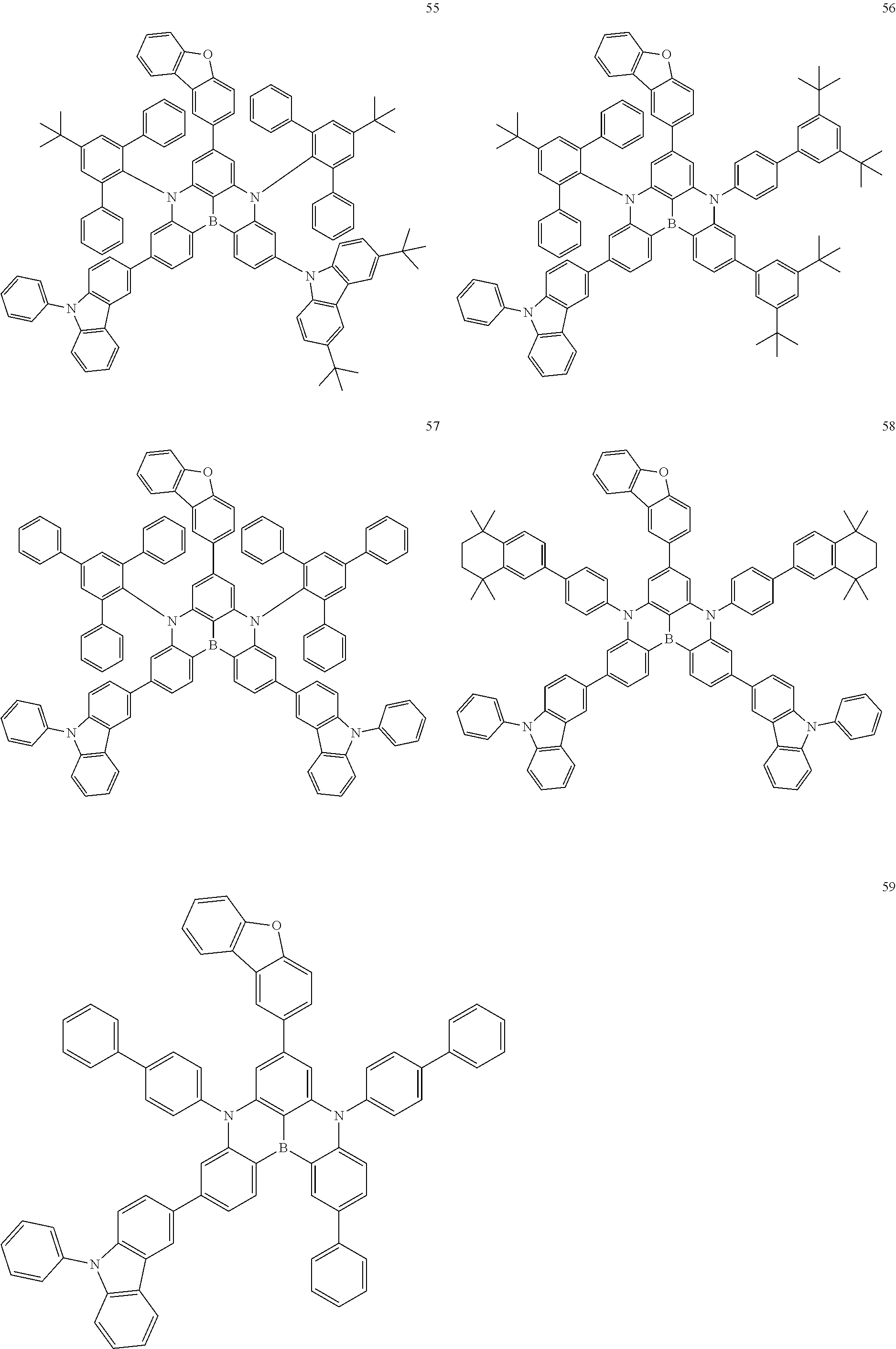

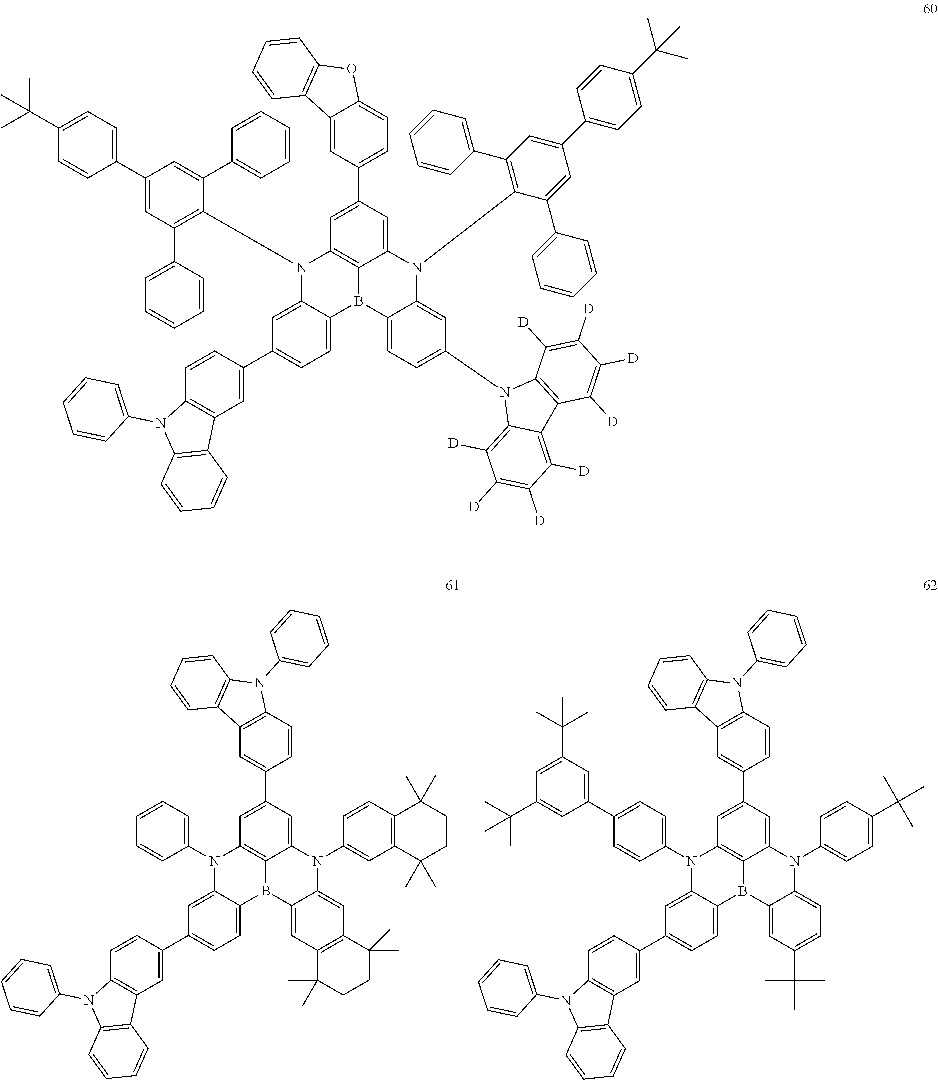

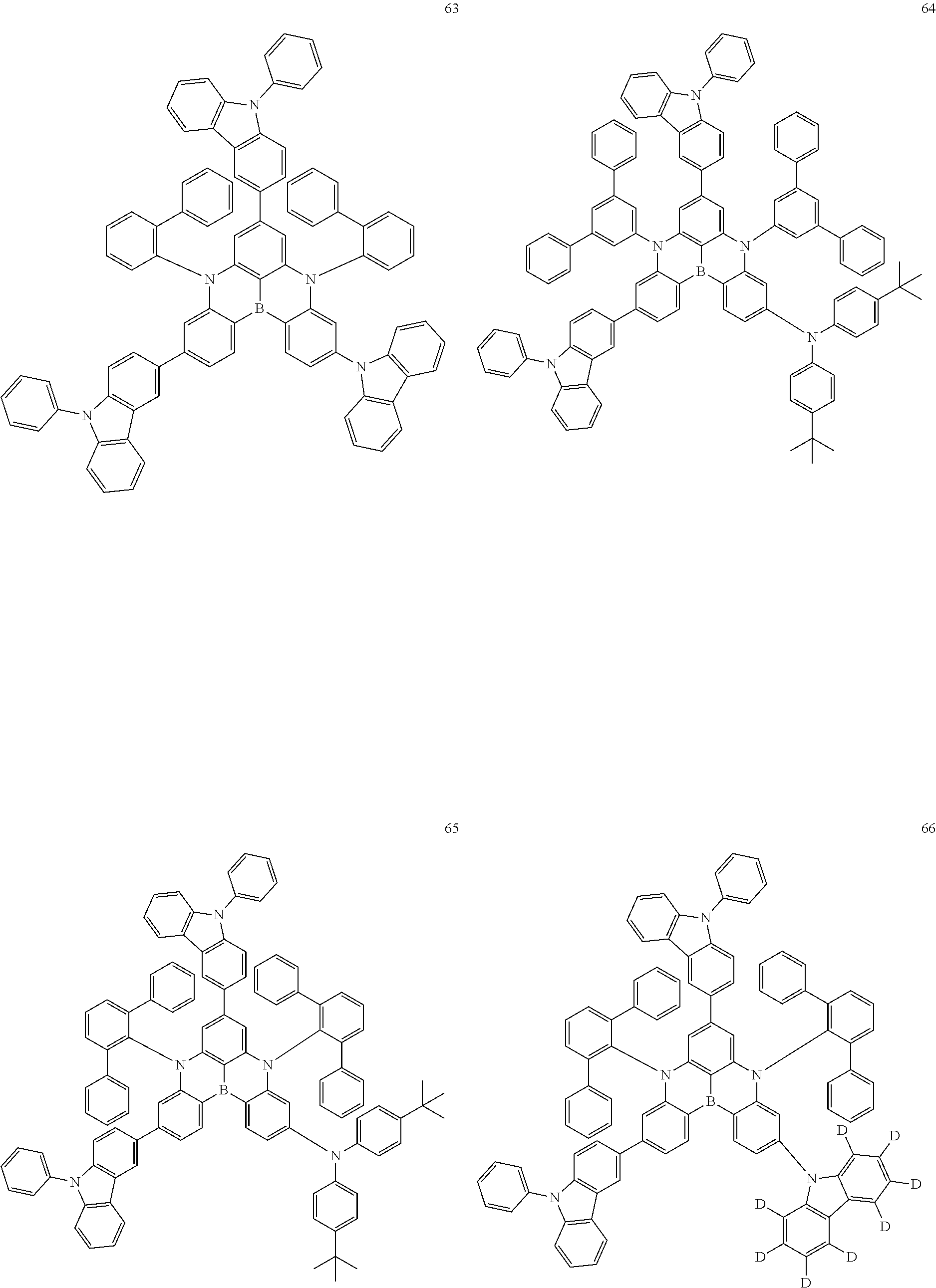

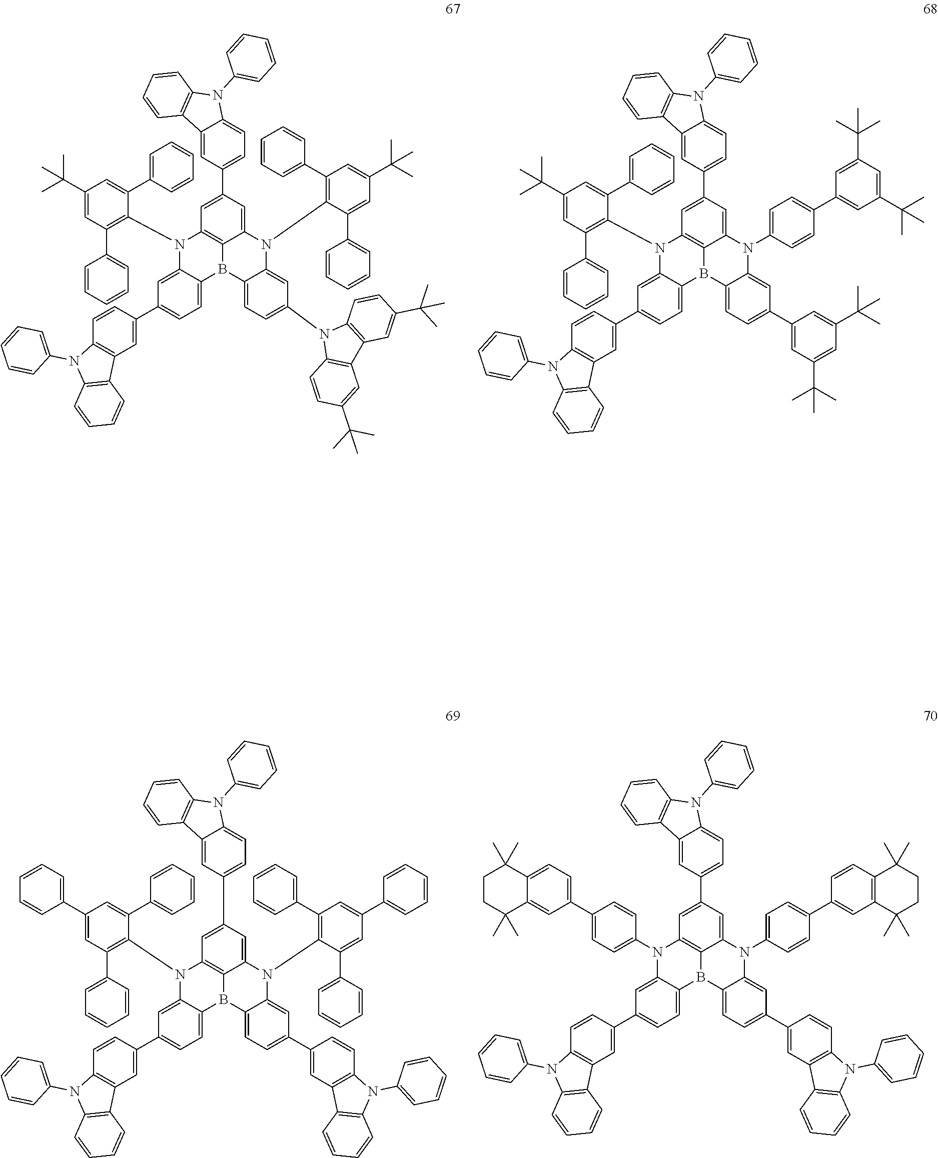

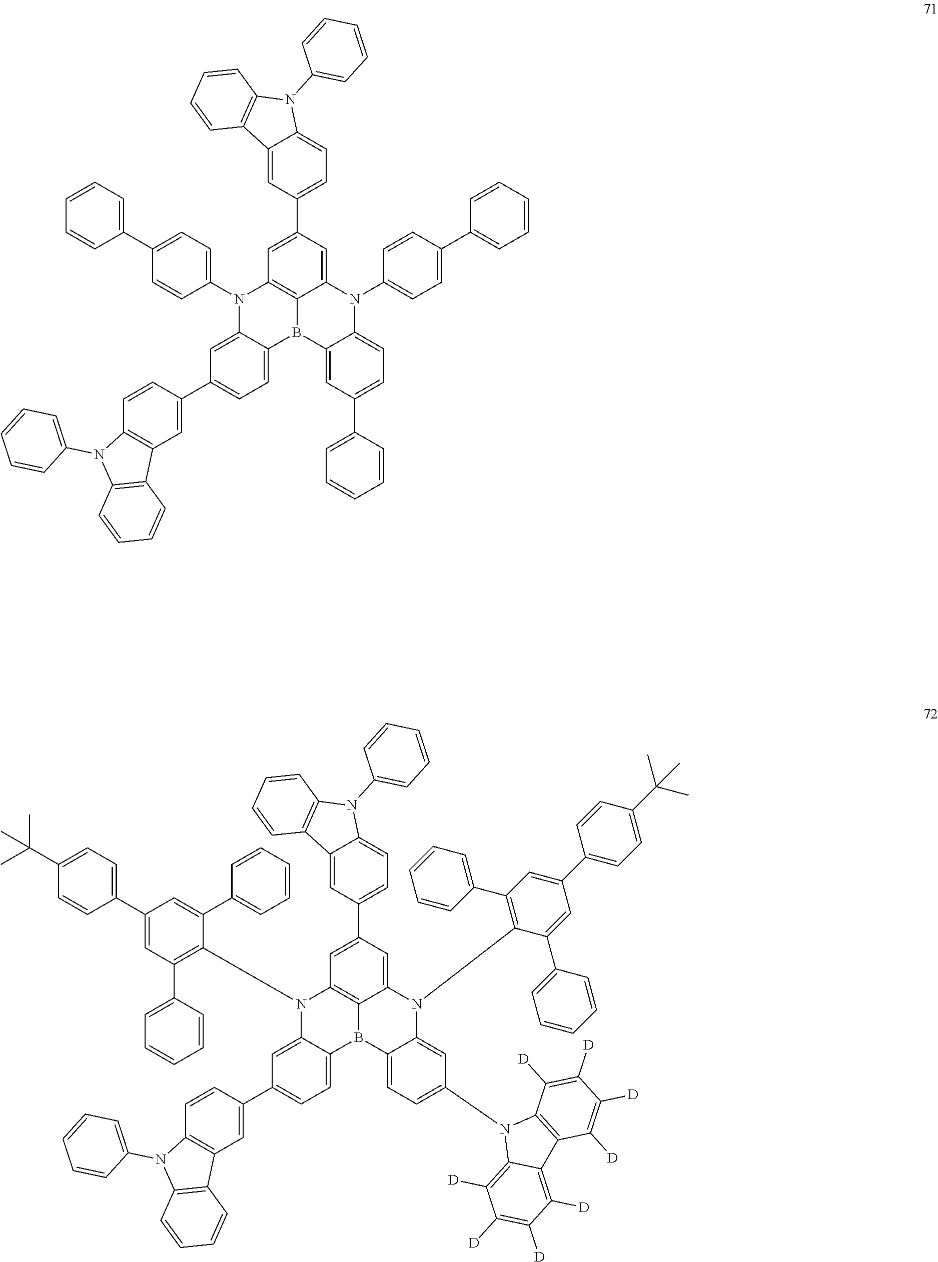 [SMILES: c1ccc(-c2ccc(N3c4ccc(-c5ccccc5)cc4B4c5ccc(-c6ccc7c(c6)c6ccccc6n7-c6ccccc6)cc5N(c5ccc(-c6ccccc6)cc5)c5cc(-c6ccc7c(c6)c6ccccc6n7-c6ccccc6)cc3c54)cc2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4c(c3)c3ccccc3n4-c3ccccc3)cc3c1B2c1ccc(-c2ccc4c(c2)c2ccccc2n4-c2ccccc2)cc1N3c1c(-c2ccccc2)cc(-c2ccc(C(C)(C)C)cc2)cc1-c1ccccc1]

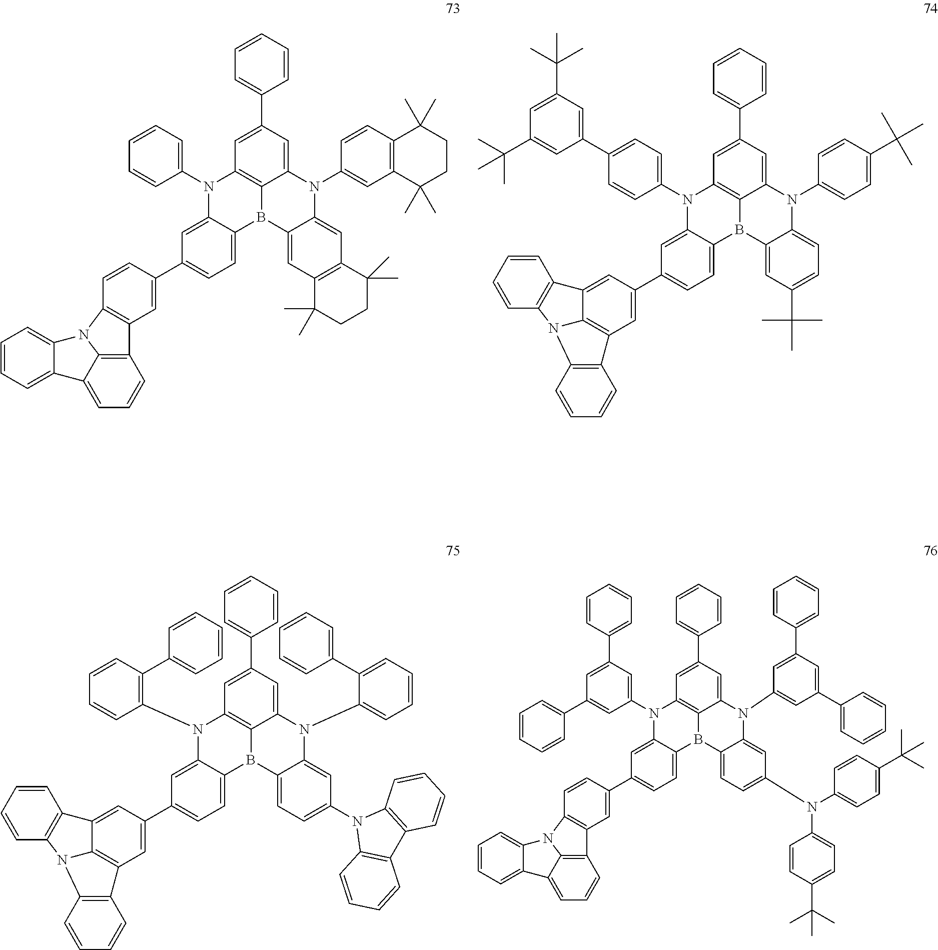

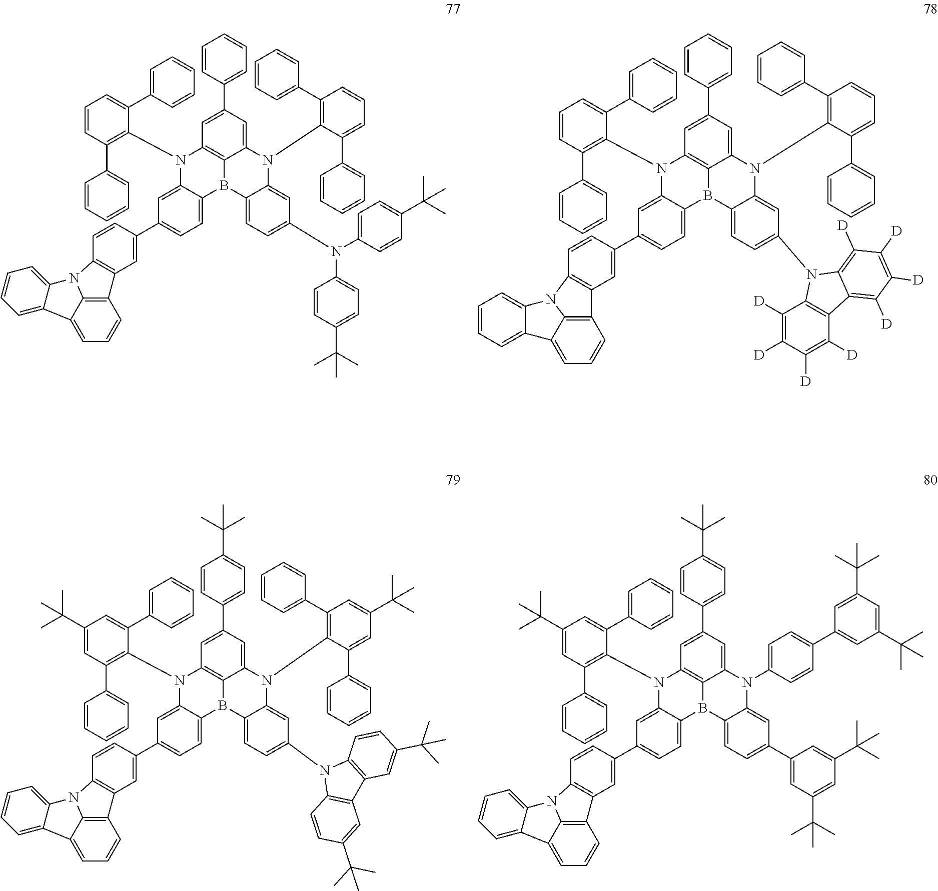

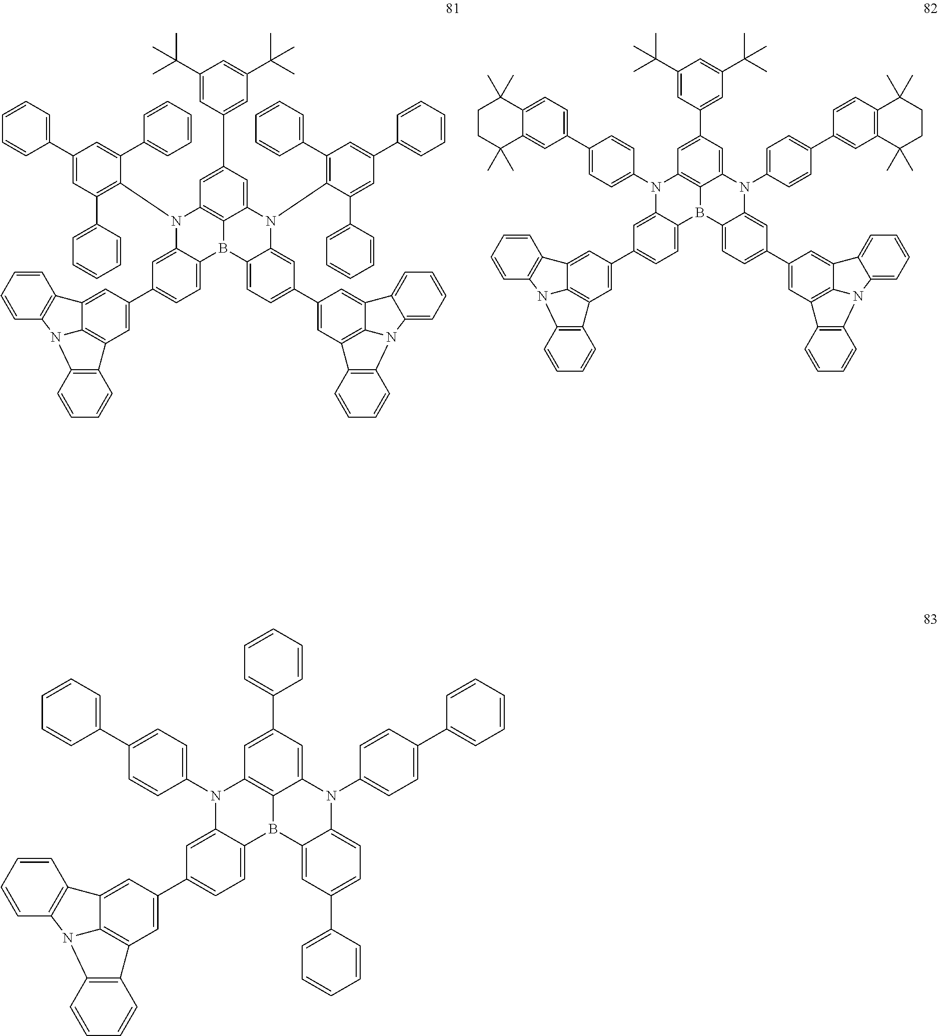

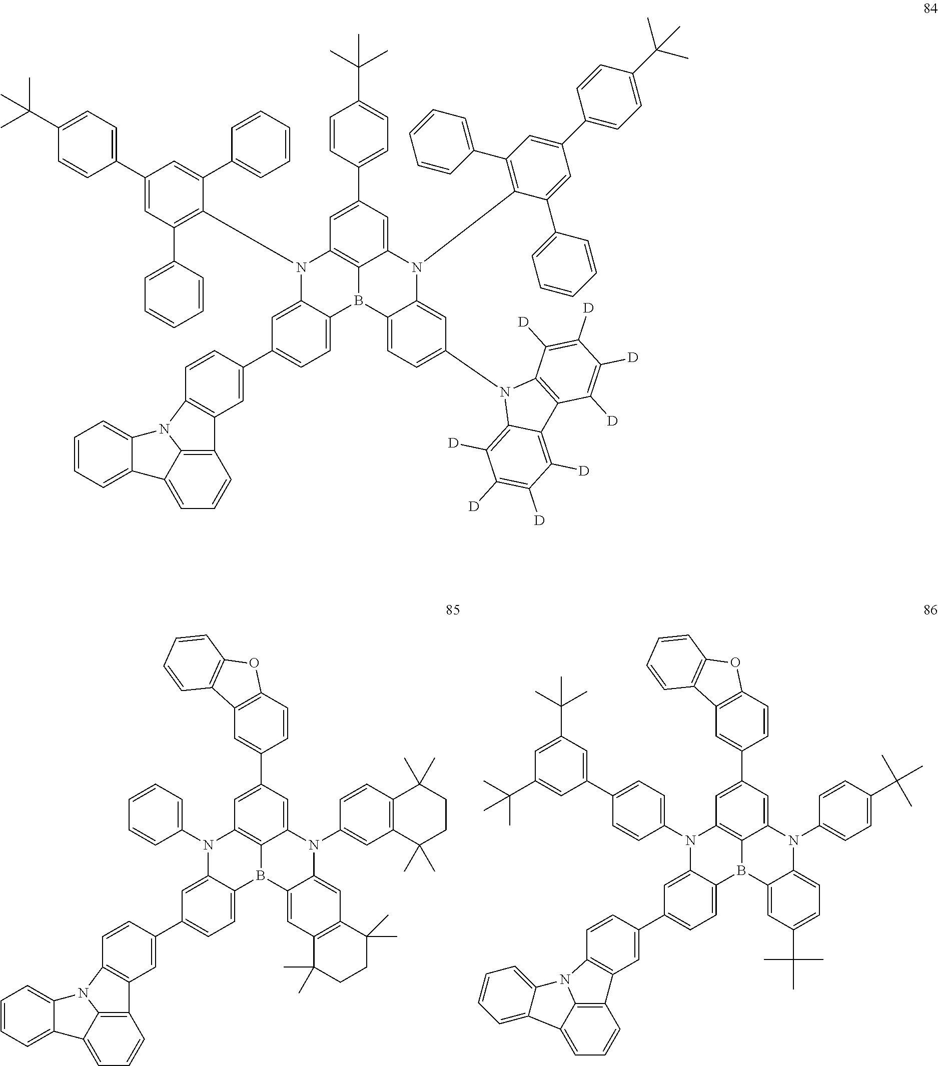

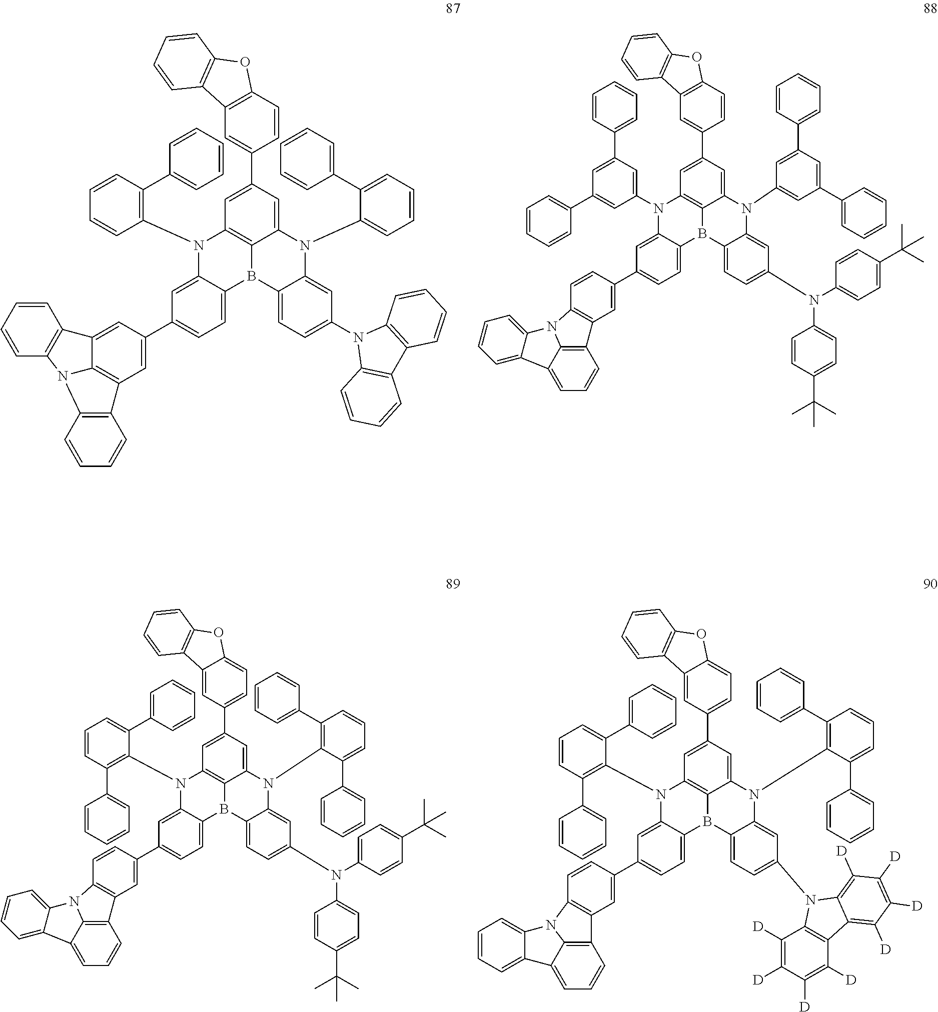

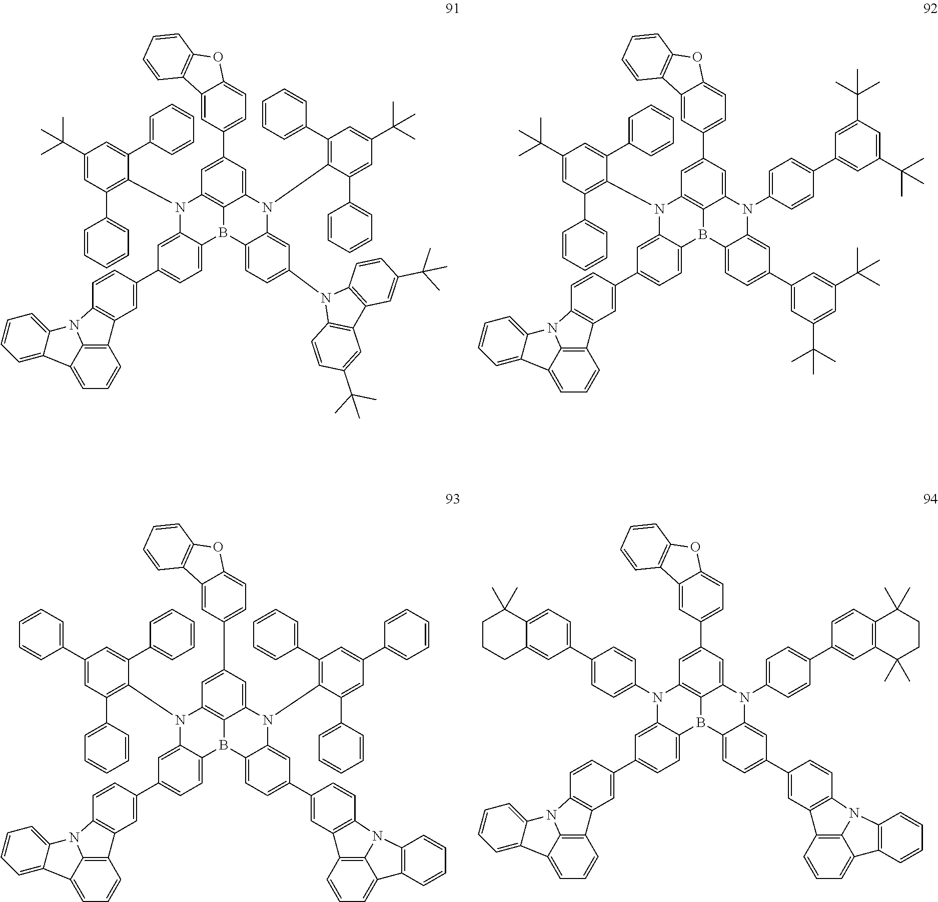

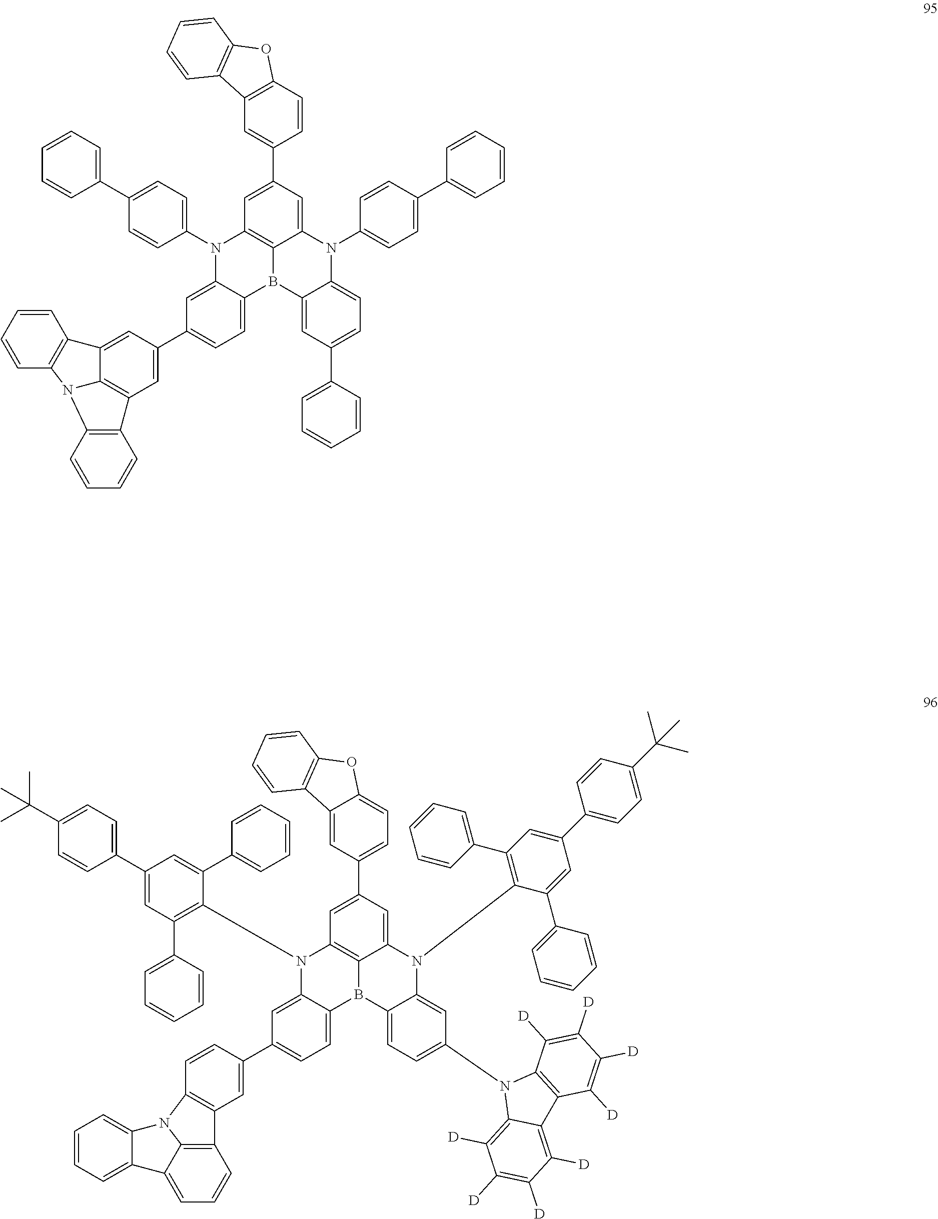 [SMILES: c1ccc(-c2ccc(N3c4ccc(-c5ccccc5)cc4B4c5ccc(-c6cc7c8ccccc8n8c9ccccc9c(c6)c78)cc5N(c5ccc(-c6ccccc6)cc5)c5cc(-c6ccc7oc8ccccc8c7c6)cc3c54)cc2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4oc5ccccc5c4c3)cc3c1B2c1ccc(-c2ccc4c(c2)c2cccc5c6ccccc6n4c52)cc1N3c1c(-c2ccccc2)cc(-c2ccc(C(C)(C)C)cc2)cc1-c1ccccc1]

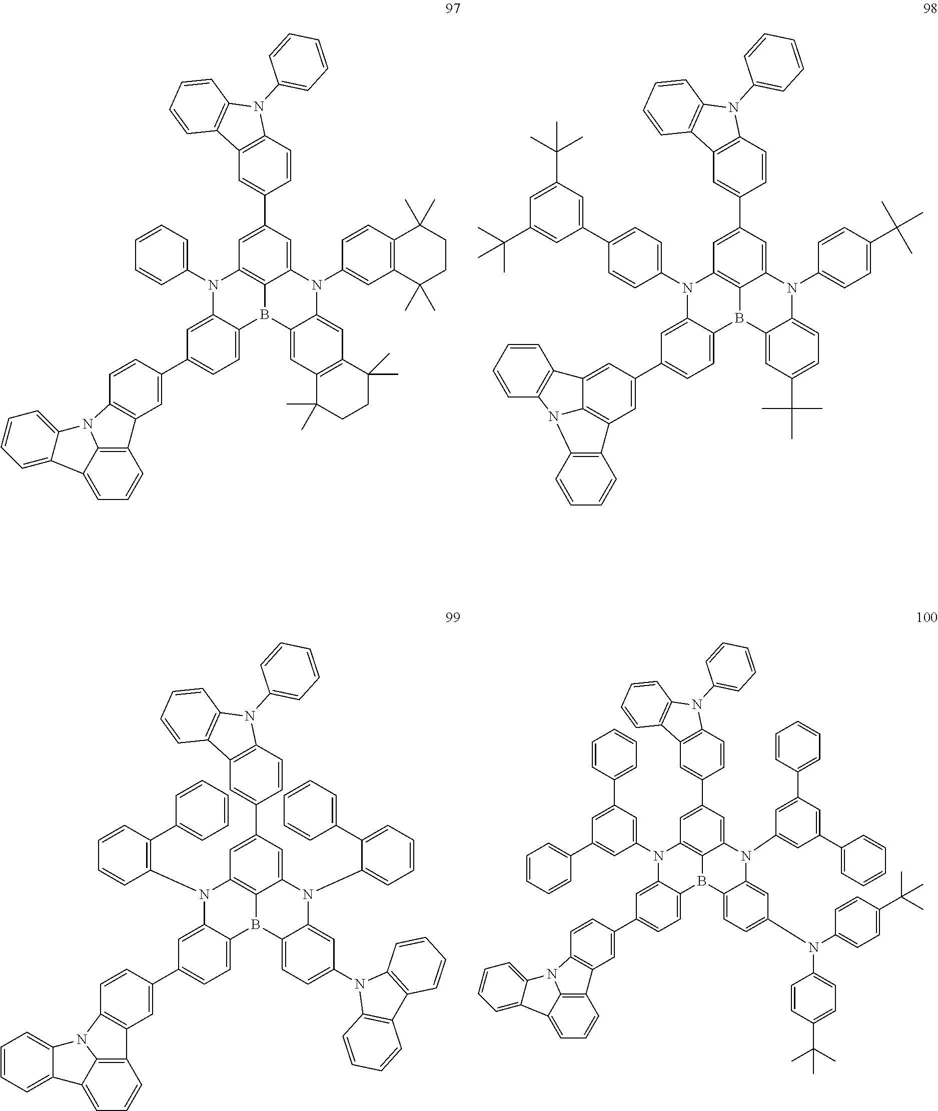

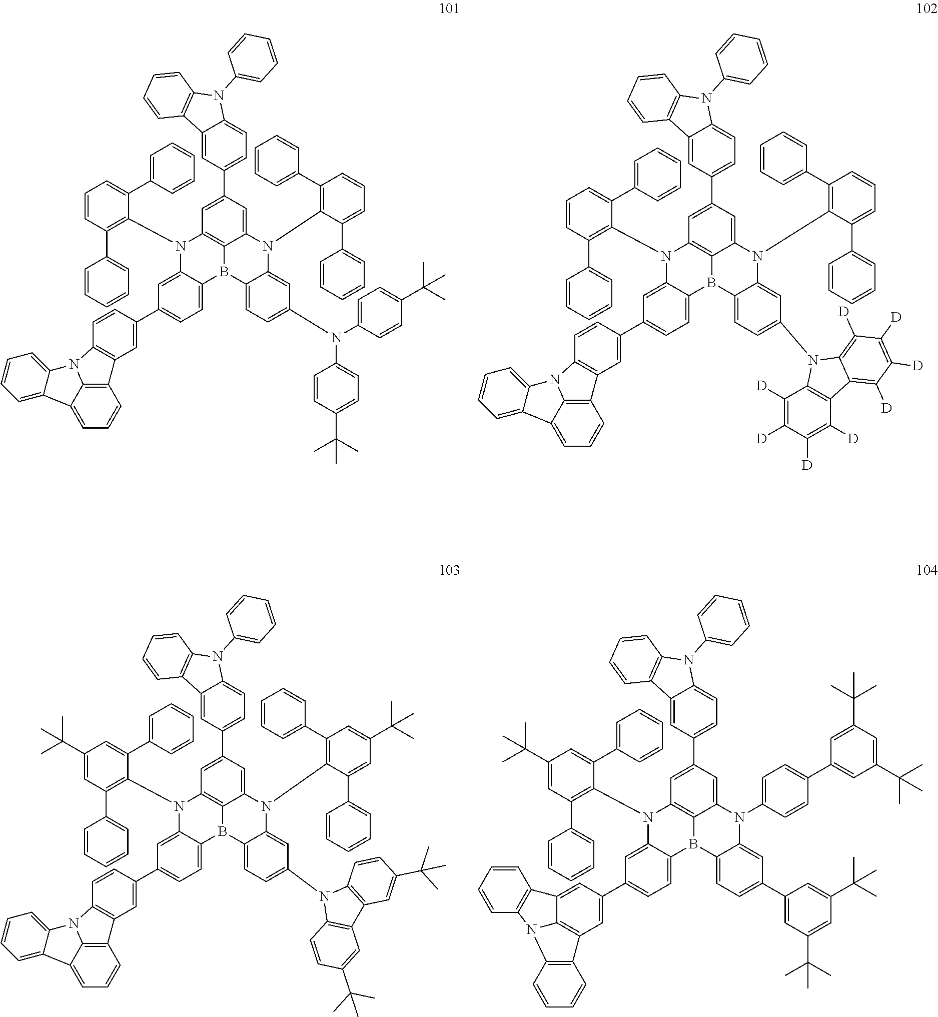

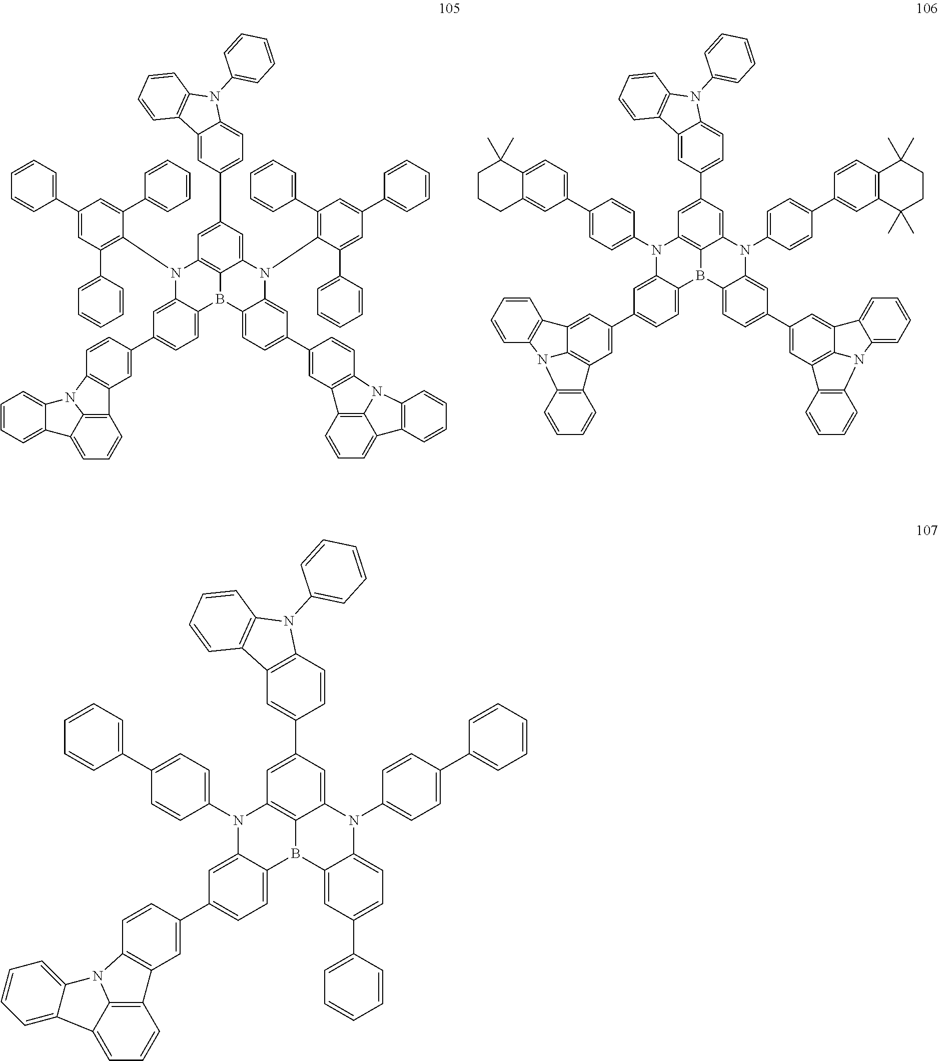

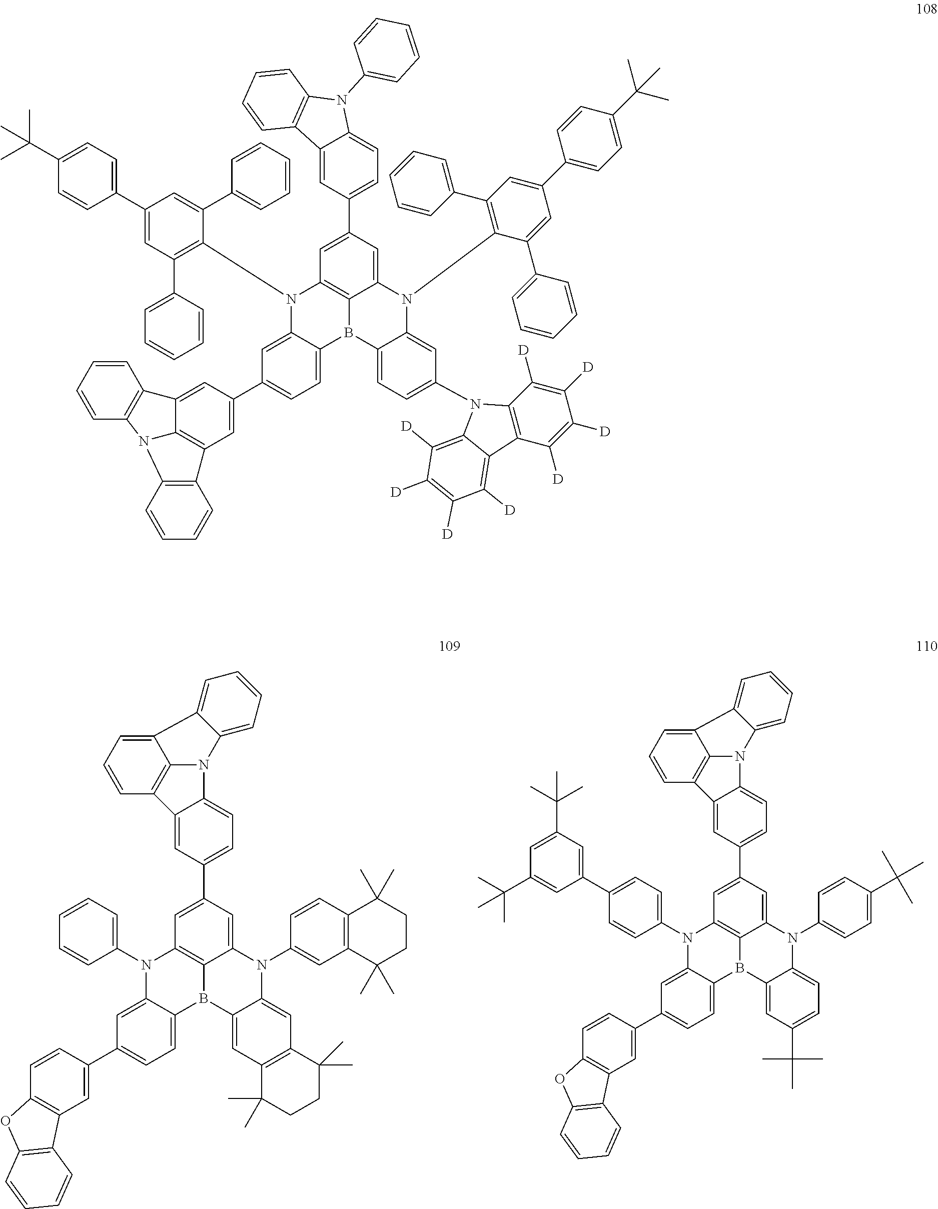

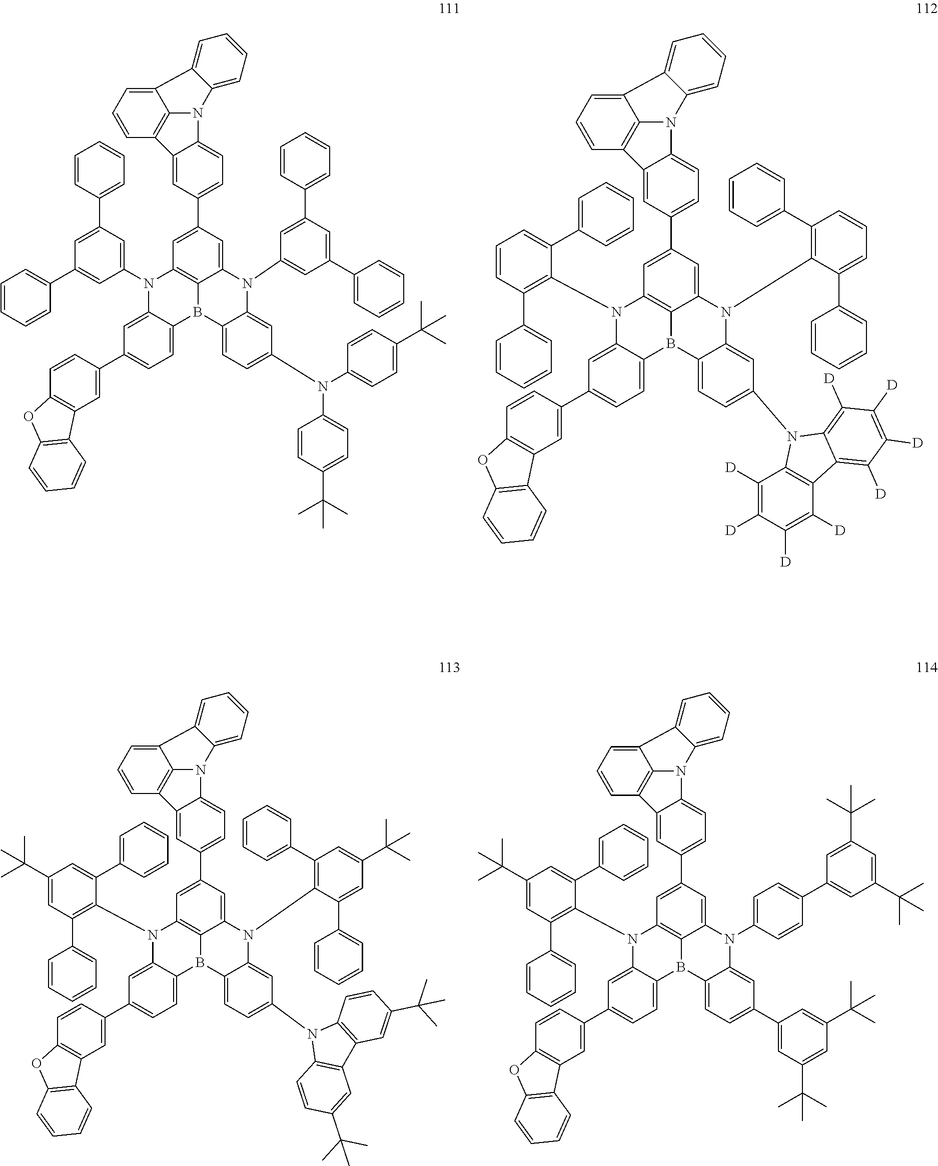

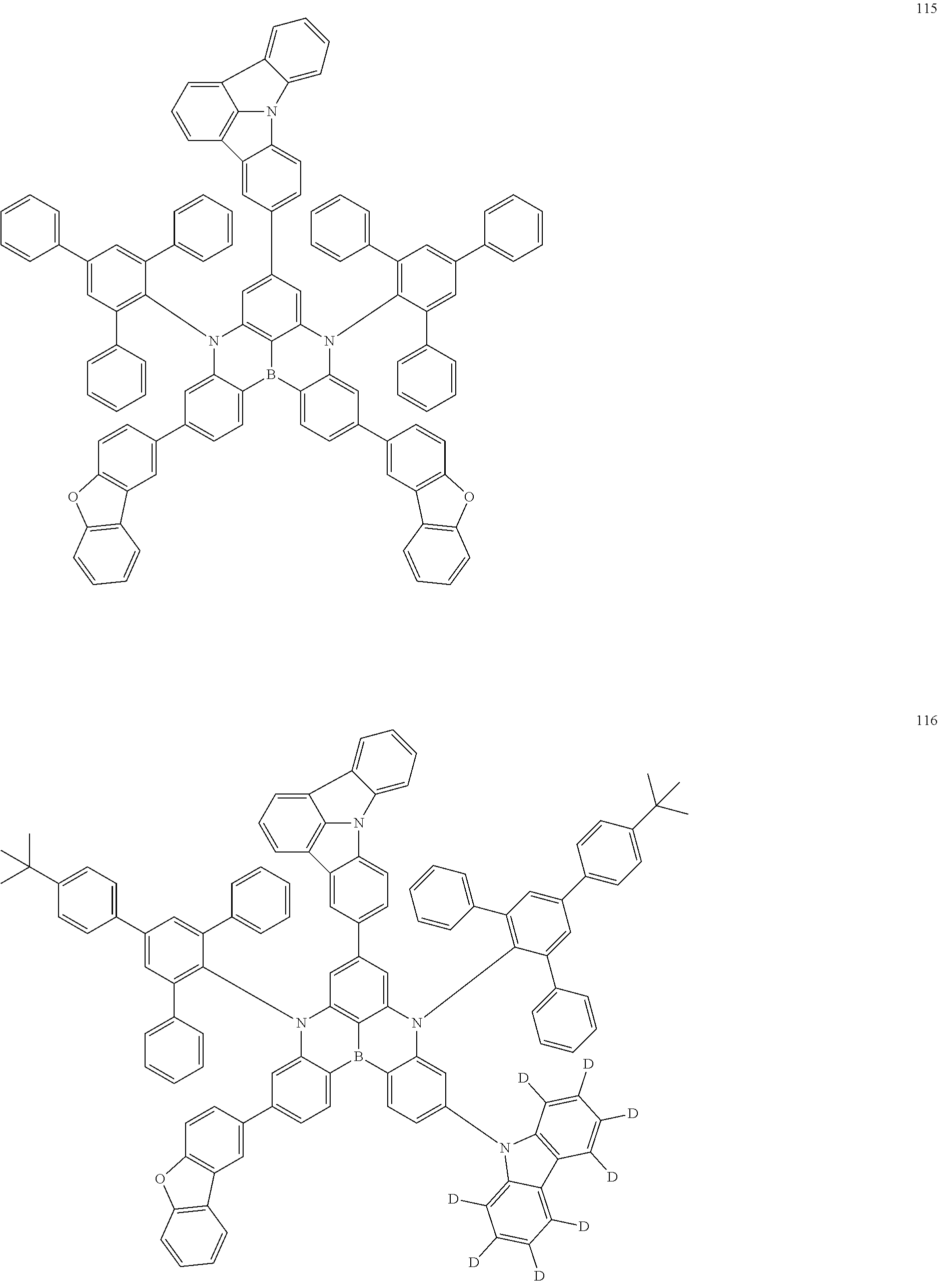 [SMILES: c1ccc(-c2cc(-c3ccccc3)c(N3c4cc(-c5ccc6oc7ccccc7c6c5)ccc4B4c5ccc(-c6ccc7oc8ccccc8c7c6)cc5N(c5c(-c6ccccc6)cc(-c6ccccc6)cc5-c5ccccc5)c5cc(-c6ccc7c(c6)c6cccc8c9ccccc9n7c86)cc3c54)c(-c3ccccc3)c2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4c(c3)c3cccc5c6ccccc6n4c53)cc3c1B2c1ccc(-c2ccc4oc5ccccc5c4c2)cc1N3c1c(-c2ccccc2)cc(-c2ccc(C(C)(C)C)cc2)cc1-c1ccccc1]

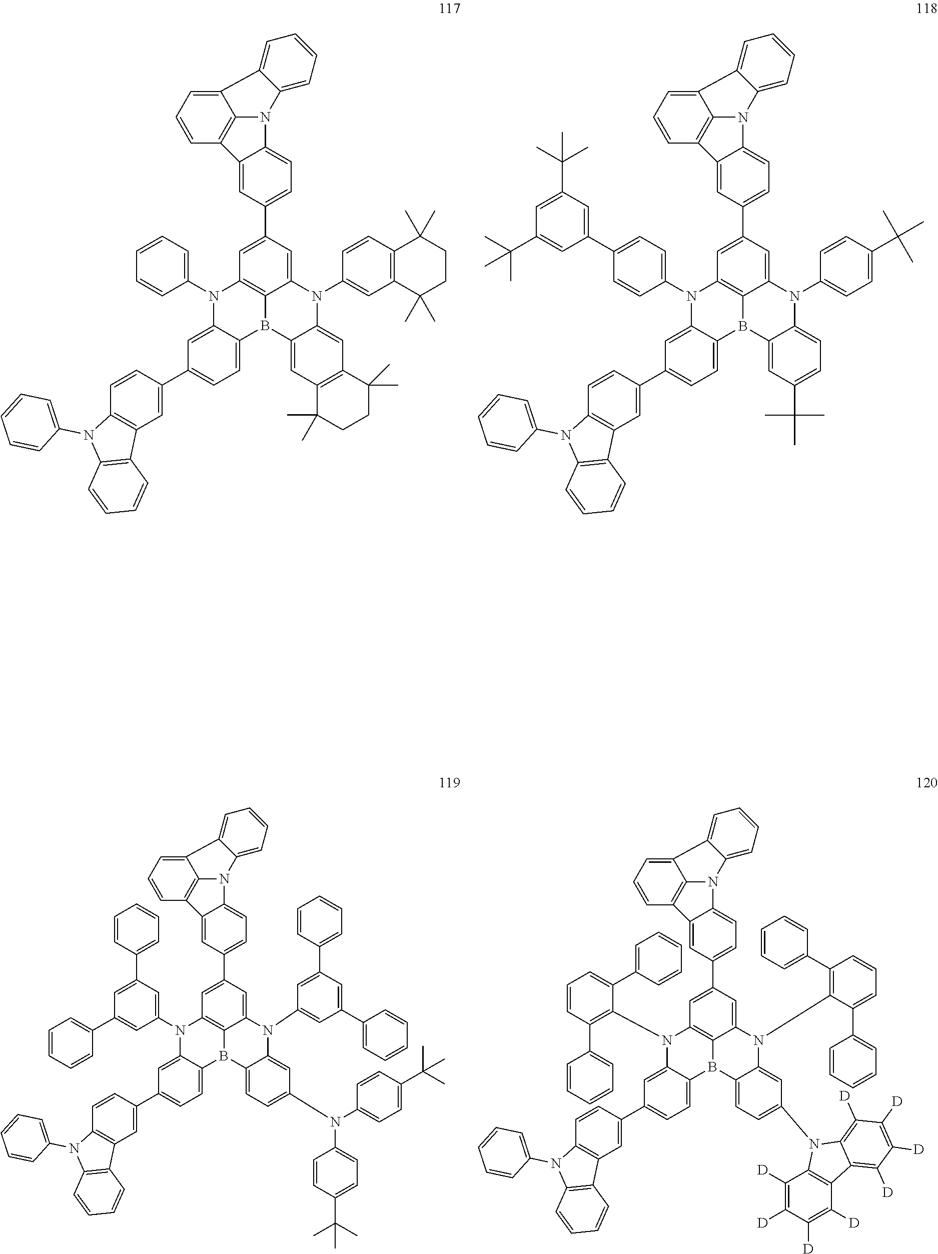

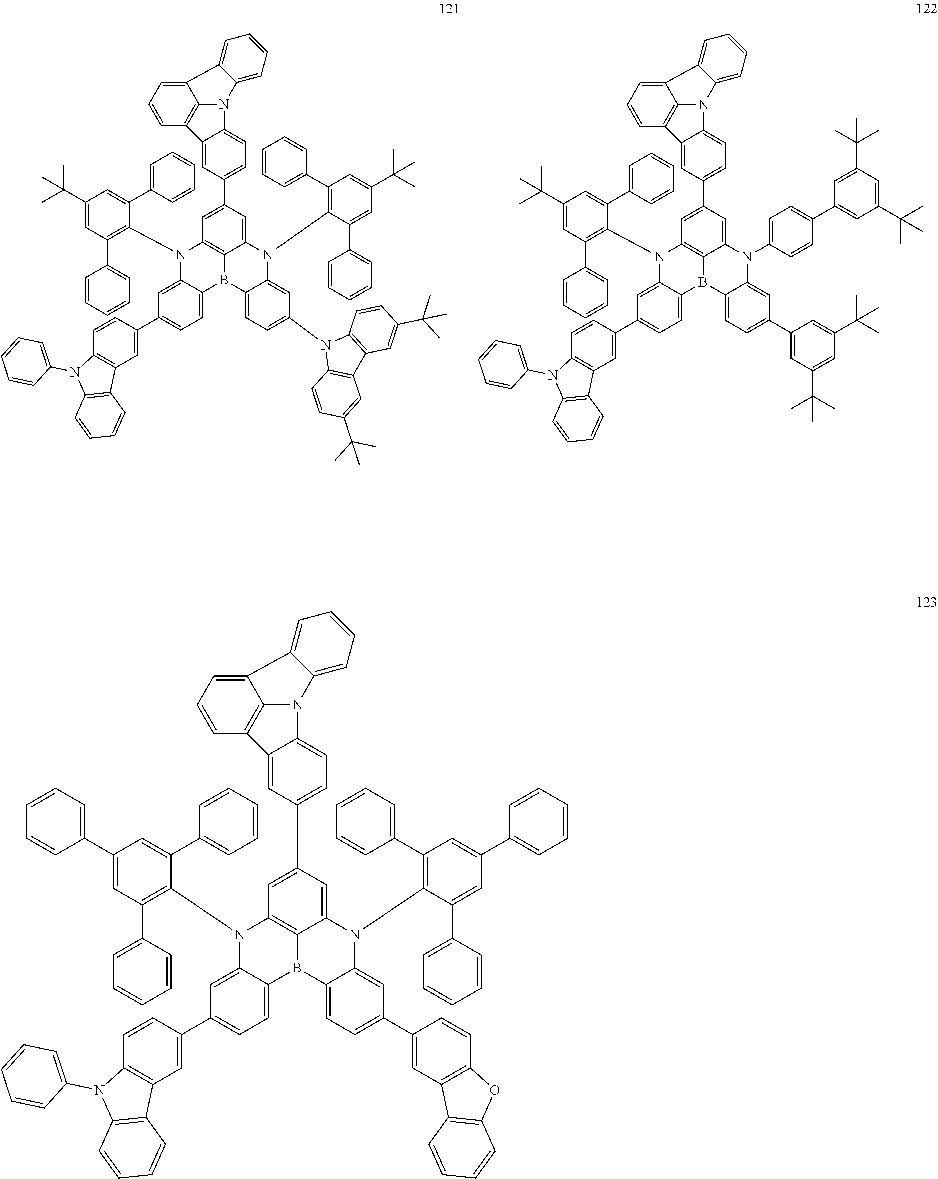

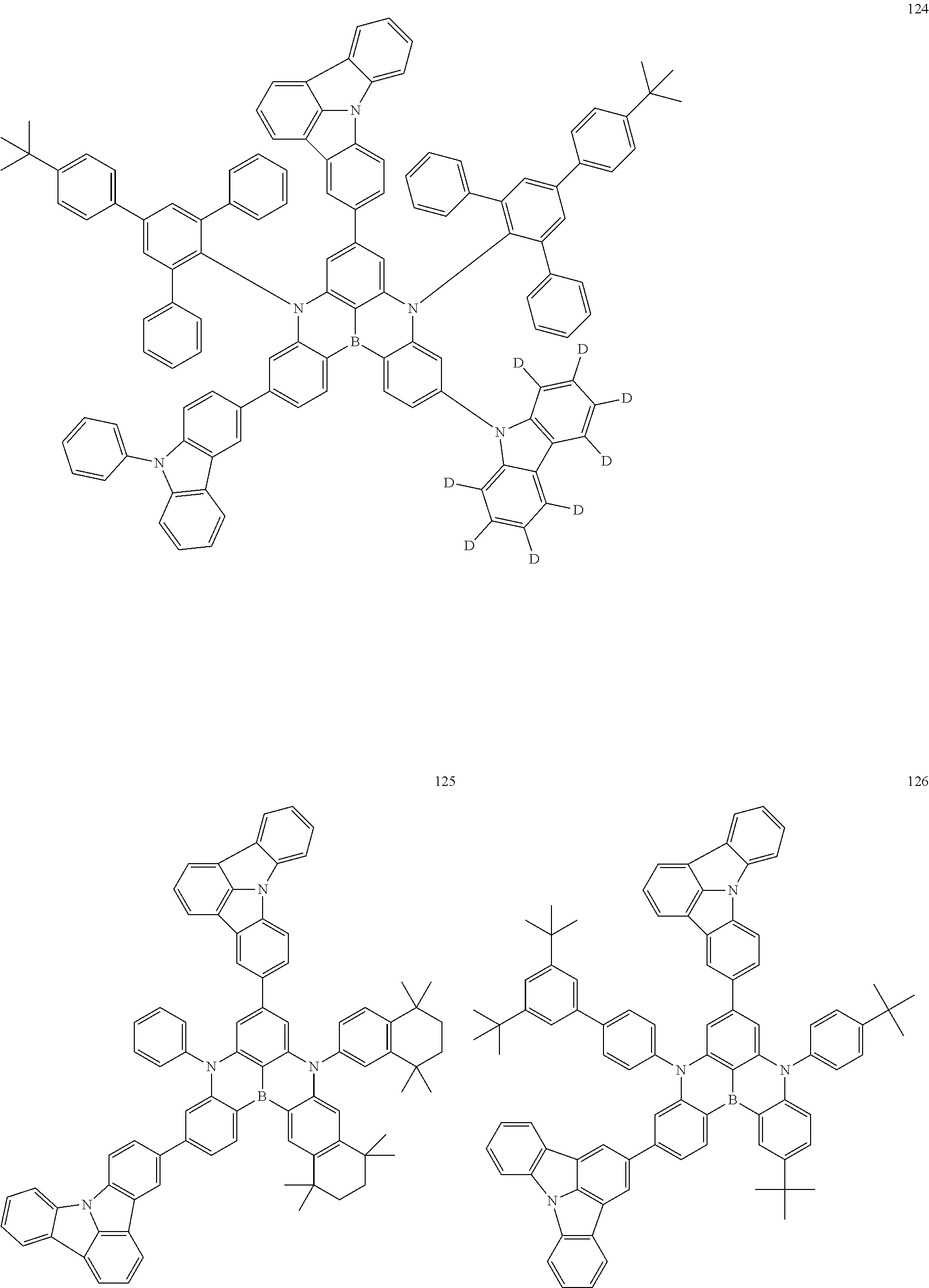

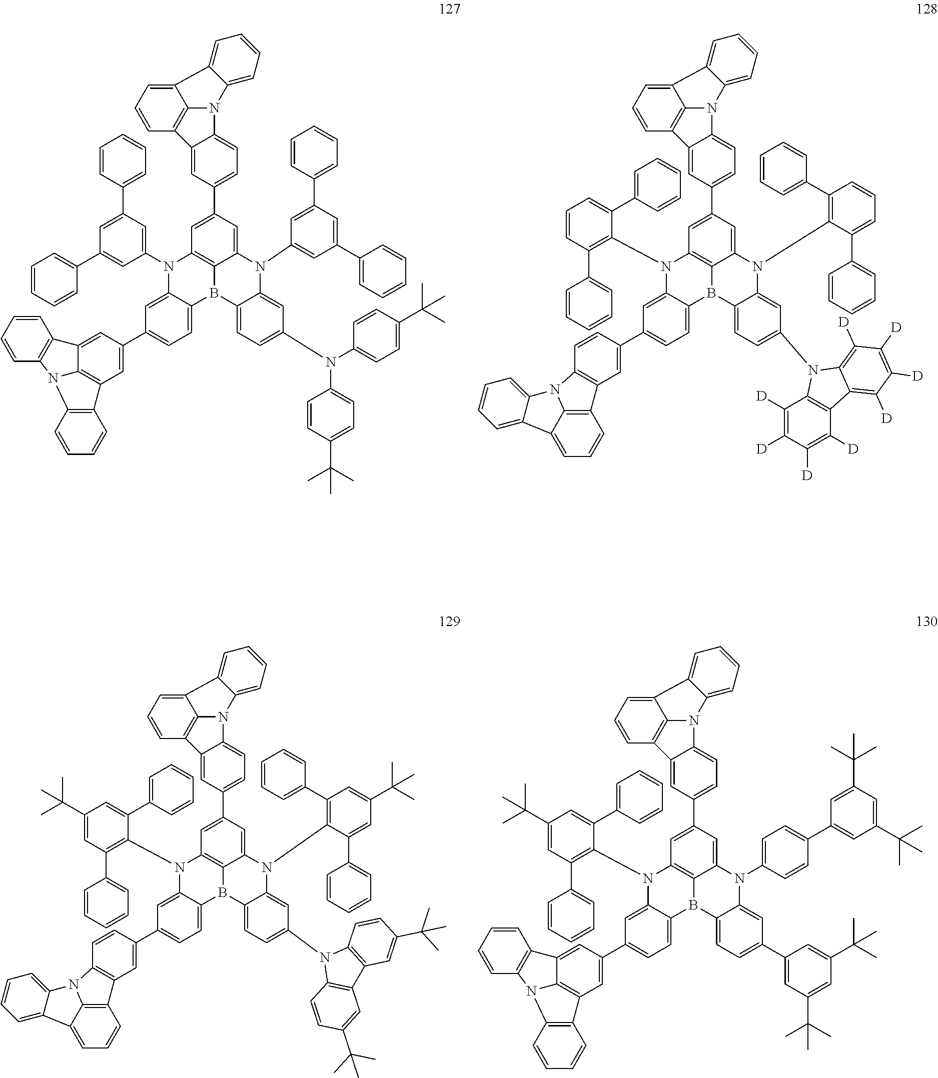

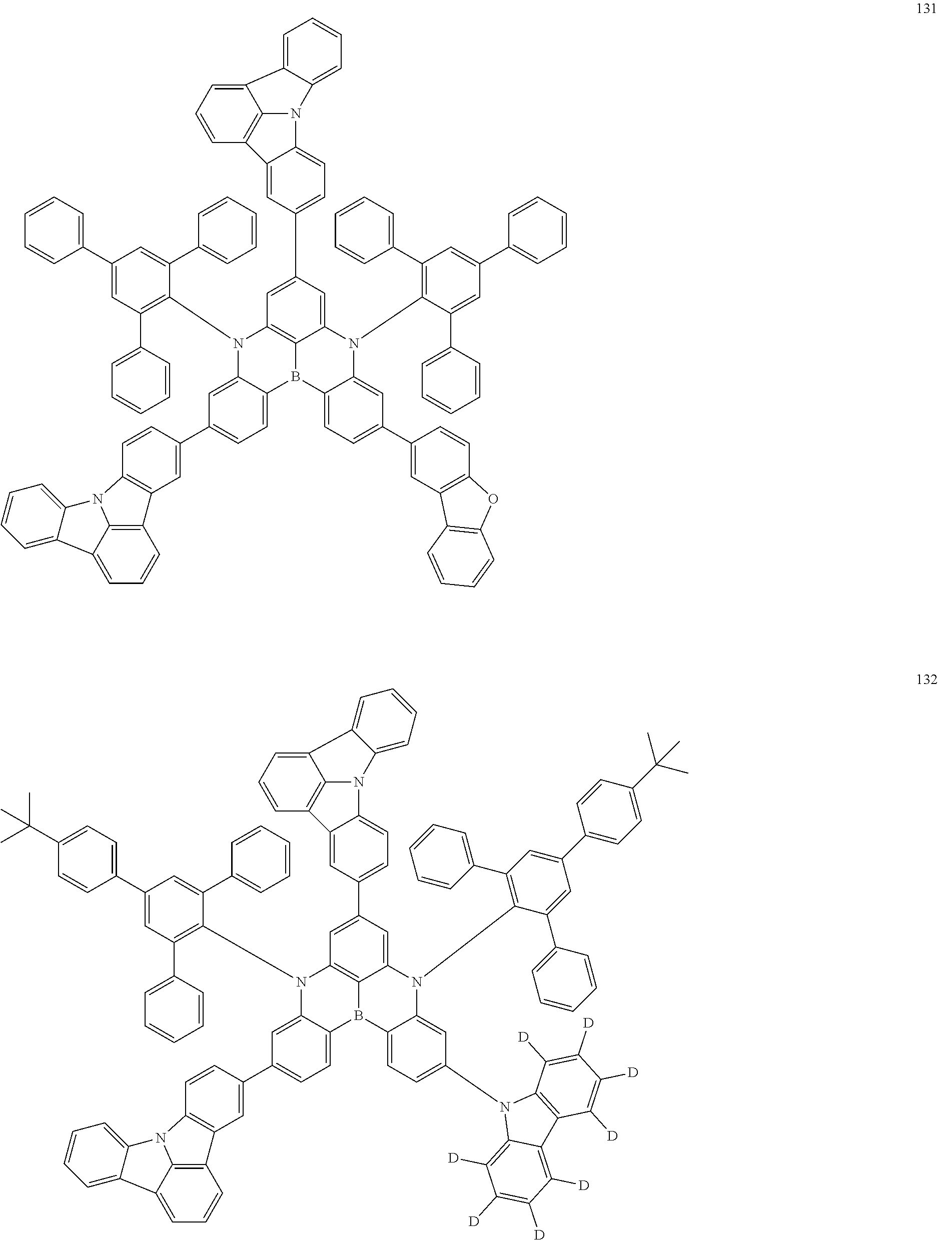 [SMILES: c1ccc(-c2cc(-c3ccccc3)c(N3c4cc(-c5ccc6oc7ccccc7c6c5)ccc4B4c5ccc(-c6ccc7c(c6)c6cccc8c9ccccc9n7c86)cc5N(c5c(-c6ccccc6)cc(-c6ccccc6)cc5-c5ccccc5)c5cc(-c6ccc7c(c6)c6cccc8c9ccccc9n7c86)cc3c54)c(-c3ccccc3)c2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4c(c3)c3cccc5c6ccccc6n4c53)cc3c1B2c1ccc(-c2ccc4c(c2)c2cccc5c6ccccc6n4c52)cc1N3c1c(-c2ccccc2)cc(-c2ccc(C(C)(C)C)cc2)cc1-c1ccccc1]

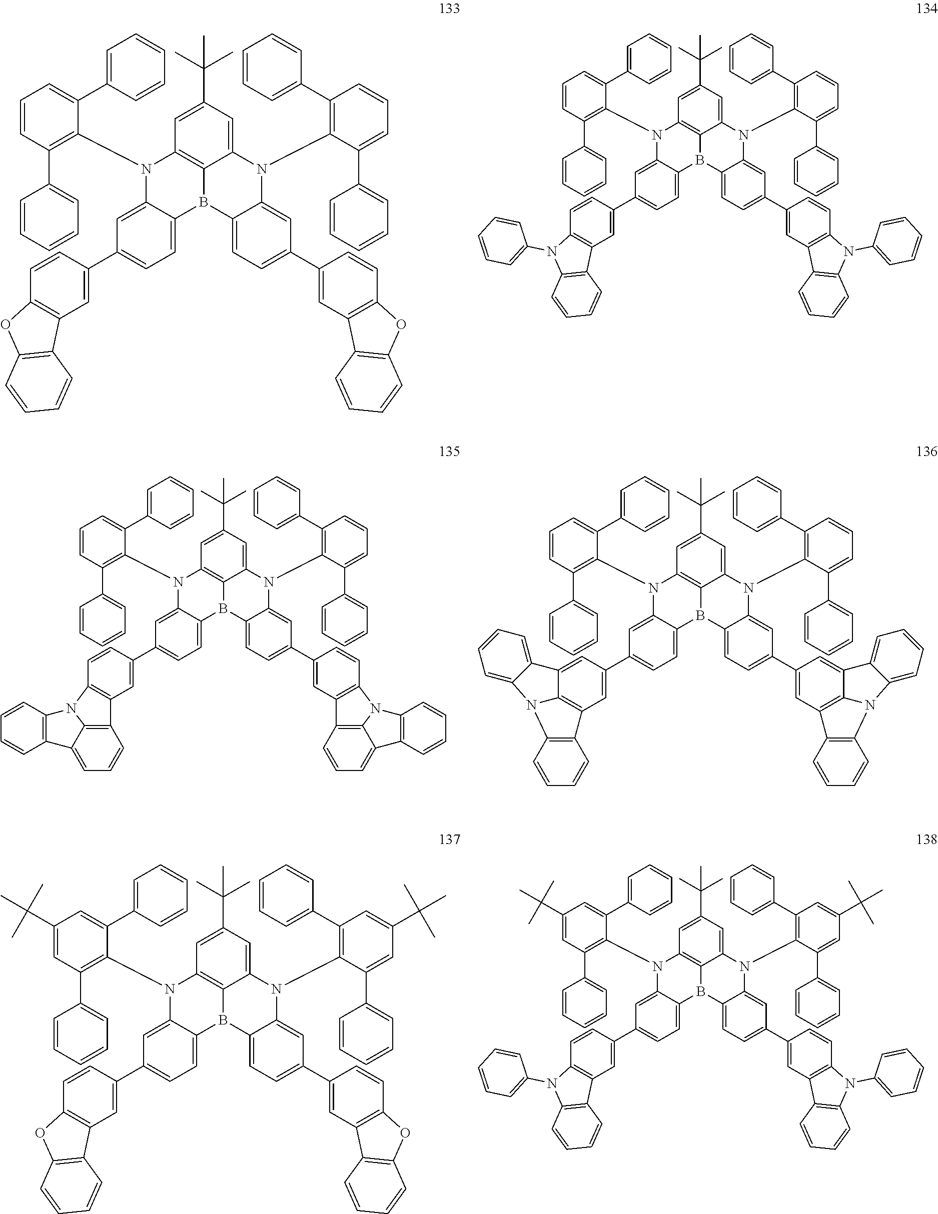

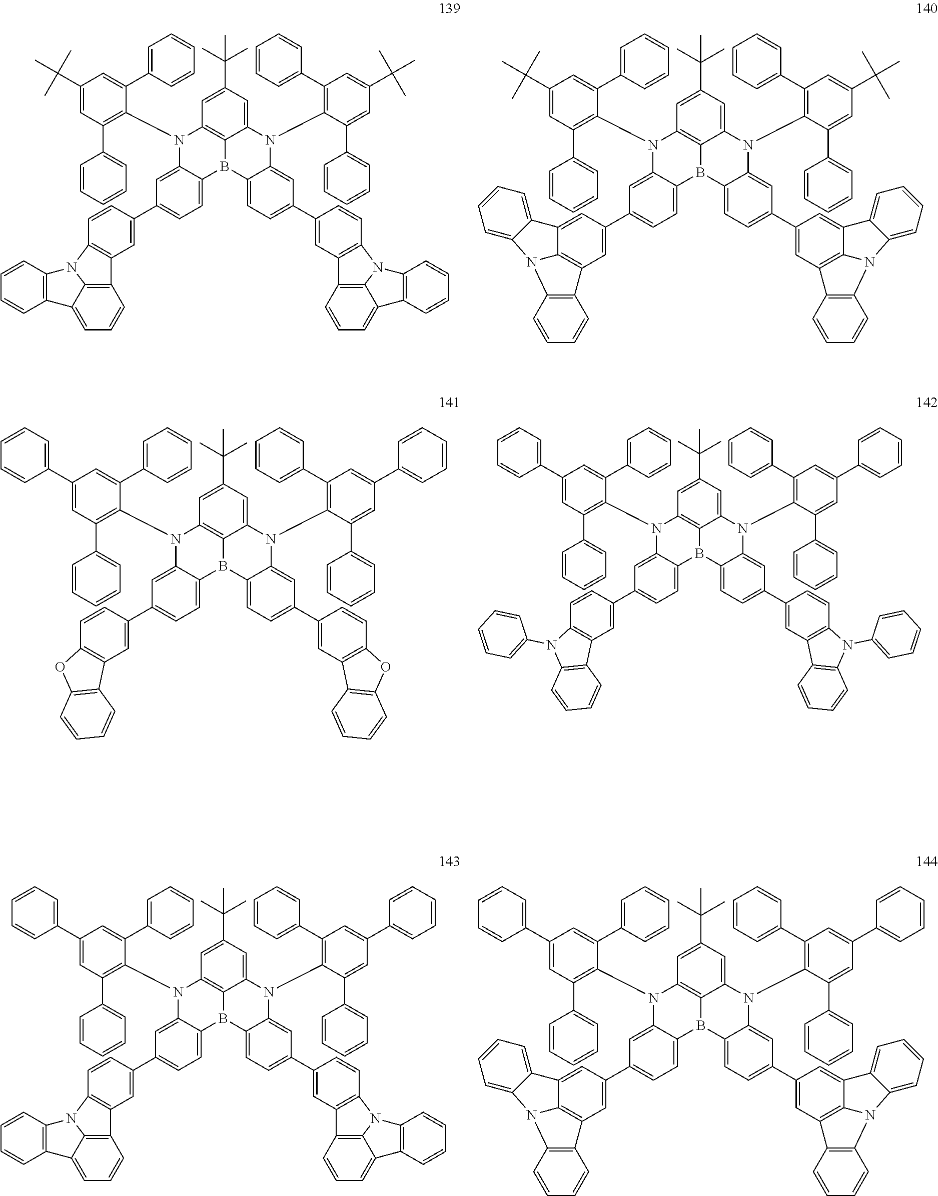

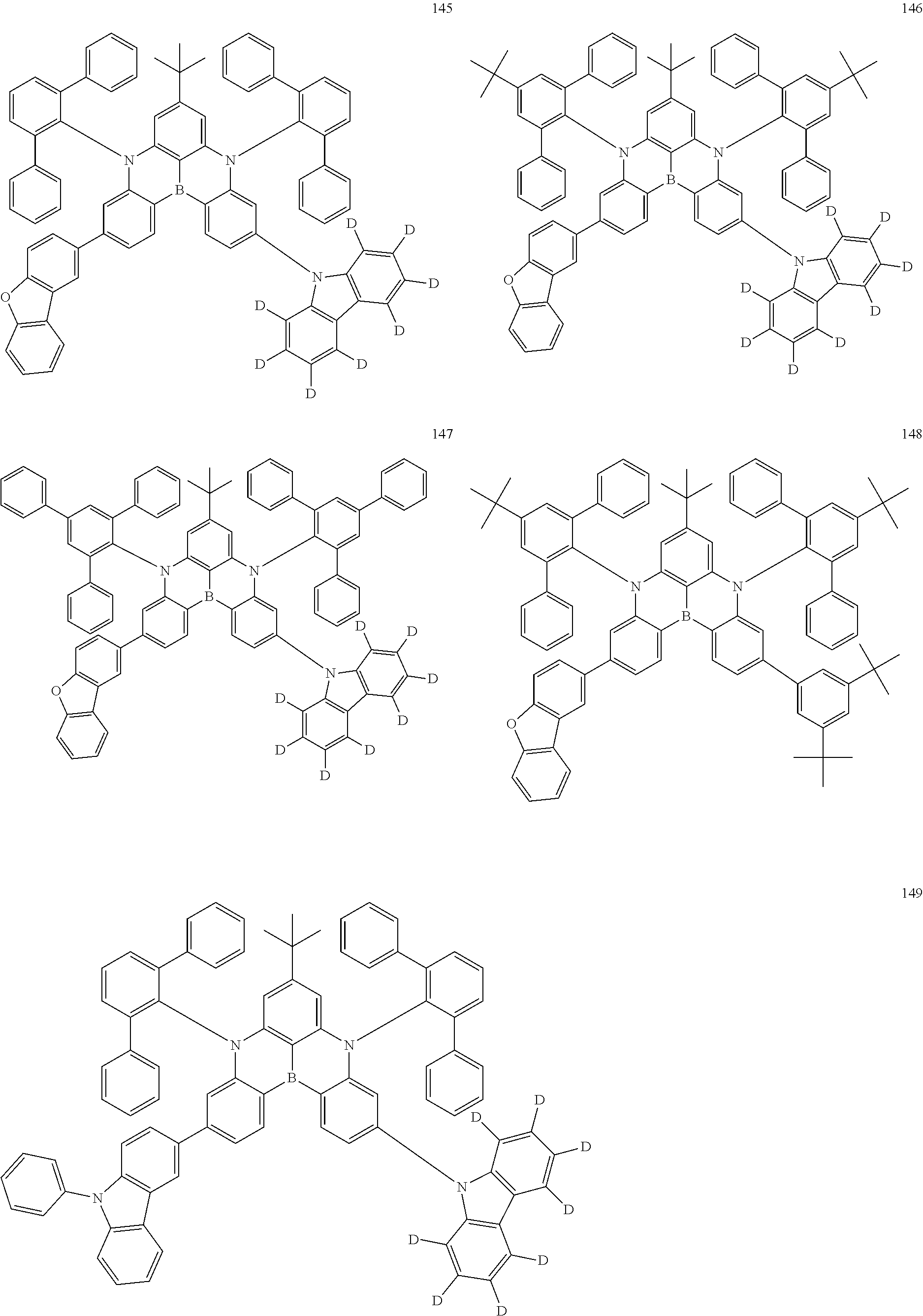

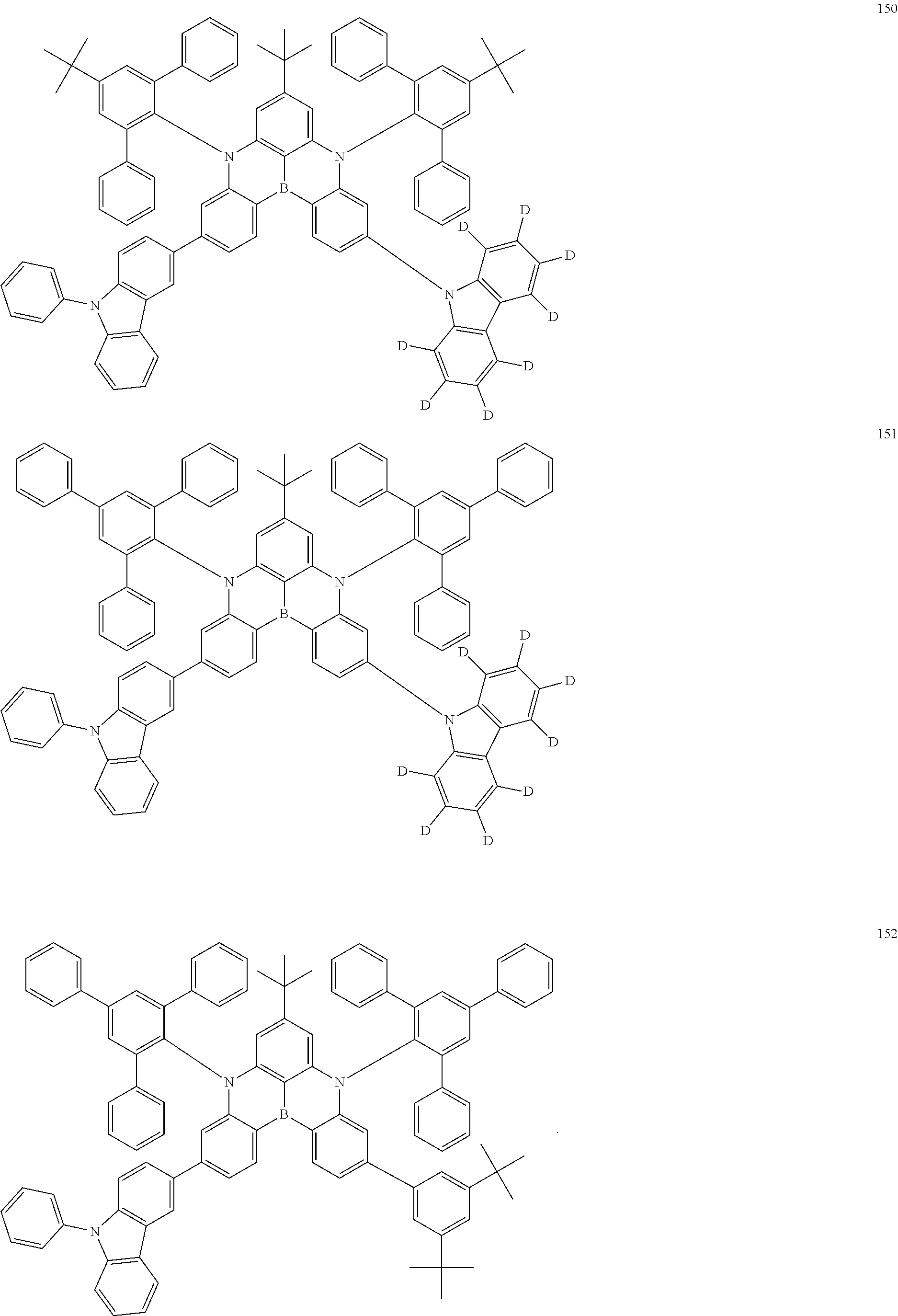

15. A light emitting device, comprising:
a first electrode;
a hole transport region on the first electrode;
an emission layer on the hole transport region;
an electron transport region on the emission layer; and
a second electrode on the electron transport region,
wherein the emission layer comprises:
a first compound represented by Formula 1; and
the hole transport region comprises a hole transport compound represented by Formula H-a: 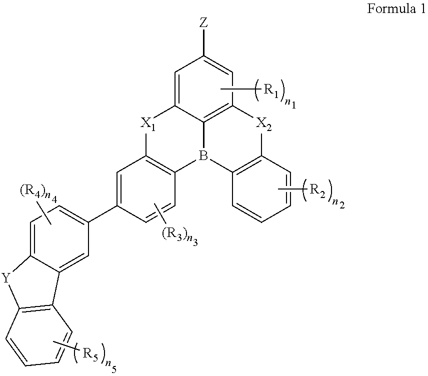
in Formula 1,
X₁ and X₂ are each independently NR₆, O, or S, where at least one among X₁ and X₂ is NR₆,
Y is NR₇, O, or S,
Z is a substituted or unsubstituted t-butyl group, a substituted or unsubstituted aryl group of 6 to 30 ring-forming carbon atoms, or a substituted or unsubstituted heteroaryl group of 2 to 30 ring-forming carbon atoms,
R₁ to R₇ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
n₁ is an integer of 0 to 2,
n₂ and n₅ are each independently an integer of 0 to 4, and
n₃ and n₄ are each independently an integer of 0 to 3, 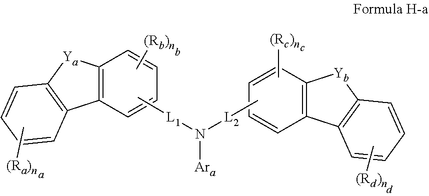
in Formula H-a,
Yₐ and Y_{b} are each independently CRₑR_{f}, NR_{g}, O, or S,
Arₐ is a substituted or unsubstituted aryl group of 6 to 30 ring-forming carbon atoms, or a substituted or unsubstituted heteroaryl group of 2 to 30 ring-forming carbon atoms,
L₁ and L₂ are each independently a direct linkage, a substituted or unsubstituted arylene group of 6 to 30 ring-forming carbon atoms, or a substituted or unsubstituted heteroarylene group of 2 to 30 ring-forming carbon atoms,
Rₐ to R_{g} are each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
nₐ and n_{d} are each independently an integer of 0 to 4, and
n_{b} and n_{c} are each independently an integer of 0 to 3.

16. The light emitting device of claim 15, wherein the first compound represented by Formula 1 is represented by any one of Formula 2-1 to Formula 2-4: 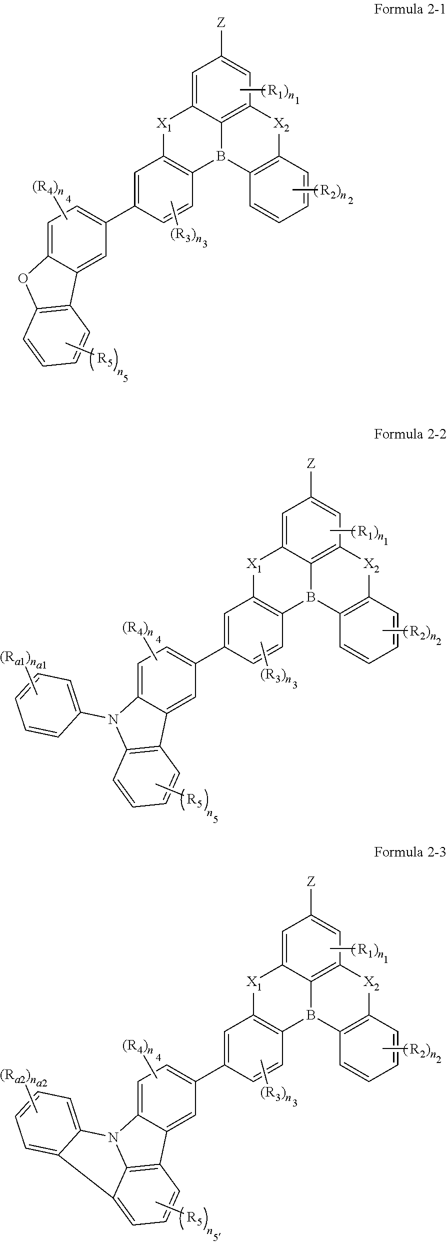 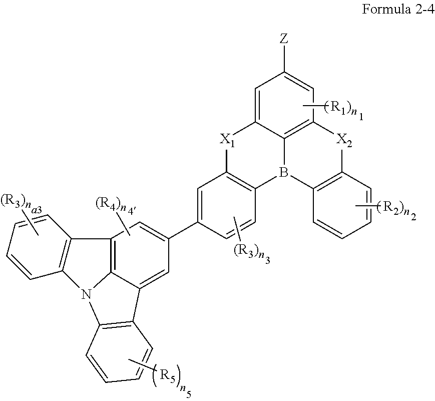
in Formula 2-1 to Formula 2-4,
Rₐ₁ to Rₐ₃ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
nₐ₁ is an integer of 0 to 5,
nₐ₂ and nₐ₃ are each independently an integer of 0 to 4,
n_{a4′} is an integer of 0 to 2,
n_{a5′} is an integer of 0 to 3, and
X₁, X₂, Z, R₁ to R₇, and n₁ to n₅ are the same as defined in Formula 1.

17. The light emitting device of claim 15, wherein the first compound represented by Formula 1 is represented by any one of Formula 3-1 to Formula 3-3: 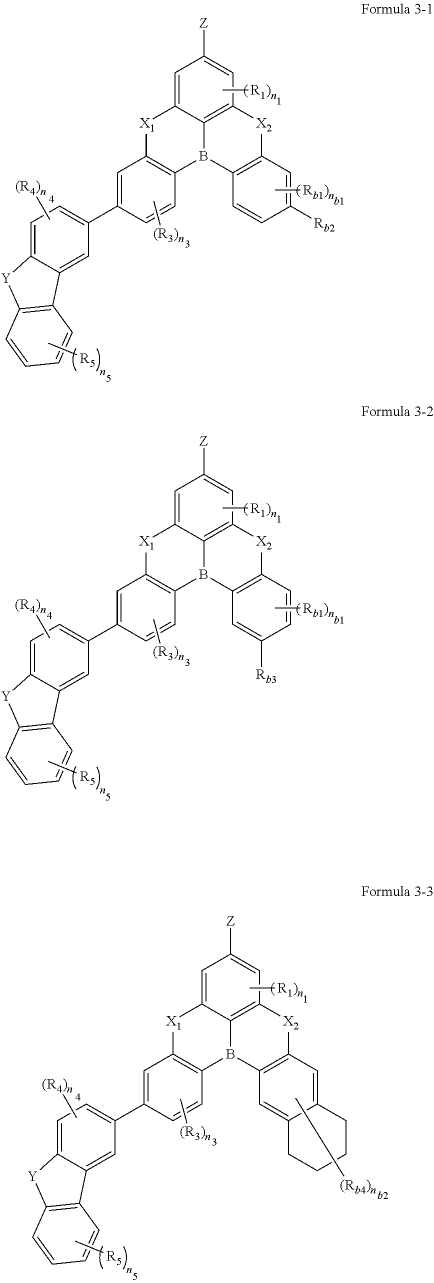
in Formula 3-1 to Formula 3-3,
R_{b1} to R_{b4} are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n_{b1} is an integer of 0 to 3,
n_{b2} is an integer of 0 to 10, and
X₁, X₂, Y, Z, R₁, R₃ to R₇, n₁, and n₃ to n₅ are the same as defined in Formula 1.

18. The light emitting device of claim 15, wherein the first compound represented by Formula 1 is represented by Formula 4: 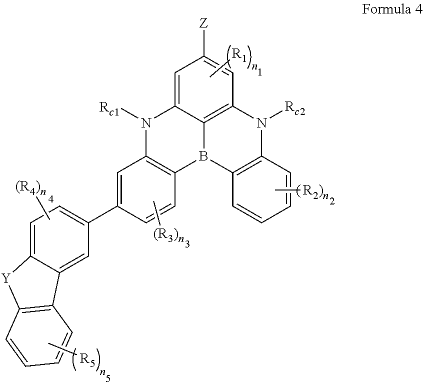
in Formula 4,
R_{c1} and R_{c2} are each independently a substituted or unsubstituted aryl group of 6 to 30 ring-forming carbon atoms, or a substituted or unsubstituted heteroaryl group of 2 to 30 ring-forming carbon atoms, and
Y, Z, R₁ to R₇, and n₁ to n₅ are the same as defined in Formula 1.

19. The light emitting device of claim 15, wherein the first compound represented by Formula 1 is represented by any one of Formula 6-1 to Formula 6-5: 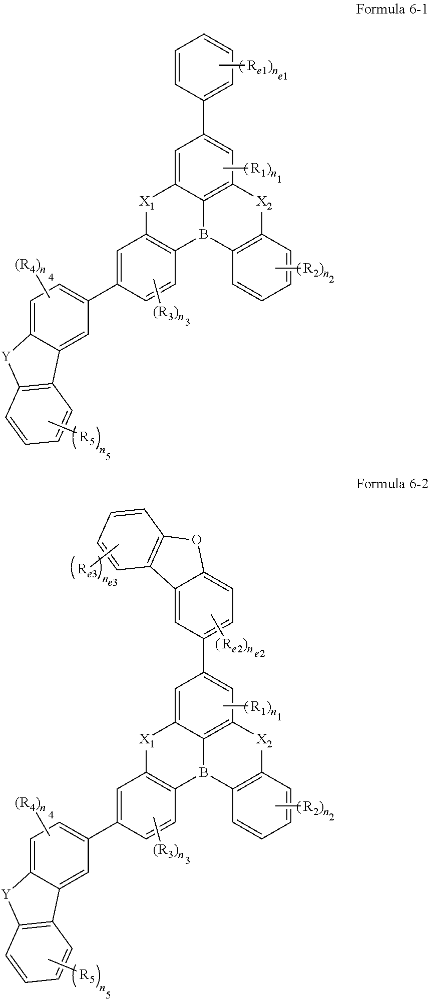 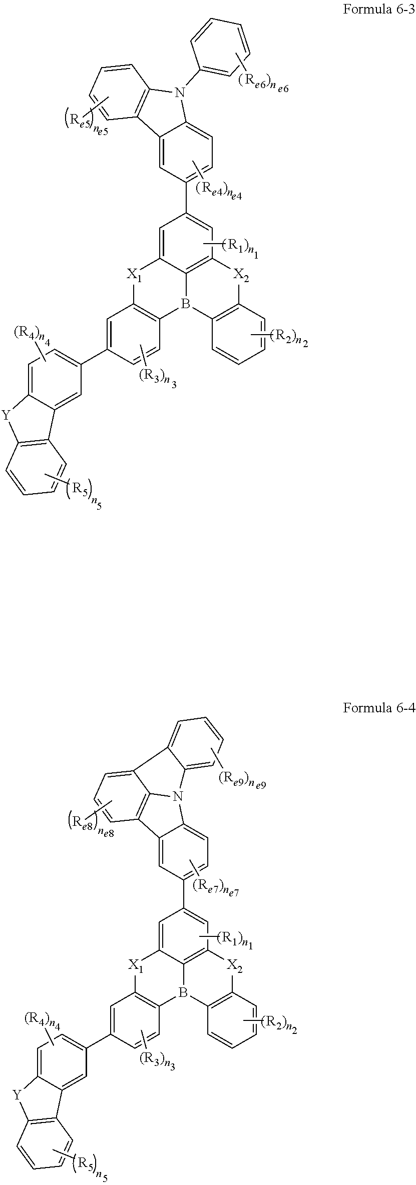 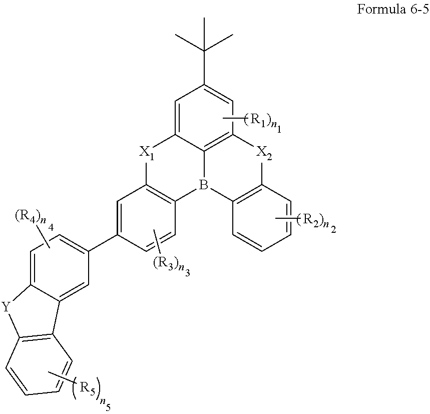
in Formula 6-1 to Formula 6-5,
Rₑ₁ to Rₑ₉ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
nₑ₁ and nₑ₆ are each independently an integer of 0 to 5,
nₑ₂, nₑ₄, nₑ₇ and nₑ₈ are each independently an integer of 0 to 3,
nₑ₃, nₑ₅ and nₑ₉ are each independently an integer of 0 to 4, and
X₁, X₂, Y, R₁ to R₇, and n₁ to n₅ are the same as defined in Formula 1.

20. The light emitting device of claim 15, wherein the first compound comprises at least one of the compounds in Compound Group 1: 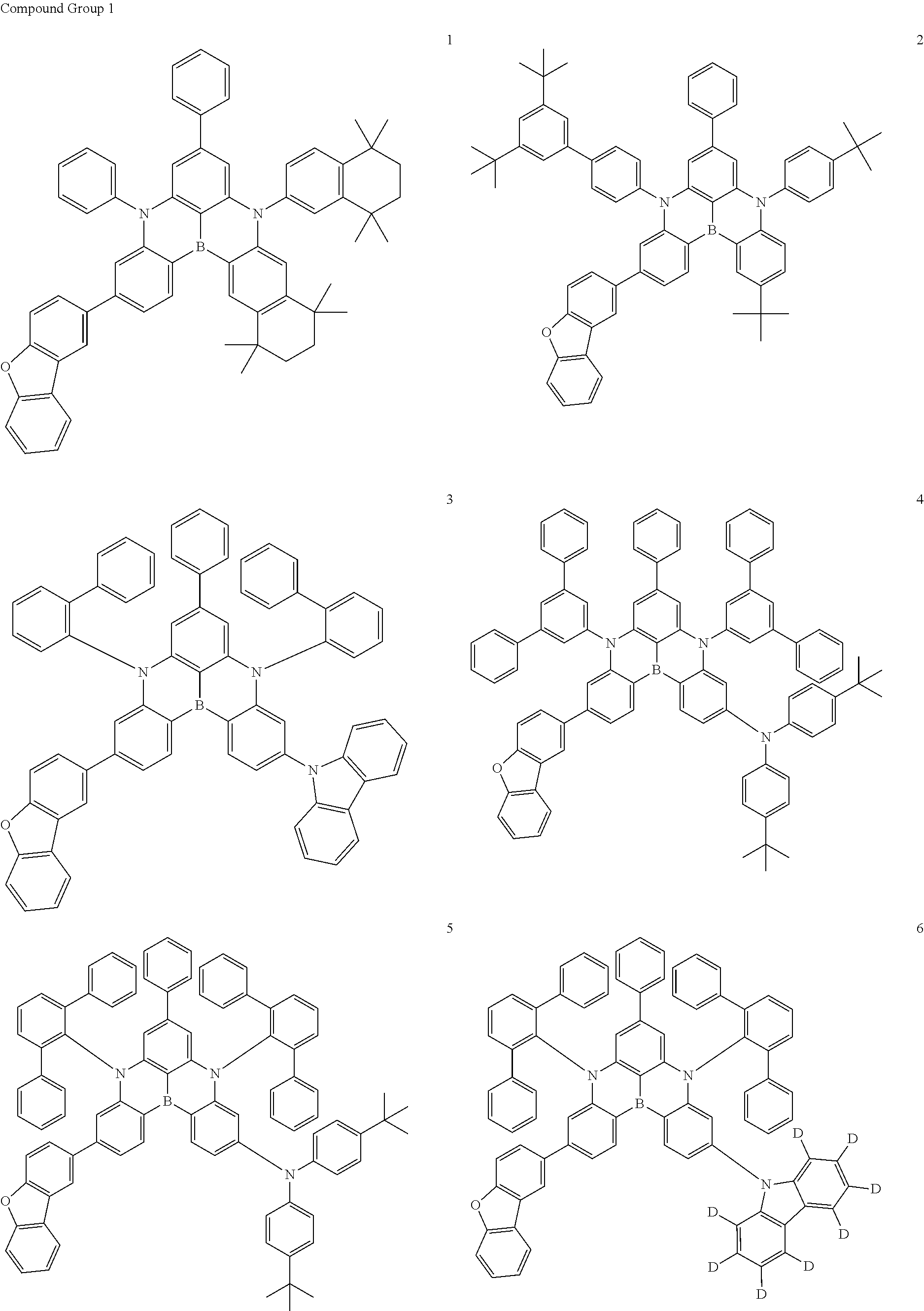 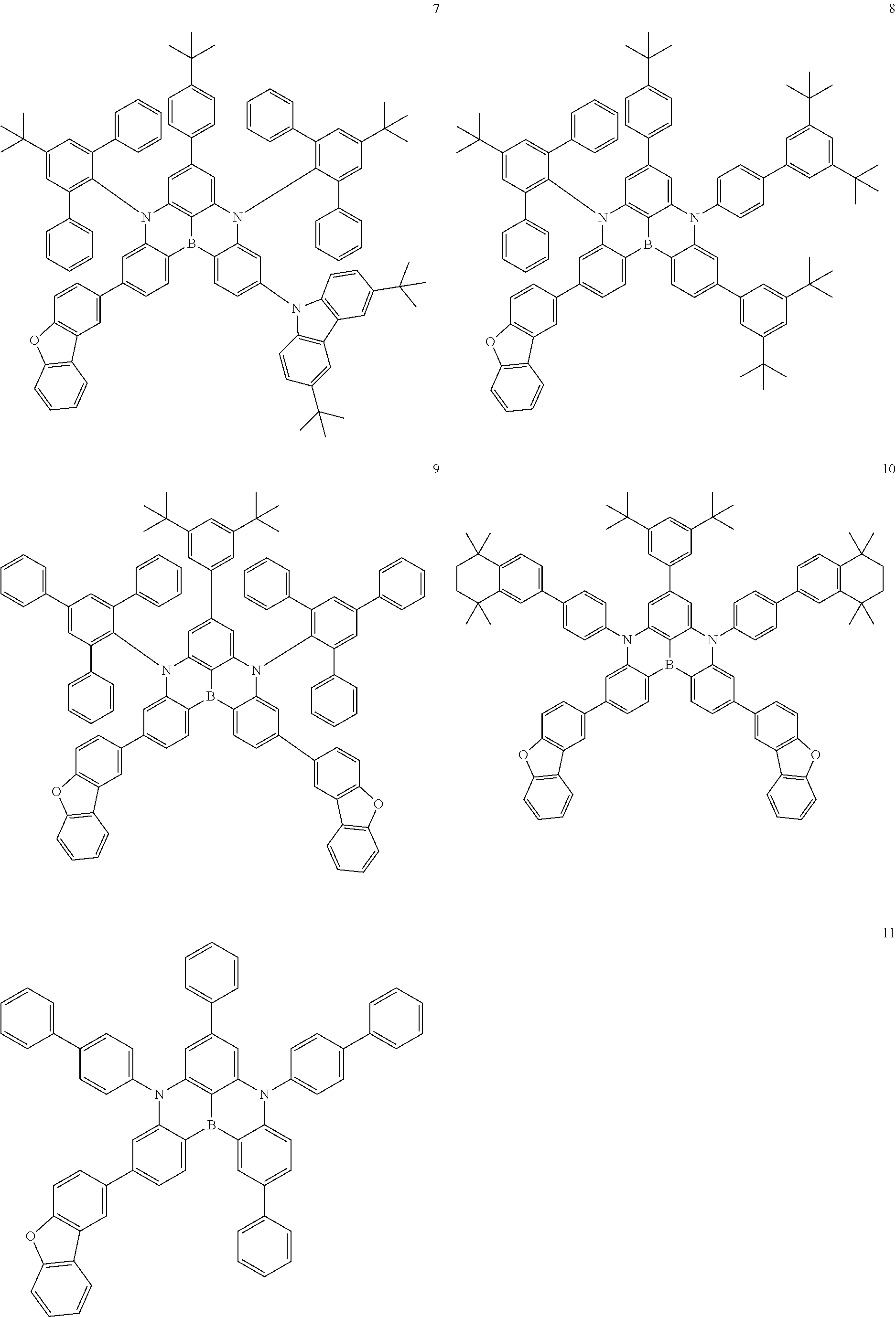 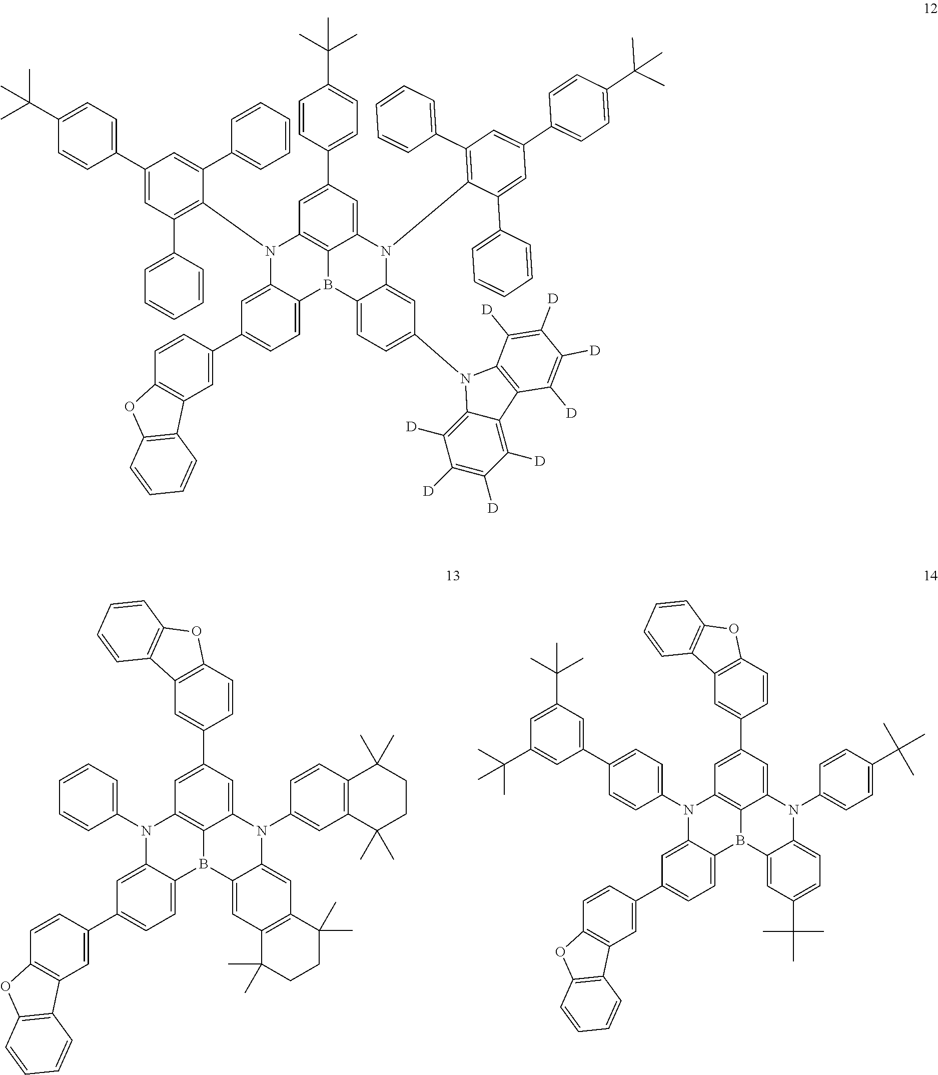 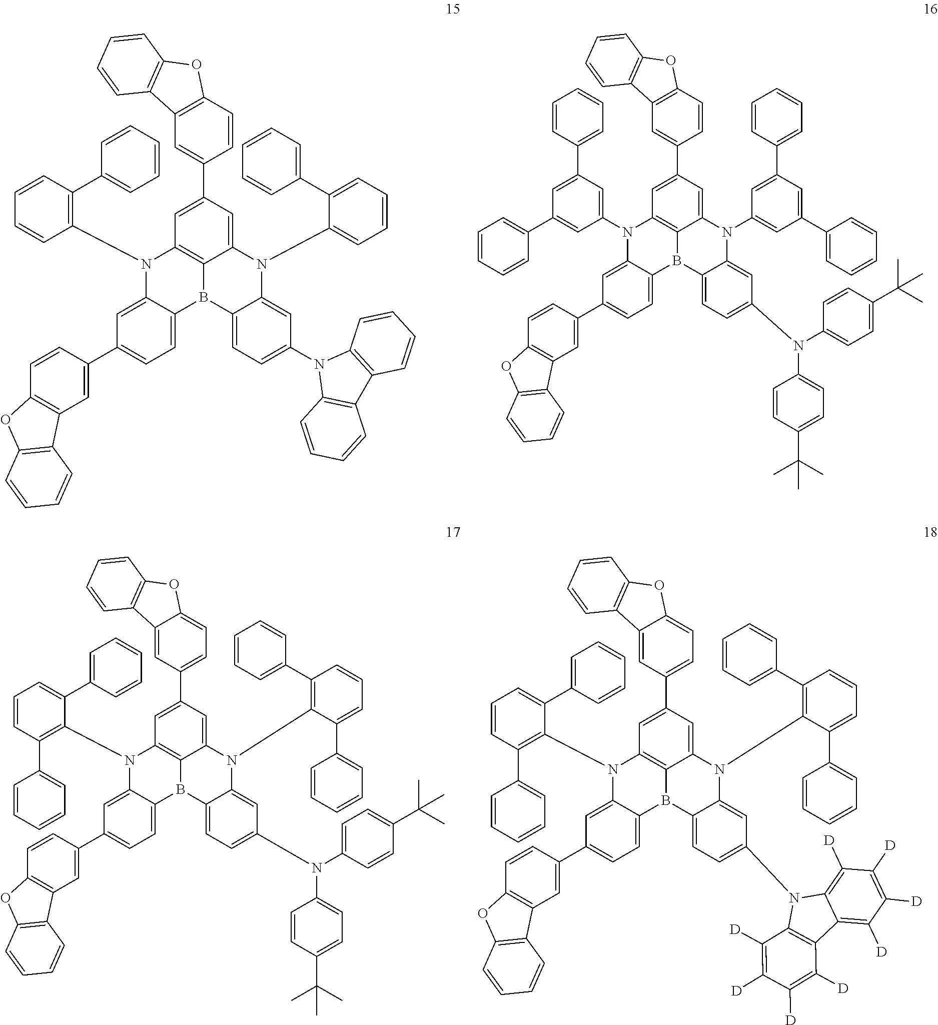 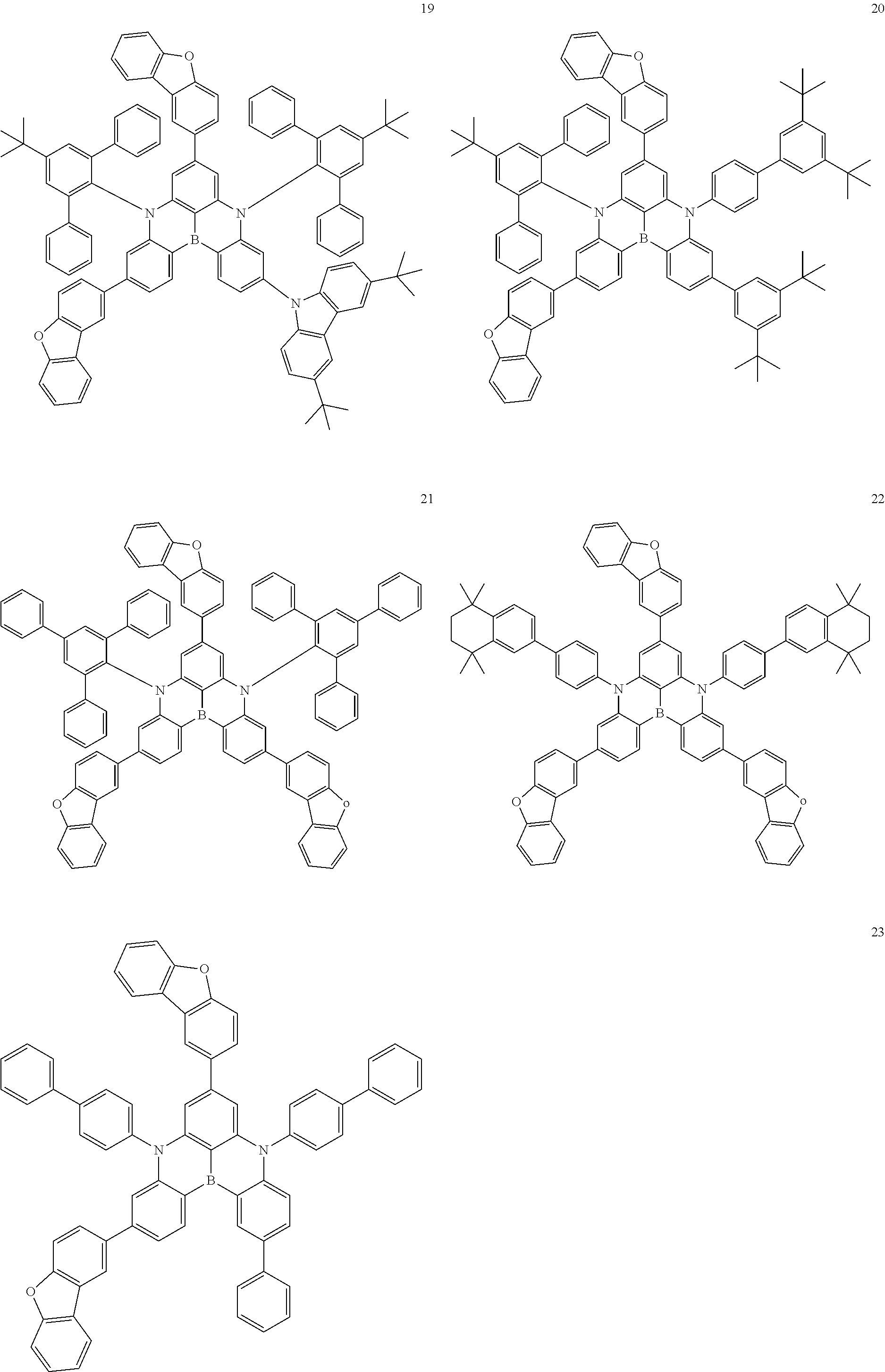 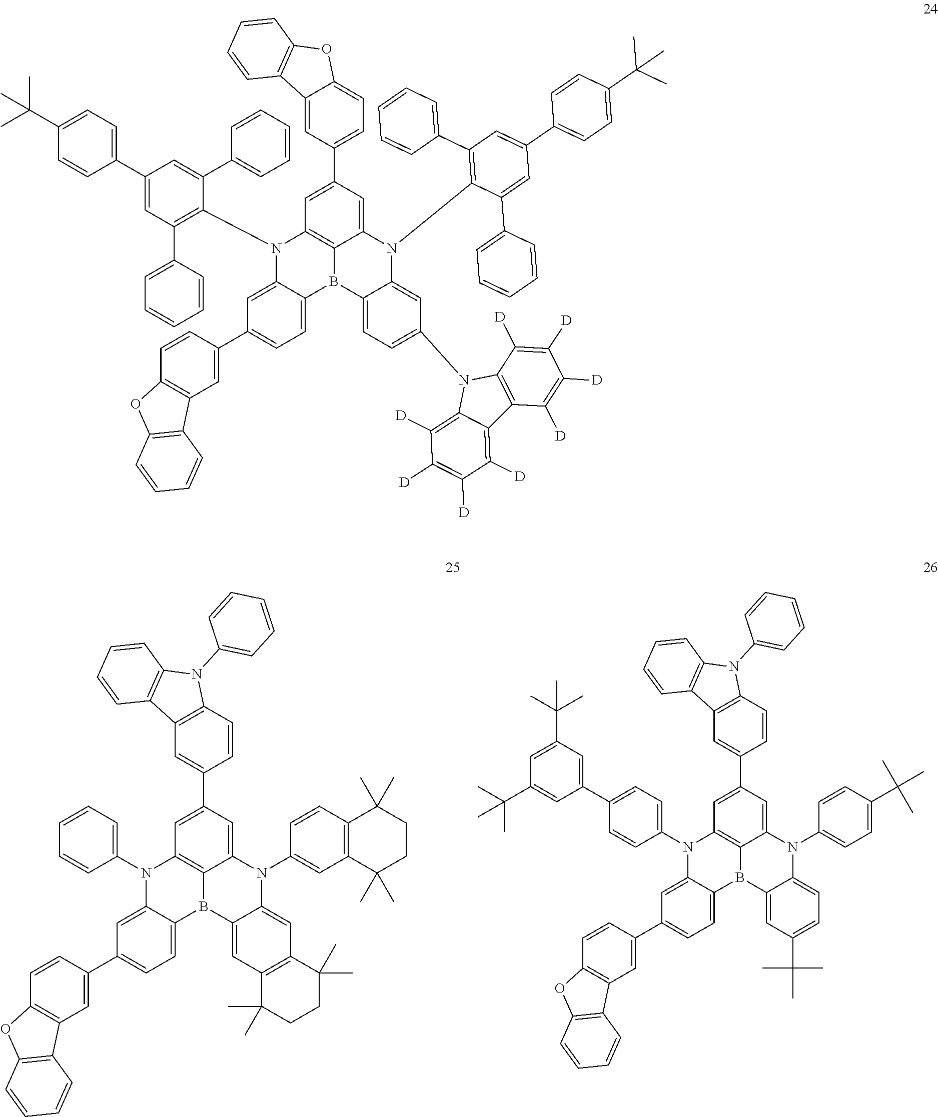 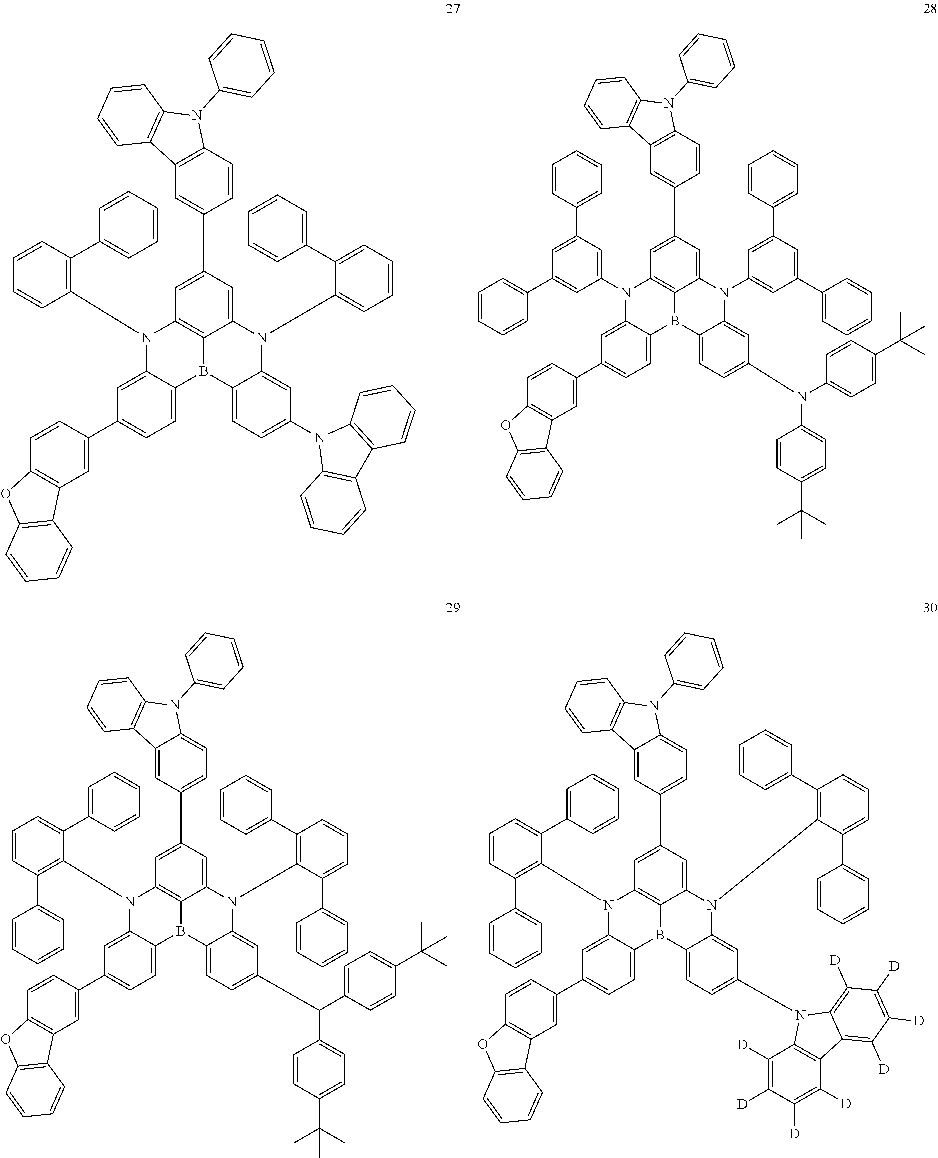 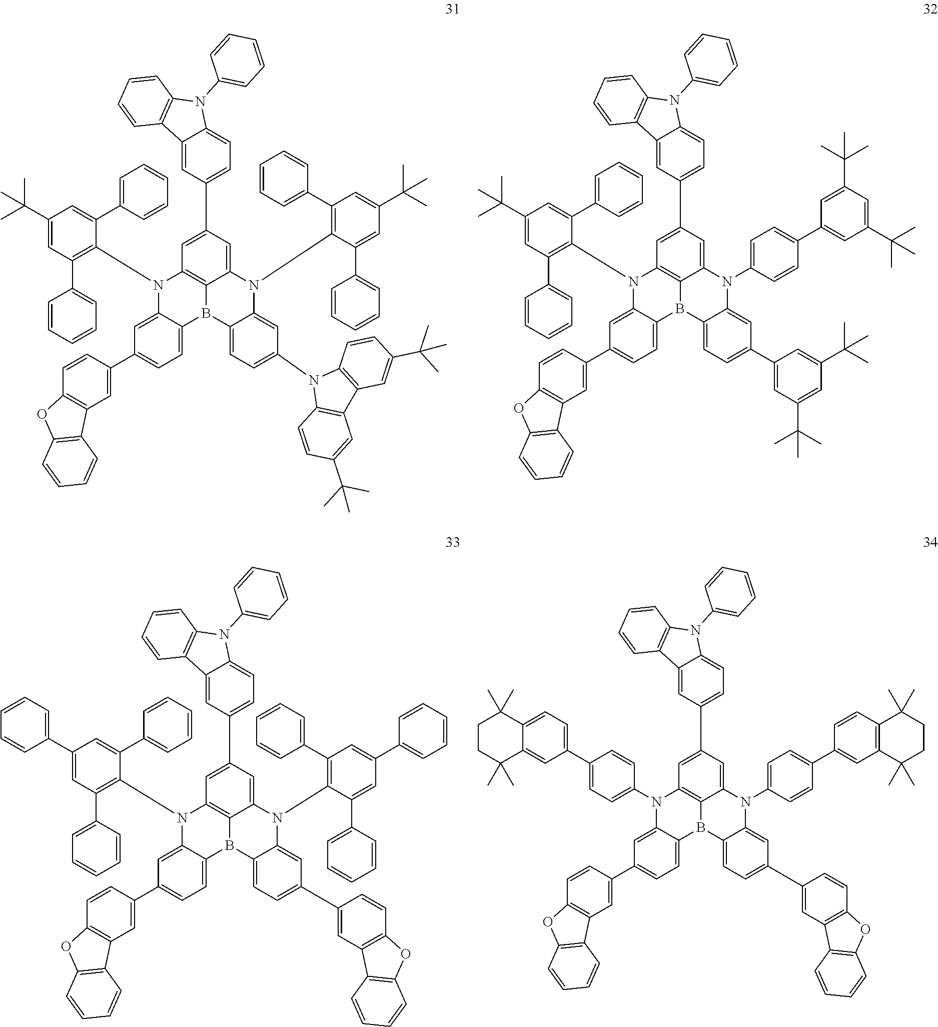 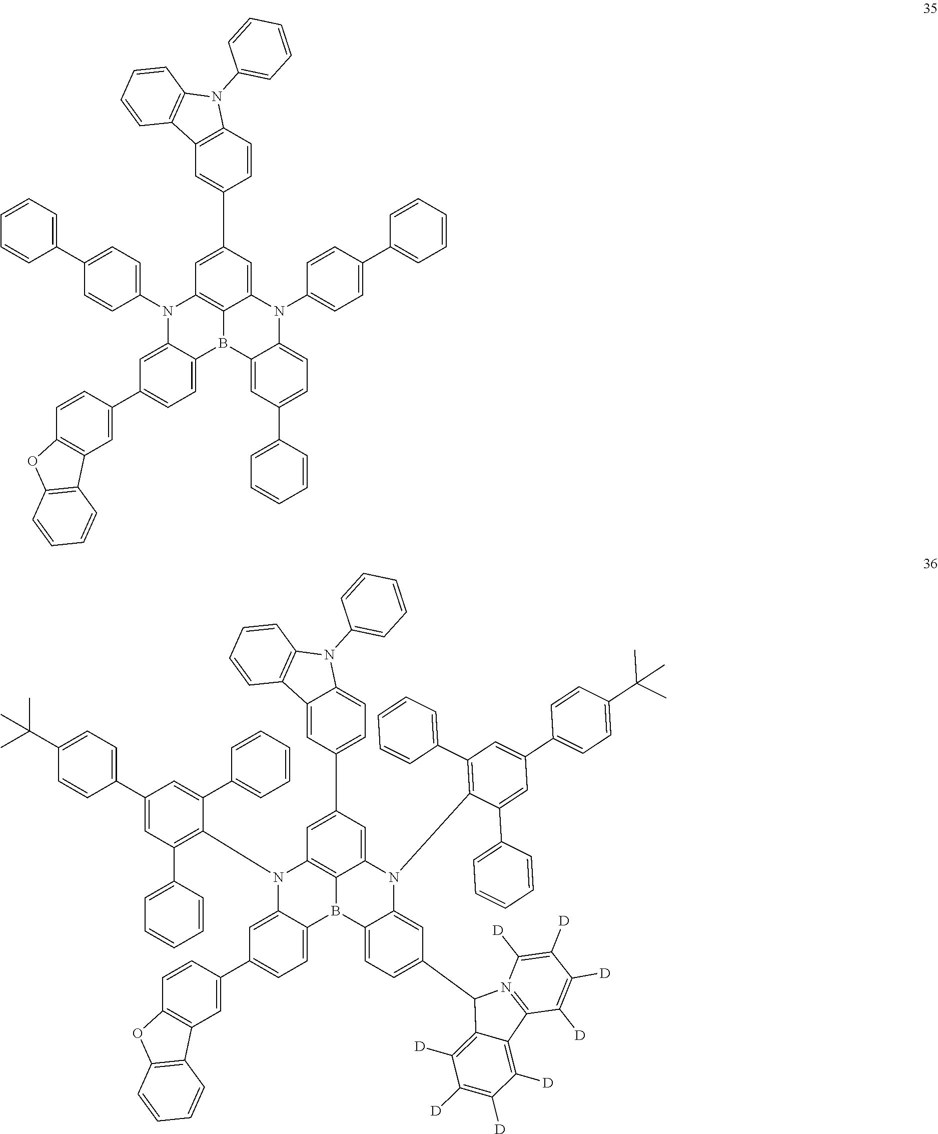 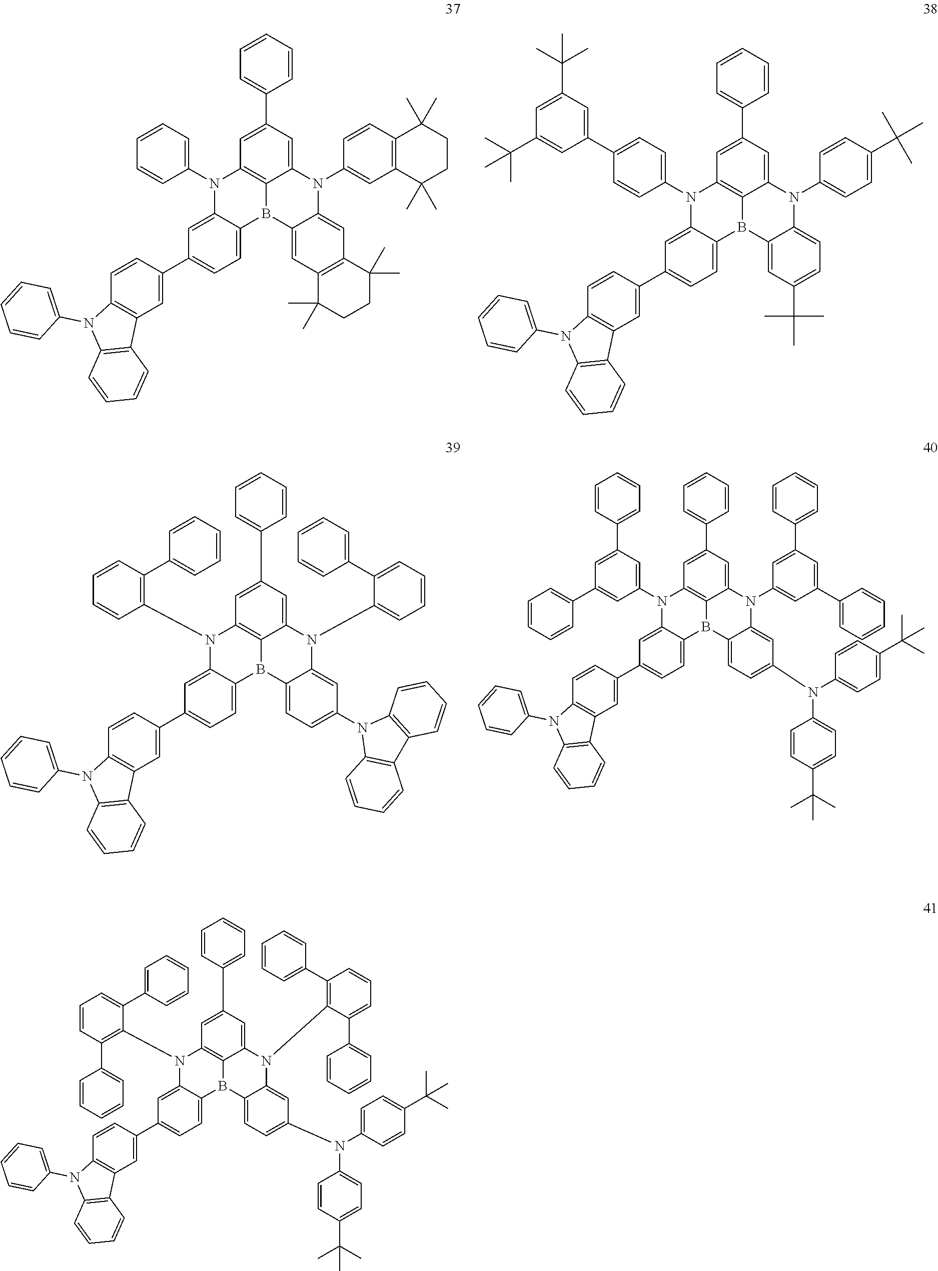 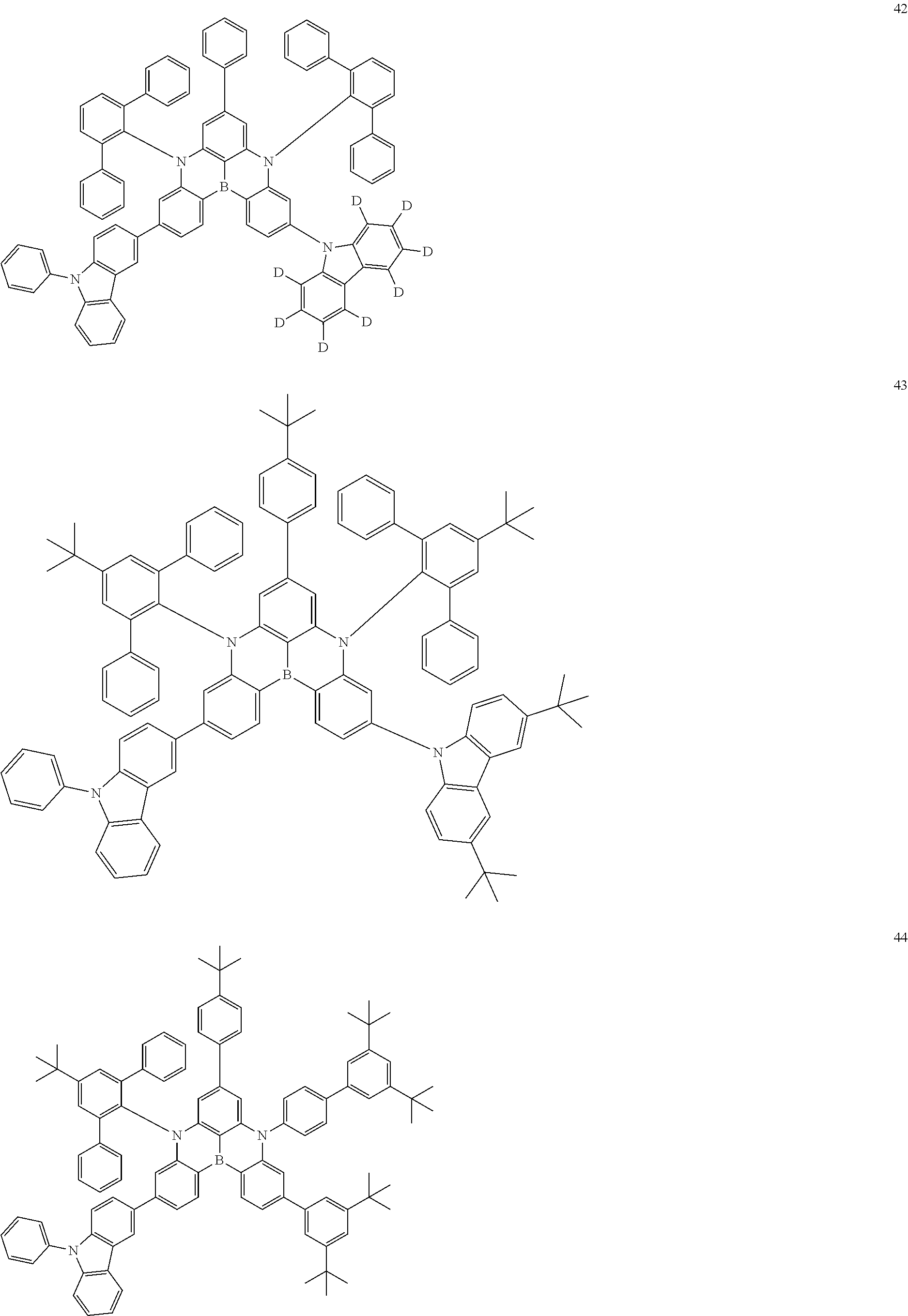 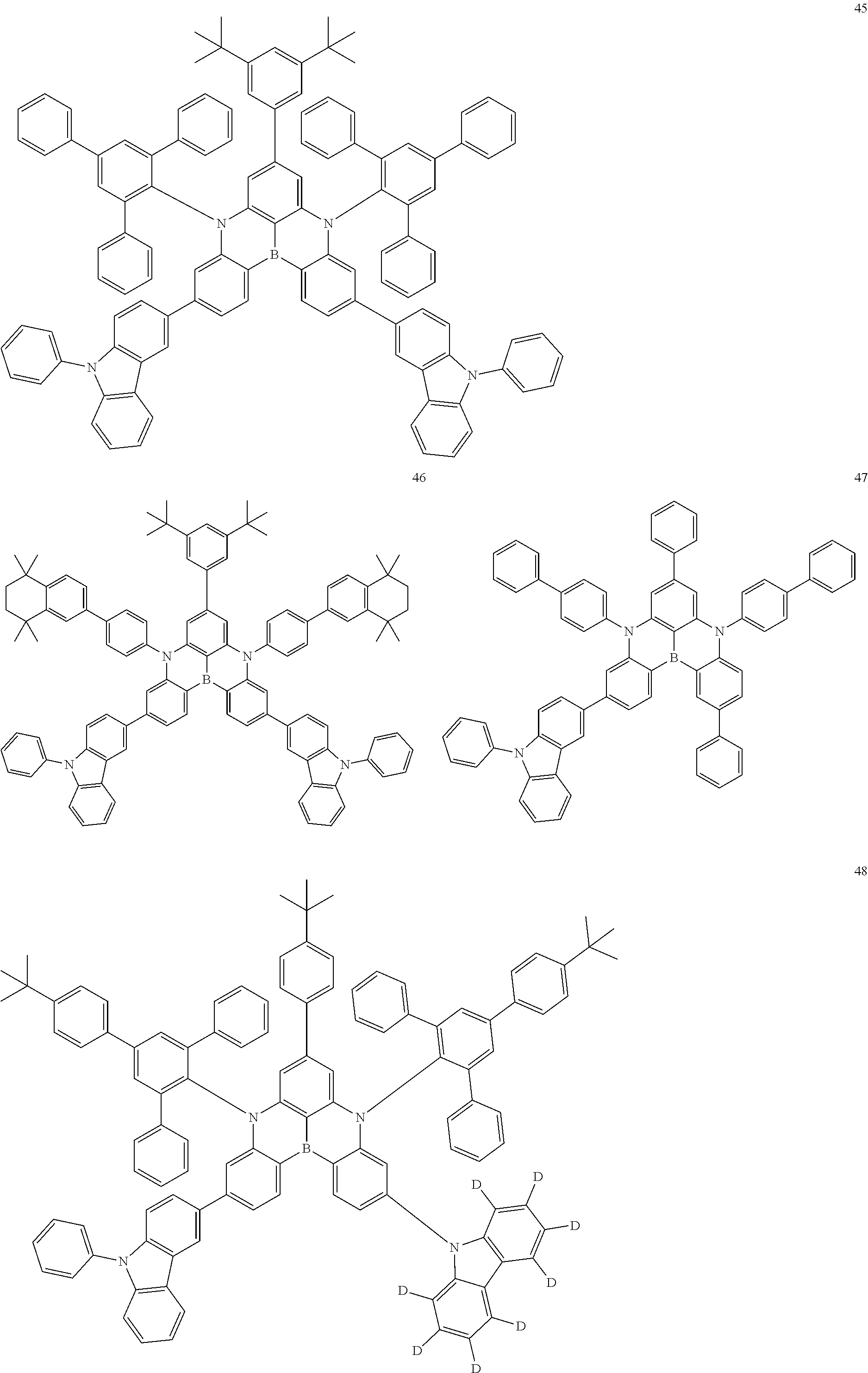 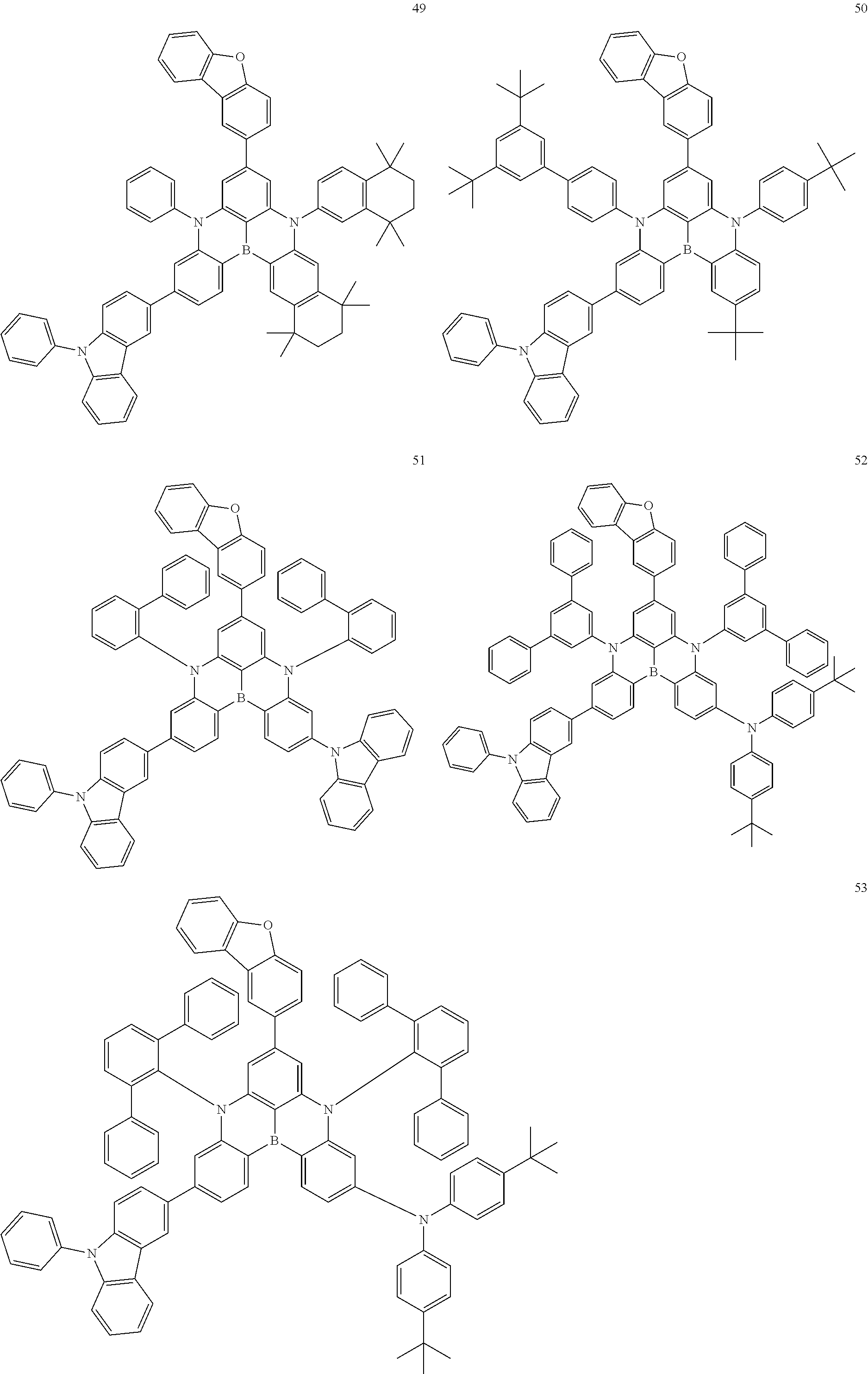 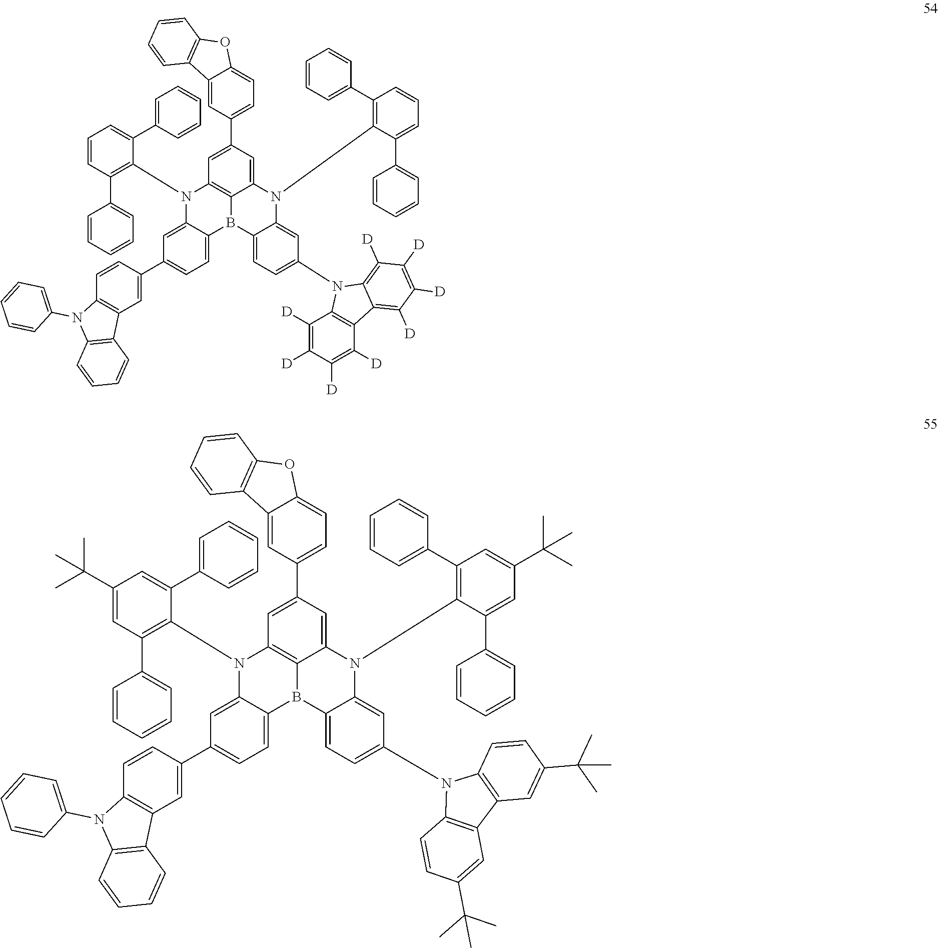 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc(-c2ccc4c(c2)c2ccccc2n4-c2ccccc2)cc1N3c1c(-c2ccccc2)cccc1-c1ccccc1 ; CC(C)(C)c1cc(-c2ccccc2)c(N2c3cc(-c4ccc5c(c4)c4ccccc4n5-c4ccccc4)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-c5ccc6oc7ccccc7c6c5)cc2c43)c(-c2ccccc2)c1] 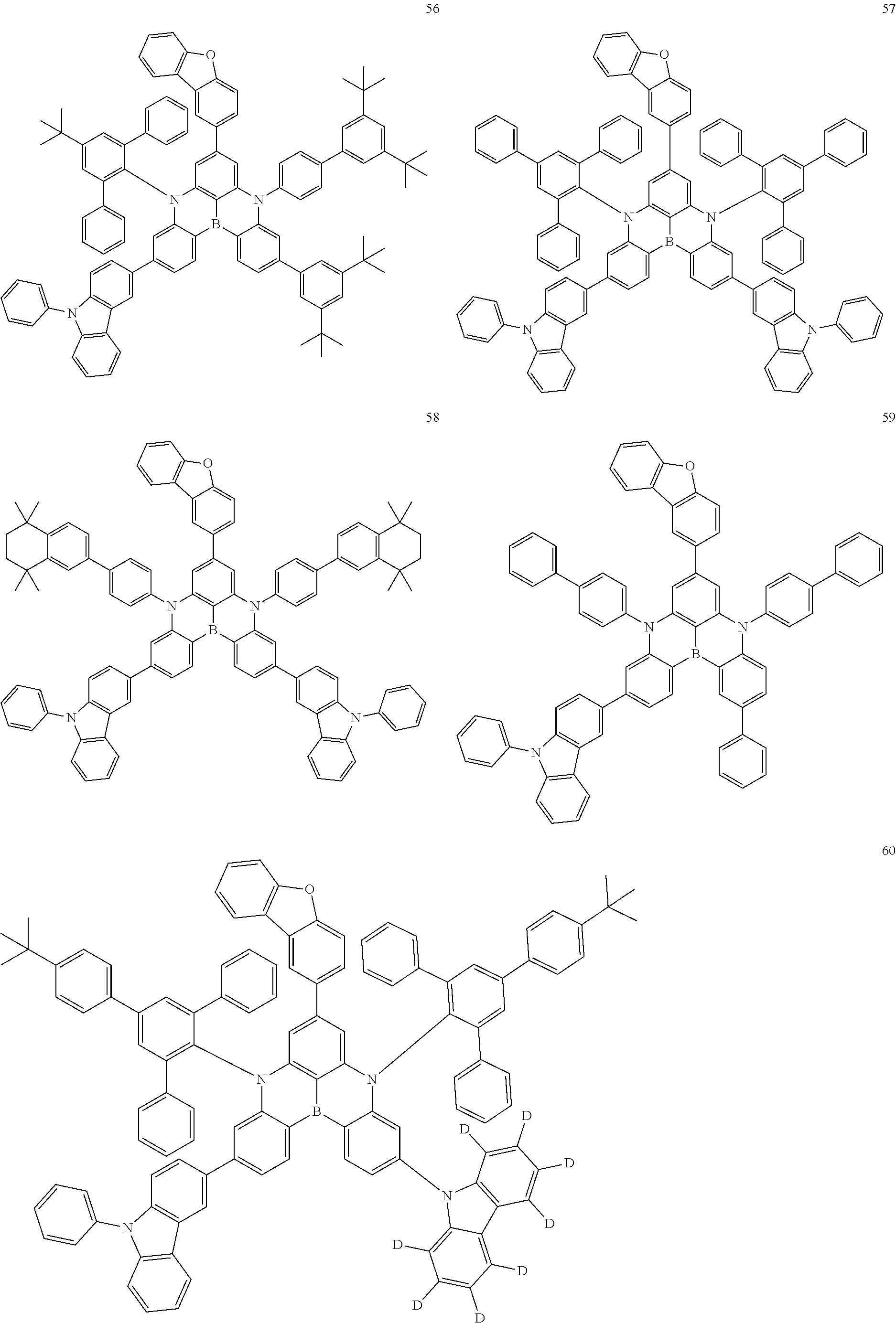 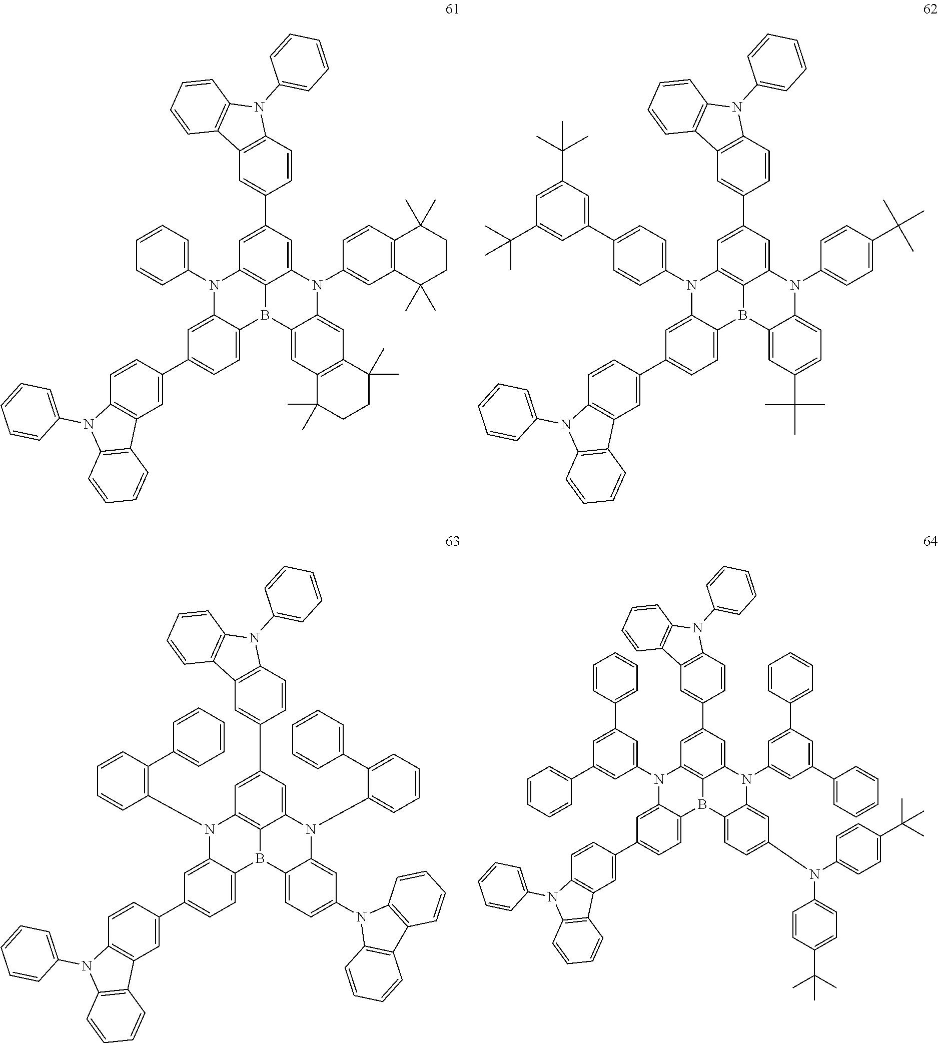 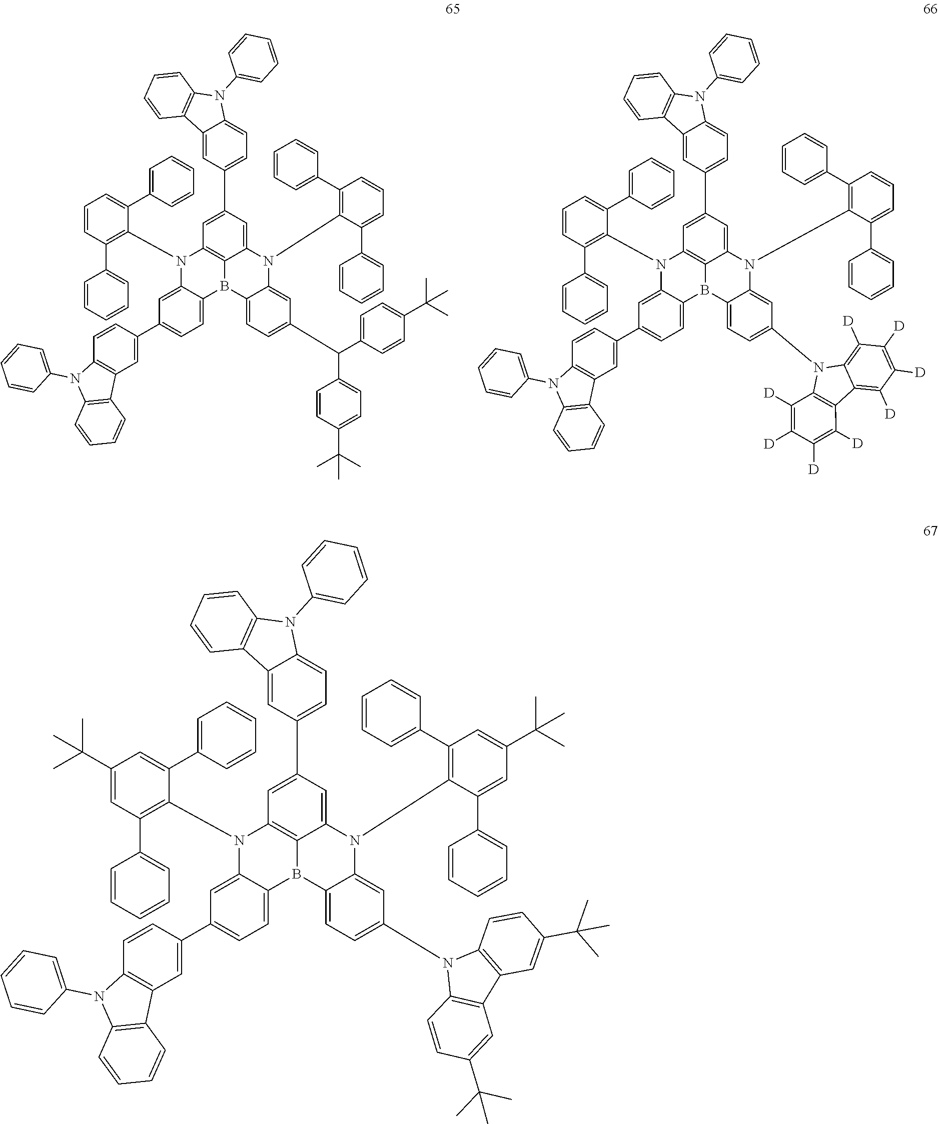 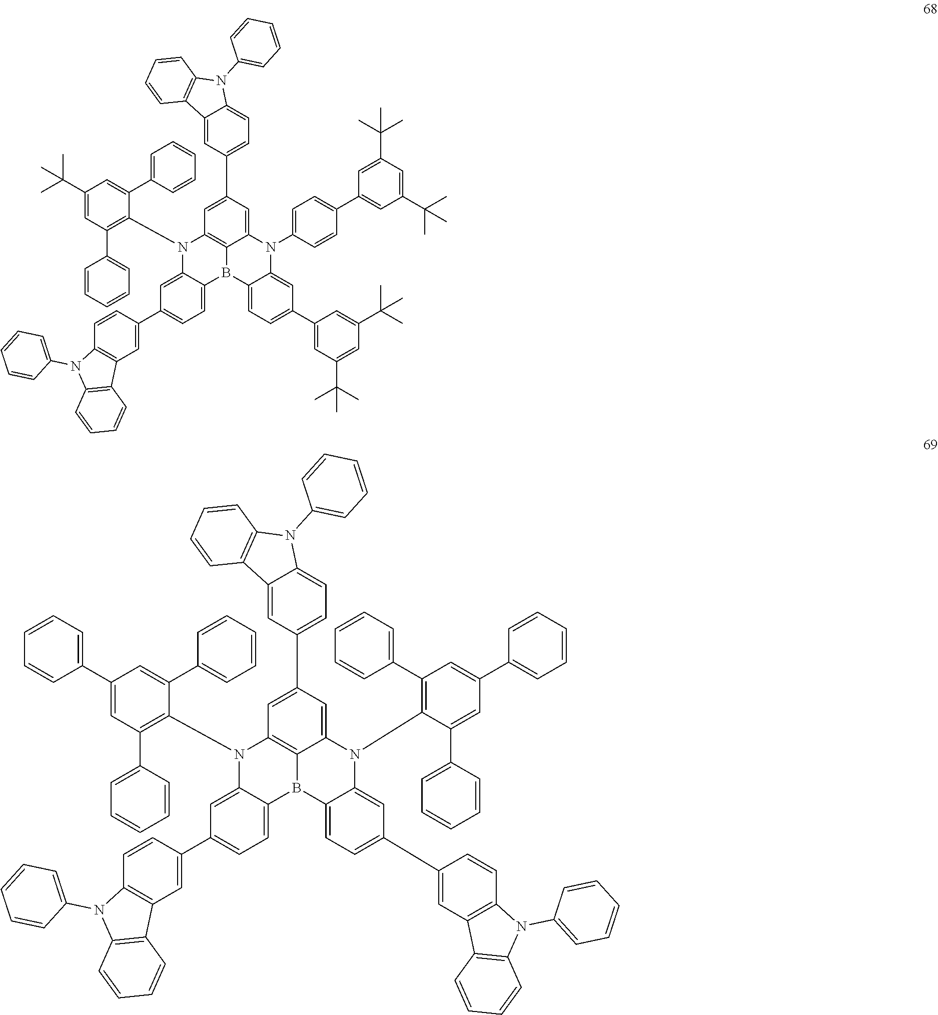 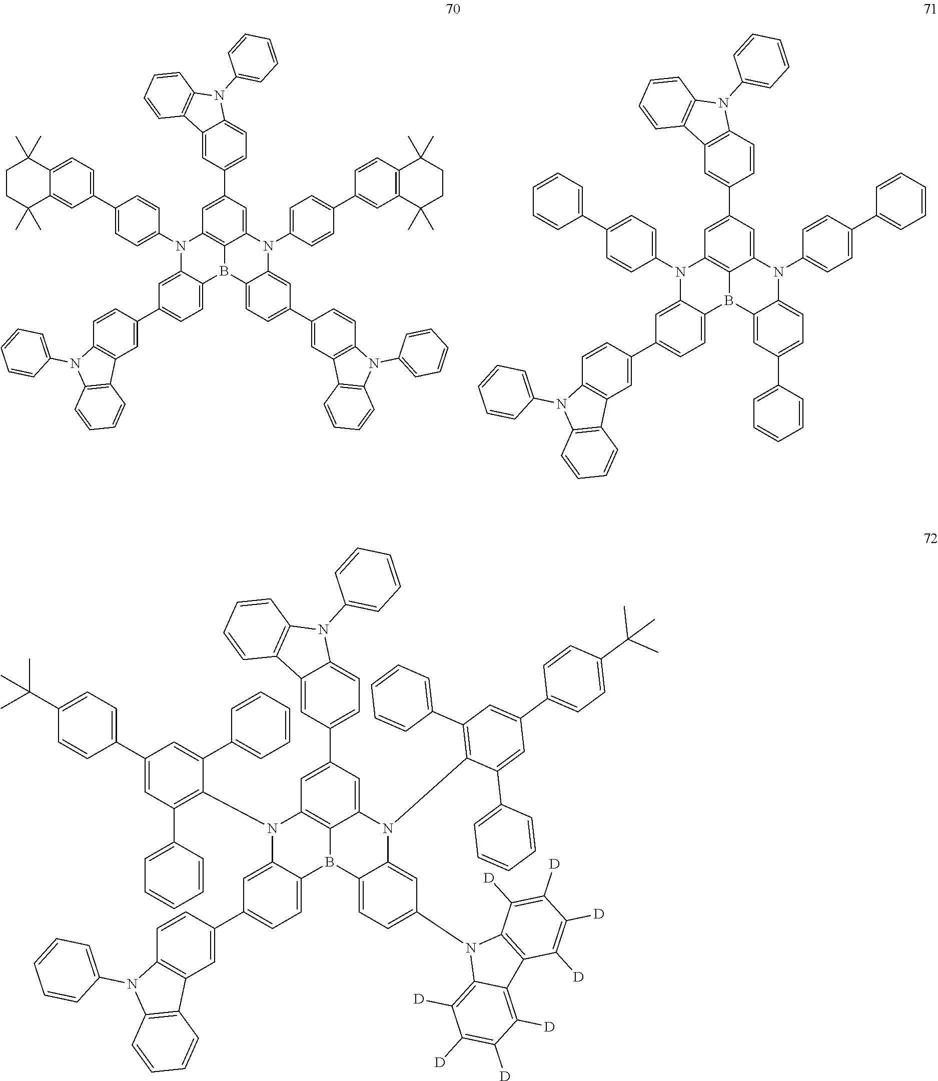 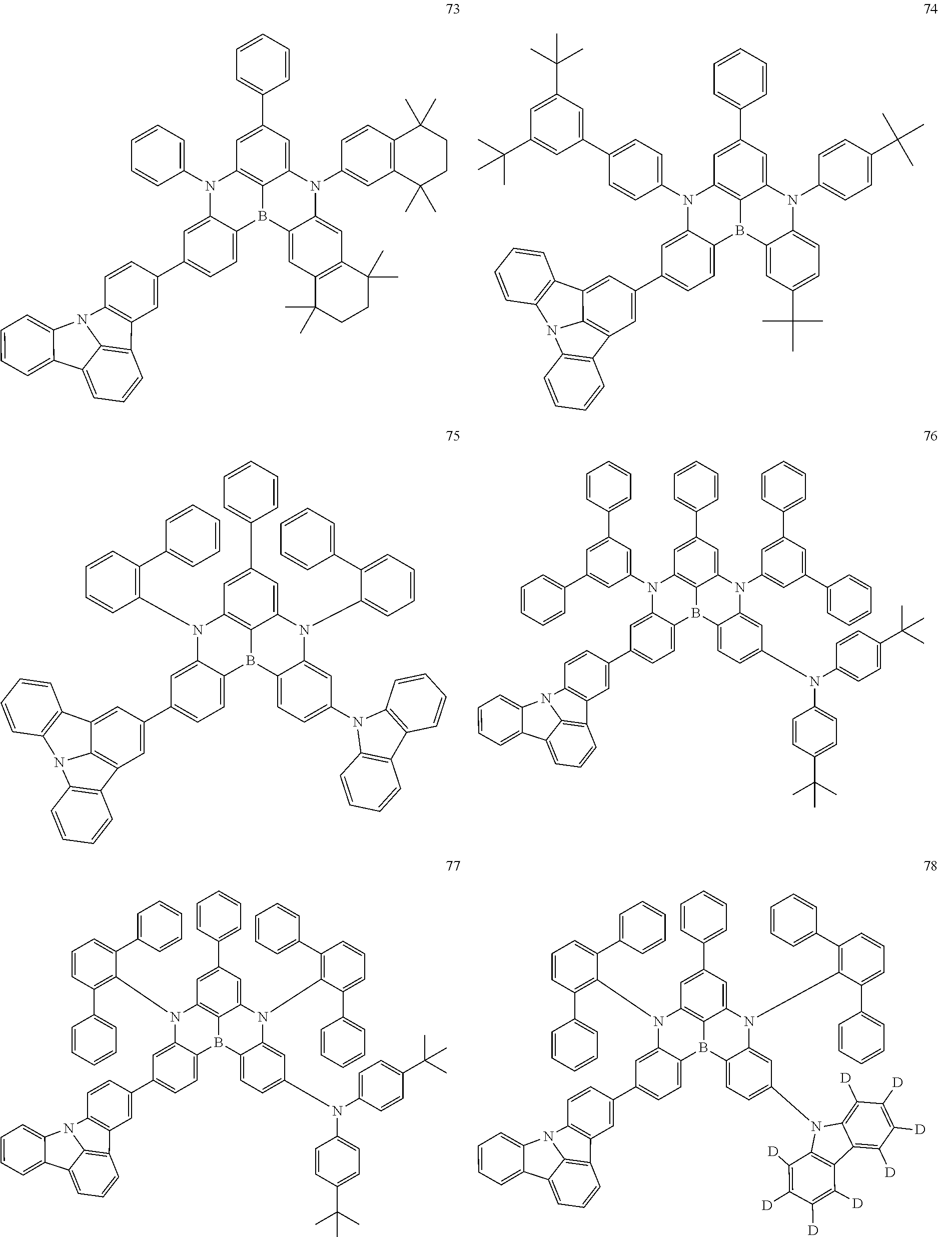 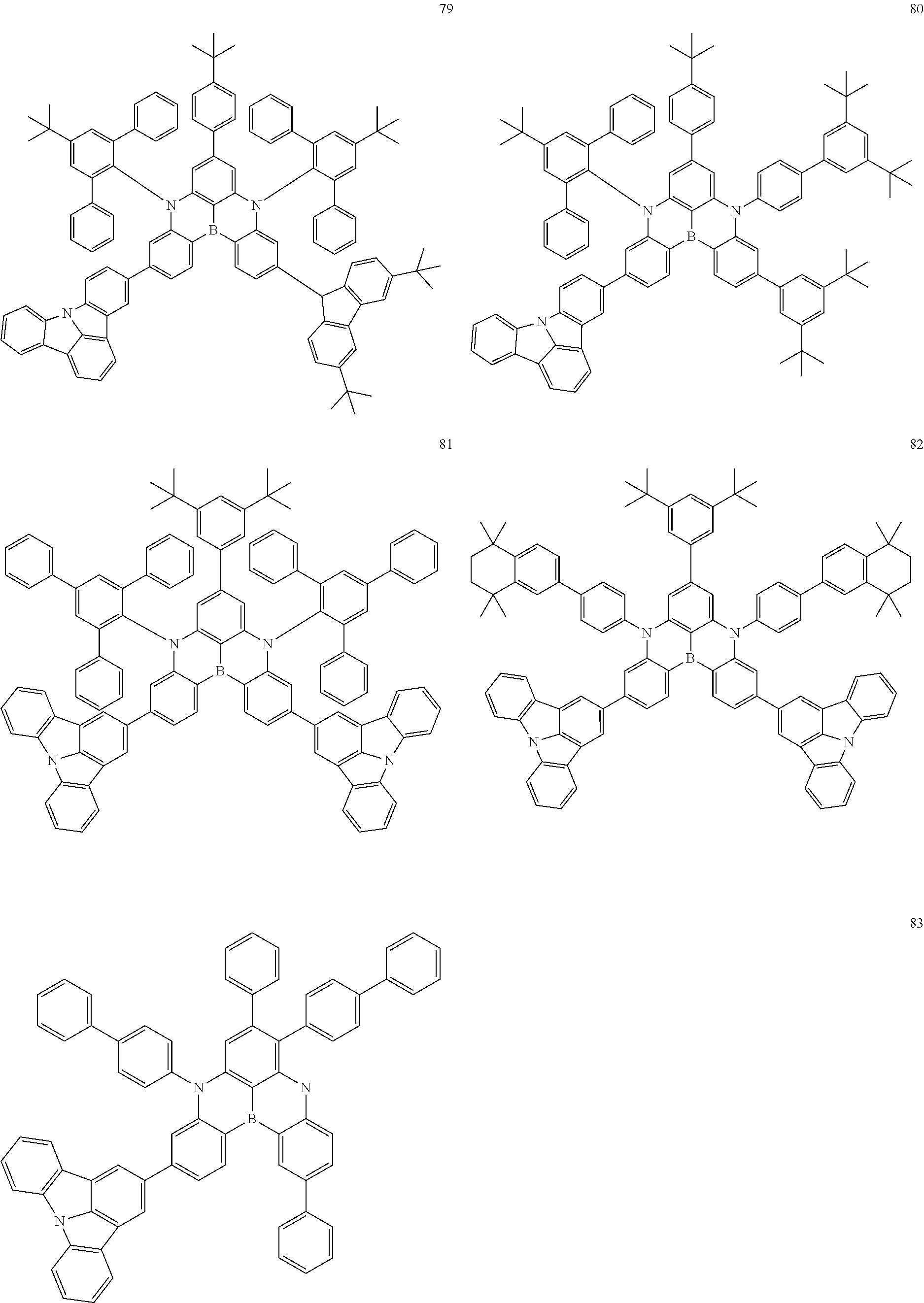 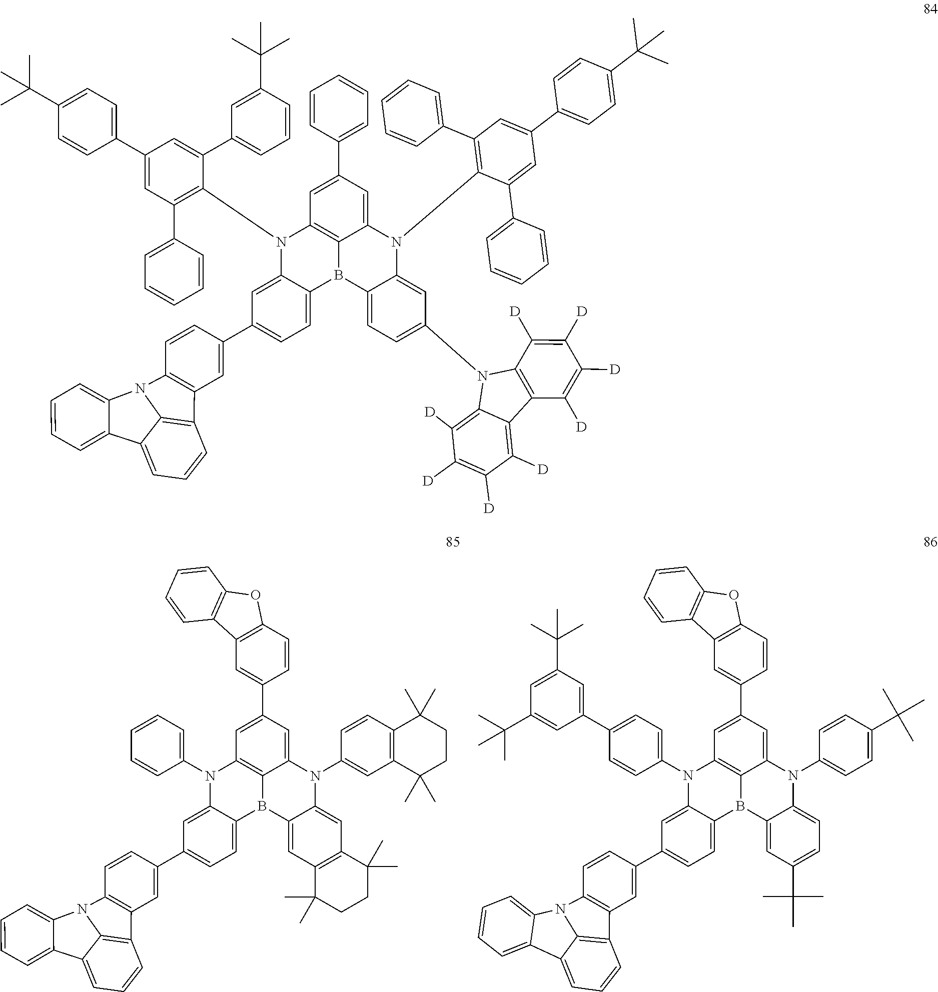 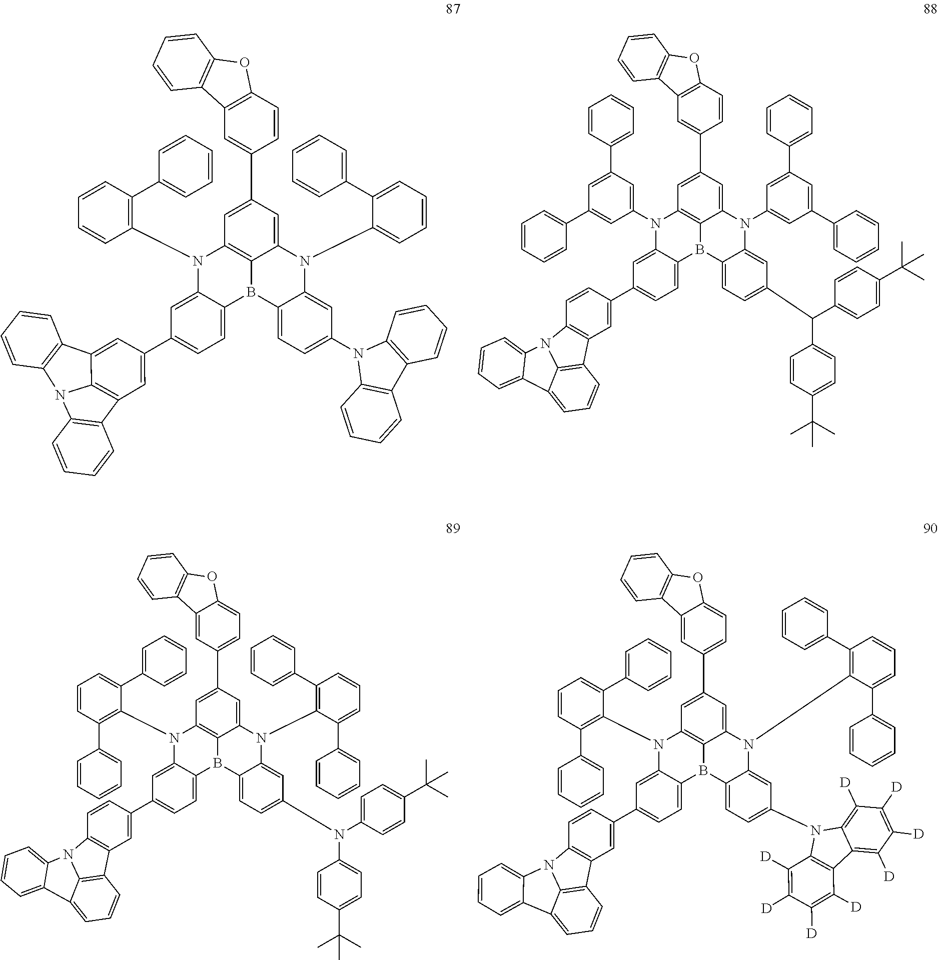 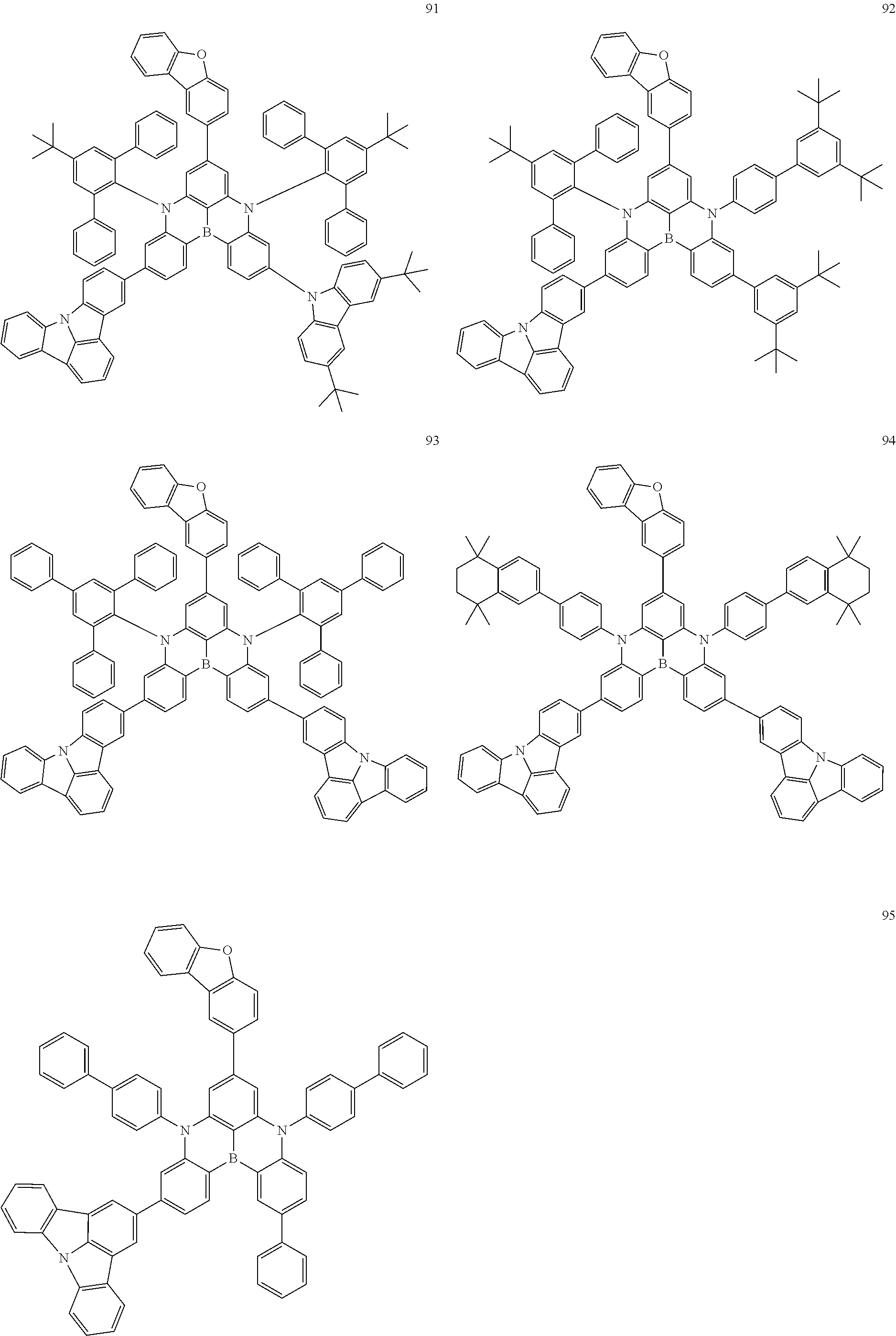 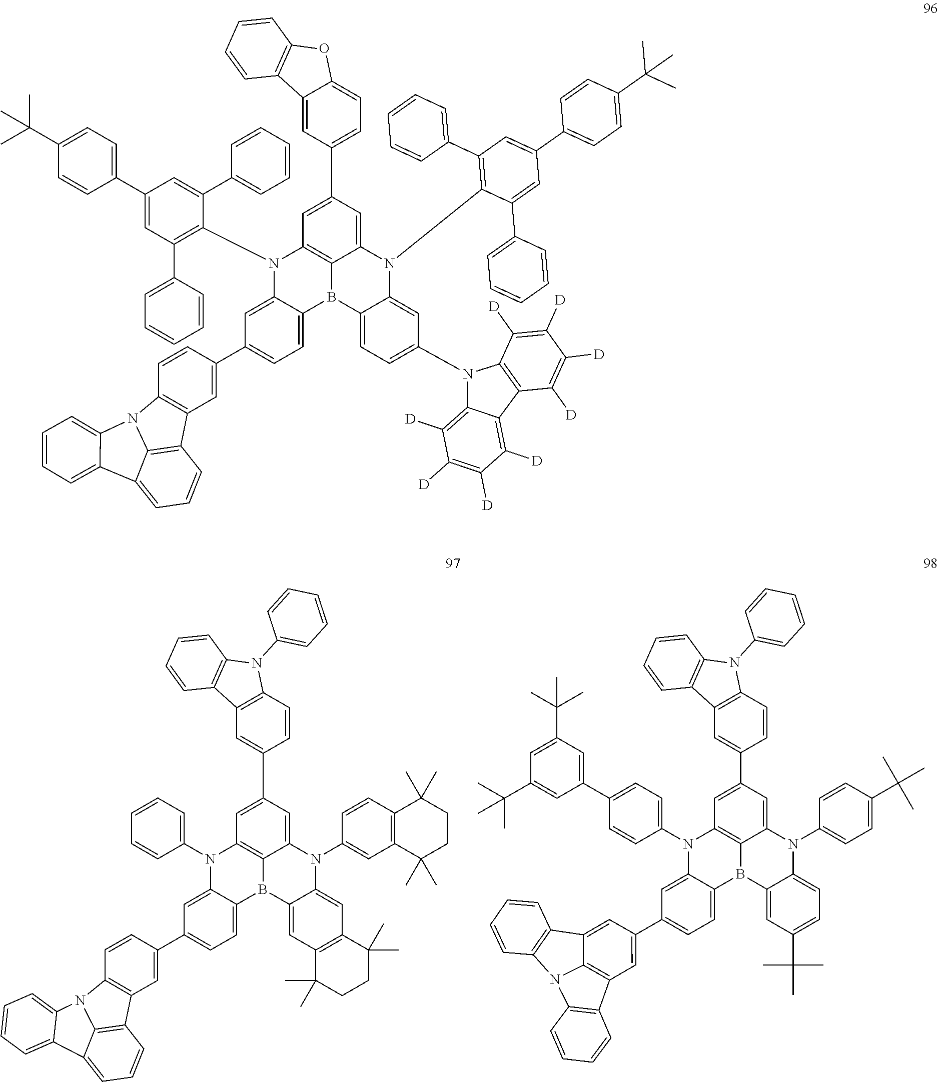 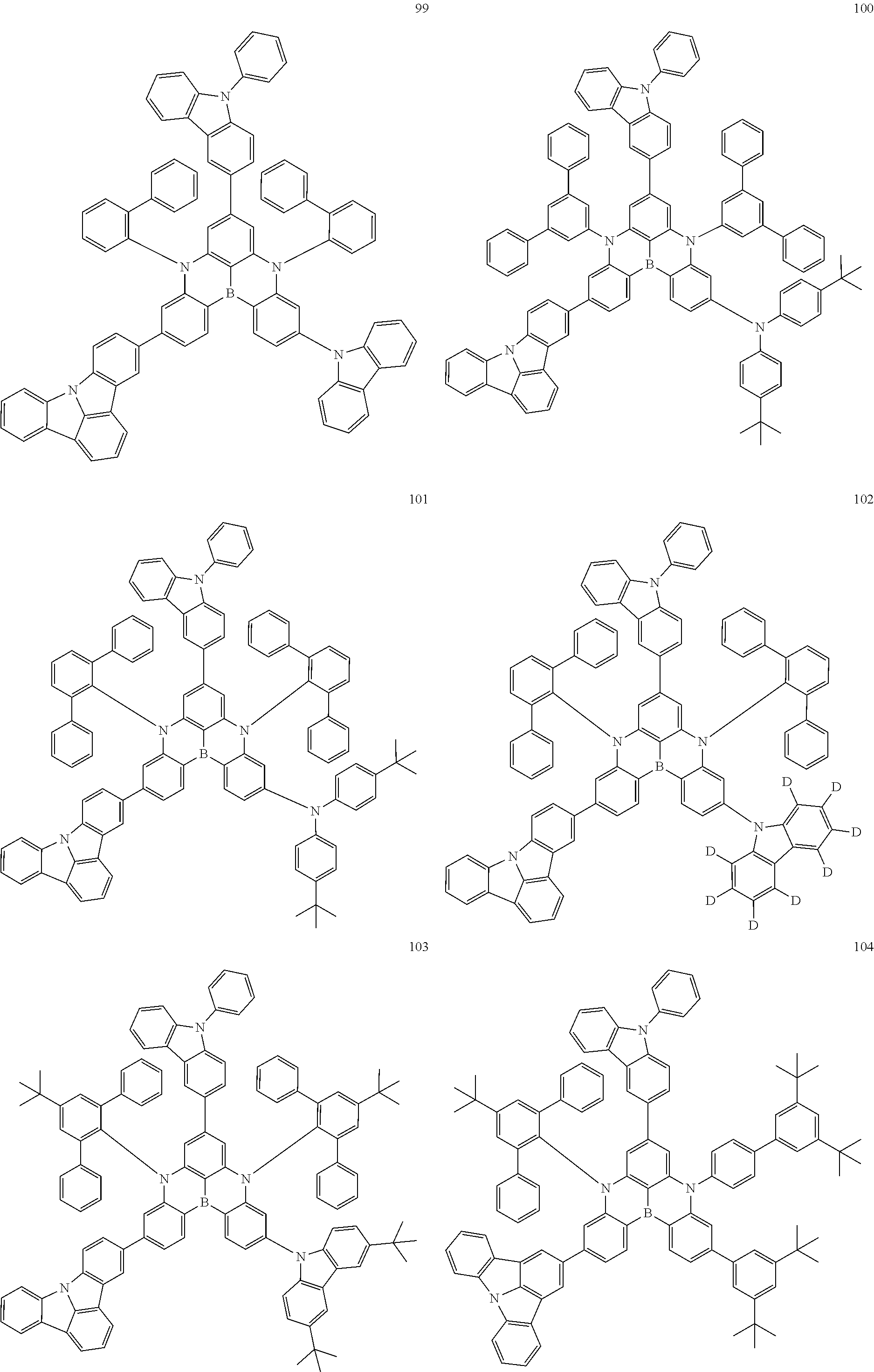 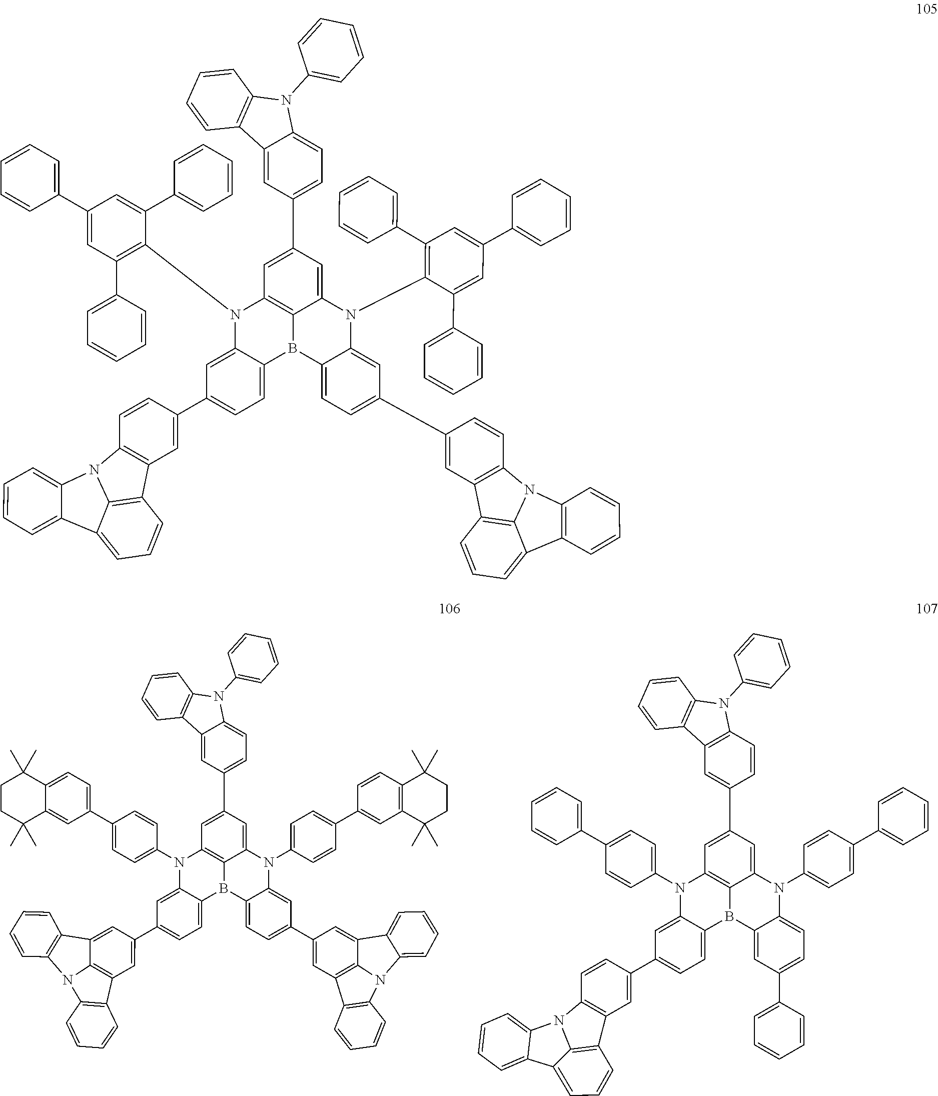 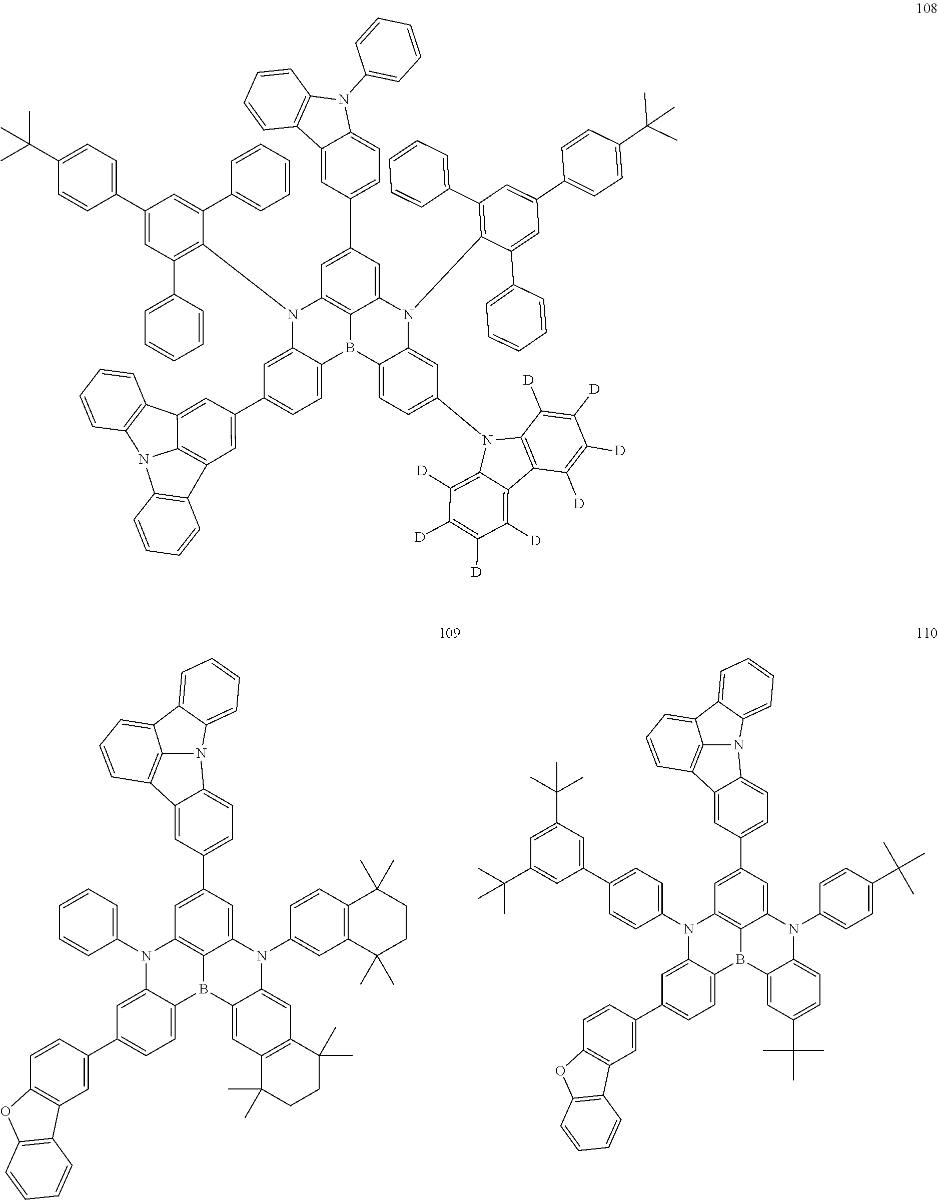 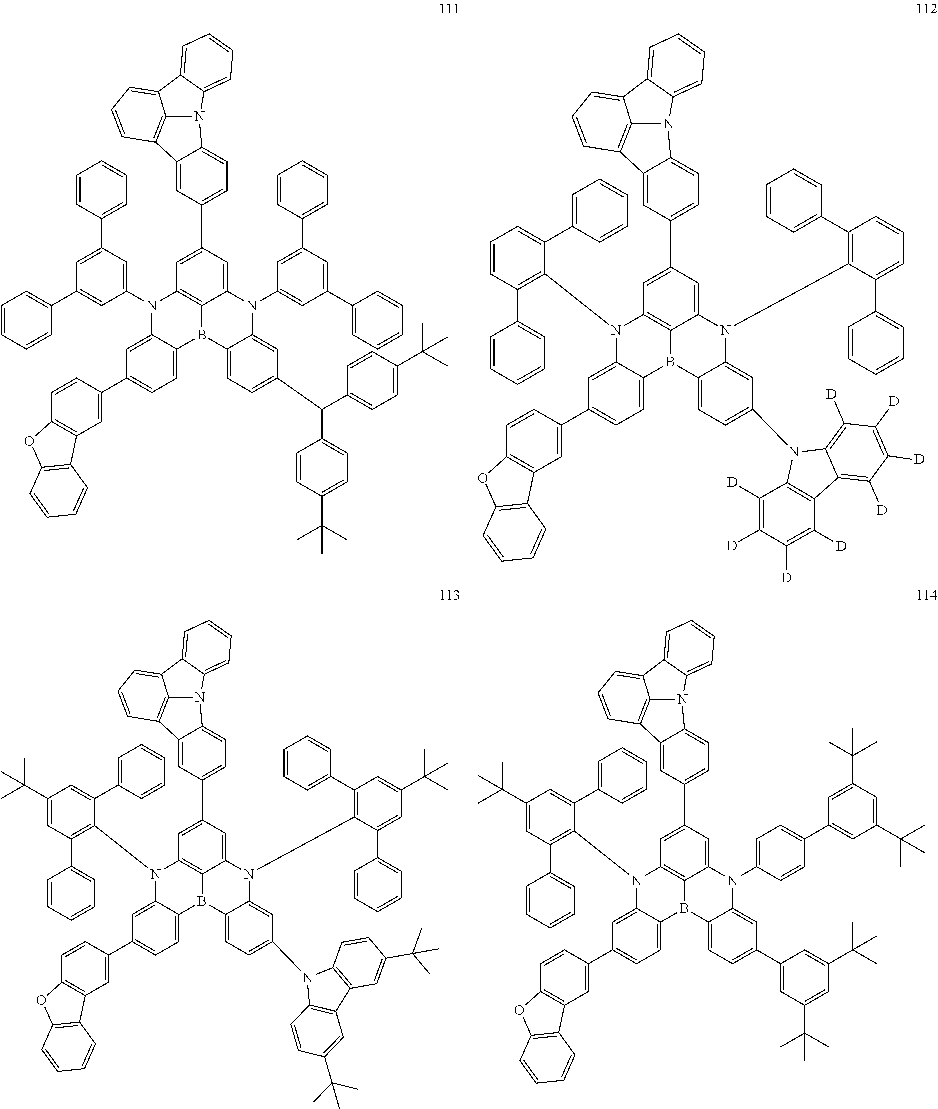 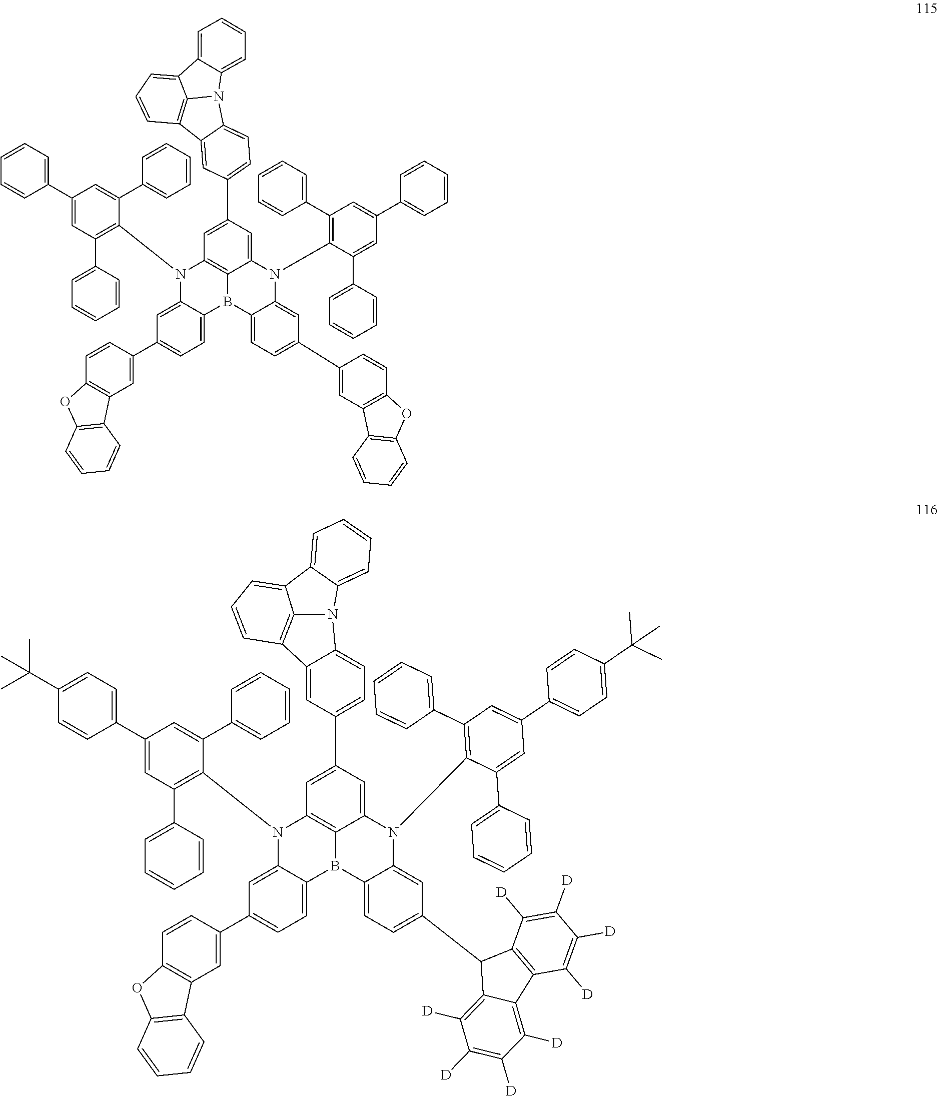 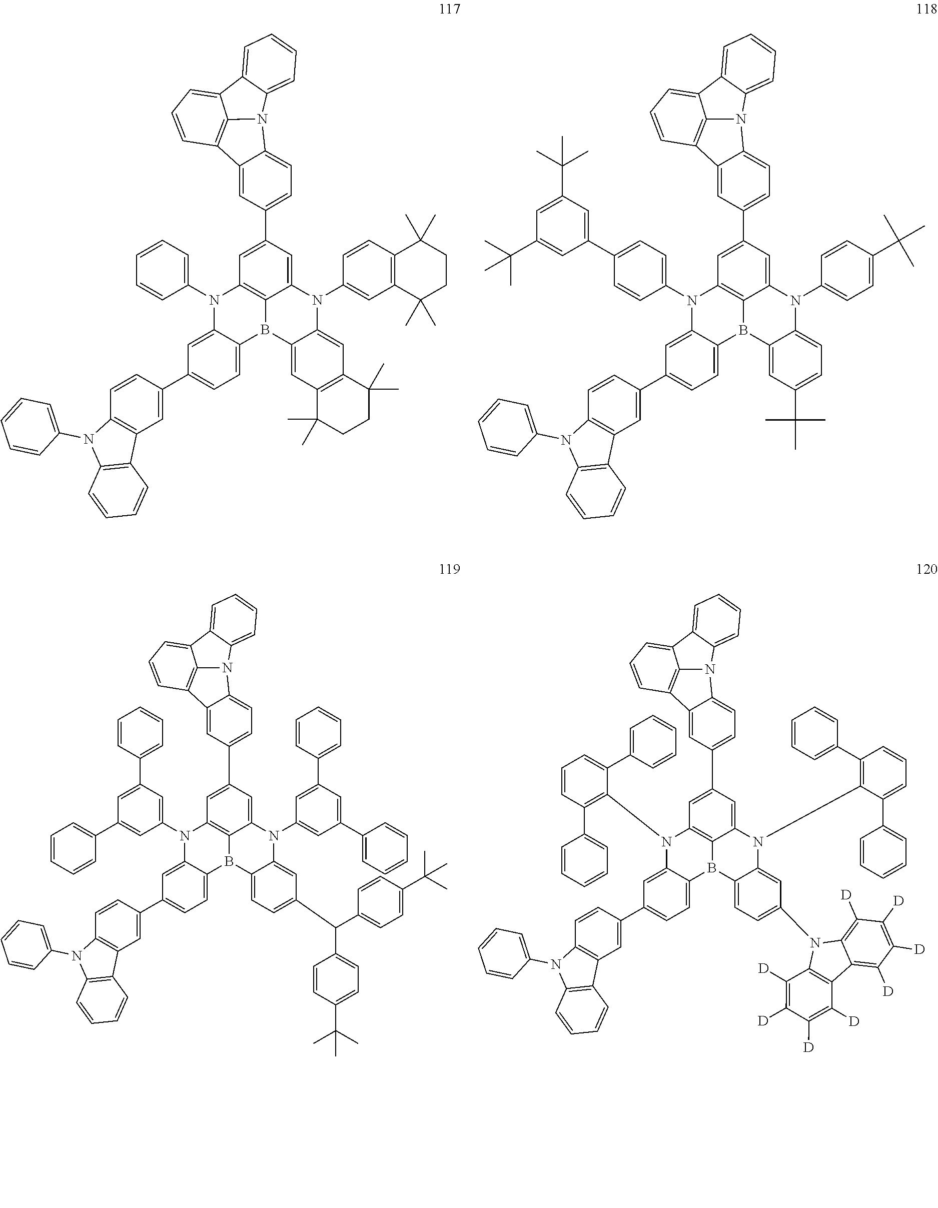 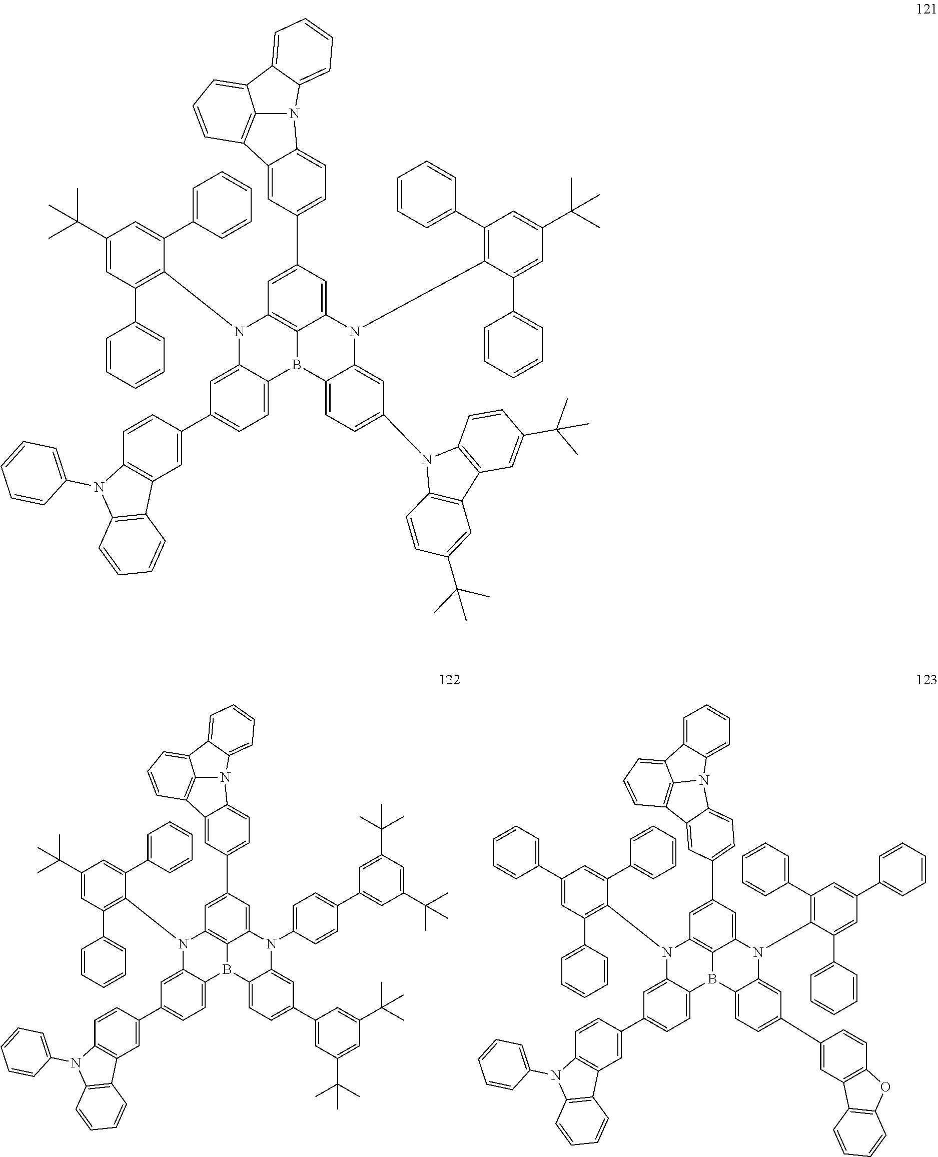 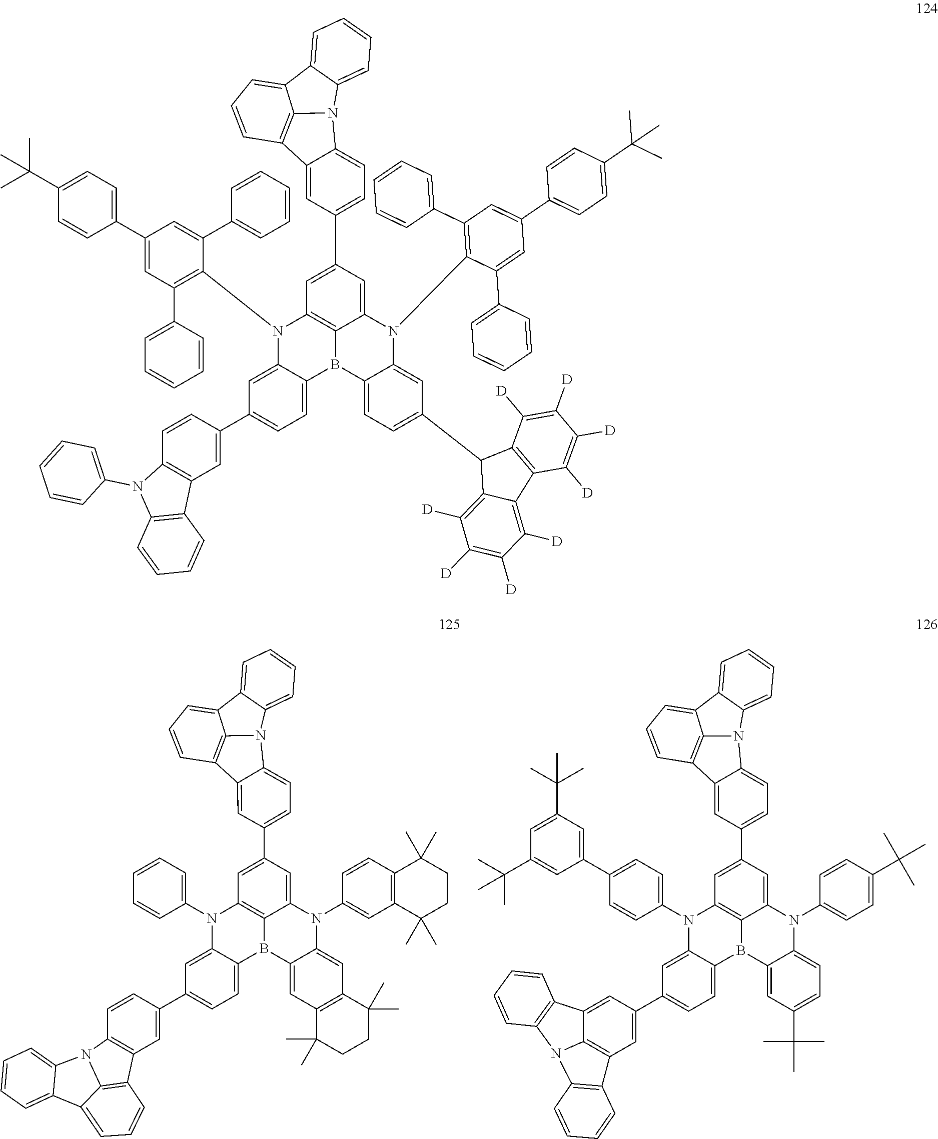 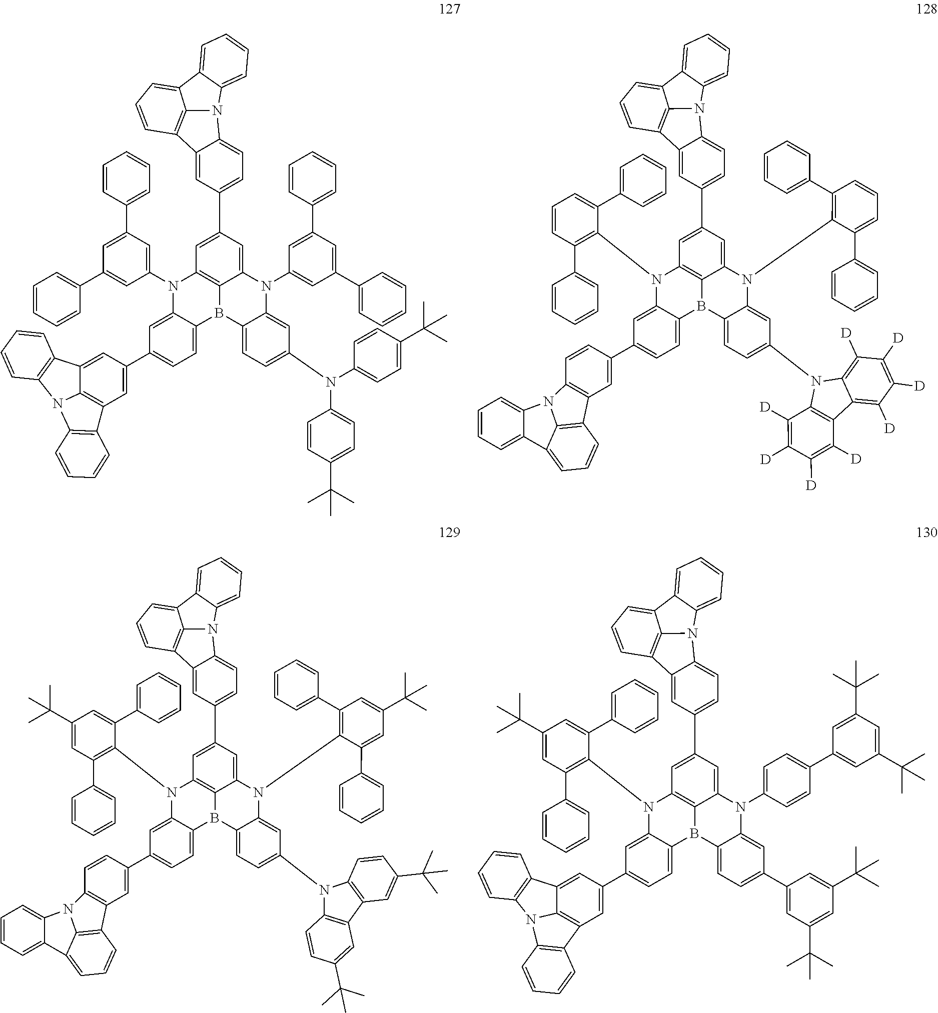 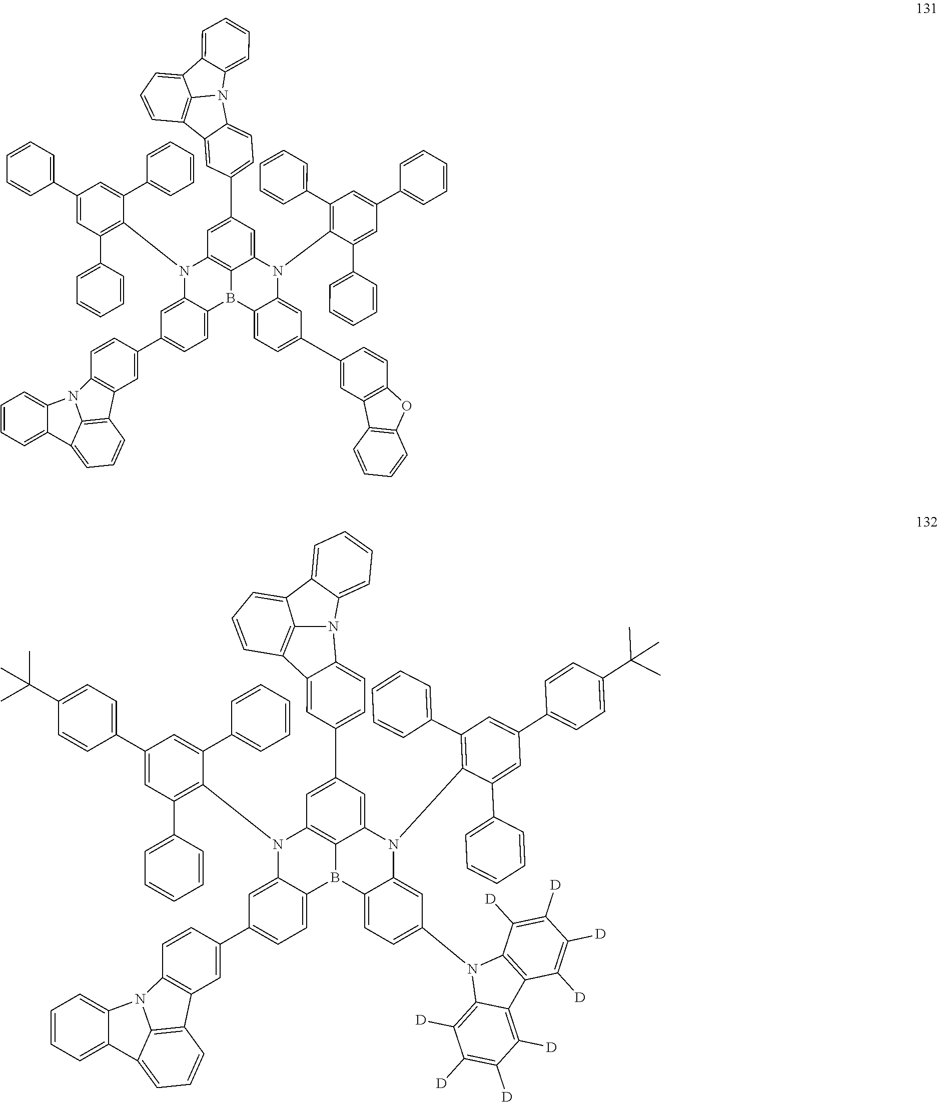 [SMILES: c1ccc(-c2cc(-c3ccccc3)c(N3c4cc(-c5ccc6oc7ccccc7c6c5)ccc4B4c5ccc(-c6ccc7c(c6)c6cccc8c9ccccc9n7c86)cc5N(c5c(-c6ccccc6)cc(-c6ccccc6)cc5-c5ccccc5)c5cc(-c6ccc7c(c6)c6cccc8c9ccccc9n7c86)cc3c54)c(-c3ccccc3)c2)cc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccc(C(C)(C)C)cc3)cc1-c1ccccc1)c1cc(-c3ccc4c(c3)c3cccc5c6ccccc6n4c53)cc3c1B2c1ccc(-c2ccc4c(c2)c2cccc5c6ccccc6n4c52)cc1N3c1c(-c2ccccc2)cc(-c2ccc(C(C)(C)C)cc2)cc1-c1ccccc1] 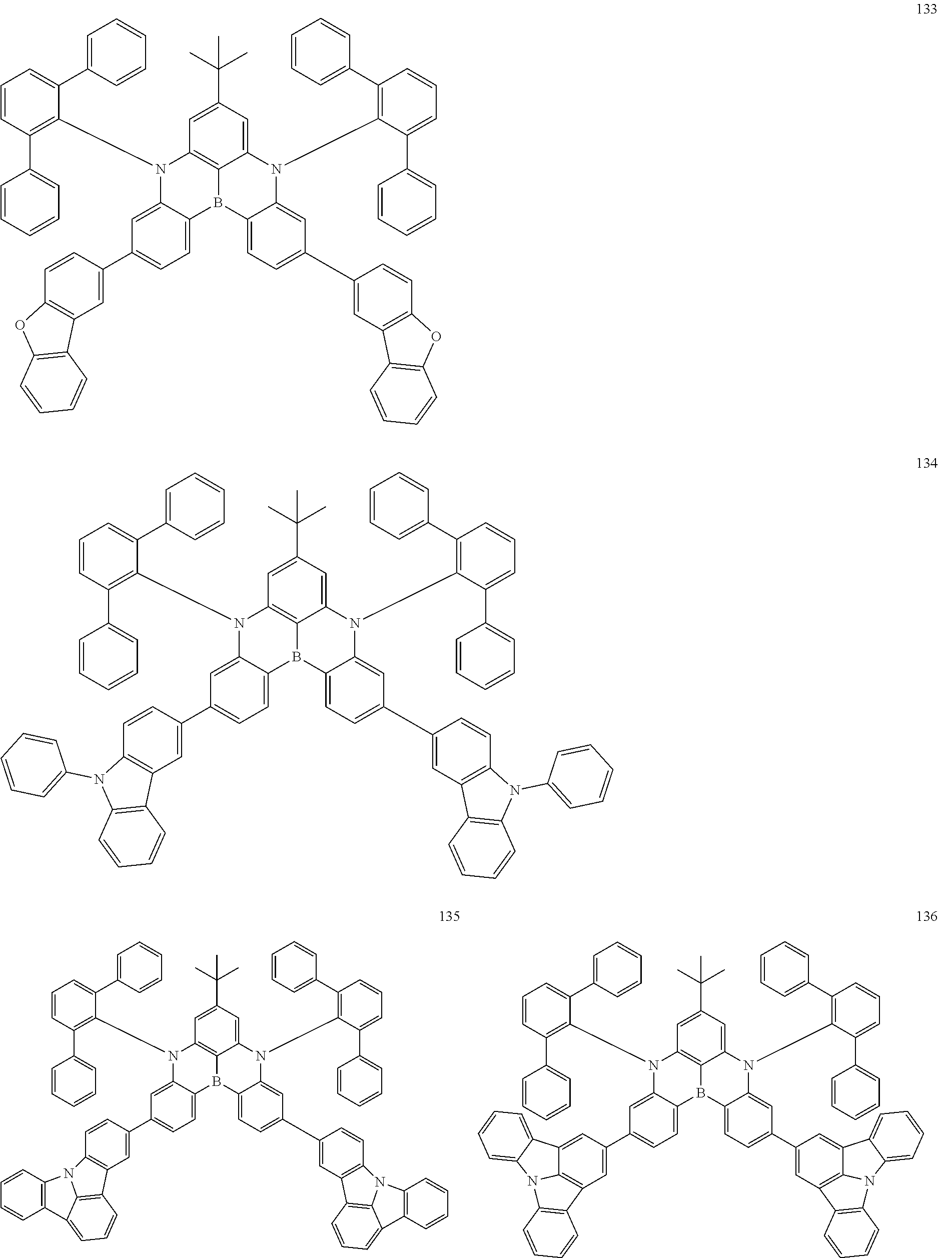 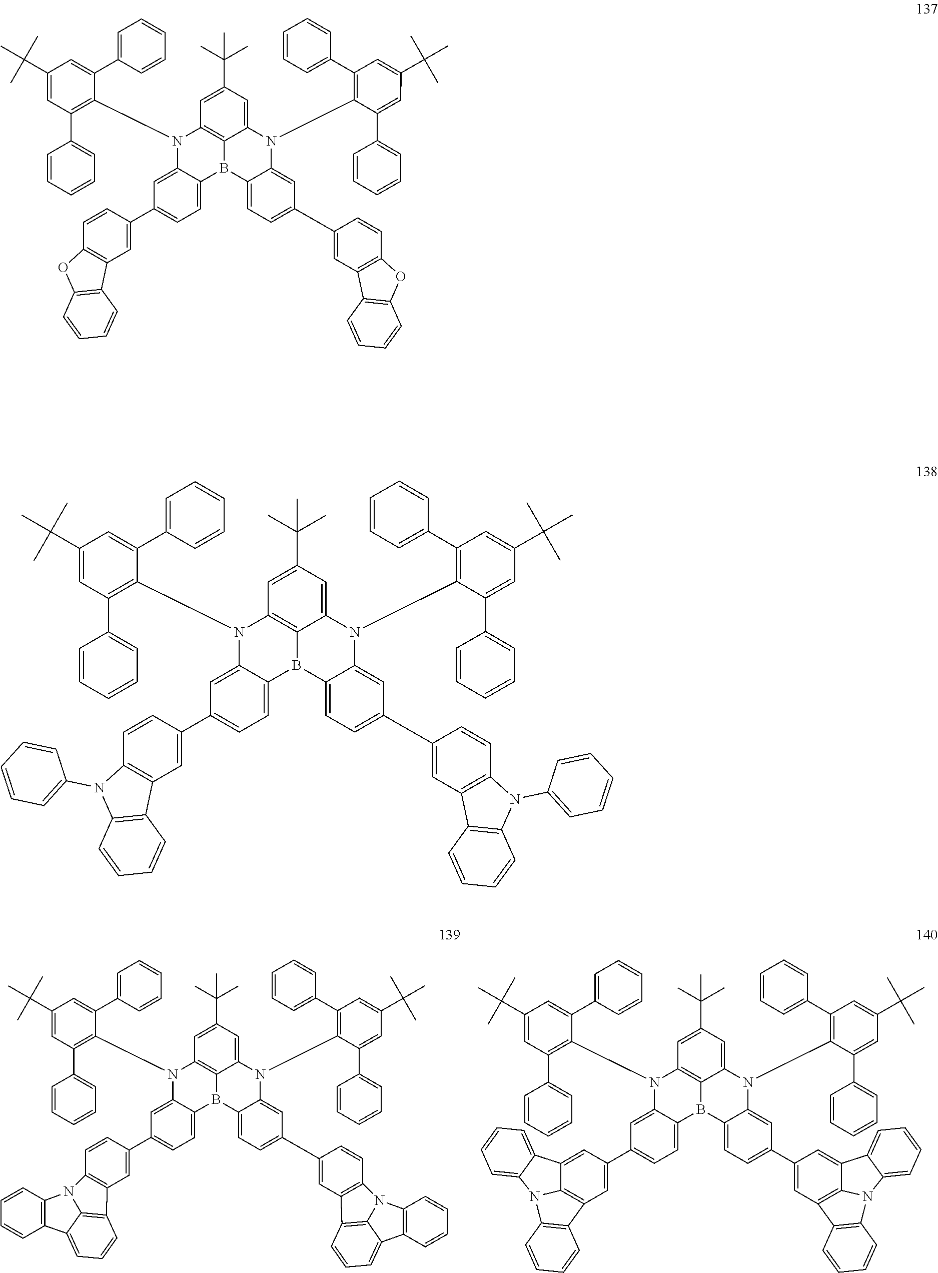 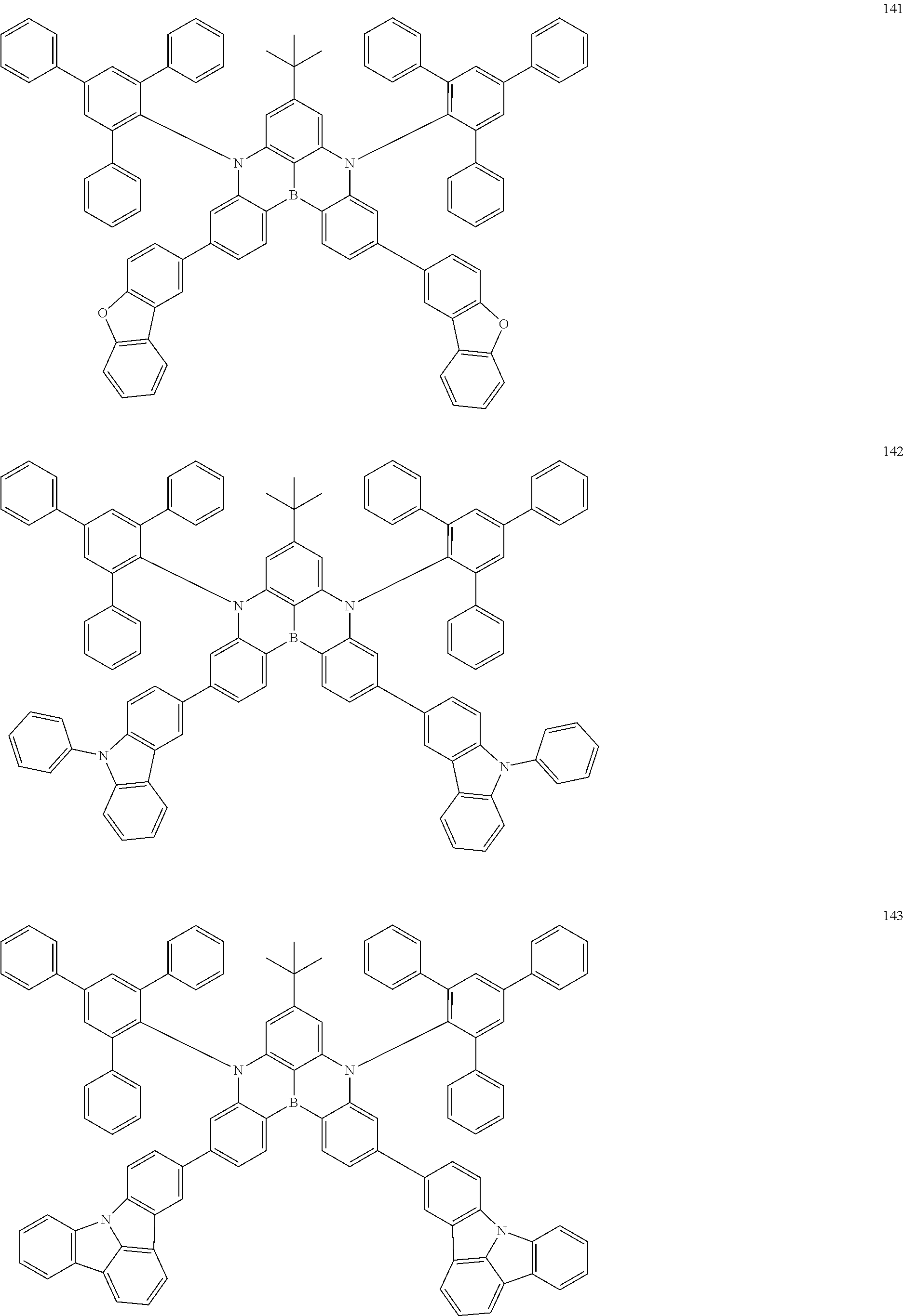 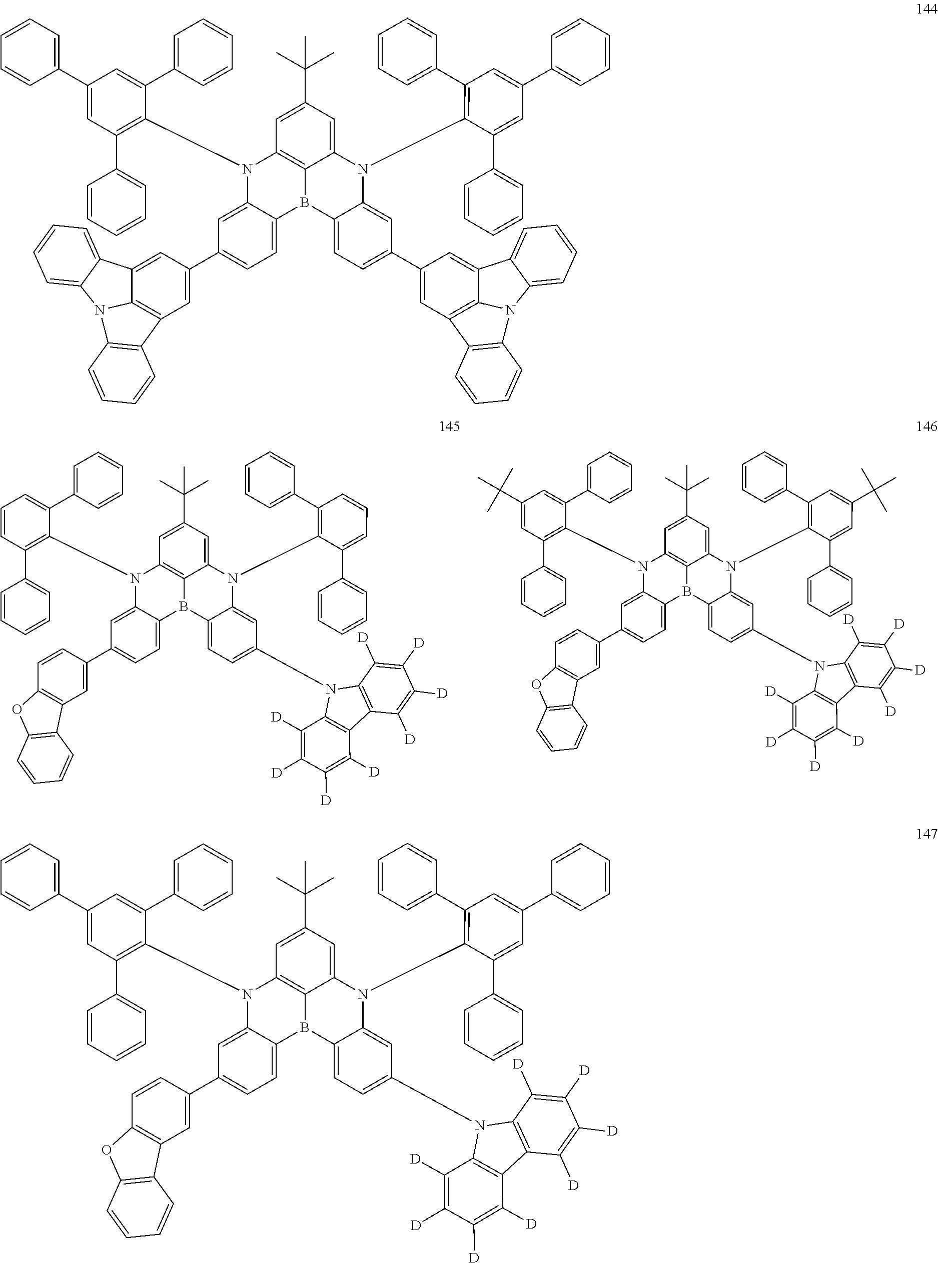 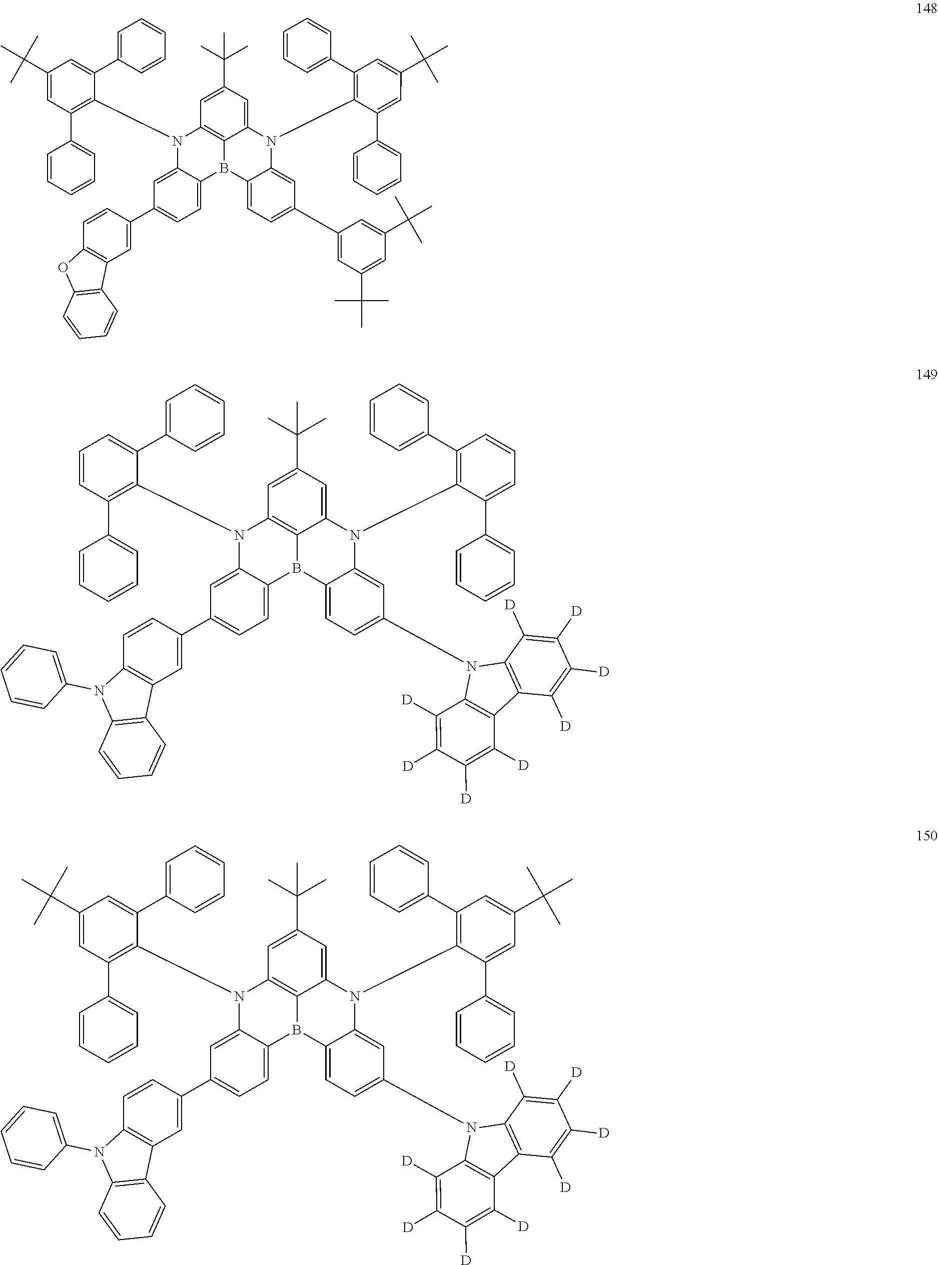 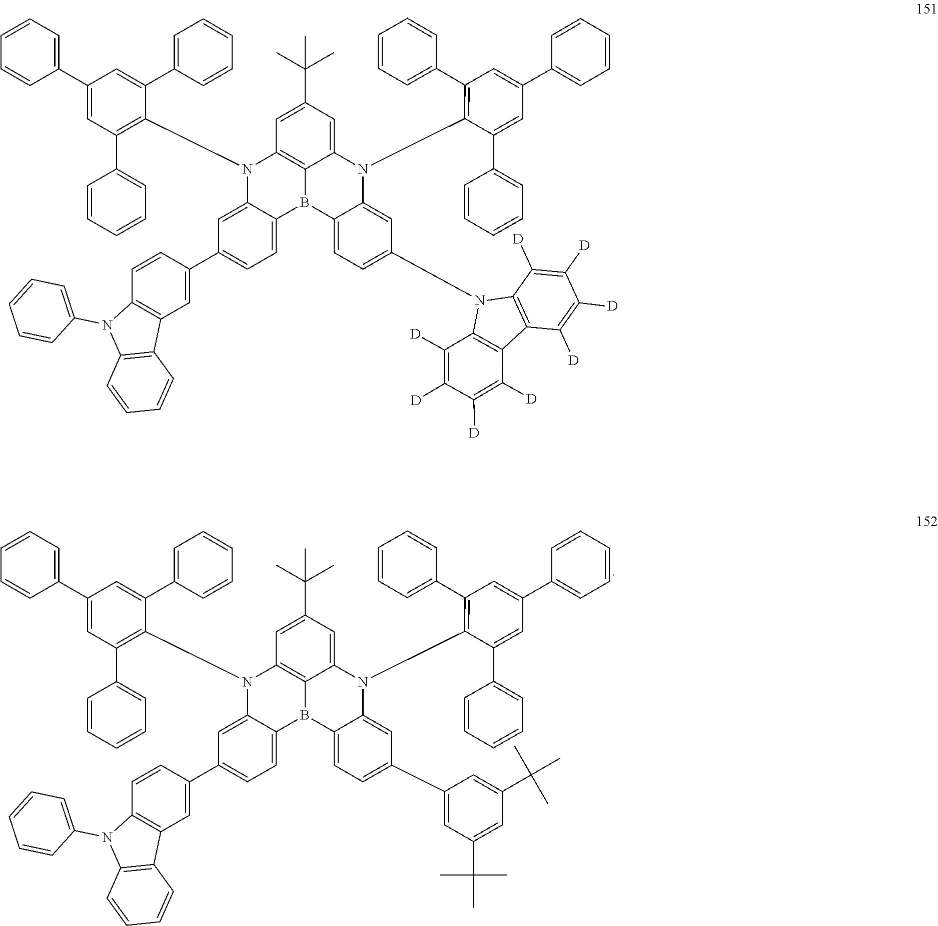 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(C(C)(C)C)cc3c1B2c1ccc(-c2ccc4c(c2)c2ccccc2n4-c2ccccc2)cc1N3c1c(-c2ccccc2)cc(-c2ccccc2)cc1-c1ccccc1 ; CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(-c3ccc5c(c3)c3ccccc3n5-c3ccccc3)cc2N4c2c(-c3ccccc3)cc(-c3ccccc3)cc2-c2ccccc2)cc(C(C)(C)C)c1]
